(19) United States
(12) Patent Application Publication
(10) Pub. No.: US 2018/0190679 A1
(43) Pub. Date: Jul. 5, 2018

(54) THIN FILM TRANSISTOR SUBSTRATE AND METHOD FOR MANUFACTURING SAME

(71) Applicant: Mitsubishi Electric Corporation, Tokyo (JP)

(72) Inventors: Kazunori INOUE, Kumamoto (JP); Ken IMAMURA, Kumamoto (JP); Naoki TSUMURA, Kumamoto (JP); Koji ODA, Kumamoto (JP)

(73) Assignee: Mitsubishi Electric Corporation, Tokyo (JP)

(21) Appl. No.: 15/736,259

(22) PCT Filed: Sep. 8, 2016
(86) PCT No.: PCT/JP2016/076446

§ 371 Date: Dec. 13, 2017

(30) Foreign Application Priority Data
Sep. 11, 2015 (JP) 2015-179767

(51) Int. Cl. H01L 27/12; H01L 29/786

(52) U.S. Cl. CPC H01L 27/1225; H01L 27/1288; G02F 1/1368; H01L 29/78633; H01L 27/124

(57) ABSTRACT

The present invention relates to a TFT substrate, and a pixel includes a gate electrode selectively provided on a substrate, a gate insulating film covering the gate electrode, a semiconductor channel layer selectively provided on the gate insulating film, a protective insulating film provided on the semiconductor channel layer, a first interlayer insulating film provided on the substrate, a source electrode and a drain electrode that are separated from each other and directly in contact with the semiconductor channel layer via respective contact holes penetrating the first interlayer insulating film and the protective insulating film, and a pixel electrode extending from the drain electrode. A first light shielding film is provided on the protective insulating film to overlap with at least a channel region in plan view, and a second light shielding film is provided on the source electrode and the drain electrode to overlap with the semiconductor channel layer and the first light shielding film in plan view.

### TECHNICAL FIELD

The present invention relates to a TFT active matrix substrate using a thin film transistor (TFT) as a switching device (thin film transistor substrate: hereinafter referred to as “TFT substrate”) and a method for manufacturing the same.

### BACKGROUND ART

A TFT substrate is used, for example, in an electro-optical device such as a display device (liquid crystal display device) using liquid crystal. A semiconductor device such as a TFT has characteristics of low power consumption and thin type, and has been actively applied to flat panel displays.

Liquid crystal display devices (LCDs) include a simple matrix LCD and a TFT-LCD using a TFT as a switching device. Specifically, the TFT-LCD is superior than a cathode-ray tube (CRT) and a simple matrix LCD in portability and display quality, and has been widely put into practical use in a display product such as a mobile computer, a notebook computer, and a television.

Generally, the TFT-LCD includes a liquid crystal display panel having a configuration in which a liquid crystal layer is interposed between a TFT substrate equipped with a plurality of TFTs arranged in an array state and a counter substrate equipped with a color filter and the like. A light polarizing plate is provided on each of the front side and back side of the liquid crystal display panel, and a backlight is provided on the further outside of one of them. This configuration enables achievement of good color display.

Driving methods of liquid crystal in a liquid crystal display device include a vertical electric field method such as twisted nematic (TN) mode and vertical alignment (VA) mode, and a lateral electric field method such as in plane switching (IPS) mode (“IPS” is a registered trademark) and fringe field switching (FFS) mode. Generally, a liquid crystal display device of the lateral electric field method can achieve high viewing angle, high definition, and high brightness as compared with that of the vertical electric field method, and has been becoming mainstream in a small and medium sized panel such as in car display equipment, a smart phone, and a tablet.

In a liquid crystal display panel of vertical electric field method, a pixel electrode to which a voltage depending on image signal is applied is arranged on a TFT substrate, and a common electrode to be fixed at a constant electric potential (common electric potential) is arranged on a counter electrode. Consequently, the liquid crystal in a liquid crystal layer is driven by an electric field substantially perpendicular to the surface of the liquid crystal display panel.

In contrast, in a liquid crystal display panel of lateral electric field method, both a pixel electrode and a common electrode are arranged on a TFT substrate, and the liquid crystal in a liquid crystal layer is driven by an electric field substantially parallel to the surface of the liquid crystal display panel. Specifically, in the TFT substrate of FFS mode, a pixel electrode and a common electrode are arranged to oppose vertically via an insulating film. Any of the pixel electrode and the common electrode may be formed to be located on the lower side, but the one arranged on the lower side is formed in a flat plate shape, and the one arranged on the upper side (the side nearer to a liquid crystal layer) is formed in a grid shape having slits or a comb tooth shape having slits.

Conventionally, in a switching device of a TFT substrate for a liquid crystal display device, amorphous silicon (a-Si) has been used for a semiconductor film for forming an active layer (channel layer) of TFT. Recently, development of a TFT using oxide semiconductor for an active layer has been actively performed. An oxide semiconductor has a mobility higher than that of conventional amorphous silicon, and has an advantage of providing a small and high performance TFT.

As the oxide semiconductor, zinc oxide (ZnO) series material and amorphous InGaZnO series material in which gallium oxide (Ga₂O₃) and indium oxide (In₂O₃) are added to zinc oxide are mainly used. Patent Documents 1 and 2 and Non-Patent Document 1 disclose such techniques.

Such oxide semiconductor materials are generally capable of being etched by weak acid series solution such as oxalic acid and carboxylic acid similar to oxide conductor such as amorphous ITO (indium oxide (In₂O₃)+tin oxide (SnO₂)) and amorphous InZnO (indium oxide (In₂O₃)+zinc oxide (ZnO)) that are transparent conductors, and has an advantageous in that pattern processing is easy.

However, such oxide semiconductor materials also suffer etching damage by acid series solution used in etching processing of a typical metal film (e.g., Cr, Ti, Mo, Ta, Al, Cu, and an alloy thereof) used for a source electrode and a drain electrode of a TFT, deteriorating their properties in some cases. Furthermore, oxide semiconductor materials are disadvantageously dissolved in the acid series solution depending on their types in some cases. Therefore, when a TFT in which a source electrode and a drain electrode are arranged on a channel layer configured by an oxide semiconductor (generally called back channel etching (BCE) type TFT) is formed as disclosed in, for example, (b) portion of FIG. 11 of Patent Document 2, the channel layer is damaged by the acid series solution used for processing of the source electrode and the drain electrode to unfortunately deteriorate TFT properties in some cases. Furthermore, when forming a metal film that becomes a source electrode and a drain electrode on an oxide semiconductor film (channel layer), the channel layer is damaged by oxidation-reduction reaction at its boundary face to unfortunately deteriorate properties of the TFT in some cases.

In order to solve the problem, there is an idea of using a TFT configuration in which a protective insulating film is formed on the upper layer of a semiconductor film as illustrated in Patent Document 3. This TFT configuration makes it possible to prevent the oxide semiconductor film from being damaged or disappeared by etching for the processing to form a metal film into a source electrode and a drain electrode. The TFT having the configuration is generally called etching stopper or etching stopper (ES) type TFT.

For example, FIG. 1 and FIG. 2 of Patent Document 1 using a metallic oxide such as ZnO for a semiconductor film discloses an ES type TFT substrate of TN mode in which a channel protective film (channel protective layer) made of oxide silicon or nitride silicon is provided on a semiconductor film (channel layer) made of metallic oxide.

Herein, when a TFT substrate of TN mode having a back channel etching type TFT in which an a-Si semiconductor film is used as a channel layer as disclosed in, for example, FIG. 1 and FIG. 2 of Patent Document 5 is produced, the manufacturing is typically possible through five photolithography steps in total that are (1) step of forming a gate electrode, (2) step of forming a gate insulating film and a channel layer, (3) step of forming a source electrode and a drain electrode, (4) step of forming a contact hall in a protective insulating film, and (5) step of forming a pixel electrode.

Furthermore, as disclosed in, for example, FIG. 2 and FIG. 3 of Patent Document 6, when manufacturing an FFS-TFT substrate equipped with a back channel etching type TFT, the manufacturing is possible through seven photolithography steps in total that are (1) step of forming a gate electrode, (2) step of forming a gate insulating film and a channel layer, (3) step of forming a source electrode and a drain electrode, (4) step of forming a contact hole in a protective insulating film, (5) step of forming a pixel electrode, (6) step of forming a contact hole in an interlayer insulating film, and (7) step of forming a common electrode.

However, in order to manufacture a TFT substrate equipped with a typical etch stopper type TFT in which oxide semiconductor is used for its channel layer, it is necessary to add at least one photolithography step to form a protective insulating film on the oxide semiconductor film. Therefore, there is a problem in that production capability is reduced to increase production cost.

Furthermore, although an oxide semiconductor material has been conventionally considered to be difficult to change its properties because of little absorption with respect to visible light because of generally having translucency under the condition where energy band gap is not less than 3 eV, it has been pointed that there is a problem in that its properties are deteriorated with respect to visual light in a short wavelength region as disclosed in, for example, Non-Patent Document 2 and the like.

### PRIOR ART DOCUMENTS

### Patent Documents

Patent Document 1: Japanese Patent Application Laid-Open No. 2005-77822
Patent Document 2: Japanese Patent Application Laid-Open No. 2007-281409
Patent Document 3: Japanese Patent Application Laid-Open No. 62-235784 (1987)
Patent Document 4: PCT International Publication No. 2011/077607
Patent Document 5: Japanese Patent Application Laid-Open No. 10-268353 (1998)
Patent Document 6: Japanese Patent Application Laid-Open No. 2009-151285

### Non-Patent Documents

Non-Patent Document 1: Written by Kenji Nomura et al. “Room-temperature fabrication of transparent flexible thin-film transistors using amorphous oxide semiconductors”, Nature 2004, Vol. 432, page 488 to page 492
Non-Patent Document 2: Written by Dharam Pal Gosain, et al. “Instability of Amorphous Indium Gallium Zinc Oxide Thin Film Transistors under Light Illumination”, Japanese Journal of Applied Physics 2009, Vol. 48, page 03B018-1 to page 03B018-5

### SUMMARY

### Problems to be Solved by the Invention

For example, Patent Document 4 proposes a method of manufacturing an etch stopper type TFT substrate of TN mode by using four photolithography steps in total that are (1) step of forming a gate electrode, (2) step of forming a channel layer using an oxide semiconductor, (3) step of forming a contact hole in a protective insulating film, and (4) step of forming a pixel electrode, a source electrode, and a drain electrode. Note that there is a case that a photolithography step for forming a source wiring to be connected to the source electrode is performed between the step (2) and the step (3) to be five photolithography steps in total.

When a TFT substrate is manufactured by the method disclosed in Patent Document 4, a first insulating film in the same layer as the gate insulating film and a second insulating film in the same layer as the protective insulating film exist below the source wiring to be connected to the source electrode of a TFT. Furthermore, a step of etching an oxide semiconductor film is performed between the step of forming a film that is a first insulating film and the step of forming a film that is a second insulating film. Consequently, a surface of the first insulating film is damaged by the step of etching the oxide semiconductor film, which can deteriorate adhesiveness between the first insulating film and the second insulating film. This readily cases disconnection of the source wiring at a portion where adhesiveness between the first insulating film and the second insulating is bad during using the liquid crystal display device for a long period, disadvantageously lowering reliability.

Although Patent Document 4 describes a method of reducing the number of photolithography steps for LCD using an etch stopper type TFT, there is no description about methods of reducing the number of photolithography steps and production cost when manufacturing an LCD of lateral electric field method (specifically FFS-LCD). Furthermore, there is no description about a method of preventing property deterioration (optical deterioration) in the case where light is incident on the oxide semiconductor film. Note that, when a light shielding film is newly formed to prevent the property deterioration, the number of photolithography steps disadvantageously increases.

The present invention has been conceived to solve the above described problems, and an object thereof is to provide a TFT substrate and a method for manufacturing the same capable of preventing property deterioration of a channel layer due to backlight light, external light, and scattering light thereof, capable of preventing lowering of adhesiveness between layers, and capable of suppressing increase of the number of photolithography steps when an oxide semiconductor is used for a channel layer of a TFT in a TFT substrate having an etch stopper type TFT and a TFT substrate of an LCD of lateral electric field method (specifically, FFS-LCD)

### Means to Solve the Problems

A thin film transistor substrate according to the present invention is a thin film transistor substrate in which a plurality of pixels are provided in a matrix manner, and each of the pixels includes a gate electrode selectively provided on a substrate, a gate insulating film covering the gate electrode, a semiconductor channel layer formed by an oxide semiconductor film and selectively provided on the gate insulating film, a protective insulating film provided on the semiconductor channel layer, a first interlayer insulating film provided on the substrate to cover the protective insulating film and the semiconductor channel layer, a source electrode and a drain electrode that are formed by a transparent conductive film, separated from each other, and directly in contact with the semiconductor channel layer via respective contact holes penetrating the first interlayer insulating film and the protective insulating film, and a pixel electrode extending from the drain electrode. A region between the source electrode and the drain electrode in the semiconductor channel layer forms a channel region, a first light shielding film is provided on the protective insulating film to overlap with at least the channel region in plan view, and a second light shielding film is provided on the source electrode and the drain electrode to overlap with the semiconductor channel layer and the first light shielding film in plan view.

### Effects of the Invention

According to the thin film transistor substrate according to the present invention, the semiconductor channel layer is configured such that its entire region is shielded from light also by the first and second light shielding films on the upper side of the semiconductor channel layer in addition to light shielding by the gate electrode on the lower side of the semiconductor channel layer, making it possible to prevent deterioration (optical deterioration) of the channel layer due to absorption of backlight light during operating a liquid crystal display device and external light.

### BRIEF DESCRIPTION OF DRAWINGS

FIG. 1 is a plan view illustrating a configuration of a TFT substrate according to a first embodiment of the present invention.

FIG. 2 is a cross sectional view illustrating the configuration of the TFT substrate according to the first embodiment of the present invention.

FIG. 3 is a plan view illustrating a manufacturing method of the TFT substrate according to the first embodiment of the present invention.

FIG. 4 is a cross sectional view illustrating the manufacturing method of the TFT substrate according to the first embodiment of the present invention.

FIG. 5 is a plan view illustrating the manufacturing method of the TFT substrate according to the first embodiment of the present invention.

FIG. 6 is a cross sectional view illustrating the manufacturing method of the TFT substrate according to the first embodiment of the present invention.

FIG. 7 is a plan view illustrating the manufacturing method of the TFT substrate according to the first embodiment of the present invention.

FIG. 8 is a cross sectional view illustrating the manufacturing method of the TFT substrate according to the first embodiment of the present invention.

FIG. 9 is a plan view illustrating the manufacturing method of the TFT substrate according to the first embodiment of the present invention.

FIG. 10 is a cross sectional view illustrating the manufacturing method of the TFT substrate according to the first embodiment of the present invention.

FIG. 11 is a plan view illustrating the manufacturing method of the TFT substrate according to the first embodiment of the present invention.

FIG. 12 is a cross sectional view illustrating the manufacturing method of the TFT substrate according to the first embodiment of the present invention.

FIG. 13 is a plan view illustrating a configuration of a TFT substrate according to a second embodiment of the present invention.

FIG. 14 is a cross sectional view illustrating the configuration of the TFT substrate according to the second embodiment of the present invention.

FIG. 15 is a plan view illustrating a manufacturing method of the TFT substrate according to the second embodiment of the present invention.

FIG. 16 is a cross sectional view illustrating the manufacturing method of the TFT substrate according to the second embodiment of the present invention.

FIG. 17 is a plan view illustrating the manufacturing method of the TFT substrate according to the second embodiment of the present invention.

FIG. 18 is a cross sectional view illustrating the manufacturing method of the TFT substrate according to the second embodiment of the present invention.

FIG. 19 is a cross sectional view illustrating the manufacturing method of the TFT substrate according to the second embodiment of the present invention.

FIG. 20 is a cross sectional view illustrating the manufacturing method of the TFT substrate according to the second embodiment of the present invention.

FIG. 21 is a cross sectional view illustrating the manufacturing method of the TFT substrate according to the second embodiment of the present invention.

FIG. 22 is a cross sectional view illustrating the manufacturing method of the TFT substrate according to the second embodiment of the present invention.

FIG. 23 is a plan view illustrating the manufacturing method of the TFT substrate according to the second embodiment of the present invention.

FIG. 24 is a cross sectional view illustrating the manufacturing method of the TFT substrate according to the second embodiment of the present invention.

FIG. 25 is a plan view illustrating a configuration of a TFT substrate according to a modification of the second embodiment of the present invention.

FIG. 26 is a cross sectional view illustrating the configuration of the TFT substrate according to the modification of the second embodiment of the present invention.

FIG. 27 is a plan view illustrating a manufacturing method of the TFT substrate according to the modification of the second embodiment of the present invention.

FIG. 28 is a cross sectional view illustrating the manufacturing method of the TFT substrate according to the modification of the second embodiment of the present invention.

FIG. 29 is a plan view illustrating the manufacturing method of the TFT substrate according to the modification of the second embodiment of the present invention.

FIG. 30 is a cross sectional view illustrating the manufacturing method of the TFT substrate according to the modification of the second embodiment of the present invention.

FIG. 31 is a plan view illustrating the manufacturing method of the TFT substrate according to the modification of the second embodiment of the present invention.

FIG. 32 is a cross sectional view illustrating the manufacturing method of the TFT substrate according to the modification of the second embodiment of the present invention.

FIG. 33 is a plan view illustrating a configuration of a TFT substrate according to a third embodiment of the present invention.

FIG. 34 is a cross sectional view illustrating the configuration of the TFT substrate according to the third embodiment of the present invention.

FIG. 35 is a plan view illustrating a manufacturing method of the TFT substrate according to the third embodiment of the present invention.

FIG. 36 is a cross sectional view illustrating the manufacturing method of the TFT substrate according to the third embodiment of the present invention.

FIG. 37 is a plan view illustrating the manufacturing method of the TFT substrate according to the third embodiment of the present invention.

FIG. 38 is a cross sectional view illustrating the manufacturing method of the TFT substrate according to the third embodiment of the present invention.

FIG. 39 is a plan view illustrating the manufacturing method of the TFT substrate according to the third embodiment of the present invention.

FIG. 40 is a cross sectional view illustrating the manufacturing method of the TFT substrate according to the third embodiment of the present invention.

FIG. 41 is a plan view illustrating a configuration of a TFT substrate according to a modification of the third embodiment of the present invention.

FIG. 42 is a cross sectional view illustrating the configuration of the TFT substrate according to the modification of the third embodiment of the present invention.

FIG. 43 is a plan view illustrating a configuration of a TFT substrate according to a fourth embodiment of the present invention.

FIG. 44 is a cross sectional view illustrating the configuration of the TFT substrate according to the fourth embodiment of the present invention.

FIG. 45 is a plan view illustrating a manufacturing method of the TFT substrate according to the fourth embodiment of the present invention.

FIG. 46 is a cross sectional view illustrating the manufacturing method of the TFT substrate according to the fourth embodiment of the present invention.

FIG. 47 is a plan view illustrating the manufacturing method of the TFT substrate according to the fourth embodiment of the present invention.

FIG. 48 is a cross sectional view illustrating the manufacturing method of the TFT substrate according to the fourth embodiment of the present invention.

FIG. 49 is a plan view illustrating the manufacturing method of the TFT substrate according to the fourth embodiment of the present invention.

FIG. 50 is a cross sectional view illustrating the manufacturing method of the TFT substrate according to the fourth embodiment of the present invention.

FIG. 51 is a plan view illustrating the manufacturing method of the TFT substrate according to the fourth embodiment of the present invention.

FIG. 52 is a cross sectional view illustrating the manufacturing method of the TFT substrate according to the fourth embodiment of the present invention.

FIG. 53 is a cross sectional view illustrating the manufacturing method of the TFT substrate according to the fourth embodiment of the present invention.

FIG. 54 is a plan view illustrating the manufacturing method of the TFT substrate according to the fourth embodiment of the present invention.

FIG. 55 is a cross sectional view illustrating the manufacturing method of the TFT substrate according to the fourth embodiment of the present invention.

FIG. 56 is a plan view illustrating a configuration of a TFT substrate according to a modification of the fourth embodiment of the present invention.

FIG. 57 is a cross sectional view illustrating the configuration of the TFT substrate according to the modification of the fourth embodiment of the present invention.

FIG. 58 is a plan view illustrating a manufacturing method of the TFT substrate according to the modification of the fourth embodiment of the present invention.

FIG. 59 is a cross sectional view illustrating the manufacturing method of the TFT substrate according to the modification of the fourth embodiment of the present invention.

FIG. 60 is a plan view illustrating the manufacturing method of the TFT substrate according to the modification of the fourth embodiment of the present invention.

FIG. 61 is a cross sectional view illustrating the manufacturing method of the TFT substrate according to the modification of the fourth embodiment of the present invention.

FIG. 62 is a plan view illustrating the manufacturing method of the TFT substrate according to the modification of the fourth embodiment of the present invention.

FIG. 63 is a cross sectional view illustrating the manufacturing method of the TFT substrate according to the modification of the fourth embodiment of the present invention.

FIG. 64 is a plan view illustrating the manufacturing method of the TFT substrate according to the modification of the fourth embodiment of the present invention.

FIG. 65 is a cross sectional view illustrating the manufacturing method of the TFT substrate according to the modification of the fourth embodiment of the present invention.

FIG. 66 is a plan view illustrating the manufacturing method of the TFT substrate according to the modification of the fourth embodiment of the present invention.

FIG. 67 is a cross sectional view illustrating the manufacturing method of the TFT substrate according to the modification of the fourth embodiment of the present invention.

FIG. 68 is a cross sectional view illustrating the manufacturing method of the TFT substrate according to the modification of the fourth embodiment of the present invention.

FIG. 69 is a cross sectional view illustrating the manufacturing method of the TFT substrate according to the modification of the fourth embodiment of the present invention.

FIG. 70 is a cross sectional view illustrating the manufacturing method of the TFT substrate according to the modification of the fourth embodiment of the present invention.

FIG. 71 is a plan view illustrating a configuration of a TFT substrate according to a fifth embodiment of the present invention.

FIG. 72 is a cross sectional view illustrating the configuration of the TFT substrate according to the fifth embodiment of the present invention.

FIG. 73 is a plan view illustrating a manufacturing method of the TFT substrate according to the fifth embodiment of the present invention.

FIG. 74 is a cross sectional view illustrating the manufacturing method of the TFT substrate according to the fifth embodiment of the present invention.

FIG. 75 is a plan view illustrating the manufacturing method of the TFT substrate according to the fifth embodiment of the present invention.

FIG. 76 is a cross sectional view illustrating the manufacturing method of the TFT substrate according to the fifth embodiment of the present invention.

FIG. 77 is a plan view illustrating the manufacturing method of the TFT substrate according to the fifth embodiment of the present invention.

FIG. 78 is a cross sectional view illustrating the manufacturing method of the TFT substrate according to the fifth embodiment of the present invention.

FIG. 79 is a cross sectional view illustrating the manufacturing method of the TFT substrate according to the fifth embodiment of the present invention.

FIG. 80 is a plan view illustrating the manufacturing method of the TFT substrate according to the fifth embodiment of the present invention.

FIG. 81 is a cross sectional view illustrating the manufacturing method of the TFT substrate according to the fifth embodiment of the present invention.

FIG. 82 is a plan view illustrating a configuration of a TFT substrate according to a modification of the fifth embodiment of the present invention.

FIG. 83 is a cross sectional view illustrating the configuration of the TFT substrate according to the modification of the fifth embodiment of the present invention.

FIG. 84 is a plan view illustrating a manufacturing method of the TFT substrate according to the modification of the fifth embodiment of the present invention.

FIG. 85 is a cross sectional view illustrating the manufacturing method of the TFT substrate according to the modification of the fifth embodiment of the present invention.

FIG. 86 is a plan view illustrating the manufacturing method of the TFT substrate according to the modification of the fifth embodiment of the present invention.

FIG. 87 is a cross sectional view illustrating the manufacturing method of the TFT substrate according to the modification of the fifth embodiment of the present invention.

FIG. 88 is a plan view illustrating the manufacturing method of the TFT substrate according to the modification of the fifth embodiment of the present invention.

FIG. 89 is a cross sectional view illustrating the manufacturing method of the TFT substrate according to the modification of the fifth embodiment of the present invention.

FIG. 90 is a plan view illustrating the manufacturing method of the TFT substrate according to the modification of the fifth embodiment of the present invention.

FIG. 91 is a cross sectional view illustrating the manufacturing method of the TFT substrate according to the modification of the fifth embodiment of the present invention.

FIG. 92 is a cross sectional view illustrating the manufacturing method of the TFT substrate according to the modification of the fifth embodiment of the present invention.

FIG. 93 is a plan view illustrating the manufacturing method of the TFT substrate according to the modification of the fifth embodiment of the present invention.

FIG. 94 is a cross sectional view illustrating the manufacturing method of the TFT substrate according to the modification of the fifth embodiment of the present invention.

### DESCRIPTION OF EMBODIMENTS

### First Embodiment

Configuration of Pixel of TFT Substrate

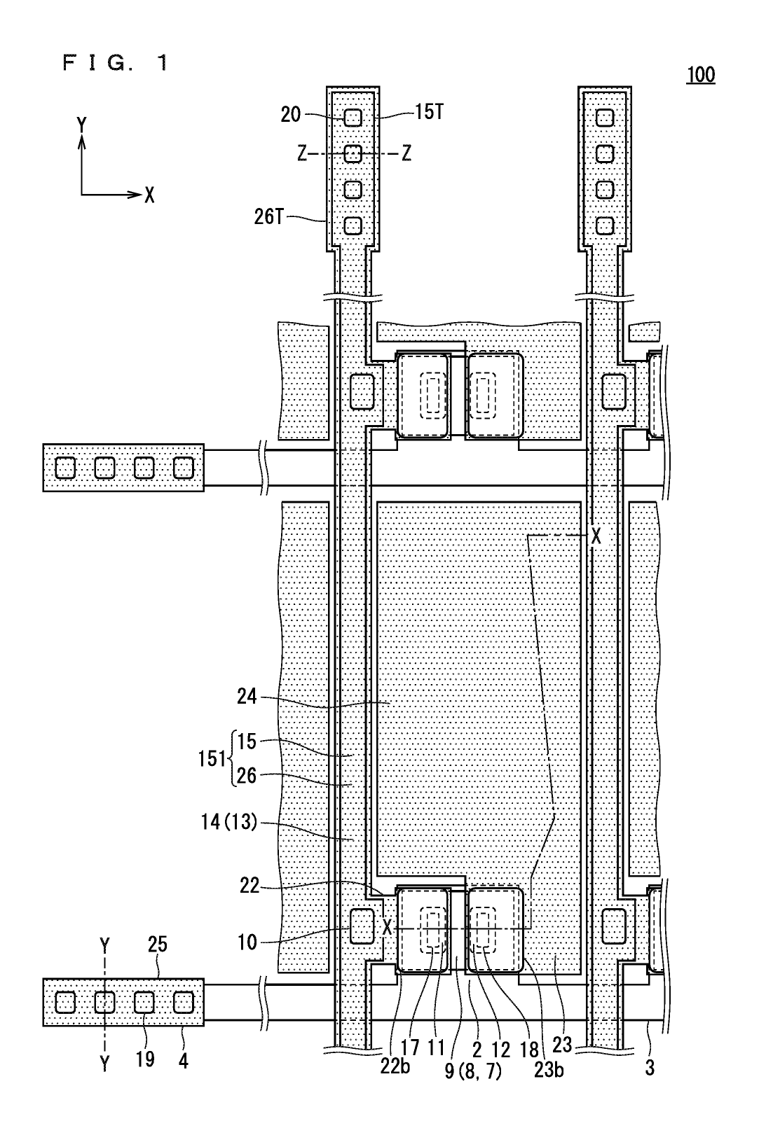

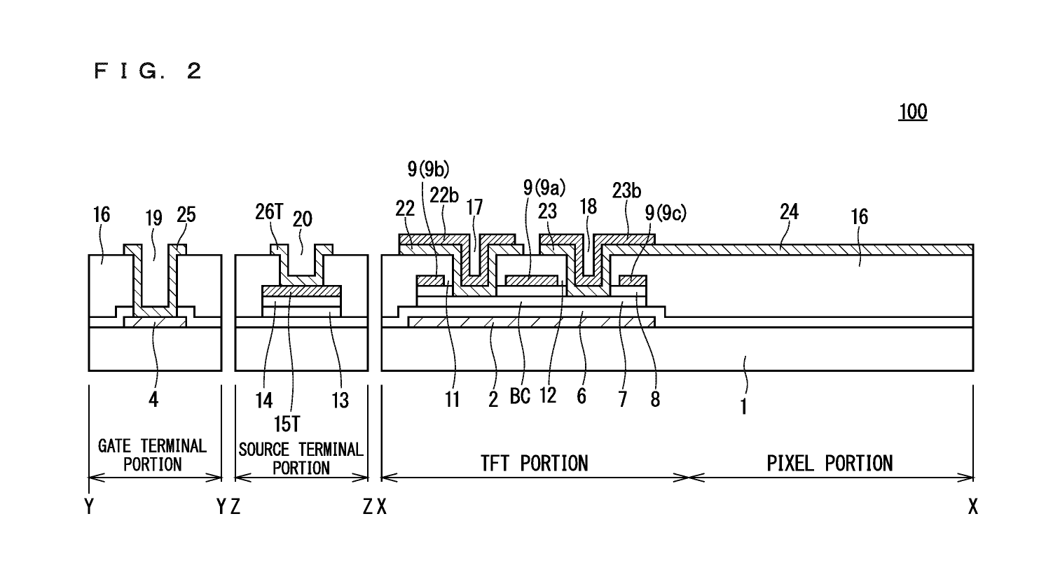

First, with reference to FIG. 1 and FIG. 2, a configuration of a TFT substrate 100 according to a first embodiment will be described. Note that although the present invention relates to a TFT substrate, the present invention has a characteristic specifically in a configuration of a pixel, so that the configuration of the pixel will be described below. FIG. 1 is a plan view illustrating a planar configuration of a pixel according to the first embodiment, and FIG. 2 is a cross sectional view illustrating a cross sectional configuration taken along the line X-X (cross sectional configuration of TFT portion and cross sectional configuration of pixel portion), a cross sectional configuration taken along the line Y-Y (cross sectional configuration of gate terminal portion), and a cross sectional configuration taken along the line Z-Z (cross sectional configuration of source terminal portion) in FIG. 1. Note that, in the following description, the TFT substrate 100 shall be used for a liquid crystal display device of TN mode of light transmission type.

As illustrated in FIG. 1, in the TFT substrate 100, a plurality of gate wirings 3 (scanning signal lines) and a plurality of source wirings 151 (display signal lines) are perpendicularly arranged, and a TFT is arranged near each of the intersections of both the lines, and a gate electrode 2 of the TFT is configured by a portion of the gate wiring 3. That is, a portion brunched from the gate wiring 3 to extend to a formation region of the TFT (TFT portion) forms the gate electrode 2. In the embodiment, the depth and the width of the portion to be the gate electrode 2 is made wider than the width of the gate wiring 3 so as to be a size that enables a source electrode 22 and a drain electrode 23 to be arranged above the gate electrode 2.

As illustrated in FIG. 1, the gate wirings 3 are arranged to extend in a lateral direction (X direction), and the source wirings 151 are arranged to extend in a vertical direction (Y direction). Note that the source wiring 151 is configured by a lower layer source wiring 15 and an upper layer source wiring 26.

One end of the gate wiring 3 is electrically connected to a gate terminal 4, and a gate terminal extraction electrode 25 is connected to the gate terminal 4 via a first gate terminal portion contact hole 19. Note that as the gate terminal 4, as described below, a first conductive film formed of a metal or an alloy having light shielding properties, for example, a metal such as molybdenum (Mo), and aluminum (Al), or an alloy obtained by adding another element to the metal is used.

Furthermore, one end of the lower layer source wiring 15 is connected to a source terminal 15T, and a source terminal extraction electrode 26T is connected to the source terminal 15T via a first source terminal portion contact hole 20.

Making the upper layer source wiring 26 extending from the source electrode 22 be connected to the lower layer source wiring 15 via a first source wiring contact hole 10 makes the source electrode 22 be electrically connected to the lower layer source wiring 15. Furthermore, the drain electrode 23 extends to a pixel region to form a transmissive pixel electrode 24 of light transmission type. Furthermore, upper layer light shielding films 22b and 23b are respectively provided on the regions of the source electrode 22 and the drain electrode 23.

Note that the region surrounded by the adjacent gate wirings 3 and the adjacent lower layer source wirings 15 becomes a pixel region, so that pixel regions are arranged in a matrix manner in the TFT substrate 100.

Next, a cross sectional configuration of the TFT substrate 100 will be described using FIG. 2. As illustrated in FIG. 2, the TFT substrate 100 includes a substrate 1 that is a transparent insulating substrate such as a glass as its base material, and the gate electrode 2 (including gate wiring 3), and the gate terminal 4 are arranged on the substrate 1.

Then, an insulating film 6 (first insulating film) is arranged to cover the gate electrode 2 and the gate terminal 4. The insulating film 6 functions as a gate insulating film at the TFT portion, so that the insulating film 6 is referred to as a gate insulating film 6 in some cases.

In the TFT portion, an oxide semiconductor film 7 is arranged on the insulating film 6 at the position overlapping with the gate electrode 2. The oxide semiconductor film 7 functions as a channel layer of the TFT, so that the oxide semiconductor film 7 is referred to as a semiconductor channel layer 7 in some cases. Note that, in the embodiment, the planer pattern of the semiconductor channel layer 7 is made smaller than the planer pattern of the gate electrode 2 in plan view, so that the outline of the semiconductor channel layer 7 exists inside the outline of the gate electrode 2.

For the semiconductor channel layer 7, for example, an oxide semiconductor of zinc oxide (ZnO) series, an oxide semiconductor of InZnSnO series in which indium oxide (In₂O₃) and tin oxide (SnO₂) are added to zinc oxide, or an oxide semiconductor of InGaZnO series in which gallium oxide (Ga₂O₃) and indium oxide (In₂O₃) are added to zinc oxide can be used. Making the semiconductor channel layer 7 be formed of an oxide semiconductor makes it possible to increase mobility as compared with a conventional configuration in which amorphous silicon is used for the semiconductor channel layer.

A protective insulating film 8 (second insulating film) is arranged on the semiconductor channel layer 7, and a channel region lower layer light shielding film 9 (second conductive film) formed of a metal film having light shielding properties is arranged on the protective insulating film 8.

In the embodiment, as the channel region lower layer light shielding film 9, for example, a metal such as molybdenum (Mo) and aluminum (Al) or an alloy obtained by adding another element to the metals is used. Then, a first source electrode contact hole 11 and a first drain electrode contact hole 12 are provided in the channel region lower layer light shielding film 9 above the semiconductor channel layer 7. Note that the channel region lower layer light shielding film 9 is referred to as a lower layer light shielding film 9a, 9b, or 9c in some cases depending on its arranged position for descriptive purposes.

Furthermore, in the source terminal portion, an oxide semiconductor film 13 in the same layer as the semiconductor channel layer 7 of the TFT portion is provided, and an insulating film 14 in the layer the same as the protective insulating film 8 is provided on the oxide semiconductor film 13. Then, the source terminal 15T (including lower layer source wiring 15) in the same layer as the channel region lower layer light shielding film 9 (second conductive film) is provided on the insulating film 14, so that the source terminal 15T is the upper most layer film of the laminate of the three layers.

Furthermore, in the gate terminal portion, the insulating film 6 is formed to cover the gate terminal 4 (including gate wiring 3).

Then, an interlayer insulating film 16 (third insulating film) is arranged above the entire surface of the substrate 1 to cover the insulating film 6, the semiconductor channel layer 7, the protective insulating film 8, and the channel region lower layer light shielding film 9. Then, in the TFT portion, a second source electrode contact hole 17 and a second drain electrode contact hole 18 penetrating the interlayer insulating film 16 and the protective insulating film 8 to reach the semiconductor channel layer 7 are provided. The second source electrode contact hole 17 is arranged to be located inside the outer circumference of the first source electrode contact hole 11 in plan view, and is formed such that a surface of the semiconductor channel layer 7 is exposed at its bottom surface. Furthermore, the second drain electrode contact hole 18 is arranged to be located inside the outer circumference of the first drain electrode contact hole 12 in plan view, and is formed such that a surface of the semiconductor channel layer 7 is exposed at its bottom surface.

Then, the source electrode 22 and the drain electrode 23 formed as a third conductive film are arranged so as to be separated from each other and directly connected respectively to the semiconductor channel layer 7 via the second source electrode contact hole 17 and the second drain electrode contact hole 18. The region between the source electrode 22 and the drain electrode 23 in the semiconductor channel layer 7 forms a channel region BC. Note that, in the embodiment, a transparent conductive film (translucent conductive film) is used as the third conductive film.

The upper layer light shielding films 22b and 23b (fourth conductive film) are respectively provided on the source electrode 22 and the drain electrode 23. When the upper layer light shielding films 22b and 23b are formed by, for example, a metal film having light shielding properties, the upper layer light shielding films 22b and 23b are formed so as to be separated from each other to prevent electrical short circuit between the source electrode 22 and the drain electrode 23. In the embodiment, as the upper layer light shielding films 22b, 23b, a metal such as molybdenum (Mo) and aluminum (Al), or an alloy obtained by adding another element to the metals can be used.

As illustrated in FIG. 1, the upper region of the semiconductor channel layer 7 of the TFT portion is configured such that light from an upper surface is shielded in its entire region in plan view by the upper layer light shielding films 22b, 23b and the lower layer light shielding films 9a, 9b, 9c. Furthermore, the lower region of the semiconductor channel layer 7 of the TFT portion is configured such that light from a lower surface (surface on the side of the substrate 1) is shielded in its entire region in plan view by the gate electrode 2. Forming the TFT portion in this manner makes it possible to almost perfectly prevent backlight light, external light, and scattering light thereof from being incident on the semiconductor channel layer 7 (light shielding), making it possible to prevent property degradation of the semiconductor channel layer 7 due to light absorption.

Furthermore, in the source terminal portion, the source extraction electrode 26T is provided to be directly connected to the source terminal 15T via the first source terminal portion contact hole 20 penetrating the interlayer insulating film 16 to reach the source terminal 15T.

Furthermore, in the gate terminal portion, the gate terminal extraction electrode 25 is provided to be directly connected to the gate terminal 4 via the first gate terminal portion contact hole 19 penetrating the interlayer insulating film 16 and the insulating film 6 to reach the gate terminal.

Note that, the source extraction electrode 26T and the gate terminal extraction electrode 25 are formed by the third conductive film in the same layer as the source electrode 22 and the drain electrode 23 of the TFT portion.

Manufacturing Method

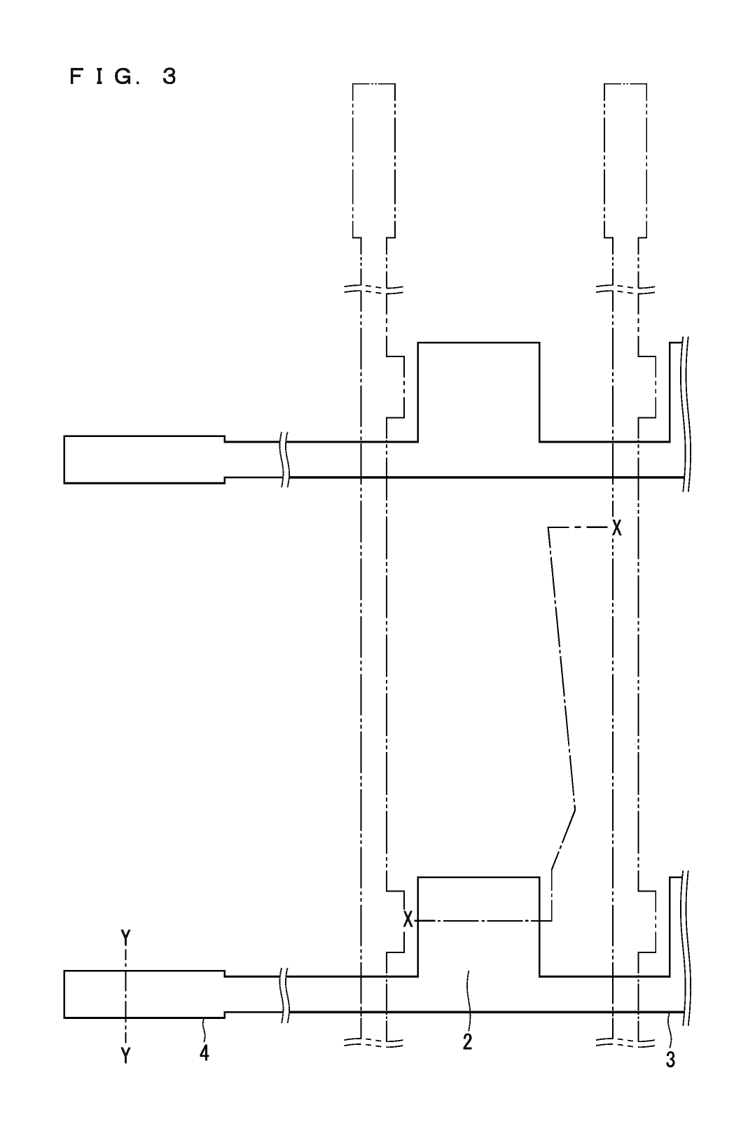

Hereinafter, a manufacturing method of the TFT substrate 100 according to the first embodiment will be described with reference to FIGS. 3 to 12. Note that a plan view and a cross sectional view illustrating the final step respectively correspond to FIG. 1 and FIG. 2.

First, the substrate 1 that is a transparent insulating substrate such as glass is washed using cleaning liquid or pure water. In the embodiment, a glass substrate having a thickness of 0.6 mm is used as the substrate 1. Then, the first conductive film that is the material of the gate electrode 2, the gate wiring 3, and the like is formed on one of the entire main surfaces of the substrate 1 that has been washed. Note that one of the entire main surfaces on which the gate electrode 2, the gate wiring 3, and the like are provided shall be the upper main surface of the substrate 1.

As the first conductive film, for example, a metal such as chrome (Cr), molybdenum (Mo), titanium (Ti), copper (Cu), tantalum (Ta), tungsten (W), and aluminum (Al), an alloy in which not less than one other element is added to the metal element as a main component, and the like can be used. Herein, the element of the main component shall denote the element that is largest in content among the elements structuring the alloy. Furthermore, a laminated structure including not less than two layers of the layer of the metal or the layer of the alloy may be employed. Using the metals or the alloys enables the achievement of a conductive film having a low resistance of not more than 50 μΩcm in specific resistance value. In the embodiment, an aluminum (Al) alloy film shall be used as the first conductive film, and the Al alloy film is formed to have a thickness of 200 nm by a sputtering method using argon (Ar) gas.

First Photolithography Step

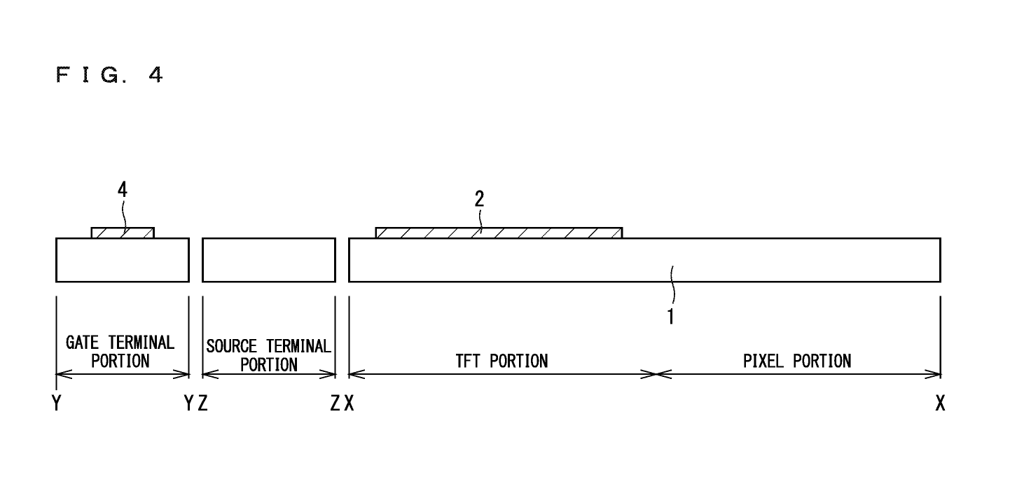

Then, a photoresist material is applied on the first conductive film, a photoresist pattern is formed in a first photolithography step, and the first conductive film is subjected to patterning by etching using the photoresist pattern as a mask. Herein, wet etching using a solution including phosphoric acid, acetic acid, and nitric acid (Phosphoric-Acetic-Nitric acid: PAN chemical solution) is used. Then, by removing the photoresist pattern, as illustrated in FIG. 3 and FIG. 4, the gate electrode 2, the gate wiring 3 (not shown in FIG. 4), and the gate terminal 4 are formed on the upper main surface of the substrate 1.

Second Photolithography Step

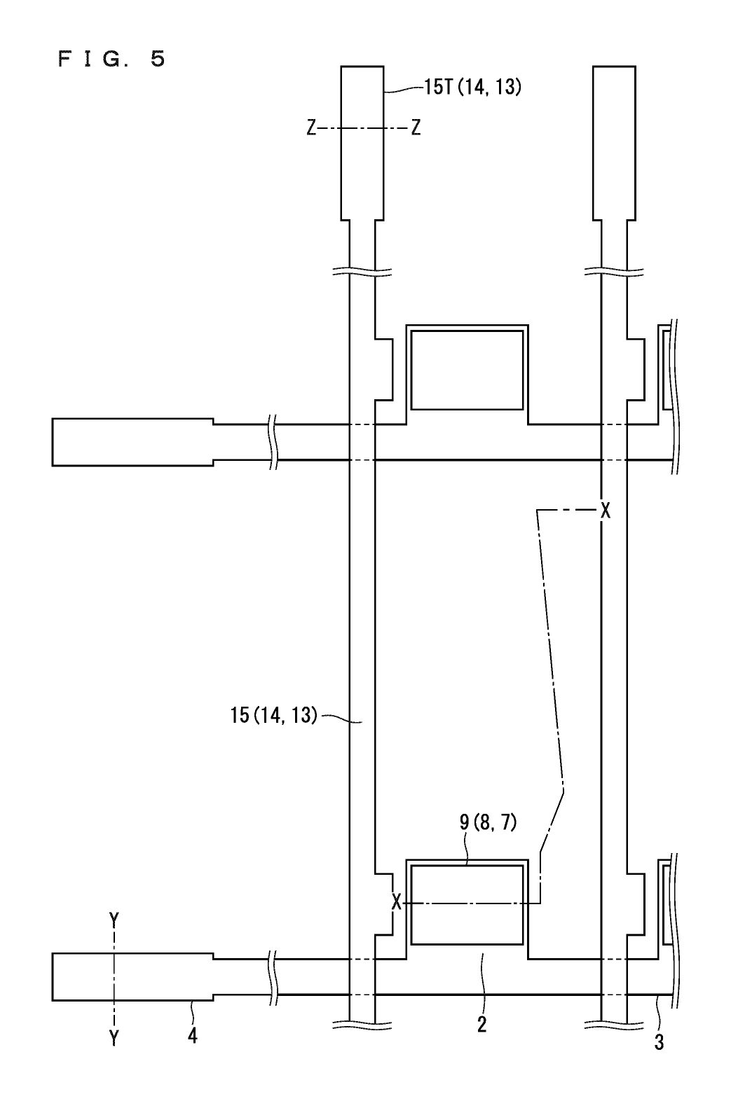

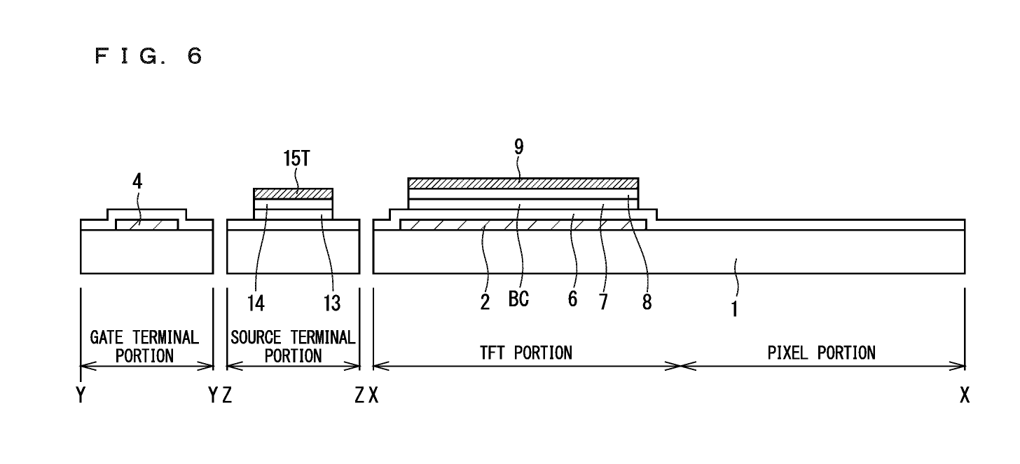

Next, in a second photolithography step, after the insulating film 6 (first insulating film) is formed on the entire upper main surface of the substrate 1 to cover the gate electrode 2, the gate wiring 3, and the gate terminal 4, the oxide semiconductor film, the second insulating film, and the second conductive film are laminated in this order on the insulating film 6 and subjected to patterning by etching to have substantially the same shape, enabling the achievement of the laminate of the semiconductor channel layer 7, the protective insulating film 8, and the channel region lower layer light shielding film 9 above the gate electrode 2 in the TFT portion as illustrated in FIG. 5 and FIG. 6. The laminate is arranged such that its outline in plan view exists inside the outline of the gate electrode 2. Furthermore, in a source wiring formation region, a laminate of the oxide semiconductor film 13, the insulating film 14, and the lower layer source wiring 15 is formed, and in a source terminal formation region, a laminate of the oxide semiconductor film 13, the insulating film 14 and the source terminal 15T is formed by the same process as the above process.

Hereinafter, the manufacturing method will be more specifically described. In the embodiment, the insulating film 6 is formed by forming a silicon nitride film (SiN), and a silicon oxide film (SiO) in this order using chemical vapor deposition (CVD) method. The oxide silicon film includes oxygen (O) atom, making it possible to suppress the influence of oxygen atoms to be diffused (discharged) in the film of the insulating film 6 from the oxide semiconductor film when the oxide semiconductor film is formed on the insulating film 6 in the post process. On the other hand, SiO film is weak in barrier properties (breaking properties) with respect to an impurity element that exerts influence to TFT properties such as moisture (H₂O), hydrogen (H₂), natrium (Na), and kalium (K). Therefore, in the embodiment, a SiN film superior in barrier properties is provided below the SiO film. To be more specific, the insulating film 6 is made as a laminated film of a SiN film having a thickness of 400 nm and a SiO film having a thickness of 50 nm. Note that the insulating film 6 functions as a gate insulating film in the TFT portion.

Furthermore, for the oxide semiconductor film to be formed on the insulating film 6, in the embodiment, an oxide including In, Ga, and Zn (e.g.: InGaZnO) is used as the oxide semiconductor. To be more specific, an InGaZnO film is formed by a spattering method using InGaZnO target in which its atom composition ratio of In:Ga:Zn:O is 1:1:1:4 [In₂O₃.Ga₂O₃.2(ZnO)].

Furthermore, in the embodiment, a SiO film is formed as the second insulating film using CVD method. The reason of using the SiO film including oxygen atoms is to suppress the influence of the oxygen atoms to be diffused (discharged) from the film of the oxide semiconductor film that is the lower layer. Herein, a SiO film having a thickness of 100 nm is formed.

Furthermore, in the embodiment, as the second conductive film, an aluminum (Al) alloy film having a thickness of 200 nm is formed. The second conductive film is not limited to the Al alloy, and a metal or an alloy having light shielding properties may be used.

A photoresist material is applied on the laminate of the oxide semiconductor film, the second insulating film, and the second conductive film laminated on the insulating film 6 in this manner, a photoresist pattern is formed in the second photolithography step, and the above laminate is subjected to patterning by being sequentially etched using the photoresist pattern as a mask.

First, the second conductive film (Al alloy film) is subjected to etching. In the etching of the second conductive film (Al alloy film), a wet etching method using a solution including phosphoric acid, acetic acid, and nitric acid (Phosphoric-Acetic-Nitric acid: PAN chemical solution) is used. In this case, the oxide semiconductor film is covered with the second insulating film, preventing the oxide semiconductor film from being damaged due to the chemical solution for etching.

After the second conductive film is subjected to etching, the second insulating film (SiO film) is subsequently subjected to etching. For the etching, a dry etching method using a gas including fluorine can be used. In the embodiment, dry etching is performed using a gas in which oxide (O₂) is added to sulfur hexafluoride (SF₆). Adding the O₂ gas makes it possible to suppress occurrence of damage of the oxide semiconductor film under the second insulating film due to reduction reaction during etching.

After etching the second insulating film, the oxide semiconductor film (InGaZnO film) is subsequently subjected to etching. In this etching, a wet etching method is used using oxalic acid series chemical solution of oxalic acid 5 wt %+water.

Then, the photoresist pattern is removed. In this manner, each of the laminates illustrated in FIG. 5 and FIG. 6 are simultaneously formed in the same process.

Third Photolithography Step

Next, a photoresist material is applied on the entire upper main surface of the substrate 1 on which the above each laminate is formed, a photoresist pattern is formed in a third photolithography step, and the channel region lower layer light shielding film 9 formed in the TFT portion is subjected to patterning by a wet etching method using PAN chemical solution using the photoresist pattern as a mask,

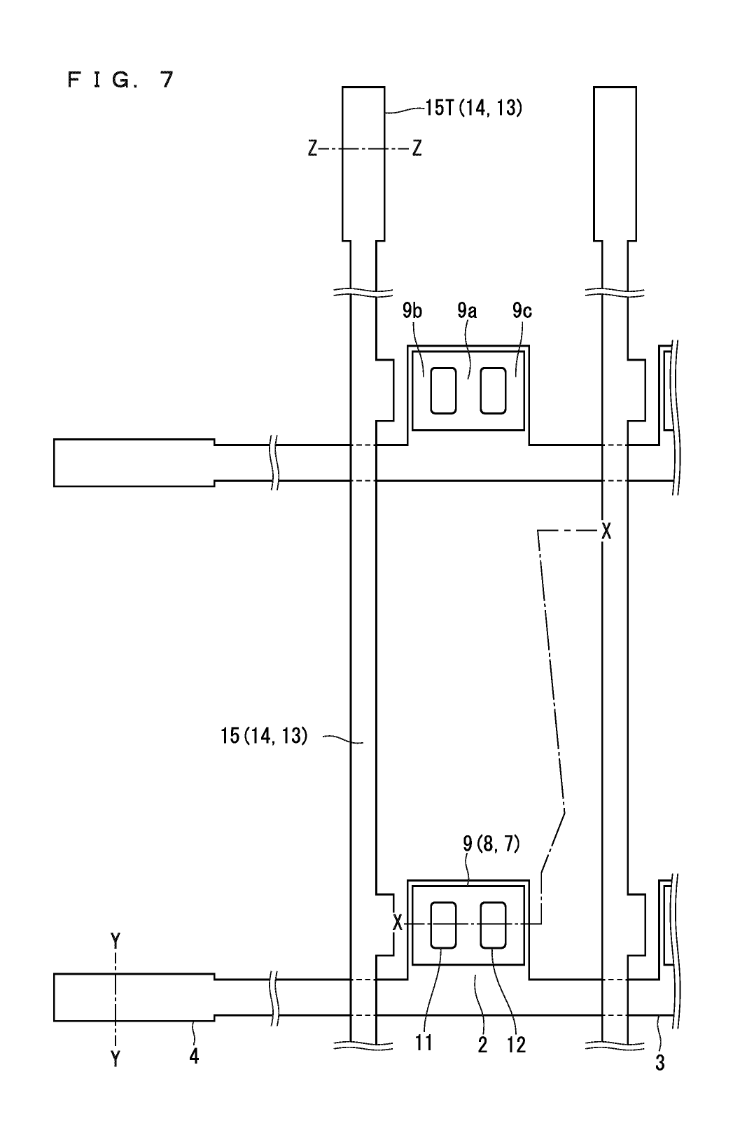

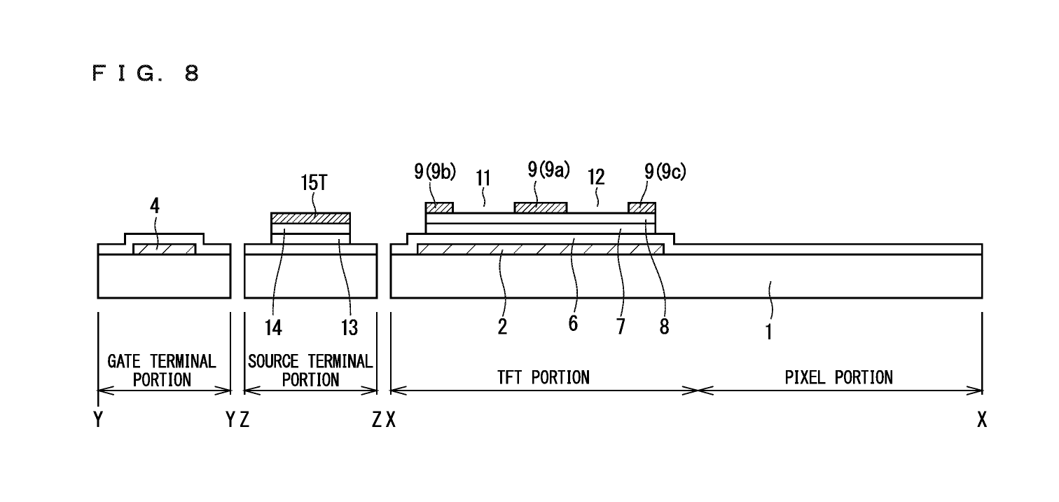

Then, by removing the photoresist pattern, as illustrated in FIG. 7 and FIG. 8, the first source electrode contact hole 11 and the first drain electrode contact hole 12 are formed in the channel region lower layer light shielding film 9.

For descriptive purposes, the channel region lower layer light shielding film 9 that remains between the first source electrode contact hole 11 and the first drain electrode contact hole 12 is referred to as the lower layer light shielding film 9a, the channel region lower layer light shielding film 9 that remains on the side opposite to the lower layer light shielding film 9a of the first source electrode contact hole 11 is referred to as the lower layer light shielding film 9b, and the channel region lower layer light shielding film 9 that remains on the side opposite to the lower layer light shielding film 9a of the first drain electrode contact hole 12 is referred to as the lower layer light shielding film 9c.

Note that although the protective insulating film 8 is exposed at the bottom surface of the first source electrode contact hole 11 and the first drain electrode contact hole 12, the semiconductor channel layer 7 that is the lower layer covered with the protective insulting film 8 is prevented from being damaged.

Next, the interlayer insulating film 16 (third insulating film) is formed on the entire upper main surface of the substrate 1. In the embodiment, a resin series insulating film is formed by an organic resin material. Specifically, for example, an organic resin material of an acrylic having photosensitivity is applied on the substrate 1 to have a thickness of 2.0 to 3.0 μm by a spin coat method as the interlayer insulating film 16.

Fourth Photolithography Step

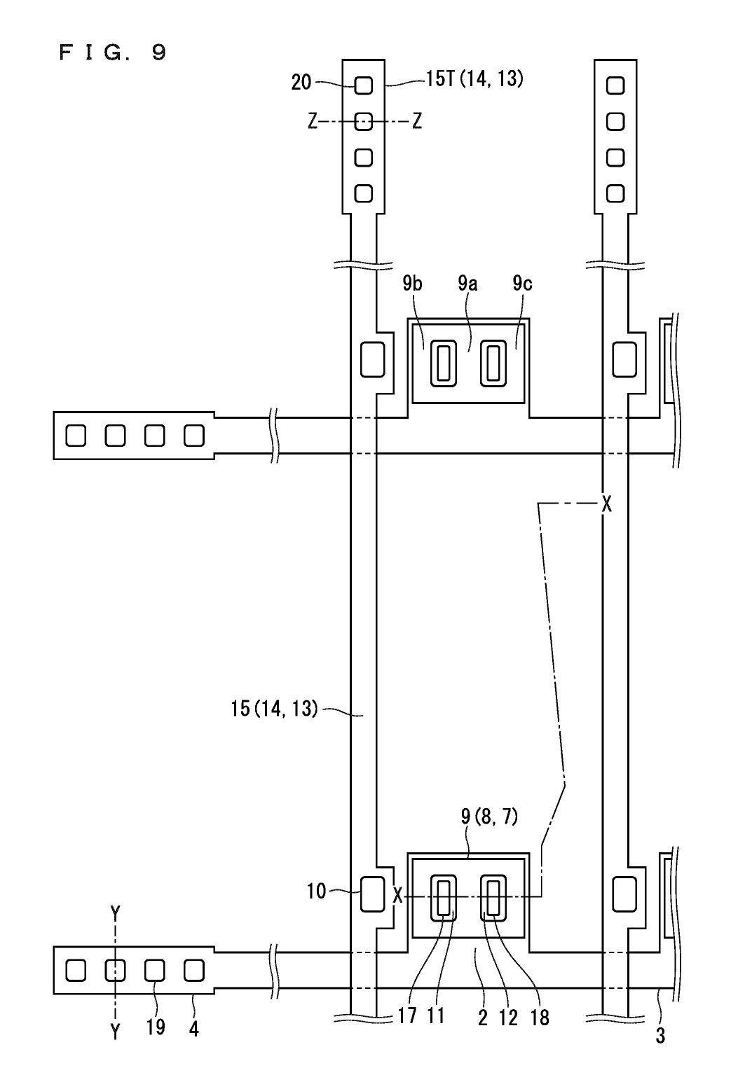

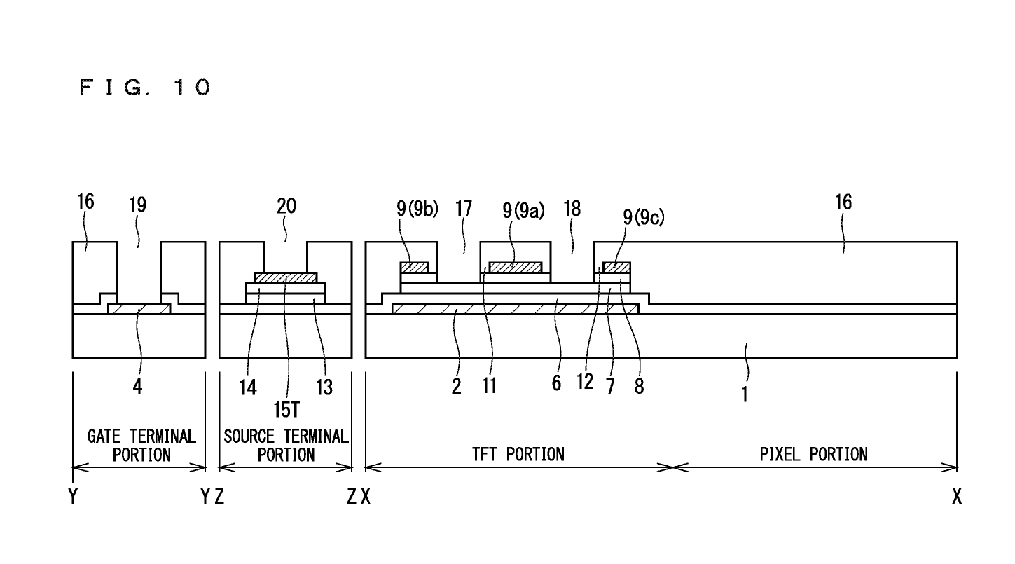

Next, by exposing and developing the interlayer insulating film 16 in a fourth photolithography step, as illustrated in FIG. 9 and FIG. 10, the first source wiring contact hole 10 (not shown in FIG. 10), the second source electrode contact hole 17, the second drain electrode contact hole 18, the first gate terminal portion contact hole 19, and the first source terminal portion contact hole 20 penetrating the interlayer insulating film 16 are formed.

Then, the protective insulating film 8 exposed at the bottom portions of the second source electrode contact hole 17 and the second drain electrode contact hole 18 are subjected to etching. For the etching, a dry etching method using a gas including fluorine can be used.

In the embodiment, dry etching is performed by using a gas in which oxygen (O₂) is added to sulfur hexafluoride (SF₆). Adding O₂ gas makes it possible to suppress that the oxide semiconductor film 7 below the protective insulating film 8 is damaged by reduction reaction during etching. By the etching, as illustrated in FIG. 9 and FIG. 10, the semiconductor channel layer 7 is exposed at the bottom surfaces of the second source electrode contact hole 17 and the second drain electrode contact hole 18.

Furthermore, although the first gate terminal portion contact hole 19 also penetrates the insulating film 6, and the gate terminal 4 of Al alloy is exposed at its bottom surface, and the lower layer source wiring 15 and the source terminal 15T of Al alloy are respectively exposed at the bottom surfaces of the first source wiring contact hole 10 and the first source terminal portion contact hole 20, the Al alloy is not etched by dry etching using a gas in which oxygen (O₂) is added to sulfur hexafluoride (SF₆), so that the patterns remain as they are.

Note that, as a material of the resin series insulating film used for the interlayer insulating film 16, besides an acrylic organic resin material, an olefin series material, a novolac series material, a polyimide series material, and a siloxane series material can be also used. Such coating type organic insulating materials have low dielectric constant and is easy to be formed into a thick film having a thickness of not less than 2.0 μm, making it possible to suppress wiring capacity to a low capacity. Thus, using such materials makes it possible to drive the TFT substrate at a low voltage, making it possible to contribute to reducing power consumption. This makes it possible to make the transmissive pixel electrode 24 be arranged on the gate wiring or the source wiring to overlap, also making it possible to make aperture ratio high.

Furthermore, for the interlayer insulating film 16, instead of the resin series insulating film material, an inorganic series insulating material such as silicon nitride (SiN) and silicon oxide (SiO) can be also used. When such an inorganic series insulating material is used, the first source wiring contact hole 10, the second source electrode contact hole 17, the second drain electrode contact hole 18, the first gate terminal portion contact hole 19, and the first source terminal portion contact hole 20 are formed using a photoresist pattern as a mask. Alternatively, an inorganic series insulating film material and a resin series insulating film material may be appropriately combined to be used.

Next, the third conductive film is formed on the entire upper surface of the interlayer insulating film 16. In the embodiment, a transparent conductive film (translucent conductive film) is used as the third conductive film. As the transparent conductive film, ITO (in which mix ratio of indium oxide (In₂O₃) and tin oxide (SnO₂) is, for example, 90:10 (mass percent)) is used. Herein, by a spattering method, an ITO film having a thickness of 100 nm is formed in amorphous state by using a gas in which a gas including hydrogen (H), for example, hydrogen (H₂) gas, moisture (H₂O), or the like is mixed with argon (Ar).

Fifth Photolithography Step

Then, a photoresist material is applied on the entire upper surface of the third conductive film (amorphous ITO), and a photoresist pattern is formed in a fifth photolithography step, and the third conductive film is subjected to patterning by etching using the photoresist pattern as a mask. In the etching of the third conductive film, a wet etching method is used using oxalic acid series chemical solution of oxalic acid 5 wt %+water.

After the photoresist pattern is removed, the whole of the substrate 1 is heated to 200° C. This heating makes the amorphous ITO film be crystallized to become a polycrystalline ITO film. The substrate temperature is not limited to 200° C., and crystallization can be realized when the temperature is not less than 140° C. in the case of a typical amorphous ITO film having a mix ratio in which indium oxide (In₂O₃) is not less than 85 mass percent, and not more than 95 mass percent, and tin oxide (SnO₂) is not less than 5 mass percent and not more than 15 mass percent (total of both is 100 mass percent). In contrast, on the high temperature side, temperature can be arbitrarily determined depending on the heatproof temperature of a material or the like used for the layer and pattern formed on the TFT substrate. For example, in the embodiment, since an acrylic organic resin film is used as the third insulating film, the temperature needs to be not more than 230° C. that is the heatproof temperature of the material.

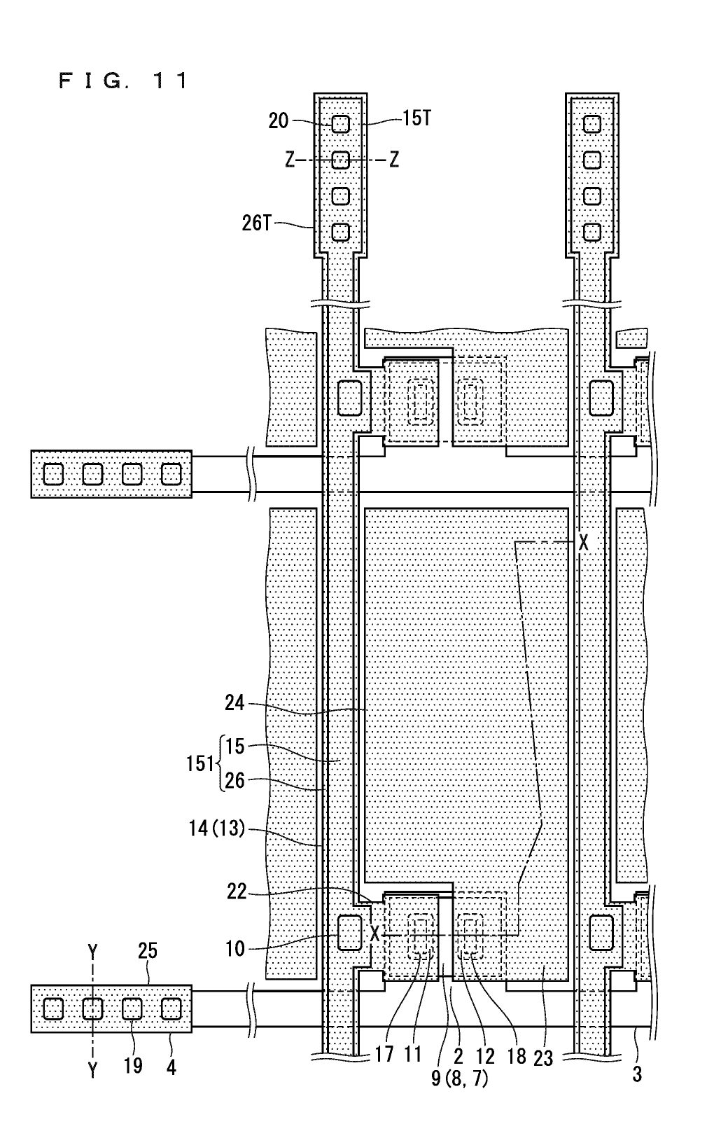

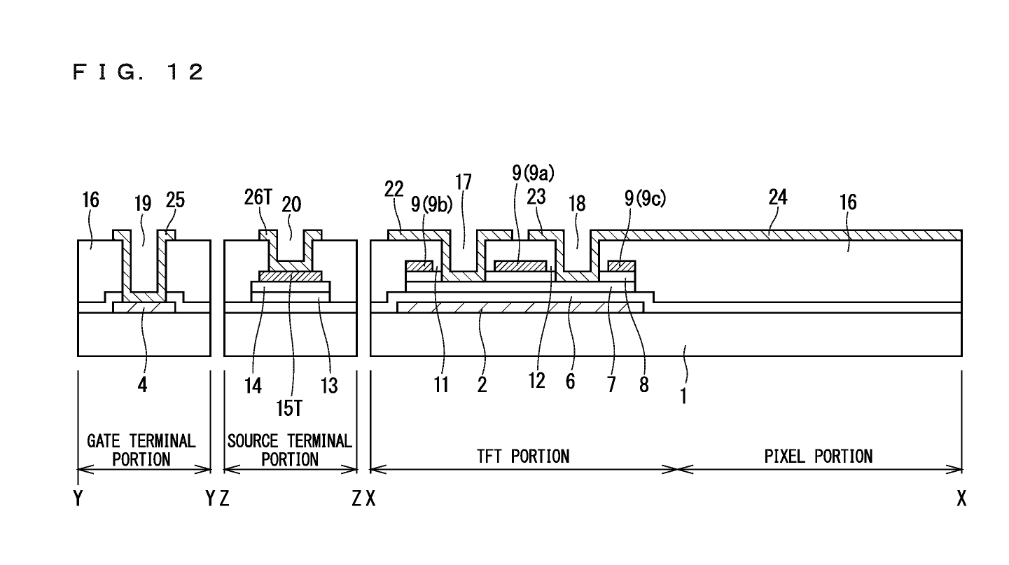

By the above described patterning of the third conductive film, as illustrated in FIG. 11 and FIG. 12, the gate terminal extraction electrode 25, the source electrode 22, the upper layer source wiring 26 extending from the source electrode 22, the source terminal extraction electrode 26T, the drain electrode 23, and the transmissive pixel electrode 24 extending from the drain electrode 23 that are configured by the transparent conductive film (polycrystalline ITO film) are formed.

Herein, the gate terminal extraction electrode 25 is directly connected to the gate terminal 4 via the first gate terminal portion contact hole 19. Furthermore, the source electrode 22 is directly connected to the semiconductor channel layer 7 via the second source electrode contact hole 17. Furthermore, the upper layer source wiring 26 is directly connected to the lower layer source wiring 15 via the first source wiring contact hole 10. Furthermore, the source wiring extraction electrode 26T is directly connected to the source terminal 15T via the first source terminal portion contact hole 20.

Next, the fourth conductive film is formed on the entire upper main surface of the substrate 1 on which the source electrode 22 and the like are formed. In the embodiment, an Al alloy film having light shielding properties is used as the fourth conductive film. Herein, an Al alloy film having a thickness of 100 nm is formed by a spattering method using Ar gas. Note that the fourth conductive film is not limited to an Al alloy, and another metal or alloy having light shielding properties may be used.

Sixth Photolithography Step

Next, a photoresist material is applied on the entire surface of the fourth conductive film (Al alloy film), a photoresist pattern is formed by a sixth photolithography step, and the fourth conductive film is subjected to patterning by etching using the photoresist pattern as a mask. In the etching of the fourth conductive film, a wet etching using PAN chemical solution is used. In this context, the ITO film that is a transparent conductive film that is the lower layer polycrystallized, so that the ITO film is chemically very stable, making it possible to etch only the Al alloy film that is the upper layer without being hardly damaged (disappearance of film, deterioration of electrical properties and optical properties) by the etching with respect to the PAN chemical solution.

Then, by removing the photoresist pattern, as illustrated in FIG. 1 and FIG. 2, the upper layer light shielding films 22b and 23b are respectively formed on the upper portion of the source electrode 22 and the upper portion of the drain electrode 23 of the TFT portion. The upper layer light shielding films 22b and 23b are formed to cover substantially the whole of the planer pattern of the semiconductor channel layer 7 excluding the channel region BC in plan view.

Through the above described steps, the TFT substrate 100 as illustrated in FIG. 1 and FIG. 2 is completed. Note that upon assembling a liquid crystal display panel, an alignment film and a spacer is formed on a surface of the completed TFT substrate 100. The alignment film is a film for aligning liquid crystal, and is configured by polyimide or the like. Furthermore, a separately manufactured counter substrate equipped with a color filter, a counter electrode, an alignment film, and the like are bonded together with the TFT substrate 100. In this context, a gap is formed between the TFT substrate and the counter substrate by the spacer, and enclosing liquid crystal in the gap forms a liquid crystal display panel of TN mode or VA mode of vertical electric field method. Finally, a liquid crystal display device is completed by arranging a light polarizing plate, a phase difference plate, a driving circuit, a backlight unit, and the like on an external side of the liquid crystal display panel.

As described above, the first embodiment makes it possible to manufacture the TFT substrate 100 equipped with an etch stopper type TFT using an oxide semiconductor film having high performance in its channel layer with the six photolithography steps. Specifically, the protective insulating film 8 that becomes an etch stopper is consecutively formed after forming the oxide semiconductor film, so that the semiconductor channel layer 7 is nearly prevented from being deteriorated in its properties due to process damage of the subsequent TFT manufacturing step. This makes it possible to use the semiconductor channel layer 7 as the channel layer of the TFT in the state where high performance properties of the oxide semiconductor are kept.

Furthermore, the source wiring 151 has a two-layered structure of the lower layer source wiring 15 and the upper layer source wiring 26 that are independently formed via the interlayer insulating film, which is so called a redundant wiring. Furthermore, the upper layer source wiring 26 is directly connected to the lower layer source wiring 15 via a plurality of the first source wiring contact holes 10 provided in the interlayer insulating film 16, making it possible to complement the function by the other wiring even when one of the wirings is disconnected. This makes it possible to reduce generation of linear defect due to disconnection of the source wiring 151 to improve yield ratio during manufacturing and reliability of the product.

Furthermore, the lower layer source wiring 15 is consecutively formed with the oxide semiconductor film and the insulating film, making it possible to form the lower layer source wiring 15 (second conductive film) with good adhesiveness, making it possible to reduce generation of disconnection defect due to peeling off of film caused by lack of sticking force. This effect is specifically large at a step portion on the gate wiring pattern in the region in which the gate wiring 3 and the lower layer source wiring 15 intersect.

Furthermore, the semiconductor channel layer 7 is configured such that its entire region is shielded from light by the two-layered light shielding films also on the upper side of the semiconductor channel layer 7 in addition to light shielding by the gate electrode 2 on the lower side of the semiconductor channel layer 7, making it possible to prevent deterioration (optical deterioration) of the channel layer due to absorption of backlight light during operating the liquid crystal display device and external light.

Furthermore, the following effects can be also obtained by forming the upper layer light shielding films 22b and 23b with a conductive film made of a metal such as Mo and Al, or an alloy obtained by adding another element to the metal and disposing them on the formation region of the second source electrode contact hole 17 and the second drain electrode contact hole 18 on the source electrode 22 and the drain electrode 23. That is, side wall portions of the second source electrode contact hole 17 and the second drain electrode contact hole 18 are two-layered structure of the source electrode 22 and the upper layer light shielding film 22b, and the drain electrode 23 and the upper layer light shielding film 23b, respectively, which are made to be redundant wirings. Thus, at the side wall portion, even when the source electrode 22 and the drain electrode 23 are disconnected, the conduction function can be complemented by the upper layer light shielding films 22b and 23b that are formed by a conductive film. This makes it possible to reduce generation of bad connection due to disconnection of the source electrode 22 and the drain electrode 23, making it possible to improve yield ratio during manufacturing and reliability of the product.

Furthermore, forming the channel region lower layer light shielding film 9 with a conductive film and making the source electrode 22 and the drain electrode 23 be electrically separated (no short circuit occurs) to be an electrically floating state enables achievement of an electrostatic shielding effect with respect to the semiconductor channel layer 7 to suppress variation of TFT properties due to unspecified external noise or the like, making it possible to improve reliability.

Furthermore, using a resin series insulating film that has low permittivity, that is made thick in its film thickness to be not less than 2.0 μm, and that has a flattening action with respect to the main surface of the substrate 1 as the interlayer insulating film 16 (third insulating film) makes it possible to suppress wiring capacity to a low level. This makes it possible to drive the TFT substrate at a low voltage, making it possible to contribute to reducing power consumption. This makes it possible to make the transmissive pixel electrode 24 be arranged on the gate wiring or the source wiring to overlap, also making it possible to make aperture ratio high.

Note that upon overlapping the transmissive pixel electrode 24 on the source wiring for preferentially making aperture ratio high, it is preferable to omit the upper layer source wiring 26 in the same layer as the transmissive pixel electrode 24, specifically the portion redundantly arranged on the lower layer source wiring 15, that is, the upper layer source wiring 26 between the adjacent first source wiring contact holes 10. Although failing to achieve the above described operation of reducing liner defect due to disconnection of the source wiring, this makes the transmissive pixel electrode 24 overlap on the lower layer source wiring 15 without interfering with the upper layer source wiring 26, making it possible to make aperture ratio high at a higher level.

### Second Embodiment

Configuration of Pixel of TFT Substrate

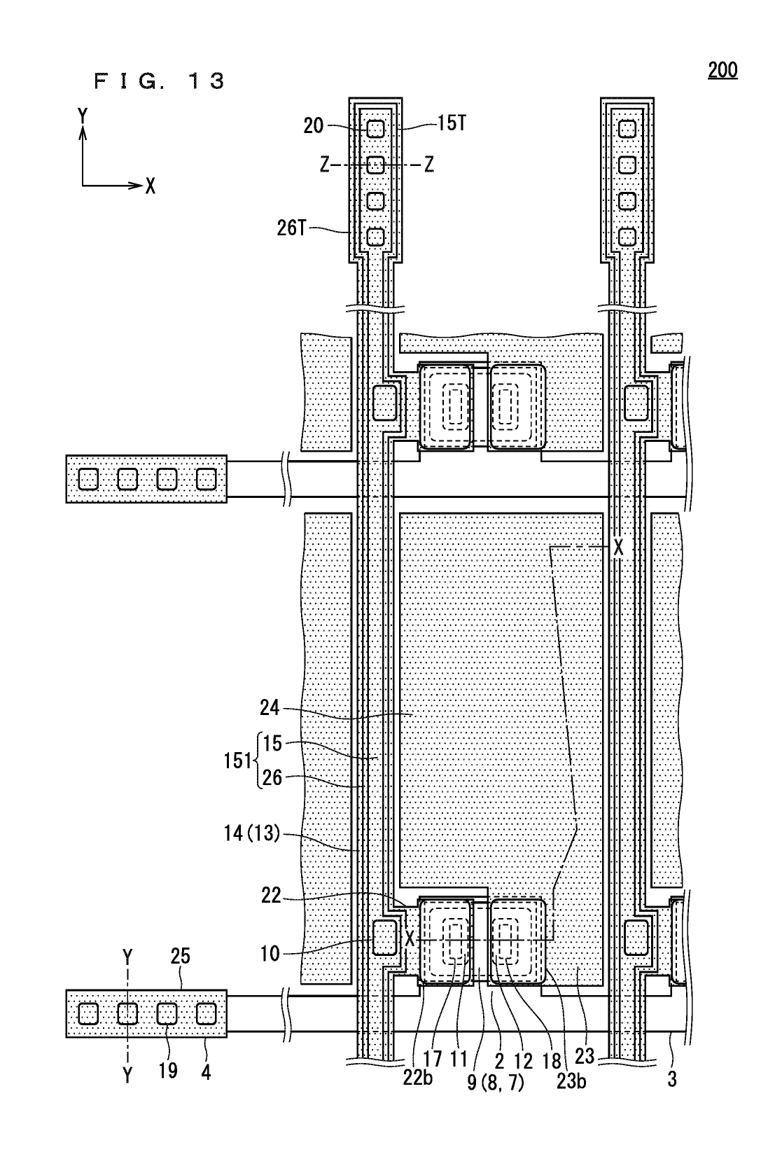

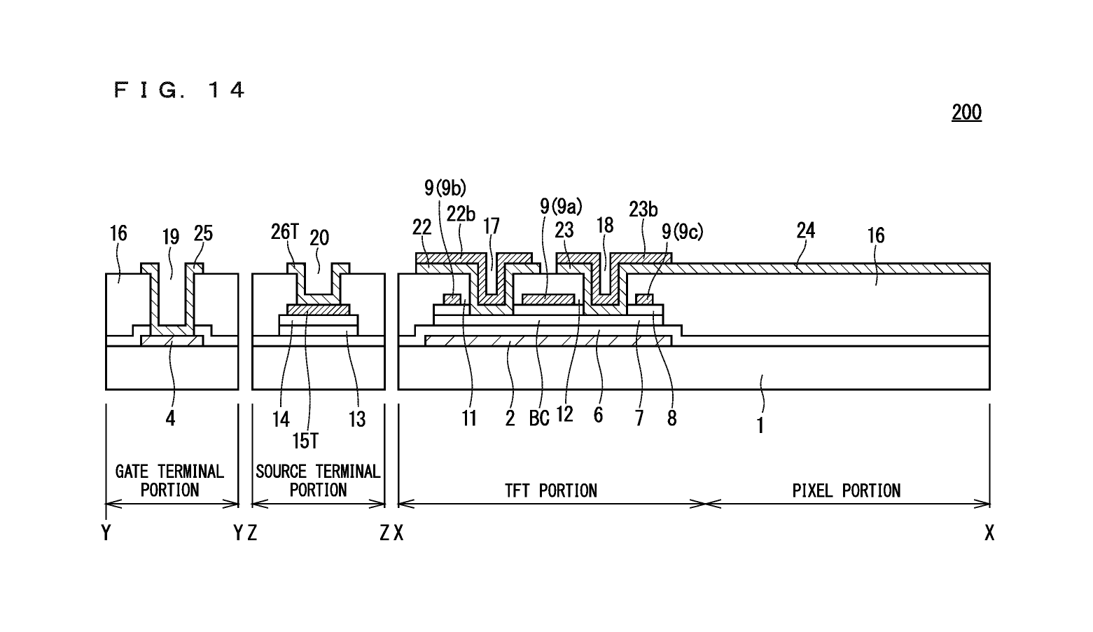

First, with reference to FIG. 13 and FIG. 14, a configuration of a TFT substrate 200 according to a second embodiment will be described. Note that the same reference numerals are given to the same components as those in the TFT substrate 100 illustrated by using FIG. 1 and FIG. 2, and the overlapping description will be omitted.

The embodiment provides a configuration and a manufacturing method capable of efficient production by reducing the number of photolithography steps while keeping the effects of the present invention of the TFT substrate according to the first embodiment.

FIG. 13 is a plan view illustrating a planar configuration of a pixel according to the second embodiment, and FIG. 14 is a cross sectional view illustrating a cross sectional configuration taken along the line X-X (cross sectional configuration of TFT portion and cross sectional configuration of pixel portion), a cross sectional configuration taken along the line Y-Y (cross sectional configuration of gate terminal portion), and a cross sectional configuration taken along the line Z-Z (cross sectional configuration of source terminal portion) in FIG. 13. Note that, in the following description, the TFT substrate 200 shall be used for a liquid crystal display device of TN mode of light transmission type.

As illustrated in FIG. 13, in the TFT substrate 200, a gate electrode 2 of the TFT is configured by a portion of a gate wiring 3. That is, a portion brunched from the gate wiring 3 to extend to a formation region of the TFT (TFT portion) forms the gate electrode 2. In the embodiment, the depth and the width of the portion to be the gate electrode 2 is made wider than the width of the gate wiring 3 so as to be a size that enables a source electrode 22 and a drain electrode 23 to be arranged above the gate electrode 2.

One end of the gate wiring 3 is electrically connected to a gate terminal 4, and a gate terminal extraction electrode 25 is connected to the gate terminal 4 via a first gate terminal portion contact hole 19. Note that as the gate wiring 3 and the gate terminal 4, as described below, a first conductive film made of a metal or an alloy having light shielding properties, for example, a metal such as molybdenum (Mo), and aluminum (Al), or an alloy obtained by adding another element to the metal is used.

As illustrated in FIG. 13, the gate wirings 3 are arranged to extend in a lateral direction (X direction), and source wirings 151 are arranged to extend in a vertical direction (Y direction). Note that the source wiring 151 is configured by a lower layer source wiring 15 and an upper layer source wiring 26.

Furthermore, one end of the lower layer source wiring 15 is connected to a source terminal 15T, and a source terminal extraction electrode 26T is connected to the source terminal 15T via a first source terminal portion contact hole 20.

Making the upper layer source wiring 26 extending from the source electrode 22 be connected to the lower layer source wiring 15 via a first source wiring contact hole 10 makes the source electrode 22 be electrically connected to the lower layer source wiring 15. Furthermore, the drain electrode 23 extends to a pixel region to form a transmissive pixel electrode 24. Furthermore, upper layer light shielding films 22b and 23b are respectively provided on the regions of the source electrode 22 and the drain electrode 23.

Note that the region surrounded by the adjacent gate wirings 3 and the adjacent lower layer source wirings 15 becomes a pixel region, so that pixel regions are arranged in a matrix manner in the TFT substrate 200.

Next, a cross sectional configuration of the TFT substrate 200 will be described using FIG. 14. As illustrated in FIG. 14, the TFT substrate 200 includes a substrate 1 that is a transparent insulating substrate such as a glass as its base material, and the gate electrode 2 (including gate wiring 3), and the gate terminal 4 are arranged on the substrate 1.

Then, an insulating film 6 (first insulating film) is arranged to cover the gate electrode 2 and the gate terminal 4. The insulating film 6 functions as a gate insulating film at the TFT portion, so that the insulating film 6 is referred to as a gate insulating film 6 in some cases.

In the TFT portion, an oxide semiconductor film 7 is arranged on the insulating film 6 at the position overlapping with the gate electrode 2. The oxide semiconductor film 7 functions as a channel layer of the TFT, so that the oxide semiconductor film 7 is referred to as a semiconductor channel layer 7 in some cases. Note that, in the embodiment, the planer pattern of the semiconductor channel layer 7 is made smaller than the planer pattern of the gate electrode 2 in plan view, so that the outline of the semiconductor channel layer 7 exists inside the outline of the gate electrode 2. Note that the material of the semiconductor channel layer 7 is the same as that described in the first embodiment, making it possible to increase mobility as compared with a conventional configuration in which amorphous silicon is used for the semiconductor channel layer.

A protective insulating film 8 (second insulating film) is arranged on the semiconductor channel layer 7, and a channel region lower layer light shielding film 9 (second conductive film) formed of a metal film having light shielding properties or the like is arranged on the protective insulating film 8.

In the embodiment, as the channel region lower layer light shielding film 9, for example, a metal such as molybdenum (Mo) and aluminum (Al), or an alloy obtained by adding another element to the metal is used. Then, a first source electrode contact hole 11 and a first drain electrode contact hole 12 are provided in the channel region lower layer light shielding film 9 above the semiconductor channel layer 7. Note that the channel region lower layer light shielding film 9 is referred to as a lower layer light shielding film 9a, 9b, or 9c in some cases depending on its arranged position for descriptive purposes. Furthermore, the outline of the channel region lower layer light shielding film 9 exists inside the outlines of the protective insulating film 8 and the semiconductor channel layer 7, which differs from the first embodiment because of difference in their manufacturing methods.

Furthermore, in the source terminal portion, an oxide semiconductor film 13 in the same layer as the semiconductor channel layer 7 of the TFT portion is provided, and an insulating film 14 in the layer the same as the protective insulating film 8 is provided on the oxide semiconductor film 13. Then, the source terminal 15T (including lower layer source wiring 15) in the same layer as the channel region lower layer light shielding film 9 (second conductive film) is provided on the insulating film 14, so that the source terminal 15T is the upper most layer film of the laminate of the three layers. Note that, the outline of the source terminal 15T (including lower layer source wiring 15) exists inside the outlines of the insulating film 14 and the oxide semiconductor film 13, which differs from the first embodiment because of difference in their manufacturing methods.

Furthermore, in the gate terminal portion, the insulating film 6 is formed to cover the gate terminal 4 (including gate wiring 3).

Then, an interlayer insulating film 16 (third insulating film) is arranged above the entire surface of the substrate 1 to cover the insulating film 6, the semiconductor channel layer 7, the protective insulating film 8, and the channel region lower layer light shielding film 9. Then, in the TFT portion, a second source electrode contact hole 17 and a second drain electrode contact hole 18 penetrating the interlayer insulating film 16 and the protective insulating film 8 to reach the semiconductor channel layer 7 are provided. The second source electrode contact hole 17 is arranged to be located inside the outer circumference of the first source electrode contact hole 11 in plan view, and is formed such that a surface of the semiconductor channel layer 7 is exposed at its bottom surface. Furthermore, the second drain electrode contact hole 18 is arranged to be located inside the outer circumference of the first drain electrode contact hole 12 in plan view, and is formed such that a surface of the semiconductor channel layer 7 is exposed at its bottom surface.

Then, the source electrode 22 and the drain electrode 23 formed as a third conductive film are arranged so as to be separated from each other and directly connected to the semiconductor channel layer 7 via the second source electrode contact hole 17 and the second drain electrode contact hole 18, respectively. The region between the source electrode 22 and the drain electrode 23 in the semiconductor channel layer 7 forms a channel region BC. Note that, in the embodiment, a transparent conductive film (translucent conductive film) is used as the third conductive film.

The upper layer light shielding films 22b and 23b (fourth conductive film) are respectively provided on the source electrode 22 and the drain electrode 23. When the upper layer light shielding films 22b and 23b are formed by, for example, a metal film having light shielding properties, the upper layer light shielding films 22b and 23b are formed so as to be separated from each other to prevent electrical short circuit between the source electrode 22 and the drain electrode 23. In the embodiment, as the upper layer light shielding films 22b, 23b, a metal such as molybdenum (Mo) and aluminum (Al), or an alloy obtained by adding another element to the metal can be used.

As illustrated in FIG. 13, the upper region of the semiconductor channel layer 7 of the TFT portion is configured such that light from an upper surface is shielded in its entire region in plan view by the upper layer light shielding films 22b, 23b, and the lower layer light shielding films 9a, 9b, 9c. Furthermore, the lower region of the semiconductor channel layer 7 of the TFT portion is configured such that light from a lower surface (surface on the side of the substrate 1) is shielded in its entire region in plan view by the gate electrode 2. Forming the TFT portion in this manner makes it possible to almost perfectly prevent backlight light, external light, and scattering light thereof from being incident on the semiconductor channel layer 7 (light shielding), making it possible to prevent property degradation of the semiconductor channel layer 7 due to light absorption.

Furthermore, in the source terminal portion, the source extraction electrode 26T is provided to be directly connected to the source terminal 15T via the first source terminal portion contact hole 20 penetrating the interlayer insulating film 16 to reach the source terminal 15T.

Furthermore, in the gate terminal portion, the gate terminal extraction electrode 25 is provided to be directly connected to the gate terminal 4 via the first gate terminal portion contact hole 19 penetrating the interlayer insulating film 16 and the insulating film 6 to reach the gate terminal.

Note that, the source extraction electrode 26T and the gate terminal extraction electrode 25 are formed by the third conductive film in the same layer as the source electrode 22 and the drain electrode 23 of the TFT portion.

Manufacturing Method

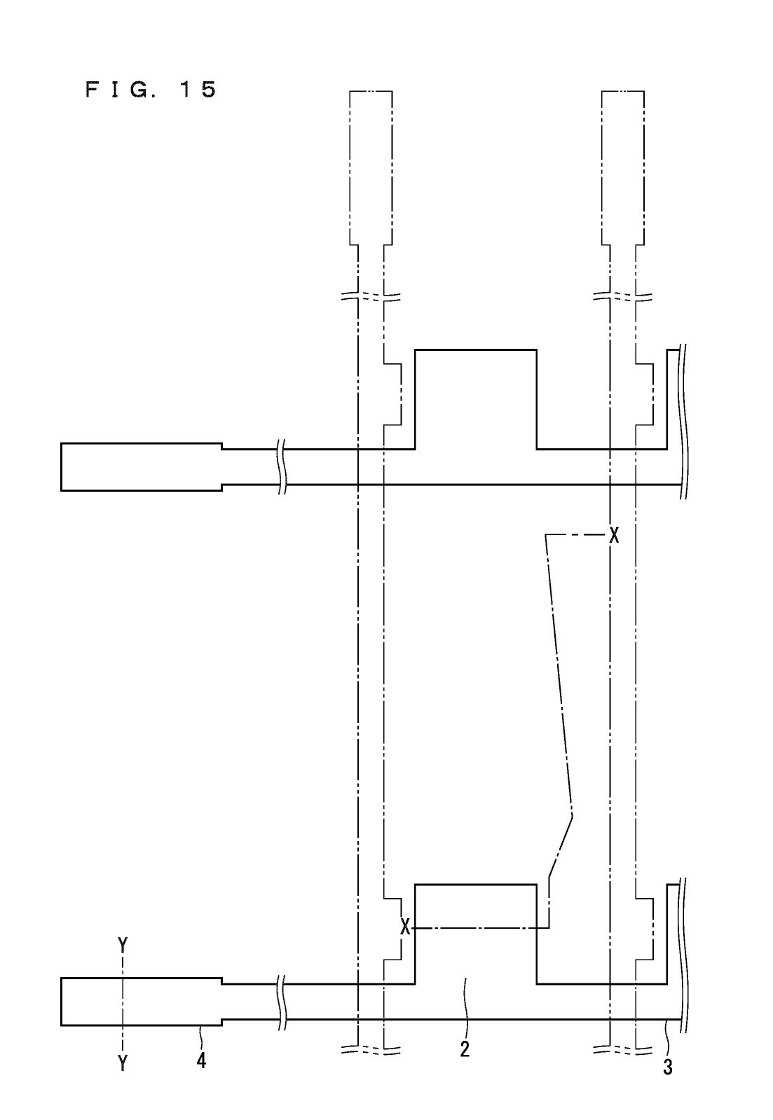

Hereinafter, a manufacturing method of the TFT substrate 200 according to the first embodiment will be described with reference to FIGS. 15 to 24. Note that a plan view and a cross sectional view illustrating the final step respectively correspond to FIG. 13 and FIG. 14.

First, the substrate 1 that is a transparent insulating substrate such as glass is washed using cleaning liquid or pure water. In the embodiment, a glass substrate having a thickness of 0.6 mm is used as the substrate 1. Then, the first conductive film that is the material of the gate electrode 2, the gate wiring 3, and the like is formed on one of the entire main surfaces of the substrate 1 that has been washed. The material capable of being used as the first conductive film is described in the first embodiment, so that overlapping description will be omitted. In the embodiment, an aluminum (Al) alloy film shall be used as the first conductive film, and the Al alloy film is formed to have a thickness of 200 nm by a sputtering method using argon (Ar) gas.

First Photolithography Step

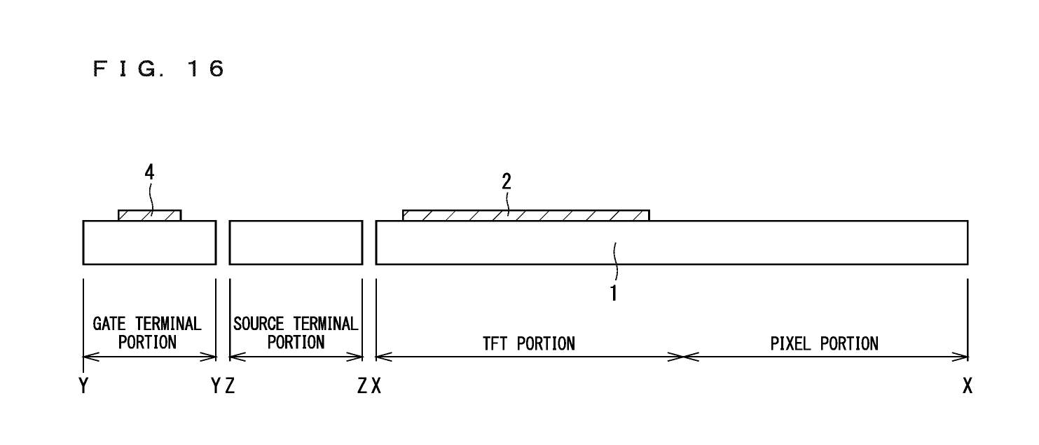

Then, a photoresist material is applied on the first conductive film, a photoresist pattern is formed in a first photolithography step, and the first conductive film is subjected to patterning by etching using the photoresist pattern as a mask. Herein, a wet etching using PAN chemical solution is used. Then, by removing the photoresist pattern, as illustrated in FIG. 15 and FIG. 16, the gate electrode 2, the gate wiring 3 (not shown in FIG. 16), and the gate terminal 4 are formed on the upper main surface of the substrate 1.

Second Photolithography Step

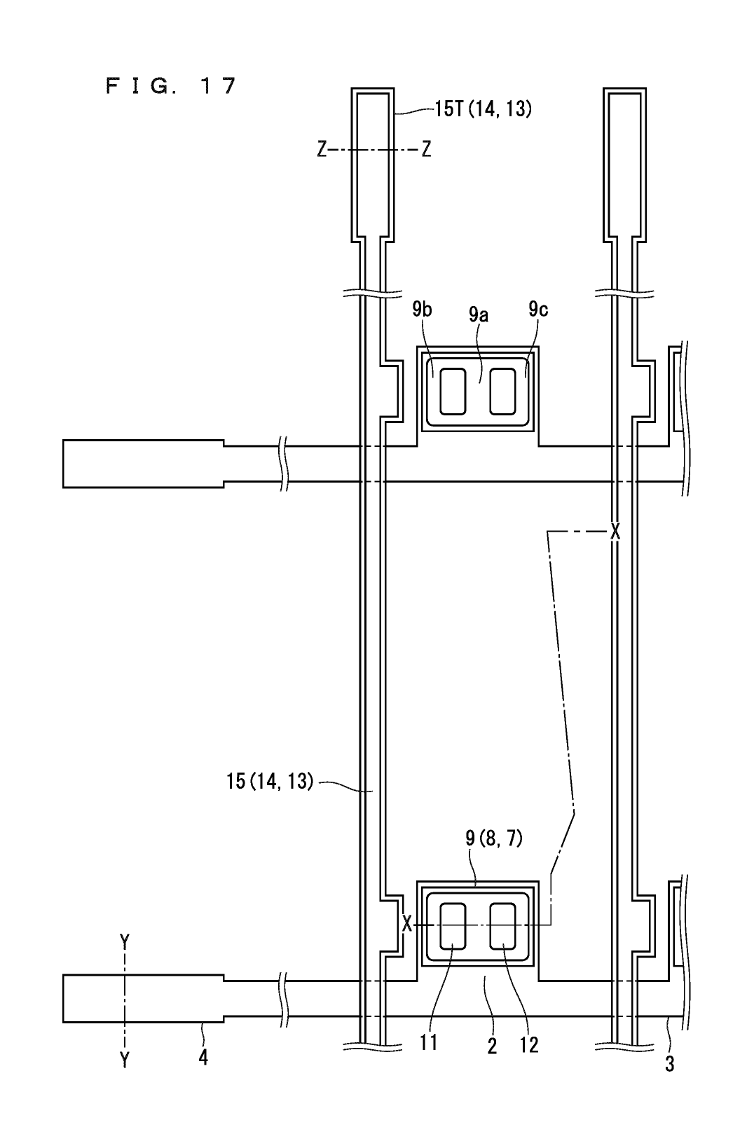

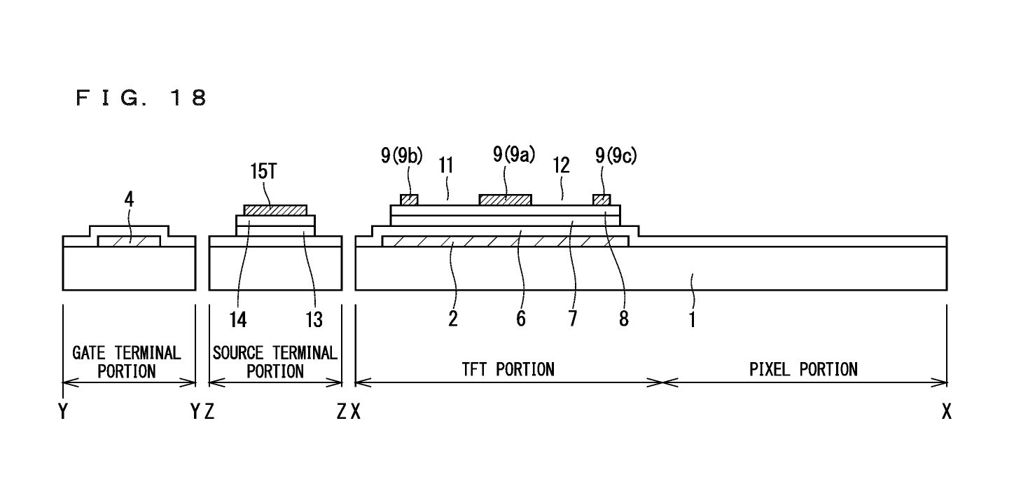

Next, after forming the insulating film 6 (first insulating film) on the entire upper main surface of the substrate 1 to cover the gate electrode 2, the gate wiring 3, and the gate terminal 4, the oxide semiconductor film, the second insulating film, and the second conductive film are laminated on the insulating film 6 in this order, and in a second photolithography step, a photoresist pattern having different thicknesses is formed by exposure (half exposure) using a half exposure mask, and the oxide semiconductor film, the second insulating film, and the second conductive film are subjected to patterning by etching. Herewith, as illustrated in FIG. 17 and FIG. 18, the laminate of the semiconductor channel layer 7, the protective insulating film 8, and the channel region lower layer light shielding film 9 is obtained above the gate electrode 2 in the TFT portion, and the first source electrode contact hole 11 and the first drain electrode contact hole 12 are formed in the channel region lower layer light shielding film 9. Herein, the outline of the semiconductor channel layer 7 in plan view is arranged to exist inside the outline of the gate electrode 2.

Furthermore, for descriptive purposes, the channel region lower layer light shielding film 9 that remains between the first source electrode contact hole 11 and the first drain electrode contact hole 12 is referred to as the lower layer light shielding film 9a, the channel region lower layer light shielding film 9 that remains on the side opposite to the lower layer light shielding film 9a of the first source electrode contact hole 11 is referred to as the lower layer light shielding film 9b, and the channel region lower layer light shielding film 9 that remains on the side opposite to the lower layer light shielding film 9a of the first drain electrode contact hole 12 is referred to as the lower layer light shielding film 9c.

Furthermore, in a source wiring formation region, a laminate of the oxide semiconductor film 13, the insulating film 14, and the lower layer source wiring 15 is formed, and in a source terminal formation region, a laminate of the oxide semiconductor film 13, the insulating film 14 and the source terminal 15T is formed by the same process as the above process.

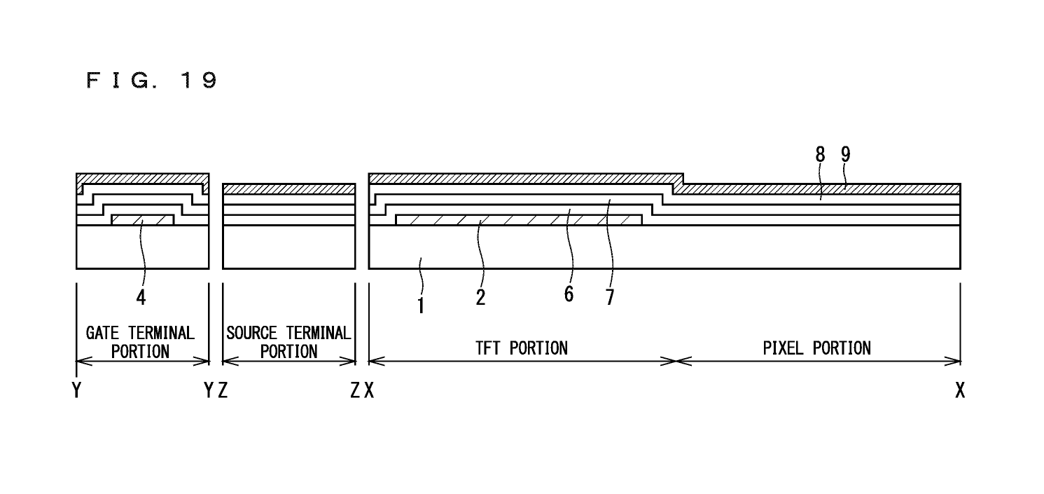

In the embodiment, in the second photolithography step, exposure (half exposure) using a half exposure mask called “gray tone mask” or “half tone mask” is performed to form a photoresist pattern having different thicknesses, and the photoresist pattern is used for pattering to be different pattern shapes, photolithography steps inherently required twice are made common, requiring only one photolithography step. Hereinafter, the second photolithography step will be further described using FIG. 19 to FIG. 22.

The first insulating film is formed on the entire upper main surface of the substrate 1 on which the gate electrode 2, the gate wiring 3, and the gate terminal 4 are formed. In the embodiment, using a CVD method, a nitride silicon film (SiN) and an oxide silicon film (SiO) are formed in this order as the insulating film 6 (first insulating film). The oxide silicon film includes oxygen (O) atom, making it possible to suppress the influence of oxygen atoms to be diffused (discharged) in the film of the insulating film 6 from the oxide semiconductor film when the oxide semiconductor film is formed on the insulating film 6 in the post process. On the other hand, SiO film is weak in barrier properties (breaking properties) with respect to an impurity element that exerts influence to TFT properties such as moisture (H₂O), hydrogen (H₂), natrium (Na), and kalium (K). Therefore, in the embodiment, a SiN film superior in barrier properties is provided below the SiO film. To be more specific, the insulating film 6 is made as a laminated film of a SiN film having a thickness of 400 nm and a SiO film having a thickness of 50 nm. Note that the insulating film 6 functions as a gate insulating film in the TFT portion.

Then, the oxide semiconductor film 7 that is the material of the channel layer is formed on the insulating film 6. In the embodiment, an oxide including In, GA, and Zn (e.g.: InGaZnO) is used as the oxide semiconductor. To be more specific, an InGaZnO film is formed by a spattering method using InGaZnO target in which the atom composition ratio of In:Ga:Zn:O is 1:1:1:4 [In₂O₃.Ga₂O₃.2(ZnO)].

Next, the insulating film 8 (second insulating film) is formed on the oxide semiconductor film 7. In the embodiment, an SiO film is formed as the insulating film 8 using a CVD method. The reason of using the SiO film including oxygen atoms is to suppress the influence of the oxygen atoms to be diffused (discharged) from the film of the oxide semiconductor film 7 that is the lower layer. Herein, a SiO film having a thickness of 100 nm is formed.

Next, the conductive film 9 (second conductive film) is formed on the insulating film 8. In the embodiment, as the conductive film 9, an aluminum (Al) alloy film having a thickness of 200 nm is formed. The second conductive film is not limited to the Al alloy, and a metal or an alloy having light shielding properties may be used.

Through the above steps, as illustrated in FIG. 19, the laminate in which the oxide semiconductor film 7, the insulating film 8, and the conductive film 9 are laminated can be obtained on the insulating film 6.

A photoresist material is applied on the laminate thus obtained, photoresist patterns are formed in the second photolithography step, and the above laminated films are subjected to patterning by being sequentially etched using the photoresist patterns as masks.

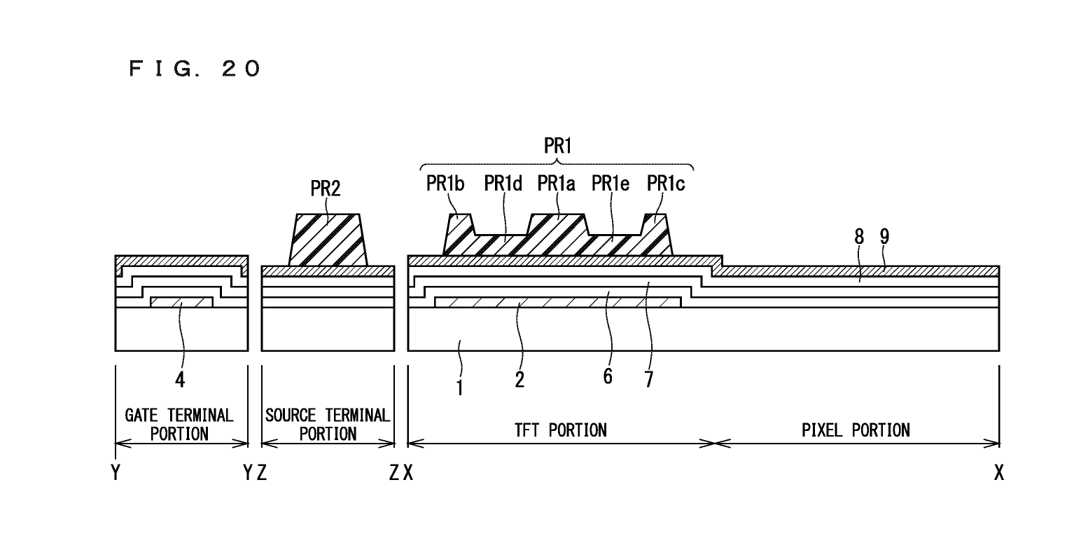

The photoresist patterns formed herein are a photoresist pattern PR1 formed in the formation region of the semiconductor channel layer 7, and a photoresist pattern PR2 formed in the formation region of the lower layer source wiring 15 and the source terminal 15T, as illustrated in FIG. 20. However, upon forming the photoresist pattern PR1, by performing a half exposure, the film thickness of a photoresist pattern PR1d above the formation region of the first source electrode contact hole 11 and the film thickness of a photoresist pattern PR1e above the formation region of the first drain electrode contact hole 12 are made thinner than those of photoresist patterns PR1a, PR1b, PR1c, and PR2 that are the other portions.

Next, the conductive film (Al alloy film) 9 is subjected to etching by using the photoresist patterns PR1 and PR2 as masks. In the etching of the conductive film 9, a wet etching using PAN chemical solution is used. In this case, since being covered with the insulating film 8, the oxide semiconductor film 7 is prevented from being damaged by the chemical solution for etching.

After the conductive film 9 is subjected to etching, the insulating film (SiO film) 8 is subsequently subjected to etching. For the etching, a dry etching method using a gas including fluorine can be used. In the embodiment, dry etching is performed using a gas in which oxide (O₂) is added to sulfur hexafluoride (SF₆). Adding O₂ gas makes it possible to suppress occurrence of damage due to reduction reaction in the oxide semiconductor film 7 below the insulating film 8 during etching.

After the insulating film 8 is subjected to etching, the oxide semiconductor film (InGaZnO film) 7 is subsequently subjected to etching. In this etching, a wet etching method is used using oxalic acid series chemical solution of oxalic acid 5 wt %+water.

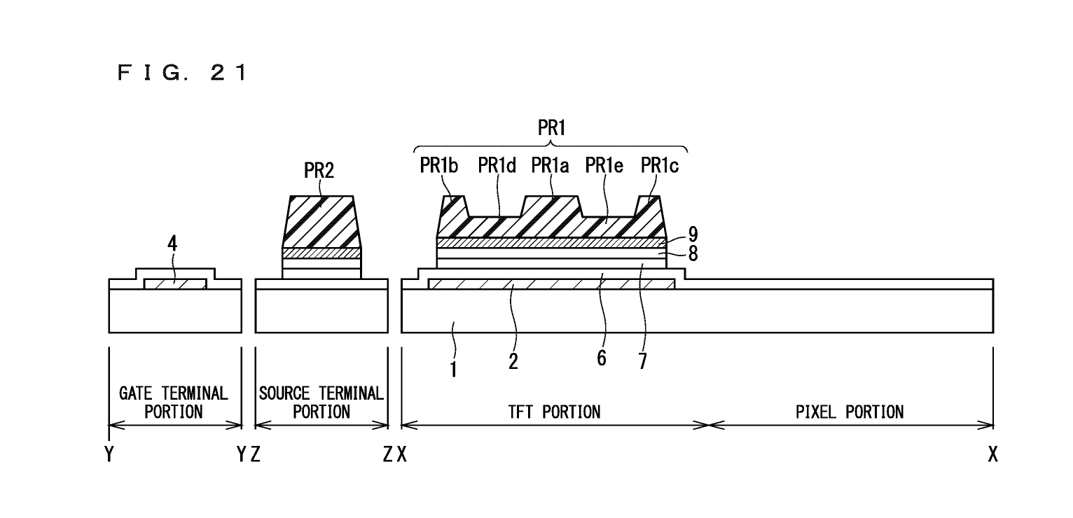

In this manner, as illustrated in FIG. 21, the pattern of the laminate of the oxide semiconductor film 7, the insulating film 8, and the conductive film 9 is formed below each of the photoresist patterns PR1 and PR2.

Then, by oxide ashing, the film thickness of the photoresist patterns PR1 and PR2 is totally reduced to completely remove the photoresist patterns PR1d and 1e having a thin film thickness. In contrast, the photoresist patterns PR1a, PR1b, PR1c, and PR2 having a thick film thickness are reduced in their film thickness to be left.

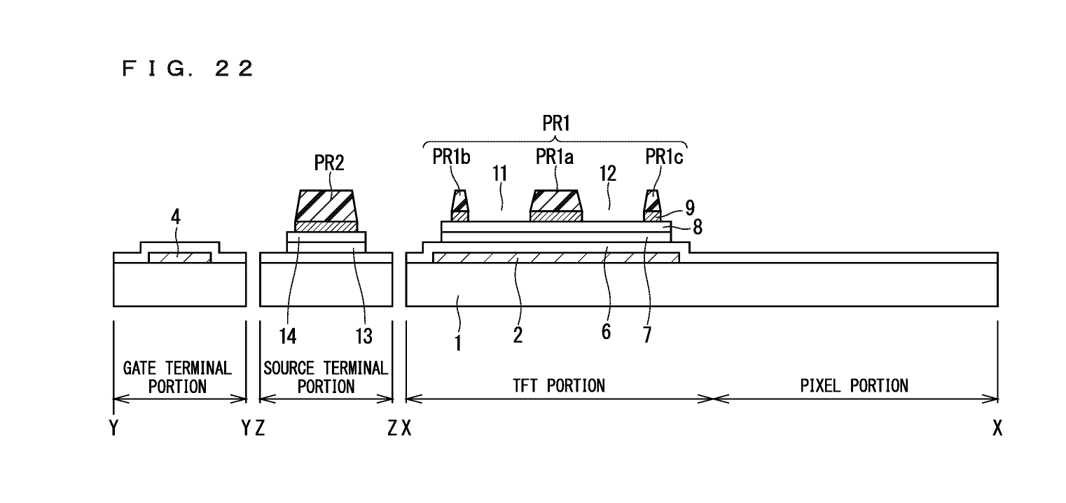

Next, by etching the conductive film 9 again using the remaining photoresist patterns PR1 and PR2 as masks, as illustrated in FIG. 22, the first source electrode contact hole 11 and the first drain electrode contact hole 12 are formed in the conductive film 9. In the etching, a wet etching using PAN chemical solution is used.

Then, by removing the photoresist patterns, as illustrated in FIG. 18, in the TFT portion, above the gate electrode 2, the laminate of the semiconductor channel layer 7, the protective insulating film 8, and the channel region lower layer light shielding film 9 is obtained, and the first source electrode contact hole 11 and the first drain electrode contact hole 12 are formed in the channel region lower layer light shielding film 9. Note that although the outline of the channel region lower layer light shielding film 9 exists inside the outline of the protective insulating film 8 and the semiconductor channel layer 7, this is because the photoresist pattern PR1 is reduced in its film thickness to be made small also in plan view.

Note that although the protective insulating film 8 is exposed at the bottom surfaces of the first source electrode contact hole 11 and the first drain electrode contact hole 12, the semiconductor channel layer 7 that is the lower layer covered with the protective insulting film 8 is prevented from being damaged.

Furthermore, in the source wiring formation region, a laminate of the oxide semiconductor film 13, the insulating film 14, and the lower layer source wiring 15 is formed, and in the source terminal formation region, a laminate of the oxide semiconductor film 13, the insulating film 14 and the source terminal 15T is formed by the same process as the above process.

Note that, although the outline of the source terminal 15T (including lower layer source wiring 15) exists inside the outline of the insulating film 14 and the oxide semiconductor film 13, this is because the photoresist pattern PR2 is reduced in its thickness to be made small also in plan view.

Next, the interlayer insulating film 16 (third insulating film) is formed on the entire upper main surface of the substrate 1. In the embodiment, a resin series insulating film is formed by an organic resin material. Specifically, for example, an organic resin material of an acrylic having photosensitivity is applied on the substrate 1 to have a thickness of 2.0 to 3.0 μm by a spin coat method as the interlayer insulating film 16.

Third Photolithography Step

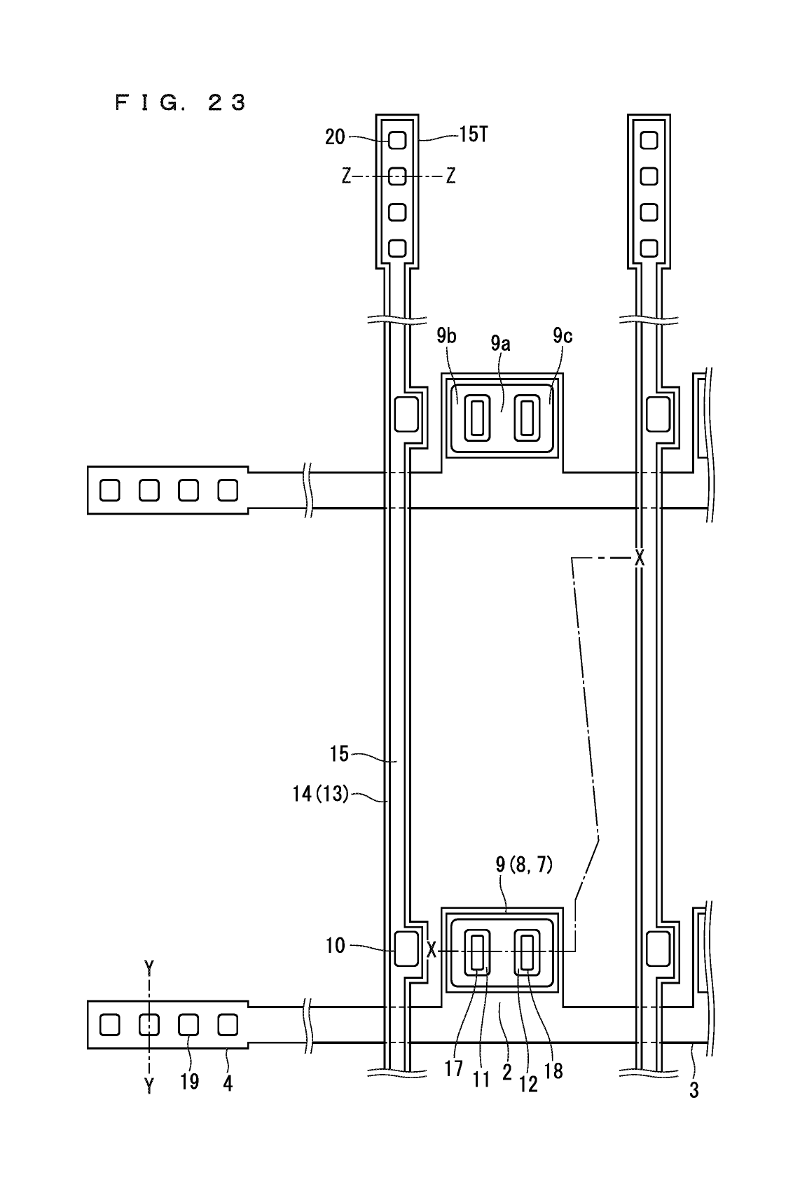

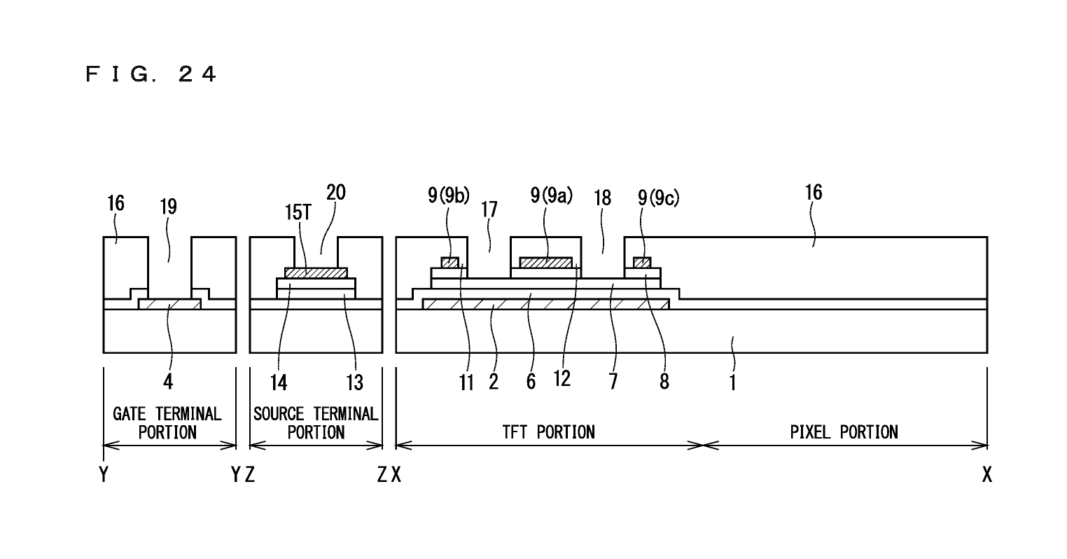

Next, by exposing and developing the interlayer insulating film 16 in a third photolithography step, as illustrated in FIG. 23 and FIG. 24, the first source wiring contact hole 10 (not shown in FIG. 24), the second source electrode contact hole 17, the second drain electrode contact hole 18, the first gate terminal portion contact hole 19, and the first source terminal portion contact hole 20 that penetrate the interlayer insulating film 16 are formed.

Then, the protective insulating film 8 exposed at the bottom portions of the second source electrode contact hole 17 and the second drain electrode contact hole 18 are subjected to etching. For the etching, a dry etching method using a gas including fluorine can be used.

In the embodiment, dry etching is performed by using a gas in which oxygen (O₂) is added to sulfur hexafluoride (SF₆). Adding O₂ gas makes it possible to suppress that the oxide semiconductor film 7 below the protective insulating film 8 is damaged by reduction reaction during etching. By the etching, as illustrated in FIG. 23 and FIG. 24, the semiconductor channel layer 7 is exposed at the bottom surfaces of the second source electrode contact hole 17 and the second drain electrode contact hole 18.

Furthermore, although the first gate terminal portion contact hole 19 also penetrates the insulating film 6, and the gate terminal 4 of Al alloy is exposed at its bottom surface, and the lower layer source wiring 15 and the source terminal 15T of Al alloy are respectively exposed at the bottom surfaces of the first source wiring contact hole 10 and the first source terminal portion contact hole 20, the Al alloy is not etched by dry etching using a gas in which oxygen (O₂) is added to sulfur hexafluoride (SF₆), so that the patterns remain as they are.

Note that, as a material of the resin series insulating film used for the interlayer insulating film 16, besides an acrylic organic resin material, an olefin series material, a novolac series material, a polyimide series material, and a siloxane series material can be also used. Such coating type organic insulating materials have low dielectric constant and is easy to be formed into a thick film having a thickness of not less than 2.0 μm, making it possible to suppress wiring capacity to a low capacity. Thus, using such materials makes it possible to drive the TFT substrate at a low voltage, making it possible to contribute to reducing power consumption. This makes it possible to make the transmissive pixel electrode 24 be arranged on the gate wiring or the source wiring to overlap, also making it possible to make aperture ratio high.

Furthermore, for the interlayer insulating film 16, instead of the resin series insulating film material, an inorganic series insulating material such as silicon nitride (SiN) and silicon oxide (SiO) can be also used. When such an inorganic series insulating material is used, the first source wiring contact hole 10, the second source electrode contact hole 17, the second drain electrode contact hole 18, the first gate terminal portion contact hole 19, and the first source terminal portion contact hole 20 are formed using a photoresist pattern as a mask. Alternatively, an inorganic series insulating film material and a resin series insulating film material may be appropriately combined to be used.

Next, the third conductive film and the fourth conductive film are laminated in this order on the entire upper surface of the interlayer insulating film 16. In the embodiment, a transparent conductive film (translucent conductive film) is used as the third conductive film. As the transparent conductive film, ITO (in which mix ratio of indium oxide (In₂O₃) and tin oxide (SnO₂) is, for example, 90:10 (mass percent)) is used. Herein, by a spattering method, an ITO film having a thickness of 100 nm is formed in amorphous state by using a gas in which a gas including hydrogen (H), for example, hydrogen (H₂) gas, moisture (H₂O), or the like is mixed with argon (Ar). Furthermore, an Al alloy film having light shielding properties is used as the fourth conductive film. Herein, an Al alloy film having a thickness of 100 nm is formed by a spattering method using Ar gas.

Fourth Photolithography Step

Next, a photoresist material is applied on the entire surface of the fourth conductive film (Al alloy film), and a photoresist pattern is formed in a fourth photolithography step. Herein, by performing a half exposure using the half exposure mask described in the second photolithography step, a photoresist pattern having different thicknesses is formed. That is, portions for leaving the fourth conductive film to form the patterns of the upper layer light shielding films 22b and 23b are made thick in their film thicknesses. Note that the fourth conductive film is subjected to etching by two steps, and the film thickness of the photoresist pattern for the portion removed by the second etching is made thin. For example, the film thickness is made thin on the region in which the transmissive pixel electrode 24 is formed so that the fourth conductive film on the region in which the transmissive pixel electrode 24 is formed is not removed in the first etching. Furthermore, the film thickness of the photoresist pattern is made thin also at the gate terminal portion and the source terminal portion.

Then, the fourth conductive film is subjected to patterning by etching using the photoresist pattern as a mask to remove the fourth conductive film at the portion that is not covered with the photoresist pattern. In the etching of the fourth conductive film, a wet etching using PAN chemical solution is used.

Subsequently, the third conductive film is subjected to patterning by etching using the same photoresist pattern as a mask to remove the third conductive film at the portion that is not covered with the photoresist pattern and the fourth conductive film. In the etching of the third conductive film (amorphous ITO), a wet etching is used using oxalic acid series chemical solution of oxalic acid 5 wt %+water.

Then, the whole of the substrate 1 is heated to 150° C. This heating makes the amorphous ITO film be crystallized to become a polycrystalline ITO film. The substrate temperature is not limited to 150° C., and in the case of a typical amorphous ITO film having a mixture ratio in which indium oxide (In₂O₃) is not less than 85 wt % and not more than 95 wt %, and tin oxide (SnO₂) is not less than 5 wt % and not more than 15 wt % (total thereof is 100 wt %), not less than 140° C. enables crystallization. In contrast, on the high temperature side, temperature can be arbitrarily determined depending on the heatproof temperature of a material or the like used for the layer and pattern formed on the TFT substrate. For example, in the embodiment, since an organic resin film of acrylic is used as the third insulating film, not more than 230° C. that is the heatproof temperature of the material is preferable, but, for example, in the case of using a typical photosensitivity resin of novolak series for the photoresist material, not more than 160° C. is preferable.

Next, by oxygen aching, the film thickness of the photoresist pattern is totally reduced to completely remove the photoresist pattern whose film thickness is thin. In contrast, the photoresist pattern whose film thickness is thick is made thin to be left.

Next, the fourth conductive film is subjected to etching again by using a wet etching method using PAN chemical solution using the remaining photoresist pattern as a mask. In this context, since the ITO film that is the transparent conductive film that is the lower layer is poly crystallized, so that the ITO film is chemically very stable, making it possible to etch the Al alloy film that is not covered with a photoresist pattern, for example, the Al alloy film on the region in which the transmissive pixel electrode 24 is formed, and the Al alloy film of the gate terminal portion and the source terminal portion without suffering etching damage practically with respect to PAN chemical solution (disappearance of film or deterioration of electrical properties or optical properties).

Then, by removing the photoresist pattern, as illustrated in FIG. 13 and FIG. 14, the gate terminal extraction electrode 25, the source electrode 22, the upper layer source wiring 26 extending from the source electrode 22, the source terminal extraction electrode 26T, the drain electrode 23, and the transmissive pixel electrode 24 extending from the drain electrode 23 configured by the transparent conductive film (polycrystalline ITO film) are formed. Furthermore, the upper layer light shielding films 22b and 23b are respectively formed on the upper portion of the source electrode 22 and the upper portion of the drain electrode 23 of the TFT portion. The upper layer light shielding films 22b and 23b are formed to cover substantially the whole of the planer pattern of the semiconductor channel layer 7 excluding the channel region BC in plan view.

Herein, the gate terminal extraction electrode 25 is directly connected to the gate terminal 4 via the first gate terminal portion contact hole 19. Furthermore, the source electrode 22 is directly connected to the semiconductor channel layer 7 via the second source electrode contact hole 17. Furthermore, the upper layer source wiring 26 is directly connected to the lower layer source wiring 15 via the first source wiring contact hole 10. Furthermore, the source wiring extraction electrode 26T is directly connected to the source terminal 15T via the first source terminal portion contact hole 20.

Then, the liquid crystal display panel is assembled and a light polarizing plate, a phase difference plate, a driving circuit, a backlight unit, and the like are arranged outside the liquid crystal display panel to complete the liquid crystal display device, but the detail thereof is described in the first embodiment, so that the description thereof is omitted.

As described above, in the second embodiment, in the second photolithography step, a photoresist pattern having different thicknesses is formed by exposure (half exposure) using a half exposure mask, and the oxide semiconductor film, the second insulating film, and the second conductive film are subjected to pattering by etching using the photoresist pattern. This makes it possible to manufacture the TFT substrate 200 equipped with an etch stopper type TFT using an oxide semiconductor film having a high performance as the channel layer with four photolithography steps reduced by up to two steps as compared with the case of the first embodiment.

Furthermore, similar to the first embodiment, the protective insulating film 8 that becomes an etch stopper is subsequently formed after formation of the oxide semiconductor film, nearly preventing the semiconductor channel layer 7 from being deteriorated in its properties due to process damage of the subsequent TFT manufacturing step. This makes it possible to use the semiconductor channel layer 7 as the channel layer of the TFT in the state where high performance properties of the oxide semiconductor are kept.

Furthermore, the source wiring 151 is made to be a redundant wiring, and the upper layer source wiring 26 is made to be directly connect with the lower layer source wiring 15 via the plurality of first source wiring contact holes 10 provided in the interlayer insulating film 16, making it possible to complement the function by the other wiring even when one of the wirings is disconnected. This makes it possible to reduce generation of linear defect due to disconnection of the source wiring 151 to improve yield ratio during manufacturing and reliability of the product.

Furthermore, the lower layer source wiring 15 is consecutively formed with the oxide semiconductor film and the insulating film, making it possible to form the lower layer source wiring 15 (second conductive film) with good adhesiveness, making it possible to reduce generation of disconnection defect due to peeling off of film caused by lack of sticking force. This effect is specifically large at a step portion on the gate wiring pattern in the region in which the gate wiring 3 and the lower layer source wiring 15 intersect.

Furthermore, the semiconductor channel layer 7 is configured such that its entire region is shielded from light by the two-layered light shielding films also on the upper side of the semiconductor channel layer 7 in addition to light shielding by the gate electrode 2 on the lower side of the semiconductor channel layer 7, making it possible to prevent deterioration (optical deterioration) of the channel layer due to absorption of backlight light during operating the liquid crystal display device and external light.

Furthermore, forming the channel region lower layer light shielding film 9 with a conductive film and making the source electrode 22 and the drain electrode 2s be electrically separated (no short circuit occurs) to be an electrically floating state enables achievement of an electrostatic shielding effect with respect to the semiconductor channel layer 7 to suppress variation of TFT properties due to unspecified external noise or the like, making it possible to improve reliability.

Furthermore, using a resin series insulating film that has low permittivity, that is made thick in its film thickness to be not less than 2.0 μm, and that has a flattening action with respect to the main surface of the substrate 1 as the interlayer insulating film 16 (third insulating film) makes it possible to suppress wiring capacity to a low level. This makes it possible to drive the TFT substrate at a low voltage, making it possible to contribute to reducing power consumption. This makes it possible to make the transmissive pixel electrode 24 be arranged on the gate wiring or the source wiring to overlap, also making it possible to make aperture ratio high.

Modification

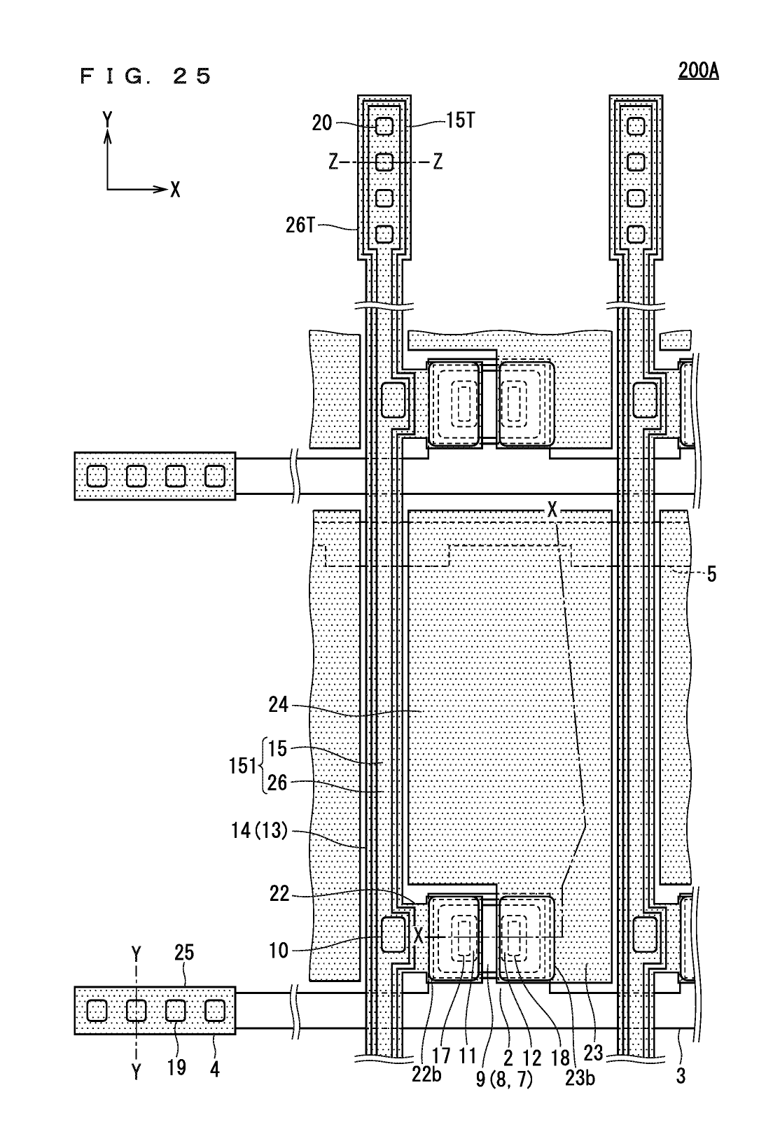

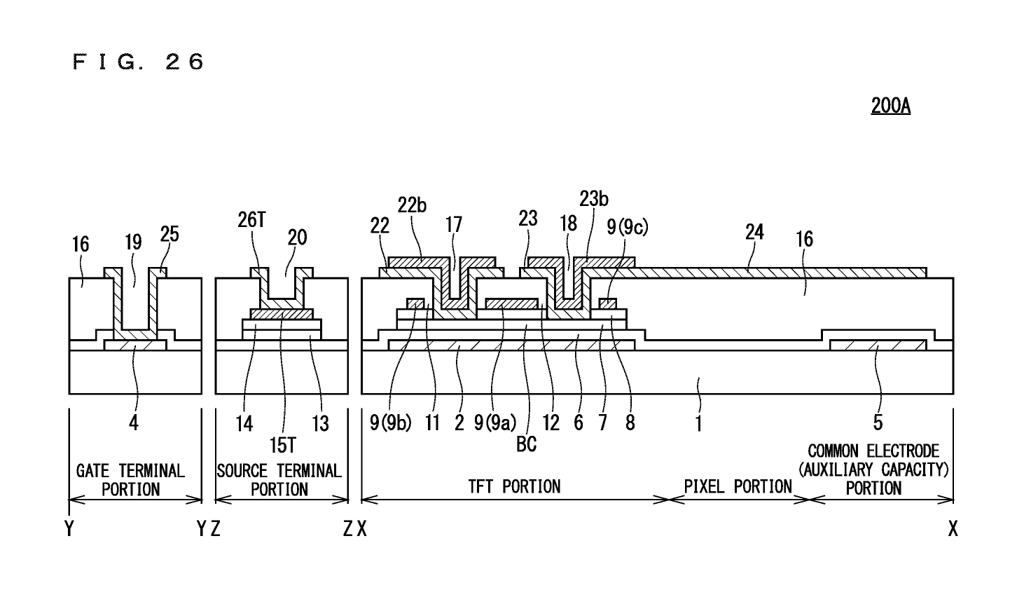

Next, with reference to FIG. 25 and FIG. 26, a configuration of a TFT substrate 200A according to a modification of the second embodiment will be described. The TFT substrate 200A has a configuration further including a common electrode that becomes an auxiliary capacity of a pixel electrode in the pixel portion of the TFT substrate 200. Note that the same reference numerals are given to the same components as those in the TFT substrate 200 illustrated by using FIG. 13 and FIG. 14, and the overlapping description will be omitted.

Configuration of Pixel of TFT Substrate

FIG. 25 is a plan view illustrating a planar configuration of a pixel according to the modification of the second embodiment, and FIG. 26 is a cross sectional view illustrating a cross sectional configuration taken along the line X-X (cross sectional configuration of TFT portion, cross sectional configuration of pixel portion, and cross sectional configuration of common electrode portion), a cross sectional configuration taken along the line Y-Y (cross sectional configuration of gate terminal portion), and cross sectional configuration taken along the line Z-Z (cross sectional configuration of source terminal portion) in FIG. 25. Note that, in the following description, the TFT substrate 200A shall be used for a liquid crystal display device of TN mode of light transmission type.

As illustrated in FIG. 25, in the TFT substrate 200A, a gate electrode 2 of the TFT is configured by a portion of a gate wiring 3. That is, a portion brunched from the gate wiring 3 to extend to a formation region of the TFT (TFT portion) forms the gate electrode 2. In the embodiment, the depth and the width of the portion to be the gate electrode 2 is made wider than the width of the gate wiring 3 so as to be a size that enables a source electrode 22 and a drain electrode 23 to be arranged above the gate electrode 2. Furthermore, a common electrode 5 is provided to extend in parallel with the gate wiring 3.

One end of the gate wiring 3 is electrically connected to a gate terminal 4, and a gate terminal extraction electrode 25 is connected to the gate terminal 4 via a first gate terminal portion contact hole 19. Note that as described below, as the gate wiring 3, the gate terminal 4, and the common electrode 5, a first conductive film made of a metal or an alloy having light shielding properties, for example, a metal such as molybdenum (Mo) and aluminum (Al), or an alloy obtained by adding another element to the metal is used.

As illustrated in FIG. 25, the gate wiring 3 and the common electrode 5 are arranged to extend in the lateral direction (X direction), and a source wiring 151 is arranged to extend in the vertical direction (Y direction). Note that the source wiring 151 is configured by a lower layer source wiring 15 and an upper layer source wiring 26.

Furthermore, one end of the lower layer source wiring 15 is connected to a source terminal 15T, and a source terminal extraction electrode 26T is connected to the source terminal 15T via a first source terminal portion contact hole 20.

Making the upper layer source wiring 26 extending from the source electrode 22 be connected to the lower layer source wiring 15 via a first source wiring contact hole 10 makes the source electrode 22 be electrically connected to the lower layer source wiring 15. Furthermore, the drain electrode 23 extends to a pixel region to form a transmissive pixel electrode 24. Furthermore, upper layer light shielding films 22b and 23b are respectively provided on the regions of the source electrode 22 and the drain electrode 23.

Note that the region surrounded by the adjacent gate wirings 3 and the adjacent lower layer source wirings 15 becomes a pixel region, so that pixel regions are arranged in a matrix manner in the TFT substrate 200A.

Next, a cross sectional configuration of the TFT substrate 200A will be described using FIG. 26. As illustrated in FIG. 26, the TFT substrate 200A includes a substrate 1 that is a transparent insulating substrate such as a glass as its base material, and the gate electrode 2 (including gate wiring 3), the gate terminal 4, and the common electrode 5 are arranged on the substrate 1.

Then, an insulating film 6 (first insulating film) is arranged to cover the gate electrode 2, the gate terminal 4, and the common electrode 5. The insulating film 6 functions as a gate insulating film at the TFT portion, so that the insulating film 6 is referred to as a gate insulating film 6 in some cases.

In the TFT portion, an oxide semiconductor film 7 is arranged on the insulating film 6 at the position overlapping with the gate electrode 2. The oxide semiconductor film 7 functions as a channel layer of the TFT, so that the oxide semiconductor film 7 is referred to as a semiconductor channel layer 7 in some cases. Note that in the modification, the planer pattern of the semiconductor channel layer 7 is made smaller than the planer pattern of the gate electrode 2 in plan view, and the outline of the semiconductor channel layer 7 exists inside the outline of the gate electrode 2. Note that the material of the semiconductor channel layer 7 is the same as that described in the first embodiment, making it possible to increase mobility as compared with a conventional configuration in which amorphous silicon is used for the semiconductor channel layer.

A protective insulating film 8 (second insulating film) is arranged on the semiconductor channel layer 7, and a channel region lower layer light shielding film 9 (second conductive film) formed of a metal film having light shielding properties or the like is arranged on the protective insulating film 8.

In the modification, as the channel region lower layer light shielding film 9, for example, a metal such as molybdenum (Mo) and aluminum (Al), or an alloy obtained by adding another element to the metal is used. Then, a first source electrode contact hole 11 and a first drain electrode contact hole 12 are provided in the channel region lower layer light shielding film 9 above the semiconductor channel layer 7. Note that the channel region lower layer light shielding film 9 is referred to as a lower layer light shielding film 9a, 9b, or 9c in some cases depending on its arranged position for descriptive purposes.

Furthermore, in the source terminal portion, an oxide semiconductor film 13 in the same layer as the semiconductor channel layer 7 of the TFT portion is provided, and an insulating film 14 in the layer the same as the protective insulating film 8 is provided on the oxide semiconductor film 13. Then, the source terminal 15T (including lower layer source wiring 15) in the same layer as the channel region lower layer light shielding film 9 (second conductive film) is provided on the insulating film 14, so that the source terminal 15T is the upper most layer film of the laminate of the three layers.

Furthermore, in the gate terminal portion, the insulating film 6 is formed to cover the gate terminal 4 (including gate wiring 3).

Then, an interlayer insulating film 16 (third insulating film) is arranged above the entire surface of the substrate 1 to cover the insulating film 6, the semiconductor channel layer 7, the protective insulating film 8, and the channel region lower layer light shielding film 9. Then, in the TFT portion, a second source electrode contact hole 17 and a second drain electrode contact hole 18 penetrating the interlayer insulating film 16 and the protective insulating film 8 to reach the semiconductor channel layer 7 are provided. The second source electrode contact hole 17 is arranged to be located inside the outer circumference of the first source electrode contact hole 11 in plan view, and is formed such that a surface of the semiconductor channel layer 7 is exposed at its bottom surface. Furthermore, the second drain electrode contact hole 18 is arranged to be located inside the outer circumference of the first drain electrode contact hole 12 in plan view, and is formed such that a surface of the semiconductor channel layer 7 is exposed at its bottom surface.

Then, the source electrode 22 and the drain electrode 23 formed as a third conductive film are arranged so as to be separated from each other and directly connected to the semiconductor channel layer 7 via the second source electrode contact hole 17 and the second drain electrode contact hole 18, respectively. The region between the source electrode 22 and the drain electrode 23 in the semiconductor channel layer 7 forms a channel region BC. Note that, in the embodiment, a transparent conductive film (translucent conductive film) is used as the third conductive film.

Furthermore, while the drain electrode 23 extends to the pixel region to form the transmissive pixel electrode 24, the transmissive pixel electrode 24 partially overlaps with the common electrode 5 of the common electrode portion in plan view, forming an auxiliary capacity for the pixel electric potential via the insulating film 6 and the interlayer insulating film 16.

The upper layer light shielding films 22b and 23b (fourth conductive film) are respectively provided on the source electrode 22 and the drain electrode 23. When the upper layer light shielding films 22b and 23b are formed by, for example, a metal film having light shielding properties, the upper layer light shielding films 22b and 23b are formed so as to be separated from each other to prevent electrical short circuit between the source electrode 22 and the drain electrode 23. In the embodiment, as the upper layer light shielding films 22b, 23b, a metal such as molybdenum (Mo) and aluminum (Al), or an alloy obtained by adding another element to the metal can be used.

As illustrated in FIG. 25, the upper region of the semiconductor channel layer 7 of the TFT portion is configured such that light from an upper surface is shielded in its entire region in plan view by the upper layer light shielding films 22b, 23b, and the lower layer light shielding films 9a, 9b, 9c. Furthermore, the lower region of the semiconductor channel layer 7 of the TFT portion is configured such that light from a lower surface (surface on the side of the substrate 1) is shielded in its entire region in plan view by the gate electrode 2. Forming the TFT portion in this manner makes it possible to almost perfectly prevent backlight light, external light, and scattering light thereof from being incident on the semiconductor channel layer 7 (light shielding), making it possible to prevent property degradation of the semiconductor channel layer 7 due to light absorption.

Furthermore, in the source terminal portion, the source extraction electrode 26T is provided to be directly connected to the source terminal 15T via the first source terminal portion contact hole 20 penetrating the interlayer insulating film 16 to reach the source terminal 15T.

Furthermore, in the gate terminal portion, the gate terminal extraction electrode 25 is provided to be directly connected to the gate terminal 4 via the first gate terminal portion contact hole 19 penetrating the interlayer insulating film 16 and the insulating film 6 to reach the gate terminal.

Note that, the source extraction electrode 26T and the gate terminal extraction electrode 25 are formed by the third conductive film in the same layer as the source electrode 22 and the drain electrode 23 of the TFT portion.

Manufacturing Method

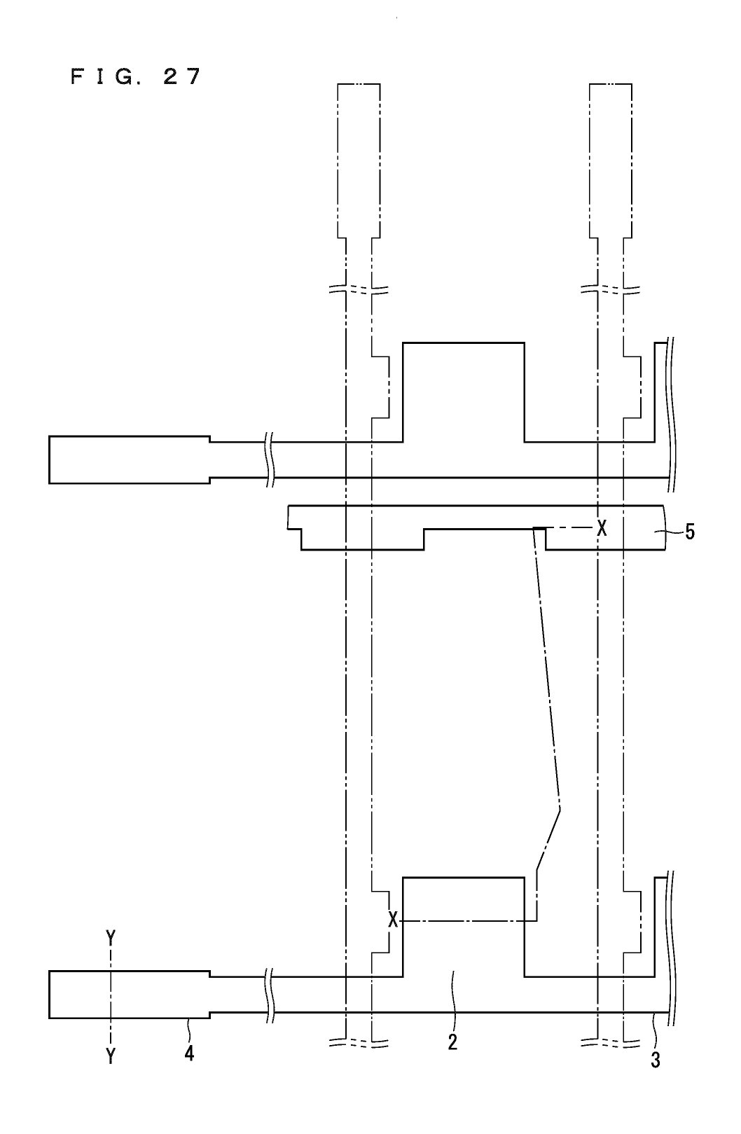

Hereinafter, a manufacturing method of the TFT substrate 200A according to the modification of the second embodiment will be described using FIG. 27 to FIG. 36. Note that a plan view and a cross sectional view illustrating the final step respectively correspond to FIG. 25 and FIG. 26.

The first conductive film that is the material of the gate electrode 2, the gate wiring 3, and the like is formed on one of the entire main surfaces of the substrate 1 that has been washed. The material capable of being used as the first conductive film is described in the first embodiment, so that overlapping description will be omitted. In the modification, an aluminum (Al) alloy film shall be used as the first conductive film, and the Al alloy film is formed to have a thickness of 200 nm by a sputtering method using argon (Ar) gas.

First Photolithography Step

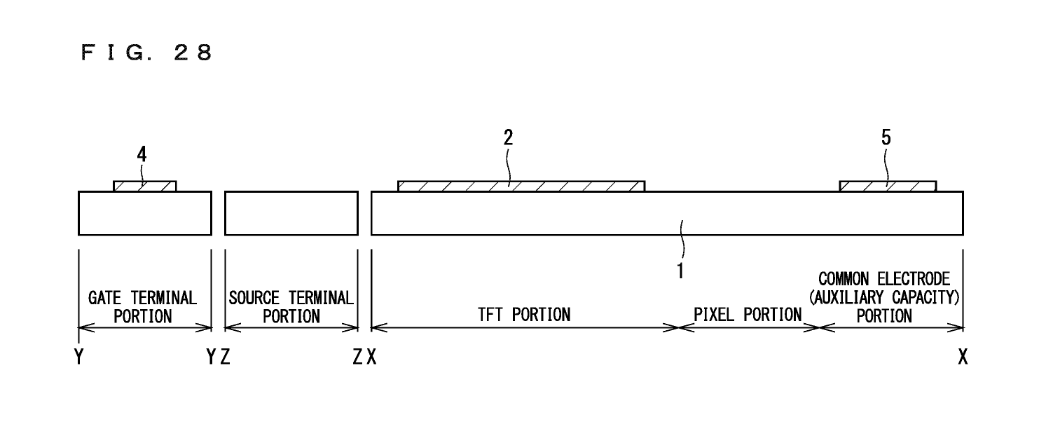

Then, a photoresist material is applied on the first conductive film, a photoresist pattern is formed in a first photolithography step, and the first conductive film is subjected to patterning by etching using the photoresist pattern as a mask. Herein, a wet etching using PAN chemical solution is used. Then, by removing the photoresist pattern, as illustrated in FIG. 27 and FIG. 28, the gate electrode 2, the gate wiring 3 (not shown in FIG. 28), the gate terminal 4, and the common electrode 5 are formed on the upper main surface of the substrate 1.

Second Photolithography Step

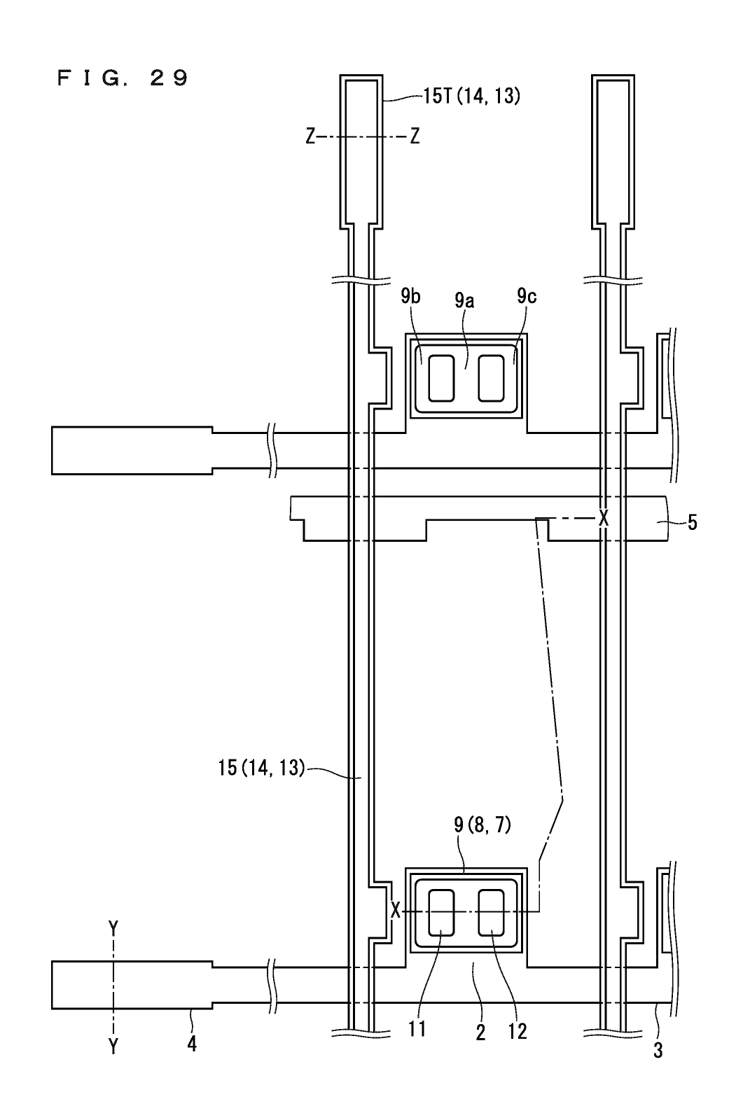

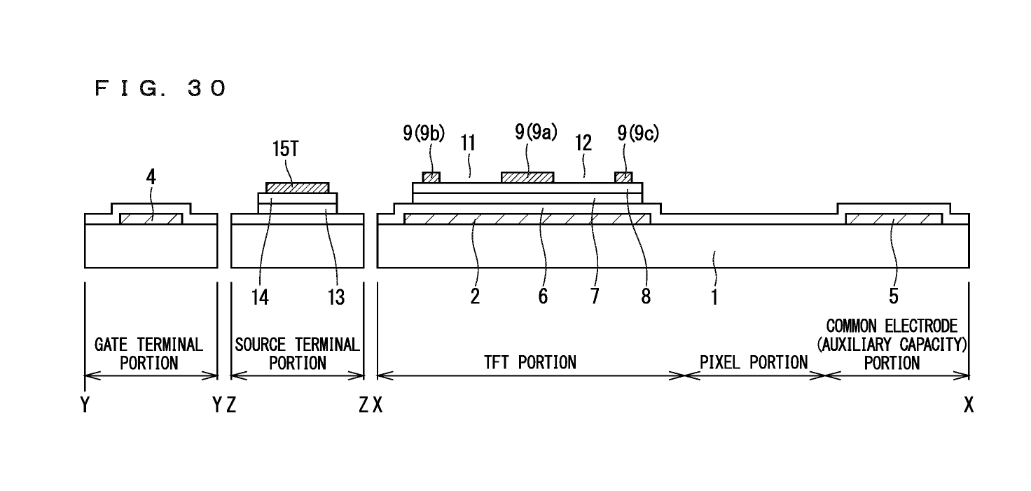

Then, after the insulating film 6 (first insulating film) is formed on the entire upper main surface of the substrate 1 to cover the gate electrode 2, the gate wiring 3, the gate terminal 4, and the common electrode 5, the oxide semiconductor film, the second insulating film, and the second conductive film are laminated in this order on the insulating film 6. Then, in a second photolithography step, a photoresist pattern having different thicknesses is formed by a half exposure using a half exposure mask, and the oxide semiconductor film, the second insulating film, and the second conductive film are subjected to patterning by etching using the photoresist pattern. Herewith, as illustrated in FIG. 29 and FIG. 30, the laminate of the semiconductor channel layer 7, the protective insulating film 8, and the channel region lower layer light shielding film 9 is obtained above the gate electrode 2, and the first source electrode contact hole 11 and the first drain electrode contact hole 12 are formed in the channel region lower layer light shielding film 9. Herein, the outline of the semiconductor channel layer 7 in plan view is arranged to exist inside the outline of the gate electrode 2.

Furthermore, for descriptive purposes, the channel region lower layer light shielding film 9 that remains between the first source electrode contact hole 11 and the first drain electrode contact hole 12 is referred to as the lower layer light shielding film 9a, the channel region lower layer light shielding film 9 that remains on the side opposite to the lower layer light shielding film 9a of the first source electrode contact hole 11 is referred to as the lower layer light shielding film 9b, and the channel region lower layer light shielding film 9 that remains on the side opposite to the lower layer light shielding film 9a of the first drain electrode contact hole 12 is referred to as the lower layer light shielding film 9c.

Furthermore, in a source wiring formation region, a laminate of the oxide semiconductor film 13, the insulating film 14, and the lower layer source wiring 15 is formed, and in a source terminal formation region, a laminate of the oxide semiconductor film 13, the insulating film 14, and the source terminal 15T is formed by the same process as the above process.

Note that, as for the material and forming method of the insulating film 6, the oxide semiconductor film, the second insulating film, and the second conductive film, and the etching using a photoresist pattern formed by a half exposure, description is made using FIG. 19 to FIG. 22 in the second embodiment, so that the description will be omitted.

Third Photolithography Step

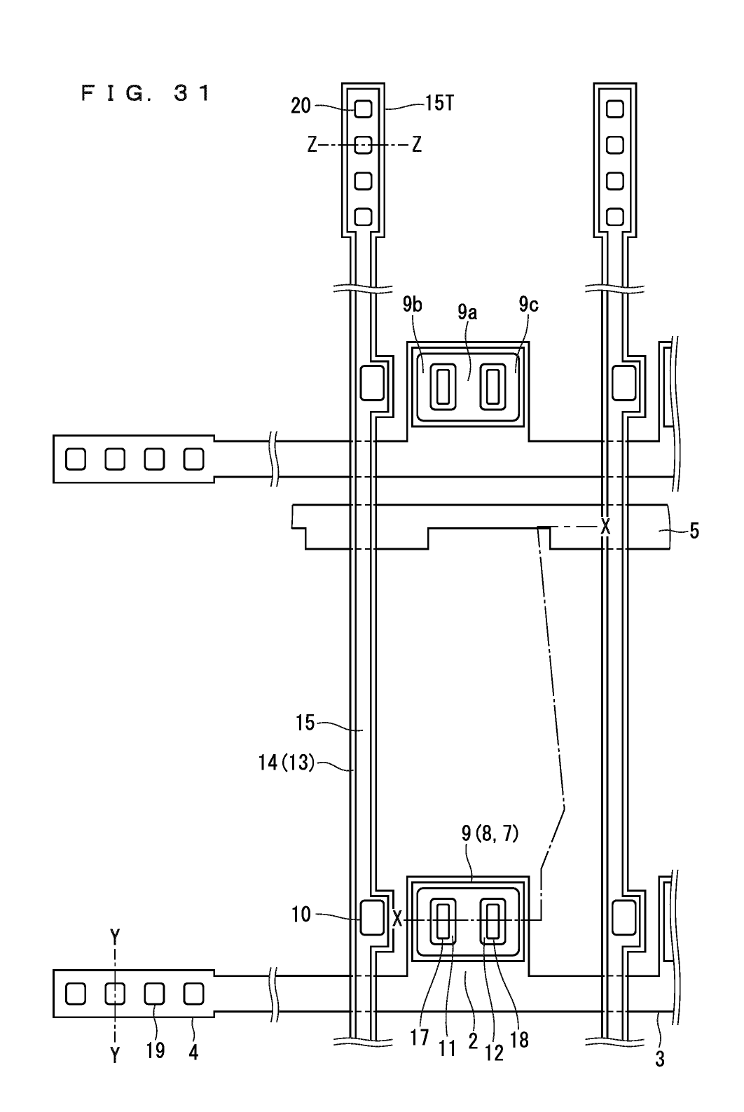

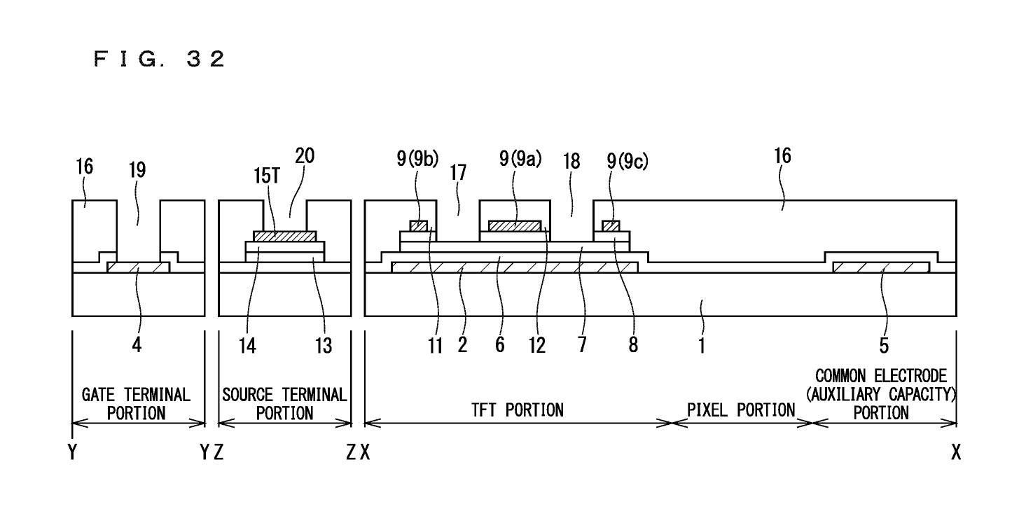

Next, the interlayer insulating film 16 (third insulating film) is formed on the entire upper main surface of the substrate 1, and by exposing and developing the interlayer insulating film 16 in a third photolithography step, as illustrated in FIG. 31 and FIG. 32, the first source wiring contact hole 10 (not shown in FIG. 32), the second source electrode contact hole 17, the second drain electrode contact hole 18, the first gate terminal portion contact hole 19, and the first source terminal portion contact hole 20 that penetrate the interlayer insulating film 16 are formed.

Then, the protective insulating film 8 exposed at the bottom portions of the second source electrode contact hole 17 and the second drain electrode contact hole 18 are subjected to etching. Note that the etching method is the same as that in the second embodiment. By the etching, as illustrated in FIG. 31 and FIG. 32, the semiconductor channel layer 7 is exposed at the bottom surfaces of the second source electrode contact hole 17 and the second drain electrode contact hole 18.

Next, the third conductive film and the fourth conductive film are laminated in this order on the entire upper surface of the interlayer insulating film 16. In the modification, a transparent conductive film (translucent conductive film) is used as the third conductive film, and an Al alloy film having light shielding properties is used as the fourth conductive film. Note that the material, the film thickness, and the manufacturing method of the transparent conductive film, and the material, the film thickness, and the manufacturing method of the Al alloy film are the same as those in the third embodiment, so that the description will be omitted.

Fourth Photolithography Step

Next, a photoresist material is applied on the entire surface of the fourth conductive film (Al alloy film), and a photoresist pattern is formed in a fourth photolithography step. Herein, by performing a half exposure using the half exposure mask described in the second photolithography step, a photoresist pattern having different thicknesses is formed.

Then, the fourth conductive film is subjected to patterning by a wet etching using PAN chemical solution using the photoresist pattern as a mask to remove the fourth conductive film at the portion that is not covered with the photoresist pattern.

Subsequently, the third conductive film is subjected to patterning by a wet etching using an oxalic acid series chemical solution of oxalic acid 5 wt %+water using the same photoresist pattern as a mask to remove the third conductive film at the portion that is not covered with the photoresist pattern and the fourth conductive film.

Then, the whole of the substrate 1 is heated to 150° C. to make the amorphous ITO film be crystallized to be a polycrystalline ITO film.

Next, by oxygen ashing, the film thickness of the photoresist pattern is totally reduced to completely remove the photoresist pattern whose film thickness is thin. In contrast, the photoresist pattern whose film thickness is thick is made thin to be left.

Next, the fourth conductive film is subjected to etching again by using a wet etching method using PAN chemical solution using the remaining photoresist pattern as a mask. In this context, the ITO film that is the transparent conductive film that is the lower layer is poly crystallized, making it possible to etch the Al alloy film that is not covered with the photoresist pattern, for example, the Al alloy film on the region in which the transmissive pixel electrode 24 is formed and the Al alloy film of the gate terminal portion and the source terminal portion without suffering etching damage practically with respect to PAN chemical solution (disappearance of film or deterioration of electrical properties or optical properties).

Then, by removing the photoresist pattern, as illustrated in FIG. 25 and FIG. 26, the gate terminal extraction electrode 25, the source electrode 22, the upper layer source wiring 26 extending from the source electrode 22, the source terminal extraction electrode 26T, the drain electrode 23, and the transmissive pixel electrode 24 extending from the drain electrode 23 configured by the transparent conductive film (polycrystalline ITO film) are formed. Furthermore, the upper layer light shielding films 22b and 23b are respectively formed on the upper portion of the source electrode 22 and the upper portion of the drain electrode 23 of the TFT portion. The upper layer light shielding films 22b and 23b are formed to cover substantially the whole of the planer pattern of the semiconductor channel layer 7 excluding the channel region BC in plan view.

Then, the liquid crystal display panel is assembled and a light polarizing plate, a phase difference plate, a driving circuit, a backlight unit, and the like are arranged outside the liquid crystal display panel to complete the liquid crystal display device, but the detail thereof is described in the first embodiment, so that the description thereof is omitted.

As described above, in the modification, an auxiliary capacity can be added to the transmissive pixel electrode 24 by providing the common electrode 5, making it possible to increase a leak margin of a display signal electric potential applied to the transmissive pixel electrode 24 in addition to the effects the same as those in the second embodiment. This makes it possible to reduce display defect caused by retention failure of signal electric potential to achieve a higher quality liquid crystal display device.

### Third Embodiment

Configuration of Pixel of TFT Substrate

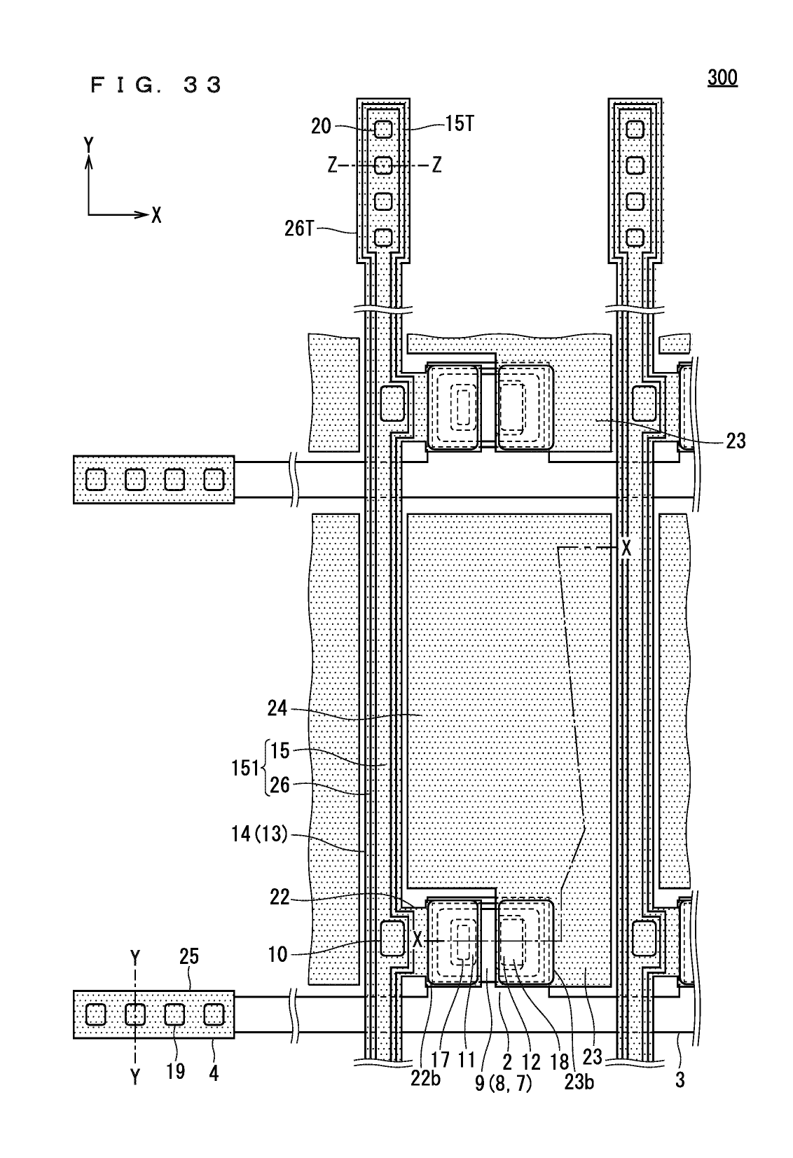

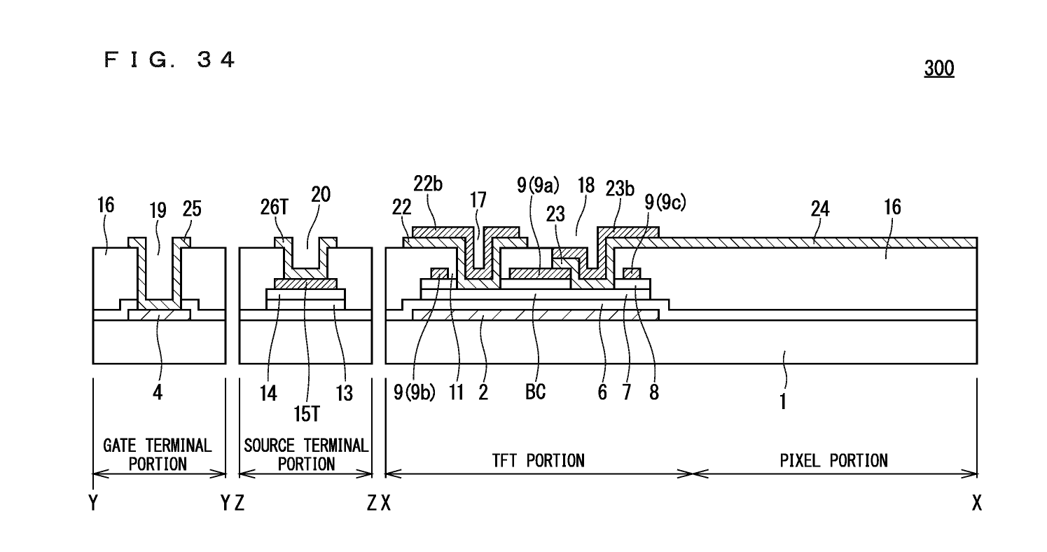

First, with reference to FIG. 33 and FIG. 34, a configuration of a TFT substrate 300 according to a third embodiment will be described. Note that the same reference numerals are given to the same components as those in the TFT substrate 100 illustrated by using FIG. 1 and FIG. 2, and the overlapping description will be omitted.

FIG. 33 is a plan view illustrating a planar configuration of a pixel according to the third embodiment, and FIG. 34 is a cross sectional view illustrating a cross sectional configuration taken along the line X-X (cross sectional configuration of TFT portion and cross sectional configuration of pixel portion), a cross sectional configuration taken along the line Y-Y (cross sectional configuration of gate terminal portion), and a cross sectional configuration taken along the line Z-Z (cross sectional configuration of source terminal portion) in FIG. 33. Note that, in the following description, the TFT substrate 300 shall be used for a liquid crystal display device of TN mode of light transmission type.

As illustrated in FIG. 33, in the TFT substrate 300, a gate electrode 2 of the TFT is configured by a portion of a gate wiring 3. That is, a portion brunched from the gate wiring 3 to extend to a formation region of the TFT (TFT portion) forms the gate electrode 2, In the embodiment, the depth and the width of the portion to be the gate electrode 2 is made wider than the width of the gate wiring 3 so as to be a size that enables a source electrode 22 and a drain electrode 23 to be arranged above the gate electrode 2.

One end of the gate wiring 3 is electrically connected to a gate terminal 4, and a gate terminal extraction electrode 25 is connected to the gate terminal 4 via a first gate terminal portion contact hole 19. Note that as the gate wiring 3 and the gate terminal 4, as described below, a first conductive film made of a metal or an alloy having light shielding properties, for example, a metal such as molybdenum (Mo), and aluminum (Al), or an alloy obtained by adding another element to the metal is used.

As illustrated in FIG. 33, the gate wirings 3 are arranged to extend in a lateral direction (X direction), and source wirings 151 are arranged to extend in a vertical direction (Y direction). Note that the source wiring 151 is configured by a lower layer source wiring 15 and an upper layer source wiring 26.

Furthermore, one end of the lower layer source wiring 15 is connected to a source terminal 15T, and a source terminal extraction electrode 26T is connected to the source terminal 15T via a first source terminal portion contact hole 20.

Making the upper layer source wiring 26 extending from the source electrode 22 be connected to the lower layer source wiring 15 via a first source wiring contact hole 10 makes the source electrode 22 be electrically connected to the lower layer source wiring 15. Furthermore, the drain electrode 23 extends to a pixel region to form a transmissive pixel electrode 24. Furthermore, upper layer light shielding films 22b and 23b are respectively provided on the regions of the source electrode 22 and the drain electrode 23.

Note that the region surrounded by the adjacent gate wirings 3 and the adjacent lower layer source wirings 15 becomes a pixel region, so that pixel regions are arranged in a matrix manner in the TFT substrate 300.

Next, a cross sectional configuration of the TFT substrate 300 will be described using FIG. 34. As illustrated in FIG. 34, the TFT substrate 300 includes a substrate 1 that is a transparent insulating substrate such as a glass as its base material, and the gate electrode 2 (including gate wiring 3), and the gate terminal 4 are arranged on the substrate 1.

Then, an insulating film 6 (first insulating film) is arranged to cover the gate electrode 2 and the gate terminal 4. The insulating film 6 functions as a gate insulating film at the TFT portion, so that the insulating film 6 is referred to as a gate insulating film 6 in some cases.

In the TFT portion, an oxide semiconductor film 7 is arranged on the insulating film 6 at the position overlapping with the gate electrode 2. The oxide semiconductor film 7 functions as a channel layer of the TFT, so that the oxide semiconductor film referred to as a semiconductor channel layer 7 in some cases. Note that, in the embodiment, the planer pattern of the semiconductor channel layer 7 is made smaller than the planer pattern of the gate electrode 2 in plan view, so that the outline of the semiconductor channel layer 7 exists inside the outline of the gate electrode 2. Note that the material of the semiconductor channel layer 7 is the same as that described in the first embodiment, making it possible to increase mobility as compared with a conventional configuration in which amorphous silicon is used for the semiconductor channel layer.

A protective insulating film 8 (second insulating film) is arranged on the semiconductor channel layer 7, and a channel region lower layer light shielding film 9 (second conductive film) formed of a metal film having light shielding properties or the like is arranged on the protective insulating film 8.

In the embodiment, as the channel region lower layer light shielding film 9, for example, a metal such as molybdenum (Mo) and aluminum (Al), or an alloy obtained by adding another element to the metal is used. Then, a first source electrode contact hole 11 and a first drain electrode contact hole 12 are provided in the channel region lower layer light shielding film 9 above the semiconductor channel layer 7. Note that the channel region lower layer light shielding film 9 is referred to as a lower layer light shielding film 9a, 9b, or 9c in some cases depending on its arranged position for descriptive purposes. Furthermore, the outline of the channel region lower layer light shielding film 9 exists inside the outlines of the protective insulating film 8 and the semiconductor channel layer 7, which differs from the first embodiment because of difference in their manufacturing methods.

Furthermore, in the source terminal portion, an oxide semiconductor film 13 in the same layer as the semiconductor channel layer 7 of the TFT portion is provided, and an insulating film 14 in the layer the same as the protective insulating film 8 is provided on the oxide semiconductor film 13. Then, the source terminal 15T (including lower layer source wiring 15) in the same layer as the channel region lower layer light shielding film 9 (second conductive film) is provided on the insulating film 14, so that the source terminal 15T is the upper most layer film of the laminate of the three layers. Note that, the outline of the source terminal 15T (including lower layer source wiring 15) exists inside the outlines of the insulating film 14 and the oxide semiconductor film 13, which differs from the first embodiment because of difference in their manufacturing methods.

Furthermore, in the gate terminal portion, the insulating film 6 is formed to cover the gate terminal 4 (including gate wiring 3).

Then, an interlayer insulating film 16 (third insulating film) is arranged above the entire surface of the substrate 1 to cover the insulating film 6, the semiconductor channel layer 7, the protective insulating film 8, and the channel region lower layer light shielding film 9. Then, in the TFT portion, a second source electrode contact hole 17 and a second drain electrode contact hole 18 penetrating the interlayer insulating film 16 and the protective insulating film 8 to reach the semiconductor channel layer 7 are provided. The second source electrode contact hole 17 is arranged to be located inside the outer circumference of the first source electrode contact hole 11 in plan view, and is formed such that a surface of the semiconductor channel layer 7 is exposed at its bottom surface. Furthermore, the second drain electrode contact hole 18 is arranged such that at least a portion thereof is located outside the outer circumference of the first drain electrode contact hole 12 in plan view, and is formed such that both of the surface of the semiconductor channel layer 7 and the surface of at least a portion of the region of the channel region lower layer light shielding film 9 (region of the lower layer light shielding film 9a in the embodiment) are exposed.

Then, the source electrode 22 and the drain electrode 23 formed as a third conductive film are arranged so as to be separated from each other and directly connected to the semiconductor channel layer 7 via the second source electrode contact hole 17 and the second drain electrode contact hole 18, respectively.

The region between the source electrode 22 and the drain electrode 23 in the semiconductor channel layer 7 forms a channel region BC. Note that the drain electrode 23 is connected to the semiconductor channel layer 7 and also directly connected to the lower layer light shielding film 9a.

The upper layer light shielding films 22b and 23b (fourth conductive film) are respectively provided on the source electrode 22 and the drain electrode 23. When the upper layer light shielding films 22b and 23b are formed by, for example, a metal film having light shielding properties, the upper layer light shielding films 22b and 23b are formed so as to be separated from each other to prevent electrical short circuit between the source electrode 22 and the drain electrode 23. In the embodiment, as the upper layer light shielding films 22b, 23b, a metal such as molybdenum (Mo) and aluminum (Al), or an alloy obtained by adding another element to the metal can be used.

As illustrated in FIG. 33, the upper region of the semiconductor channel layer 7 of the TFT portion is configured such that light from an upper surface is shielded in its entire region in plan view by the upper layer light shielding films 22b, 23b, and the lower layer light shielding films 9a, 9b, 9c. Furthermore, the lower region of the semiconductor channel layer 7 of the TFT portion is configured such that light from a lower surface (surface on the side of the substrate 1) is shielded in its entire region in plan view by the gate electrode 2. Forming the TFT portion in this manner makes it possible to almost perfectly prevent backlight light, external light, and scattering light thereof from being incident on the semiconductor channel layer 7 (light shielding), making it possible to prevent property degradation of the semiconductor channel layer 7 due to light absorption.

Furthermore, in the source terminal portion, the source extraction electrode 26T is provided to be directly connected to the source terminal 15T via the first source terminal portion contact hole 20 penetrating the interlayer insulating film 16 to reach the source terminal 15T.

Furthermore, in the gate terminal portion, the gate terminal extraction electrode 25 is provided to be directly connected to the gate terminal 4 via the first gate terminal portion contact hole 19 penetrating the interlayer insulating film 16 and the insulating film 6 to reach the gate terminal.

Note that, the source extraction electrode 26T and the gate terminal extraction electrode 25 are formed by the third conductive film in the same layer as the source electrode 22 and the drain electrode 23 of the TFT portion.

Manufacturing Method

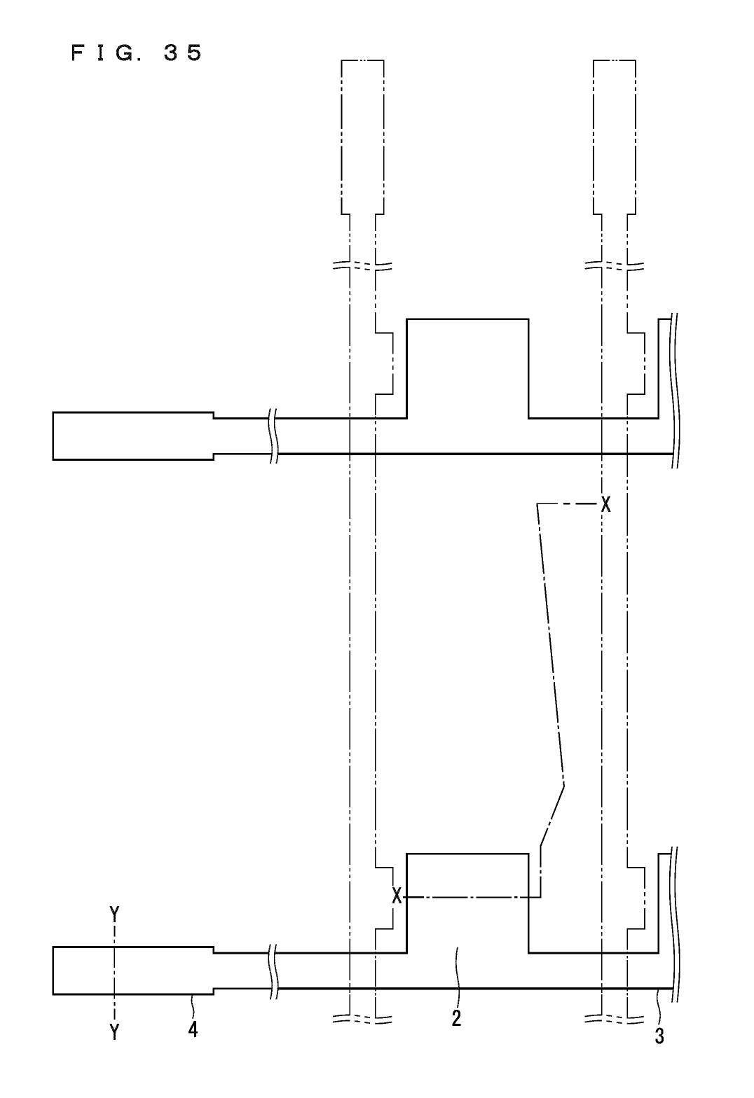

Hereinafter, a manufacturing method of the TFT substrate 300 according to the third embodiment will be described using FIG. 35 to FIG. 40. Note that a plan view and a cross sectional view illustrating the final step respectively correspond to FIG. 33 and FIG. 34.

First, the substrate 1 that is a transparent insulating substrate such as a glass is washed using cleaning liquid or pure water. In the embodiment, a glass substrate having a thickness of 0.6 mm is used as the substrate 1. Then, the first conductive film that is the material of the gate electrode 2, the gate wiring 3, and the like is formed on one of the entire main surfaces of the substrate 1 that has been washed. The material capable of being used as the first conductive film is described in the first embodiment, so that overlapping description will be omitted. In the embodiment, an aluminum (Al) alloy film shall be used as the first conductive film, and the Al alloy film is formed to have a thickness of 200 nm by a sputtering method using argon (Ar) gas.

First Photolithography Step

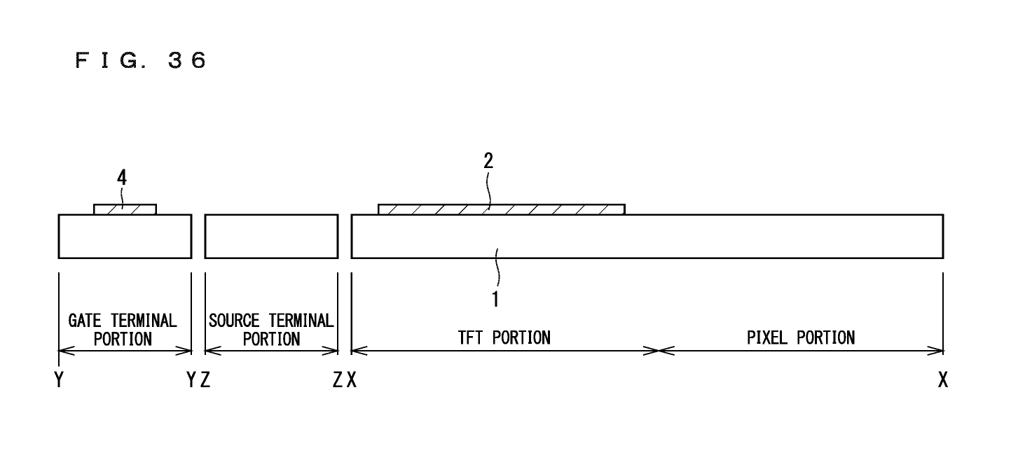

Then, a photoresist material is applied on the first conductive film, a photoresist pattern is formed in a first photolithography step, and the first conductive film is subjected to patterning by etching using the photoresist pattern as a mask. Herein, a wet etching using PAN chemical solution is used. Then, by removing the photoresist pattern, as illustrated in FIG. 35 and FIG. 36, the gate electrode 2, the gate wiring 3 (not shown in FIG. 16), and the gate terminal 4 are formed on the upper main surface of the substrate 1.

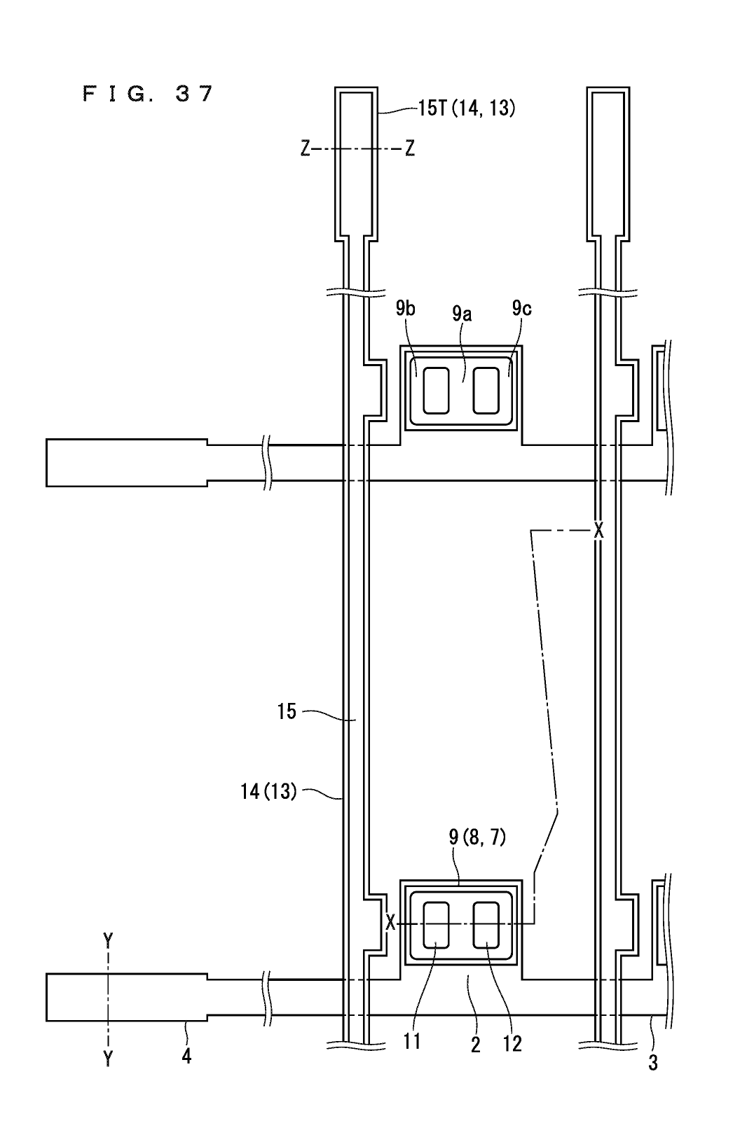

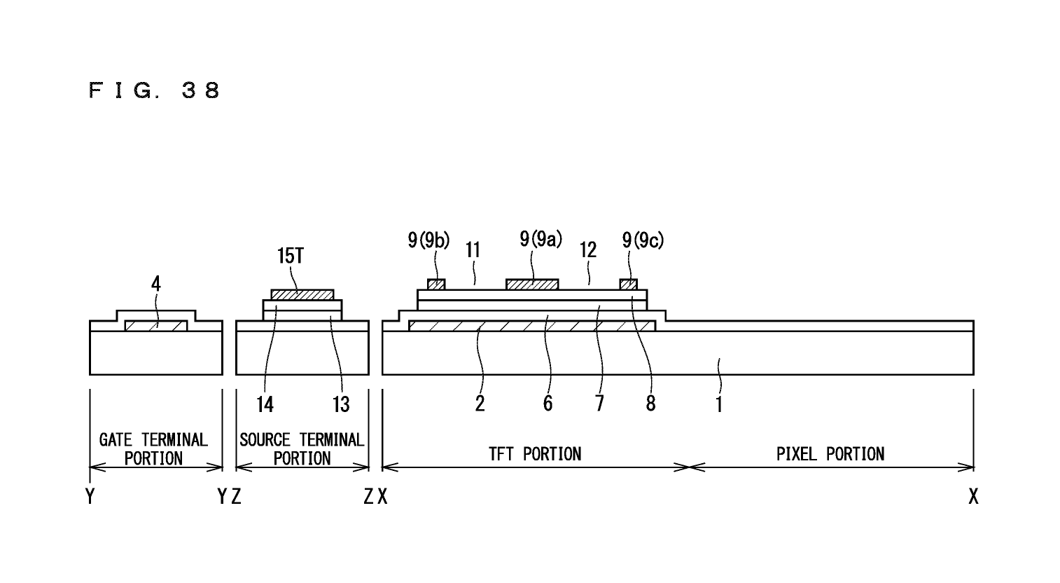

Second Photolithography Step Next, after forming the insulating film 6 (first insulating film) on the entire upper main surface of the substrate 1 to cover the gate electrode 2, the gate wiring 3, and the gate terminal 4, the oxide semiconductor film, the second insulating film, and the second conductive film are laminated in this order on the insulating film 6, and in a second photolithography step, a photoresist pattern having different thicknesses is formed by exposure (half exposure) using a half exposure mask. Then, by performing patterning by etching using the photoresist pattern, as illustrated in FIG. 37 and FIG. 38, in the TFT portion, a laminate of the semiconductor channel layer 7, the protective insulating film 8, and the channel region lower layer insulating film 9 is obtained above the gate electrode 2, and the first source electrode contact hole 11 and the first drain electrode contact hole 12 are formed in the channel region lower layer light shielding film 9.

Note that, as for the material and forming method of the insulating film 6, the oxide semiconductor film, the second insulating film, and the second conductive film, and the etching using a photoresist pattern formed by a half exposure, description is made using FIG. 19 to FIG. 22 in the second embodiment, so that the description will be omitted.

Furthermore, although the outline of the channel region lower layer light shielding film 9 exists inside the outline of the protective insulating film 8 and the semiconductor channel layer 7, this is because the photoresist pattern is reduced in its film thickness to be made small also in plan view.

Furthermore, for descriptive purposes, the channel region lower layer light shielding film 9 that remains between the first source electrode contact hole 11 and the first drain electrode contact hole 12 is referred to as the lower layer light shielding film 9a, the channel region lower layer light shielding film 9 that remains on the side opposite to the lower layer light shielding film 9a of the first source electrode contact hole 11 is referred to as the lower layer light shielding film 9b, and the channel region lower layer light shielding film 9 that remains on the side opposite to the lower layer light shielding film 9a of the first drain electrode contact hole 12 is referred to as the lower layer light shielding film 9c.

Furthermore, in a source wiring formation region, a laminate of the oxide semiconductor film 13, the insulating film 14, and the lower layer source wiring 15 is formed, and in a source terminal formation region, a laminate of the oxide semiconductor film 13, the insulating film 14, and the source terminal 15T is formed by the same process as the above process.

Note that, although the outline of the source terminal 15T (including lower layer source wiring 15) exists inside the outline of the insulating film 14 and the oxide semiconductor film 13, this is because the photoresist pattern is reduced in its film thickness to be made small also in plan view.

Next, the interlayer insulating film 16 (third insulating film) is formed on the entire upper main surface of the substrate 1. In the embodiment, a resin series insulating film is funned by an organic resin material. Specifically, for example, an organic resin material of an acrylic having photosensitivity is applied on the substrate 1 to have a thickness of 2.0 to 3.0 μm by a spin coat method as the interlayer insulating film 16. Note that the material and the manufacturing method of the interlayer insulating film 16 are described in the first embodiment, and their effects are also the same, so that the description thereof will be omitted.

Third Photolithography Step

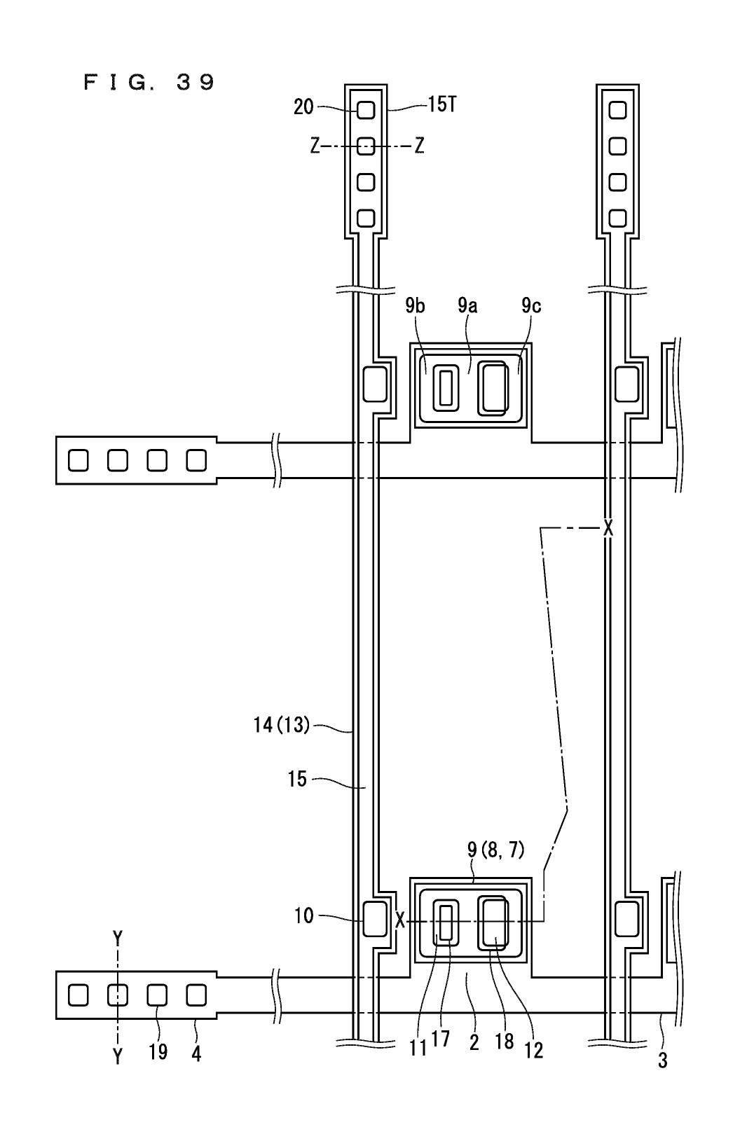

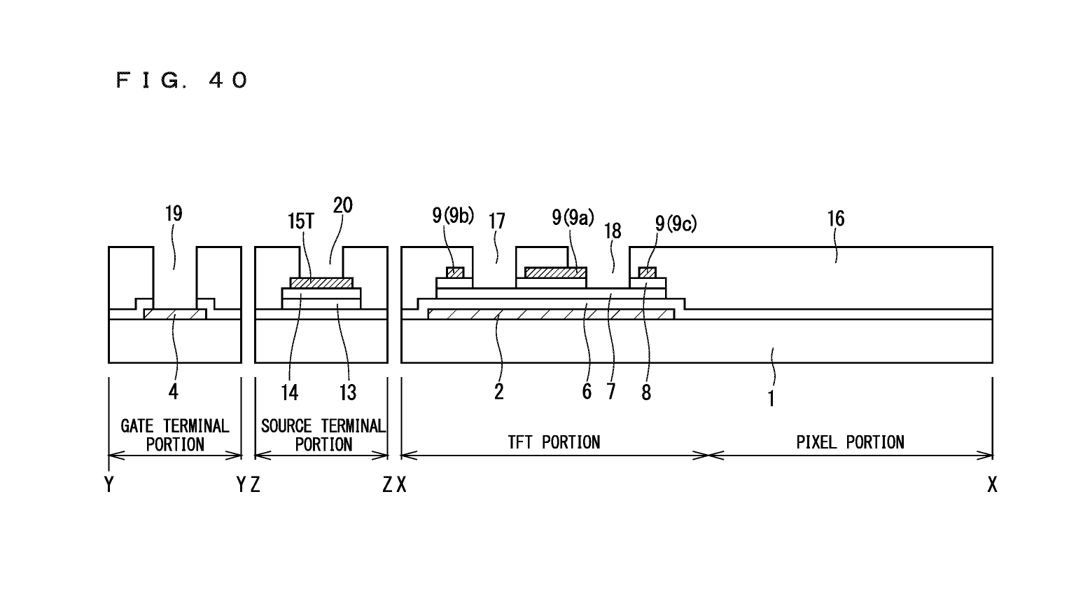

Next, by exposing and developing the interlayer insulating film 16 in a third photolithography step, as illustrated in FIG. 39 and FIG. 40, the first source wiring contact hole 10 (not shown in FIG. 40), the second source electrode contact hole 17, the second drain electrode contact hole 18, the first gate terminal portion contact hole 19, and the first source terminal portion contact hole 20 that penetrate the interlayer insulating film 16 are formed.

Then, the protective insulating film 8 exposed at the bottom portions of the second source electrode contact hole 17 and the second drain electrode contact hole 18 are subjected to etching. For the etching, a dry etching method using a gas including fluorine can be used.

In the embodiment, dry etching is performed by using a gas in which oxygen (O₂) is added to sulfur hexafluoride (SF₆). Adding O₂ gas makes it possible to suppress that the oxide semiconductor film 7 below the protective insulating film 8 is damaged by reduction reaction during etching. By the etching, as illustrated in FIG. 39 and FIG. 40, the semiconductor channel layer 7 is exposed at the bottom surface of the second source electrode contact hole 17. Furthermore, the semiconductor channel layer 7 and a portion of the channel region lower layer light shielding film 9 (lower layer light shielding film 9a in the embodiment) are exposed at the bottom surface of the second drain electrode contact hole 18.

Furthermore, although the gate terminal 4 of an Al alloy is exposed at the bottom surface of the first gate terminal portion contact hole 19 and the lower layer source wiring 15 and the source terminal 15T that are made of an Al alloy are respectively exposed at the bottom surfaces of the first source wiring contact hole 10 and the first source terminal portion contact hole 20, the Al alloy is not subjected to etching by a dry etching using a gas in which oxygen (O₂) is added to sulfur hexafluoride (SF₆), so that the patterns remain as they are.

Next, the third conductive film and the fourth conductive film are laminated in this order on the entire upper surface of the interlayer insulating film 16. In the embodiment, a transparent conductive film (translucent conductive film) is used as the third conductive film and an Al alloy film having light shielding properties is used as the fourth conductive film. Note that the material, the film thickness, and the manufacturing method of the transparent conductive film, and the material, the film thickness, and the manufacturing method of the Al alloy film are the same as those in the first embodiment, so that the description will be omitted.

Fourth Photolithography Step

Next, a photoresist material is applied on the entire surface of the fourth conductive film (Al alloy film), and a photoresist pattern is formed in a fourth photolithography step. Herein, by performing a half exposure using a half exposure mask, a photoresist pattern having different thicknesses is formed. That is, portions for leaving the fourth conductive film to form the patterns of the upper layer light shielding films 22b and 23b are made thick in their film thicknesses. Note that the fourth conductive film is subjected to etching by two steps, and the film thickness of the photoresist pattern at the portion removed by the second etching is made thin. For example, the film thickness is made thin on the region in which the transmissive pixel electrode 24 is formed so that the fourth conductive film on the region in which the transmissive pixel electrode 24 is formed is not removed in the first etching. Furthermore, the film thickness of the photoresist pattern is made thin also at the gate terminal portion and the source terminal portion.

Then, the fourth conductive film is subjected to patterning by etching using the photoresist pattern as a mask to remove the fourth conductive film at the portion that is not covered with the photoresist pattern. In the etching of the fourth conductive film, a wet etching using PAN chemical solution is used.

Subsequently, the third conductive film is subjected to patterning by etching using the same photoresist pattern as a mask to remove the third conductive film at the portion that is not covered with the photoresist pattern and the fourth conductive film. In the etching of the third conductive film (amorphous ITO), a wet etching is used using oxalic acid series chemical solution of oxalic acid 5 wt %+water.

Then, the whole of the substrate 1 is heated to 150° C. This heating makes the amorphous ITO film be crystallized to become a polycrystalline ITO film. The substrate temperature is not limited to 150° C., and in the case of a typical amorphous ITO film having a mixture ratio in which indium oxide (In₂O₃) is not less than 85 wt % and not more than 95 wt %, and tin oxide (SnO₂) is not less than 5 wt % and not more than 15 wt % (total thereof is 100 wt %), not less than 140° C. enables crystallization. In contrast, on the high temperature side, temperature can be arbitrarily determined depending on the heatproof temperature of a material or the like used for the layer and pattern formed on the TFT substrate. For example, in the embodiment, since an organic resin film of acrylic is used as the third insulating film, not more than 230° C. that is the heatproof temperature of the material is preferable, but, for example, in the case of using a typical photosensitivity resin of novolak series for the photoresist material, not more than 160° C. is preferable.

Next, by oxygen ashing, the film thickness of the photoresist pattern is totally reduced to completely remove the photoresist pattern whose film thickness is thin. In contrast, the photoresist pattern whose film thickness is thick is made thin to be left.

Next, the fourth conductive film is subjected to etching again by using a wet etching method using PAN chemical solution using the remaining photoresist pattern as a mask. In this context, since the ITO film that is the transparent conductive film that is the lower layer is poly crystallized, so that the ITO film is chemically very stable, making it possible to etch the Al alloy film that is not covered with a photoresist pattern, for example, the Al alloy film on the region in which the transmissive pixel electrode 24 is formed, and the Al alloy film of the gate terminal portion and the source terminal portion without suffering etching damage practically with respect to PAN chemical solution (disappearance of film or deterioration of electrical properties or optical properties).

Then, by removing the photoresist pattern, as illustrated in FIG. 33 and FIG. 34, the gate terminal extraction electrode 25, the source electrode 22, the upper layer source wiring 26 extending from the source electrode 22, the source terminal extraction electrode 26T, the drain electrode 23, and the transmissive pixel electrode 24 extending from the drain electrode 23 configured by the transparent conductive film (polycrystalline ITO film) are formed. Furthermore, the upper layer light shielding films 22b and 23b are respectively formed on the upper portion of the source electrode 22 and the upper portion of the drain electrode 23 of the TFT portion. The upper layer light shielding films 22b and 23b are formed to cover substantially the whole of the planer pattern of the semiconductor channel layer 7 excluding the channel region BC in plan view.

Herein, the gate terminal extraction electrode 25 is directly connected to the gate terminal 4 via the first gate terminal portion contact hole 19. Furthermore, the source electrode 22 is directly connected to the semiconductor channel layer 7 via the second source electrode contact hole 17. Furthermore, the upper layer source wiring 26 is directly connected to the lower layer source wiring 15 via the first source wiring contact hole 10. Furthermore, the source wiring extraction electrode 26T is directly connected to the source terminal 15T via the first source terminal portion contact hole 20.

Then, the liquid crystal display panel is assembled and a light polarizing plate, a phase difference plate, a driving circuit, a backlight unit, and the like are arranged outside the liquid crystal display panel to complete the liquid crystal display device, but the detail thereof is described in the first embodiment, so that the description thereof is omitted.

As described above, the third embodiment makes it possible to manufacture the TFT substrate 300 equipped with an etch stopper type TFT using an oxide semiconductor film having high performance in its channel layer with four photolithography steps that is reduced by up to two steps as compared with the case of the first embodiment. Furthermore, similar to the first embodiment, the protective insulating film 8 that becomes an etch stopper is subsequently formed after formation of the oxide semiconductor film, nearly preventing the semiconductor channel layer 7 from being deteriorated in its properties due to process damage of the subsequent TFT manufacturing step. This makes it possible to use the semiconductor channel layer 7 as the channel layer of the TFT in the state where high performance properties of the oxide semiconductor are kept.

Furthermore, the source wiring 151 is made to be a redundant wiring, and the upper layer source wiring 26 is made to be directly connected with the lower layer source wiring 15 via the plurality of first source wiring contact holes 10 provided in the interlayer insulating film 16, making it possible to complement the function by the other wiring even when one of the wirings is disconnected. This makes it possible to reduce generation of linear defect due to disconnection of the source wiring 151 to improve yield ratio during manufacturing and reliability of the product.

Furthermore, the lower layer source wiring 15 is consecutively formed with the oxide semiconductor film and the insulating film, making it possible to form the lower layer source wiring 15 (second conductive film) with good adhesiveness, making it possible to reduce generation of disconnection defect due to peeling off of film caused by lack of sticking force. This effect is specifically large at a step portion on the gate wiring pattern in the region in which the gate wiring 3 and the lower layer source wiring 15 intersect.

Furthermore, the semiconductor channel layer 7 is configured such that its entire region is shielded from light by the two-layered light shielding films also on the upper side of the semiconductor channel layer 7 in addition to light shielding by the gate electrode 2 on the lower side of the semiconductor channel layer 7, making it possible to prevent deterioration (optical deterioration) of the channel layer due to absorption of backlight light during operating the liquid crystal display device and external light.

Furthermore, using a resin series insulating film that has low permittivity, that is made thick in its film thickness to be not less than 2.0 μm, and that has a flattening action with respect to the main surface of the substrate 1 as the interlayer insulating film 16 (third insulating film) makes it possible to suppress wiring capacity to a low level. This makes it possible to drive the TFT substrate at a low voltage, making it possible to contribute to reducing power consumption. This makes it possible to make the transmissive pixel electrode 24 be arranged on the gate wiring or the source wiring to overlap, also making it possible to make aperture ratio high.

Furthermore, because the channel region lower layer light shielding film 9 is formed by a conductive film and the drain electrode 23 and the transmissive pixel electrode 24 are made to be directly connected, the electric potential of the transmissive pixel electrode 24 is applied on the channel region BC as bias electric potential. This makes it possible to reduce variation of a threshold voltage (Vth) of the plurality of TFTs structuring display pixels and suppress variation of TFT properties due to unspecified external noise or the like, making it possible to further improve display properties and reliability. Note that the channel region lower layer light shielding film 9 may be directly connected to the source electrode 22 instead of the drain electrode 23.

Modification

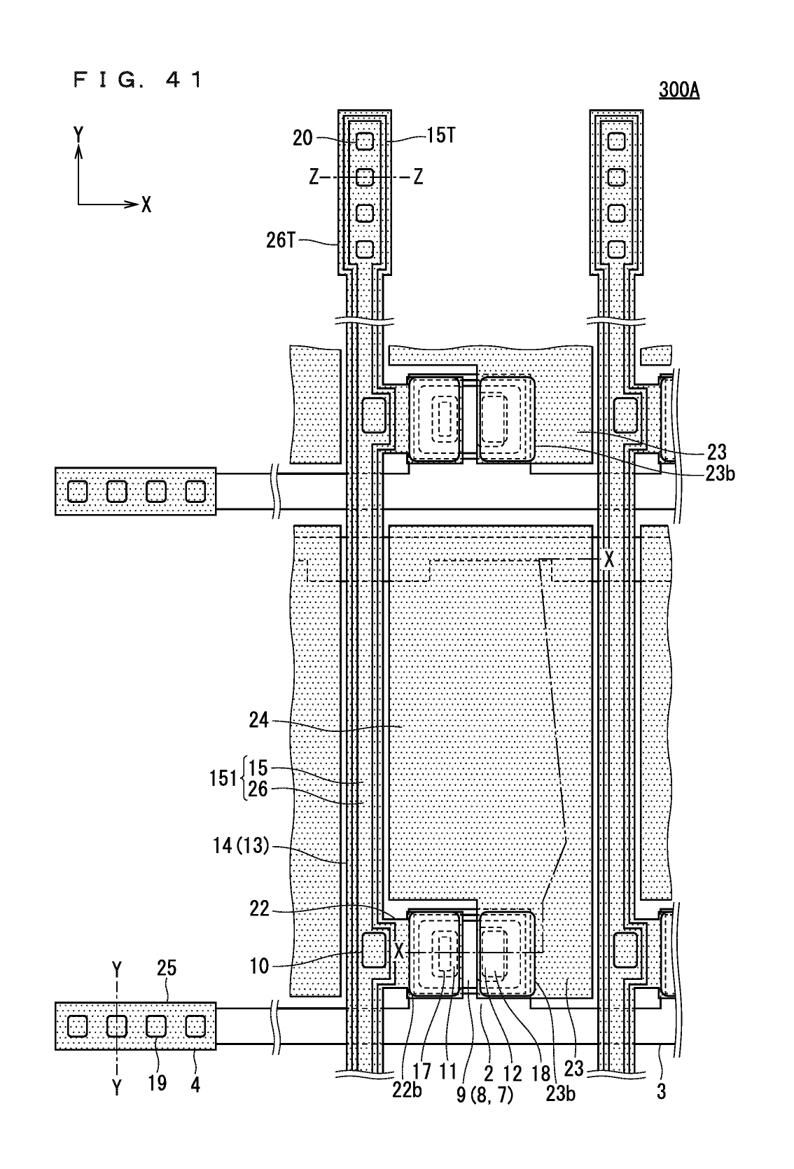

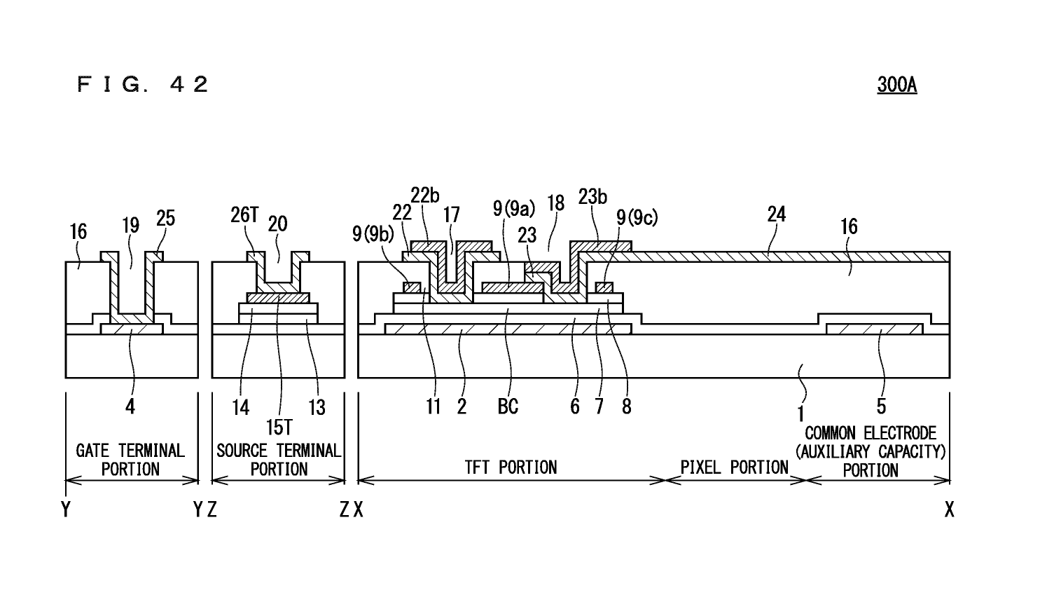

Next, with reference to FIG. 41 and FIG. 42, a configuration of a TFT substrate 300A according to a modification of the third embodiment will be described. The TFT substrate 300A has a configuration further including a common electrode that becomes an auxiliary capacity of a pixel electrode in the pixel portion of the TFT substrate 300. Note that, the same reference numerals are given to the same components as those in the TFT substrate 300 described by using FIG. 33 and FIG. 34, and the overlapping description will be omitted.

Configuration of Pixel of TFT Substrate

FIG. 41 is a plan view illustrating a planar configuration of a pixel according to the modification of the third embodiment, and FIG. 42 is a cross sectional view illustrating a cross sectional configuration taken along the line X-X (cross sectional configuration of TFT portion, cross sectional configuration of pixel portion, and cross sectional configuration of common electrode portion), a cross sectional configuration taken along the line Y-Y (cross sectional configuration of gate terminal portion), and a cross sectional configuration taken along the line Z-Z (cross sectional configuration of source terminal portion) in FIG. 41. Note that, in the following description, the TFT substrate 300A shall be used for a liquid crystal display device of TN mode of light transmission type.

As illustrated in FIG. 41, in the TFT substrate 300A, a gate electrode 2 of the TFT is configured by a portion of a gate wiring 3. That is, a portion brunched from the gate wiring 3 to extend to a formation region of the TFT (TFT portion) forms the gate electrode 2. In the embodiment, the depth and the width of the portion to be the gate electrode 2 is made wider than the width of the gate wiring 3 so as to be a size that enables a source electrode 22 and a drain electrode 23 to be arranged above the gate electrode 2. Furthermore, a common electrode 5 is provided to extend in parallel with the gate wiring 3.

One end of the gate wiring 3 is electrically connected to a gate terminal 4, and a gate terminal extraction electrode 25 is connected to the gate terminal 4 via a first gate terminal portion contact hole 19. Note that as described below, as the gate wiring 3, the gate terminal 4, and the common electrode 5, a first conductive film made of a metal or an alloy having light shielding properties, for example, a metal such as molybdenum (Mo) and aluminum (Al), or an alloy obtained by adding another element to the metal is used.

As illustrated in FIG. 41, the gate wiring 3 and the common electrode 5 are arranged to extend in the lateral direction (X direction), and a source wiring 151 is arranged to extend in the vertical direction (Y direction). Note that the source wiring 151 is configured by a lower layer source wiring 15 and an upper layer source wiring 26.

Furthermore, one end of the lower layer source wiring 15 is connected to a source terminal 15T, and a source terminal extraction electrode 26T is connected to the source terminal 15T via a first source terminal portion contact hole 20.

Making the upper layer source wiring 26 extending from the source electrode 22 be connected to the lower layer source wiring 15 via a first source wiring contact hole 10 makes the source electrode 22 be electrically connected to the lower layer source wiring 15. Furthermore, the drain electrode 23 extends to a pixel region to form a transmissive pixel electrode 24. Furthermore, upper layer light shielding films 22b and 23b are respectively provided on the regions of the source electrode 22 and the drain electrode 23.

Note that the region surrounded by the adjacent gate wirings 3 and the adjacent lower layer source wirings 15 becomes a pixel region, so that pixel regions are arranged in a matrix manner in the TFT substrate 200A.

Next, a cross sectional configuration of the TFT substrate 200A will be described using FIG. 42. As illustrated in FIG. 42, the TFT substrate 200A includes a substrate 1 that is a transparent insulating substrate such as a glass as its base material, and the gate electrode 2 (including gate wiring 3), the gate terminal 4, and the common electrode 5 are arranged on the substrate 1.

Then, an insulating film 6 (first insulating film) is arranged to cover the gate electrode 2, the gate terminal 4, and the common electrode 5. The insulating film 6 functions as a gate insulating film at the TFT portion, so that the insulating film 6 is referred to as a gate insulating film 6 in some cases.

In the TFT portion, an oxide semiconductor film 7 is arranged on the insulating film 6 at the position overlapping with the gate electrode 2. The oxide semiconductor film 7 functions as a channel layer of the TFT, so that the oxide semiconductor film 7 is referred to as a semiconductor channel layer 7 in some cases. Note that, in the embodiment, the planer pattern of the semiconductor channel layer 7 is made smaller than the planer pattern of the gate electrode 2 in plan view, so that the outline of the semiconductor channel layer 7 exists inside the outline of the gate electrode 2. Note that the material of the semiconductor channel layer 7 is the same as that described in the first embodiment, making it possible to increase mobility as compared with a conventional configuration in which amorphous silicon is used for the semiconductor channel layer.

A protective insulating film 8 (second insulating film) is arranged on the semiconductor channel layer 7, and a channel region lower layer light shielding film 9 (second conductive film) formed of a metal film having light shielding properties or the like is arranged on the protective insulating film 8.

In the embodiment, as the channel region lower layer light shielding film 9, for example, a metal such as molybdenum (Mo) and aluminum (Al), or an alloy obtained by adding another element to the metal is used. Then, a first source electrode contact hole 11 and a first drain electrode contact hole 12 are provided in the channel region lower layer light shielding film 9 above the semiconductor channel layer 7. Note that the channel region lower layer light shielding film 9 is referred to as a lower layer light shielding film 9a, 9b, or 9c in some cases depending on its arranged position for descriptive purposes.

Furthermore, in the source terminal portion, an oxide semiconductor film 13 in the same layer as the semiconductor channel layer 7 of the TFT portion is provided, and an insulating film 14 in the layer the same as the protective insulating film 8 is provided on the oxide semiconductor film 13. Then, the source terminal 15T (including lower layer source wiring 15) in the same layer as the channel region lower layer light shielding film 9 (second conductive film) is provided on the insulating film 14, so that the source terminal 15T is the upper most layer film of the laminate of the three layers.

Furthermore, in the gate terminal portion, the insulating film 6 is formed to cover the gate terminal 4 (including gate wiring 3).

Then, an interlayer insulating film 16 (third insulating film) is arranged above the entire surface of the substrate 1 to cover the insulating film 6, the semiconductor channel layer 7, the protective insulating film 8, and the channel region lower layer light shielding film 9. Then, in the TFT portion, a second source electrode contact hole 17 and a second drain electrode contact hole 18 penetrating the interlayer insulating film 16 and the protective insulating film 8 to reach the semiconductor channel layer 7 are provided. The second source electrode contact hole 17 is arranged to be located inside the outer circumference of the first source electrode contact hole 11 in plan view, and is formed such that a surface of the semiconductor channel layer 7 is exposed at its bottom surface. Furthermore, the second drain electrode contact hole 18 is arranged such that at least a portion thereof is located outside the outer circumference of the first drain electrode contact hole 12 in plan view, and is formed such that both of the surface of the semiconductor channel layer 7 and the surface of at least a portion of the region of the channel region lower layer light shielding film 9 (region of the lower layer light shielding film 9a in the embodiment) are exposed.

Then, the source electrode 22 and the drain electrode 23 formed as a third conductive film are arranged so as to be separated from each other and directly connected to the semiconductor channel layer 7 via the second source electrode contact hole 17 and the second drain electrode contact hole 18, respectively. The region between the source electrode 22 and the drain electrode 23 in the semiconductor channel layer 7 forms a channel region BC. Note that the drain electrode 23 is connected to the semiconductor channel layer 7 and also directly connected to the lower layer light shielding film 9a.

Furthermore, while the drain electrode 23 extends to the pixel region to form the transmissive pixel electrode 24, the transmissive pixel electrode 24 partially overlaps with the common electrode 5 of the common electrode portion in plan view, forming an auxiliary capacity for the pixel electric potential via the insulating film 6 and the interlayer insulating film 16.

The upper layer light shielding films 22b and 23b (fourth conductive film) are respectively provided on the source electrode 22 and the drain electrode 23. When the upper layer light shielding films 22b and 23b are formed by, for example, a metal film having light shielding properties, the upper layer light shielding films 22b and 23b are formed so as to be separated from each other to prevent electrical short circuit between the source electrode 22 and the drain electrode 23. In the embodiment, as the upper layer light shielding films 22b, 23b, a metal such as molybdenum (Mo) and aluminum (Al), or an alloy obtained by adding another element to the metal can be used.

As illustrated in FIG. 41, the upper region of the semiconductor channel layer 7 of the TFT portion is configured such that light from an upper surface is shielded in its entire region in plan view by the upper layer light shielding films 22b, 23b, and the lower layer light shielding films 9a, 9b, 9c. Furthermore, the lower region of the semiconductor channel layer 7 of the TFT portion is configured such that light from a lower surface (surface on the side of the substrate 1) is shielded in its entire region in plan view by the gate electrode 2. Forming the TFT portion in this manner makes it possible to almost perfectly prevent backlight light, external light, and scattering light thereof from being incident on the semiconductor channel layer 7 (light shielding), making it possible to prevent property degradation of the semiconductor channel layer 7 due to light absorption.

Furthermore, in the source terminal portion, the source extraction electrode 26T is provided to be directly connected to the source terminal 15T via the first source terminal portion contact hole 20 penetrating the interlayer insulating film 16 to reach the source terminal 15T.

Furthermore, in the gate terminal portion, the gate terminal extraction electrode 25 is provided to be directly connected to the gate terminal 4 via the first gate terminal portion contact hole 19 penetrating the interlayer insulating film 16 and the insulating film 6 to reach the gate terminal.

Note that, the source extraction electrode 26T and the gate terminal extraction electrode 25 are formed by the third conductive film in the same layer as the source electrode 22 and the drain electrode 23 of the TFT portion.

Manufacturing Method

In a manufacturing method of the TFT substrate 300A according to the modification of the third embodiment, first, like the manufacturing method of the TFT substrate 200A according to the modification of the second embodiment described using FIG. 27 to FIG. 30, after the first conductive film is formed on the substrate 1, a pattern of the gate electrode 2, the gate wiring 3, the gate terminal 4, and the common electrode 5 is formed on the substrate 1 through the first photolithography step and etching. Note that the material of the first conductive film, the etching method during patterning processing, and the like are the same as those in the third embodiment.

Then, through the steps similar to the second to fourth photolithography steps described by using FIG. 37 to FIG. 40 in the third embodiment, the TFT substrate 300A illustrated in FIG. 41 and FIG. 42 can be obtained.

Then, the liquid crystal display panel is assembled and a light polarizing plate, a phase difference plate, a driving circuit, a backlight unit, and the like are arranged outside the liquid crystal display panel to complete the liquid crystal display device, but the detail thereof is described in the first embodiment, so that the description thereof is omitted.

As described above, in the modification, an auxiliary capacity can be added to the transmissive pixel electrode 24 by providing the common electrode 5, making it possible to increase a leak margin of a display signal electric potential applied to the transmissive pixel electrode 24 in addition to the effects the same as those in the third embodiment. This makes it possible to reduce display defect caused by retention failure of signal electric potential to achieve a higher quality liquid crystal display device.

### Fourth Embodiment

In the above described first to third embodiments, although examples are illustrated in which the present invention is applied to the TFT substrate to be used in the liquid crystal display device of TN mode of light transmission type, in a forth embodiment, an example will be illustrated in which the present invention is applied to a TFT substrate to be used in a liquid crystal display device of FFS mode of light transmission type.

Configuration of Pixel of TFT Substrate

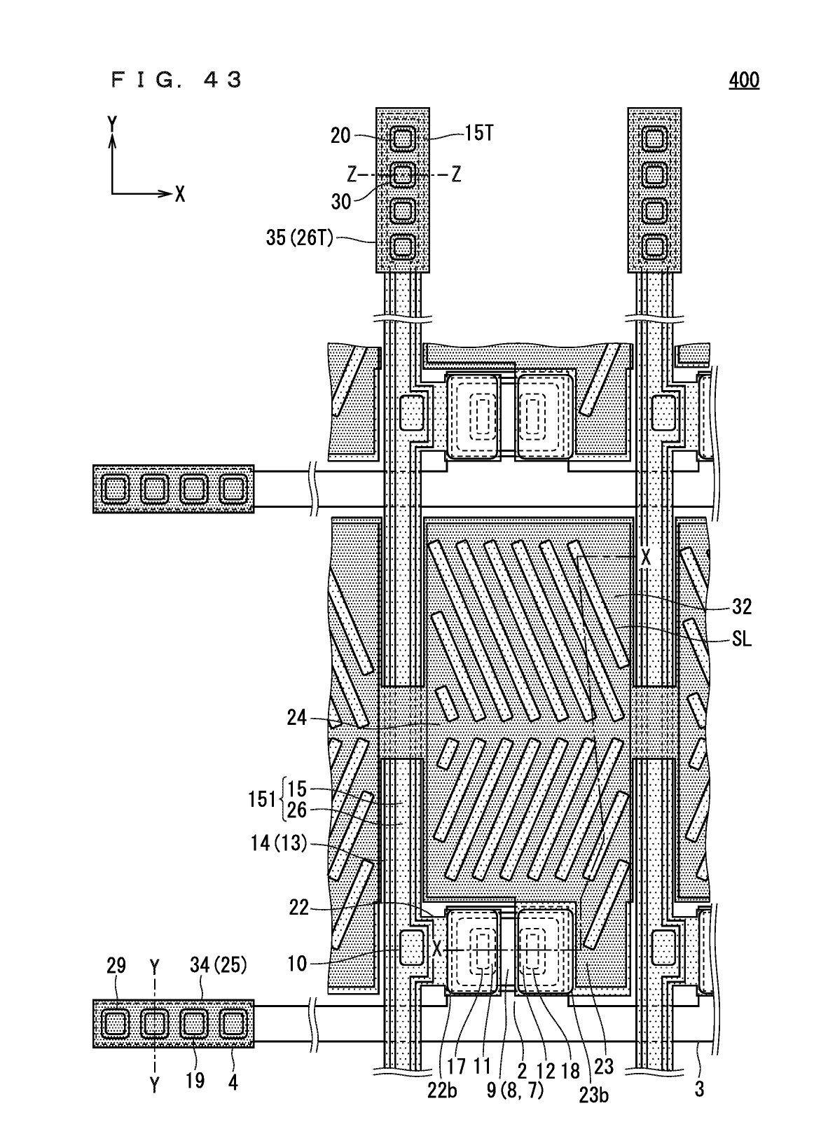

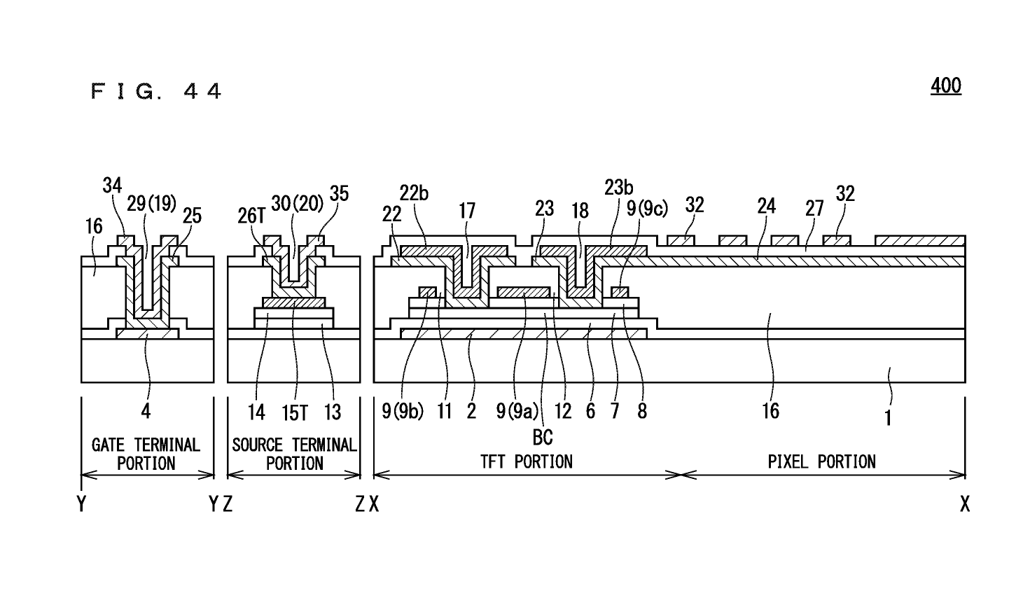

First, with reference to FIG. 43 and FIG. 44, a configuration of a TFT substrate 400 according to the fourth embodiment will be described. Note that the same reference numerals are given to the same components as those in the TFT substrate 200 illustrated by using FIG. 13 and FIG. 14, and the overlapping description will be omitted.

FIG. 43 is a plan view illustrating a planar configuration of a pixel according to the forth embodiment, and FIG. 44 is a cross sectional view illustrating a cross sectional configuration taken along the line X-X (cross sectional configuration of TFT portion and cross sectional configuration of pixel portion), a cross sectional configuration taken along the line Y-Y (cross sectional configuration of gate terminal portion), and a cross sectional configuration taken along the line Z-Z (cross sectional configuration of source terminal portion) in FIG. 43.

As illustrated in FIG. 43, in the TFT substrate 400, a gate electrode 2 of the TFT is configured by a portion of a gate wiring 3. That is, a portion brunched from the gate wiring 3 to extend to a formation region of the TFT (TFT portion) forms the gate electrode 2. In the embodiment, the depth and the width of the portion to be the gate electrode 2 is made wider than the width of the gate wiring 3 so as to be a size that enables a source electrode 22 and a drain electrode 23 to be arranged above the gate electrode 2.

One end of the gate wiring 3 is electrically connected to a gate terminal 4, and a gate terminal extraction electrode 25 is connected to the gate terminal 4 via a first gate terminal portion contact hole 19. Then, to the gate terminal extraction electrode 25, a gate terminal pad 34 on the upper side is connected via a second gate terminal portion contact hole 29. Note that as the gate wiring 3 and the gate terminal 4, as described below, a first conductive film made of a metal or an alloy having light shielding properties, for example, a metal such as molybdenum (Mo), and aluminum (Al), or an alloy obtained by adding another element to the metal is used.

As illustrated in FIG. 43, the gate wiring 3 is arranged to extend in the lateral direction (X direction), and a source wiring 151 is arranged to extend in the vertical direction (Y direction). Note that the source wiring 151 is configured by a lower layer source wiring 15 and an upper layer source wiring 26.

Furthermore, one end of the lower layer source wiring 15 is connected to a source terminal 15T, and a source terminal extraction electrode 26T is connected to the source terminal 15T via a first source terminal portion contact hole 20. Then, to the source extraction electrode 26T, a source terminal pad 35 on the upper side is connected via a second source terminal portion contact hole 30.

Making the upper layer source wiring 26 extending from the source electrode 22 be connected to the lower layer source wiring 15 via a first source wiring contact hole 10 makes the source electrode 22 be electrically connected to the lower layer source wiring 15. Furthermore, the drain electrode 23 extends to a pixel region to form a transmissive pixel electrode 24. Furthermore, upper layer light shielding films 22b and 23b are respectively provided on the regions of the source electrode 22 and the drain electrode 23.

Then, a counter electrode 32 having a plurality of slit opening portions SL (fifth conductive film) is provided to oppose the transmissive pixel electrode 24, and the counter electrodes 32 adjacent in the lateral direction (X direction) are mutually connected to stride over the corresponding source wiring 151.

Note that the region surrounded by the adjacent gate wirings 3 and the adjacent lower layer source wirings 15 becomes a pixel region, so that in the TFT substrate 400, pixel regions are arranged in a matrix manner.

Next, a cross sectional configuration of the TFT substrate 400 will be described using FIG. 44. As illustrated in FIG. 44, the TFT substrate 400 includes a substrate 1 that is a transparent insulating substrate such as a glass as its base material, and the gate electrode 2 (including gate wiring 3) and the gate terminal 4 are arranged on the substrate 1.

Then, an insulating film 6 (first insulating film) is arranged to cover the gate electrode 2 and the gate terminal 4. The insulating film 6 functions as a gate insulating film at the TFT portion, so that the insulating film 6 is referred to as a gate insulating film 6 in some cases.

In the TFT portion, an oxide semiconductor film 7 is arranged on the insulating film 6 at the position overlapping with the gate electrode 2. The oxide semiconductor film 7 functions as a channel layer of the TFT, so that the oxide semiconductor film 7 is referred to as a semiconductor channel layer 7 in some cases. Note that, in the embodiment, the planer pattern of the semiconductor channel layer 7 is made smaller than the planer pattern of the gate electrode 2 in plan view, so that the outline of the semiconductor channel layer 7 exists inside the outline of the gate electrode 2. Note that, the material of the semiconductor channel layer 7 is the same as that described in the first to third embodiments, making it possible to increase mobility as compared with a conventional configuration in which amorphous silicon is used for the semiconductor channel layer.

A protective insulating film 8 (second insulating film) is arranged on the semiconductor channel layer 7, and a channel region lower layer light shielding film 9 (second conductive film) formed of a metal film having light shielding properties or the like is arranged on the protective insulating film 8.

In the embodiment, as the channel region lower layer light shielding film 9, for example, a metal such as molybdenum (Mo) and aluminum (Al), or an alloy obtained by adding another element to the metal is used. Then, a first source electrode contact hole 11 and a first drain electrode contact hole 12 are provided in the channel region lower layer light shielding film 9 above the semiconductor channel layer 7. Note that the channel region lower layer light shielding film 9 is referred to as a lower layer light shielding film 9a, 9b, or 9c in some cases depending on its arranged position for descriptive purposes.

Furthermore, in the source terminal portion, an oxide semiconductor film 13 in the same layer as the semiconductor channel layer 7 of the TFT portion is provided, and an insulating film 14 in the layer the same as the protective insulating film 8 is provided on the oxide semiconductor film 13. Then, the source terminal 15T (including lower layer source wiring 15) in the same layer as the channel region lower layer light shielding film 9 (second conductive film) is provided on the insulating film 14, so that the source terminal 15T is the upper most layer film of the laminate of the three layers.

Furthermore, in the gate terminal portion, the insulating film 6 is formed to cover the gate terminal 4 (including gate wiring 3).

Then, an interlayer insulating film 16 (third insulating film) is arranged above the entire surface of the substrate 1 to cover the insulating film 6, the semiconductor channel layer 7, the protective insulating film 8, and the channel region lower layer light shielding film 9. Then, in the TFT portion, a second source electrode contact hole 17 and a second drain electrode contact hole 18 penetrating the interlayer insulating film 16 and the protective insulating film 8 to reach the semiconductor channel layer 7 are provided. The second source electrode contact hole 17 is arranged to be located inside the outer circumference of the first source electrode contact hole 11 in plan view, and is formed such that a surface of the semiconductor channel layer 7 is exposed at its bottom surface. Furthermore, the second drain electrode contact hole 18 is arranged to be located inside the outer circumference of the first drain electrode contact hole 12 in plan view, and is formed such that a surface of the semiconductor channel layer 7 is exposed at its bottom surface.

Then, the source electrode 22 and the drain electrode 23 formed as a third conductive film are arranged so as to be separated from each other and directly connected to the semiconductor channel layer 7 via the second source electrode contact hole 17 and the second drain electrode contact hole 18, respectively. The region between the source electrode 22 and the drain electrode 23 in the semiconductor channel layer 7 forms a channel region BC. Note that, in the embodiment, a transparent conductive film (translucent conductive film) is used as the third conductive film.

The upper layer light shielding films 22b and 23b (fourth conductive film) are respectively provided on the source electrode 22 and the drain electrode 23. When the upper layer light shielding films 22b and 23b are formed by, for example, a metal film having light shielding properties, the upper layer light shielding films 22b and 23b are formed so as to be separated from each other to prevent electrical short circuit between the source electrode 22 and the drain electrode 23. In the embodiment, as the upper layer light shielding films 22b, 23b, a metal such as Mo and Al, or an alloy obtained by adding another element to the metal can be used.

As illustrated in FIG. 43, the upper region of the semiconductor channel layer 7 of the TFT portion is configured such that light from an upper surface is shielded in its entire region in plan view by the upper layer light shielding films 22b, 23b, and the lower layer light shielding films 9a, 9b, 9c. Furthermore, the lower region of the semiconductor channel layer 7 of the TFT portion is configured such that light from a lower surface (surface on the side of the substrate 1) is shielded in its entire region in plan view by the gate electrode 2. Forming the TFT portion in this manner makes it possible to almost perfectly prevent backlight light, external light, and scattering light thereof from being incident on the semiconductor channel layer 7 (light shielding), making it possible to prevent property degradation of the semiconductor channel layer 7 due to light absorption.

Then, an interlayer insulating film 27 (fourth insulating film) is formed on the whole of the substrate 1 to cover the source electrode 22, the drain electrode 23, the transmissive pixel electrode 24, and the upper layer light shielding films 22b, 23b, and the counter electrode 32 (fifth conductive film) is provided on the interlayer insulating film 27. The counter electrode 32 is, as illustrated in FIG. 43, arranged to overlap with the transmissive pixel electrode 24 on the lower side in plan view. In the embodiment, the counter electrodes 32 are formed in a consecutive shape to stride between pixels adjacent in the lateral direction (X direction), and are configured such that a constant common electric potential is supplied to the counter electrode 32 at a peripheral portion (not shown) of the display region. Furthermore, the slit opening portions SL are provided in the counter electrode 32, and applying a voltage between the transmissive pixel electrode 24 and the counter electrode 32 makes it possible to generate between with the transmissive pixel electrode 24 an electric filed in substantially lateral direction with respect to the main surface of the substrate 1 above the counter electrode 32. Note that although the configuration in which slit shaped opening portions are formed in the counter electrode 32 is illustrated in the embodiment, it is preferable that an opening portion may be formed having a comb-tooth shape in which one ends of a plurality of slits are jointed.

Furthermore, in the source terminal portion, the source extraction electrode 26T is provided to be directly connected to the source terminal 15T via the first source terminal portion contact hole 20 penetrating the interlayer insulating film 16 to reach the source terminal 15T. Then, then, to the source extraction electrode 26T, the source terminal pad 35 on the upper side is connected to overlap in plan view via the second source terminal portion contact hole 30 penetrating the interlayer insulating film 27.

Furthermore, in the gate terminal portion, the gate terminal extraction electrode 25 is provided to be directly connected to the gate terminal 4 via the first gate terminal portion contact hole 19 penetrating the interlayer insulating film 16 and the insulating film 6 to reach the gate terminal. Then, to the gate terminal extraction electrode 25, the gate terminal pad 34 on the upper side is connected to overlap in plan view via the second gate terminal portion contact hole 29 penetrating the interlayer insulating film 27.

Note that, the source extraction electrode 26T and the gate terminal extraction electrode 25 are formed by the third conductive film in the same layer as the source electrode 22 and the drain electrode 23 of the TFT portion.

Furthermore, the source terminal pad 35 and the gate terminal pad 34 are formed by the fifth conductive film in the same layer as the counter electrode 32 of the TFT portion.

Manufacturing Method

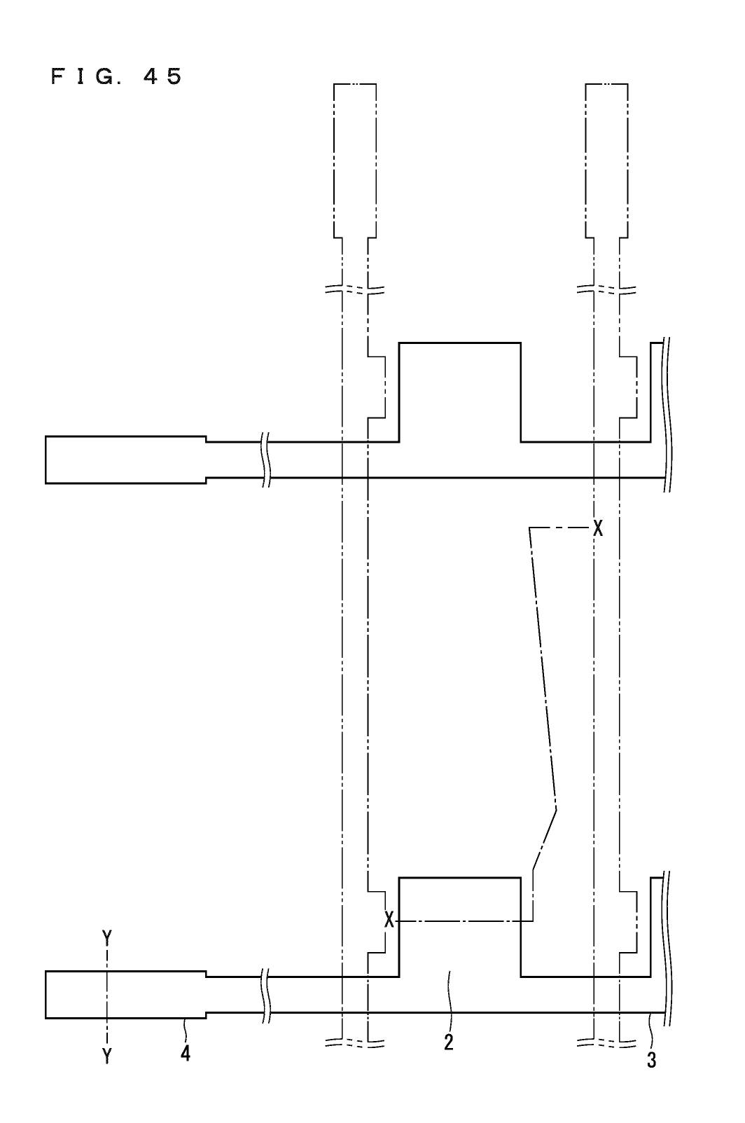

Hereinafter, a manufacturing method of the TFT substrate 400 according to the fourth embodiment will be described using FIG. 45 to FIG. 52. Note that a plan view and a cross sectional view illustrating the final step respectively correspond to FIG. 43 and FIG. 44.

First, the substrate 1 that is a transparent insulating substrate such as a glass is washed using cleaning liquid or pure water. In the embodiment, a glass substrate having a thickness of 0.6 mm is used as the substrate 1. Then, the first conductive film that is the material of the gate electrode 2, the gate wiring 3, and the like is formed on one of the entire main surfaces of the substrate 1 that has been washed. The material capable of being used as the first conductive film is described in the first embodiment, so that overlapping description will be omitted. In the embodiment, an aluminum (Al) alloy film shall be used as the first conductive film, and the Al alloy film is formed to have a thickness of 200 nm by a sputtering method using argon (Ar) gas.

First Photolithography Step

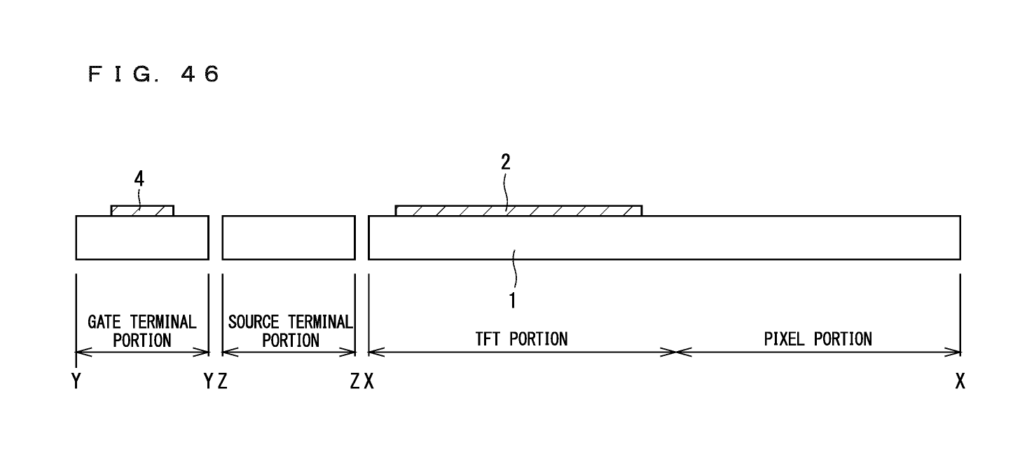

Then, a photoresist material is applied on the first conductive film, a photoresist pattern is formed in a first photolithography step, and the first conductive film is subjected to patterning by etching using the photoresist pattern as a mask. Herein, a wet etching using PAN chemical solution is used. Then, by removing the photoresist pattern, as illustrated in FIG. 45 and FIG. 46, the gate electrode 2, the gate wiring 3 (not shown in FIG. 46), and the gate terminal 4 are formed on the upper main surface of the substrate 1.

Second Photolithography Step

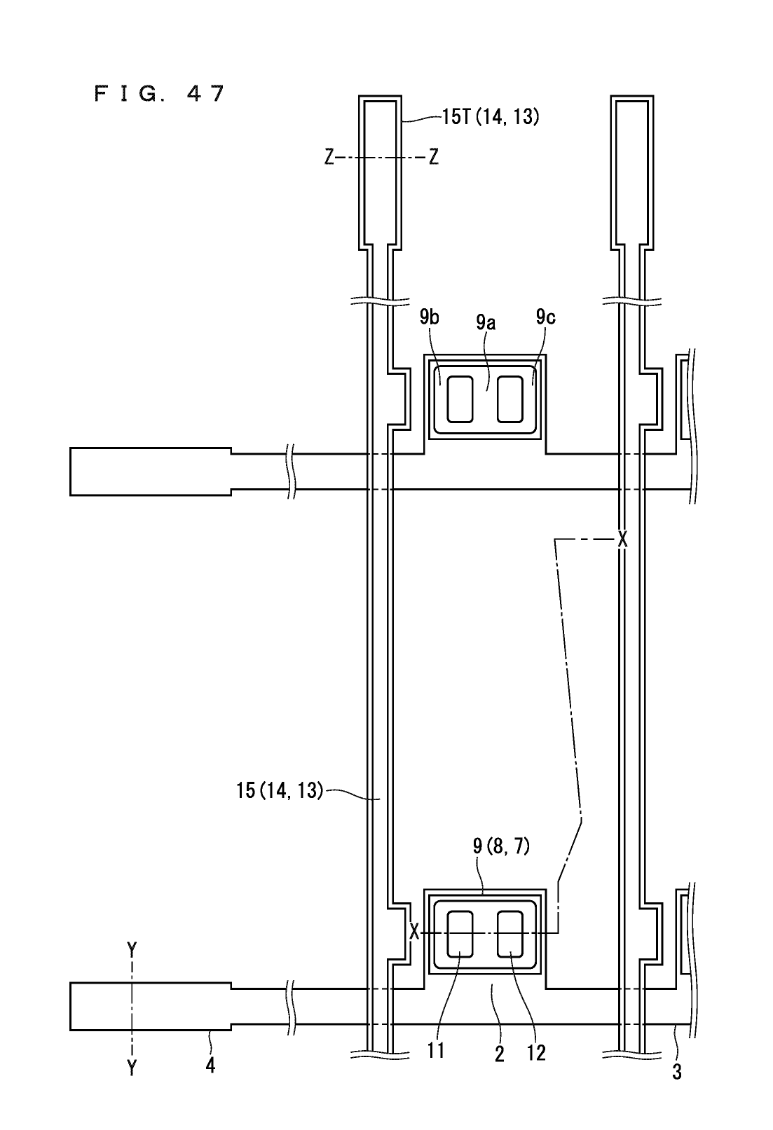

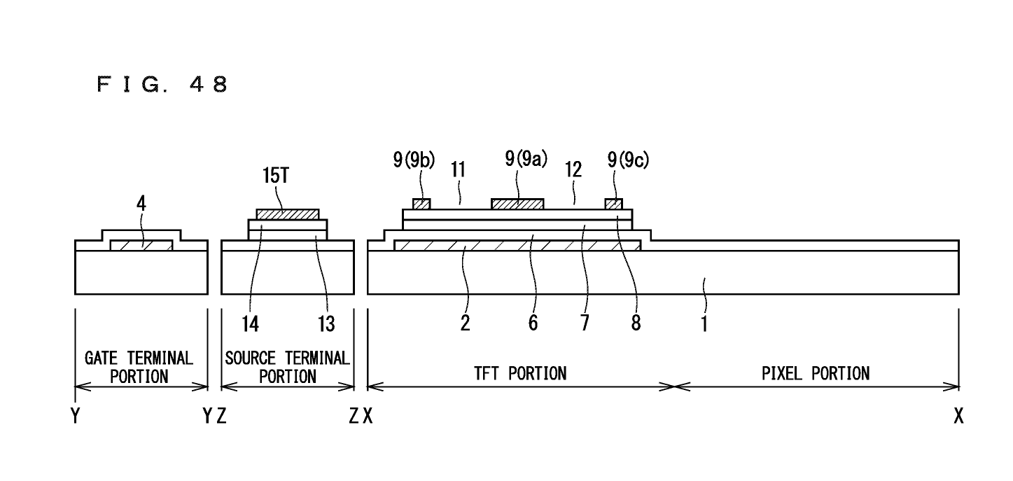

Next, after forming the insulating film 6 (first insulating film) on the entire upper main surface of the substrate 1 to cover the gate electrode 2, the gate wiring 3, and the gate terminal 4, the oxide semiconductor film, the second insulating film, and the second conductive film are laminated in this order on the insulating film 6, and in a second photolithography step, a photoresist pattern having different thicknesses is formed by exposure (half exposure) using a half exposure mask. Then, by patterning the oxide semiconductor film, the second insulating film, and the second conductive film by etching using the photoresist pattern, as illustrated in FIG. 47 and FIG. 48, in the TFT portion, the laminate of the semiconductor channel layer 7, the protective insulating film 8, and the channel region lower layer light shielding film 9 is obtained above the gate electrode 2, and the first source electrode contact hole 11 and the first drain electrode contact hole 12 are formed in the lower layer light shielding film 9. Herein, the outline of the semiconductor channel layer 7 in plan view is arranged to exist inside the outline of the gate electrode 2.

Furthermore, for descriptive purposes, the channel region lower layer light shielding film 9 that remains between the first source electrode contact hole 11 and the first drain electrode contact hole 12 is referred to as the lower layer light shielding film 9a, the channel region lower layer light shielding film 9 that remains on the side opposite to the lower layer light shielding film 9a of the first source electrode contact hole 11 is referred to as the lower layer light shielding film 9b, and the lower layer light shielding film 9 that remains on the side opposite to the lower layer light shielding film 9a of the first drain electrode contact hole 12 is referred to as the lower layer light shielding film 9c.

Furthermore, although the outline of the channel region lower layer light shielding film 9 exists inside the outline of the protective insulating film 8 and the semiconductor channel layer 7, this is because the photoresist pattern is reduced in its film thickness to be made small also in plan view.

Furthermore, in a source wiring formation region, a laminate of the oxide semiconductor film 13, the insulating film 14, and the lower layer source wiring 15 is formed, and in a source terminal formation region, a laminate of the oxide semiconductor film 13, the insulating film 14 and the source terminal 15T is formed by the same process as the above process.

Note that, although the outline of the source terminal 15T (including lower layer source wiring 15) exists inside the outline of the insulating film 14 and the oxide semiconductor film 13, this is because the photoresist pattern is reduced in its film thickness to be made small also in plan view.

Note that, as for the material and forming method of the insulating film 6, the oxide semiconductor film, the second insulating film, and the second conductive film, and the etching using a photoresist pattern formed by a half exposure, description is made using FIG. 19 to FIG. 22 in the second embodiment, so that the description will be omitted.

Next, the interlayer insulating film 16 (third insulating film) is formed on the entire upper main surface of the substrate 1. In the embodiment, a resin series insulating film is formed by an organic resin material. Specifically, for example, an organic resin material of an acrylic having photosensitivity is applied on the substrate 1 to have a thickness of 2.0 to 3.0 μm by a spin coat method as the interlayer insulating film 16.

Third Photolithography Step

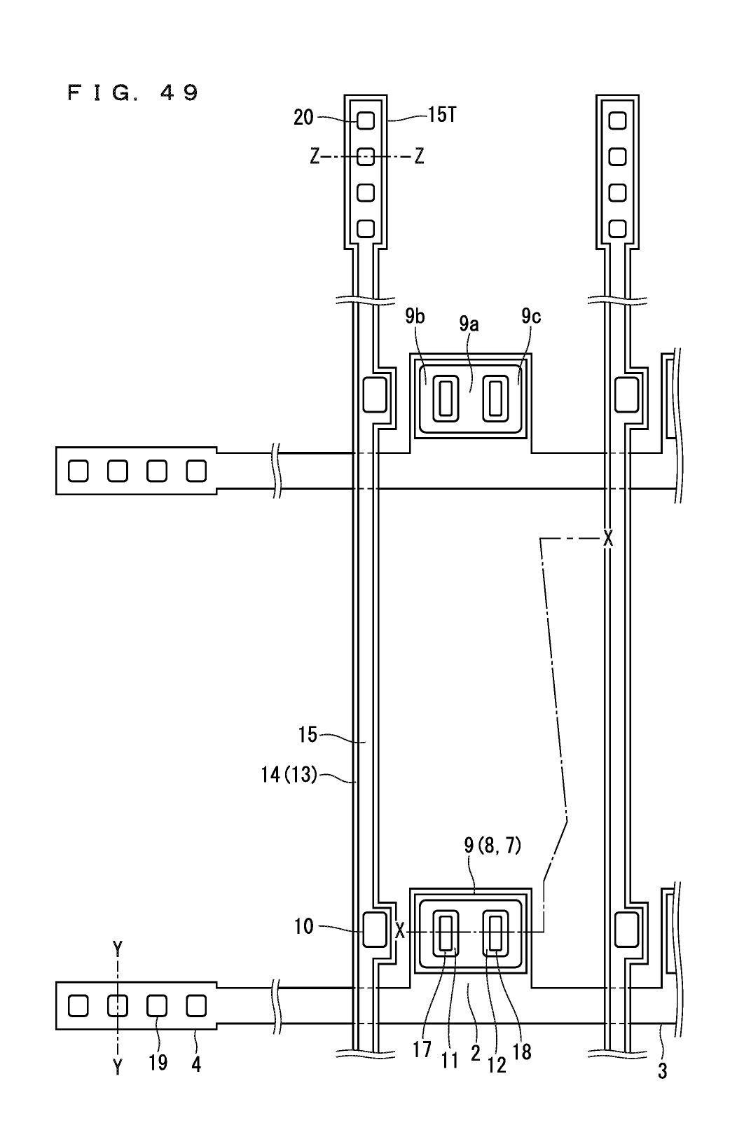

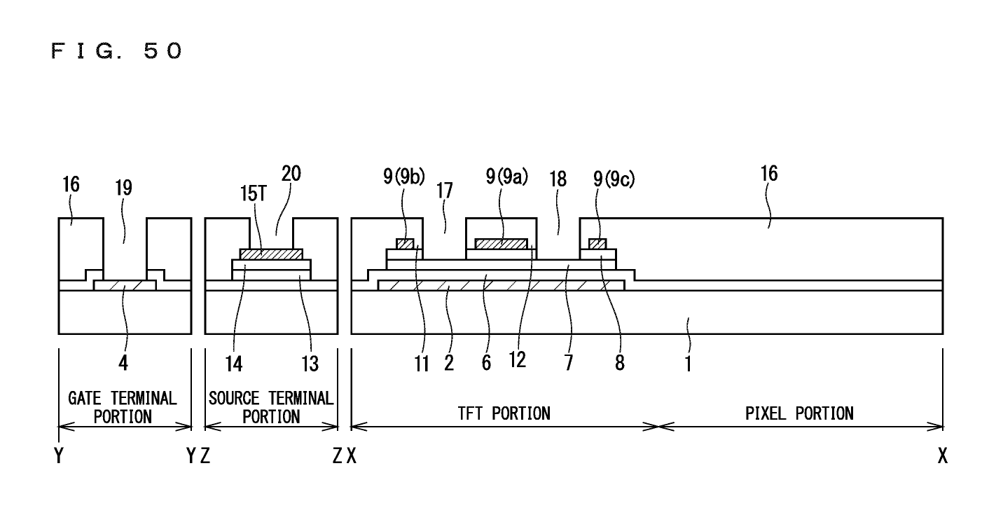

Next, the interlayer insulating film 16 is exposed and developed in a third photolithography step, and as illustrated in FIG. 49 and FIG. 50, the first source wiring contact hole 10 (not shown in FIG. 50), the second source electrode contact hole 17, the second drain electrode contact hole 18, the first gate terminal portion contact hole 19, and the first source terminal portion contact hole 20 penetrating the interlayer insulating film 16 are formed.

Then, the protective insulating film 8 exposed at the bottom portions of the second source electrode contact hole 17 and the second drain electrode contact hole 18 are subjected to etching. For the etching, a dry etching method using a gas including fluorine can be used.

In the embodiment, dry etching is performed by using a gas in which oxygen (O₂) is added to sulfur hexafluoride (SF₆). Adding O₂ gas makes it possible to suppress that the oxide semiconductor film 7 below the protective insulating film 8 is damaged by reduction reaction during etching. By the etching, as illustrated in FIG. 49 and FIG. 50, the semiconductor channel layer 7 is exposed at the bottom surfaces of the second source electrode contact hole 17 and the second drain electrode contact hole 18.

Furthermore, although the gate terminal 4 of an Al alloy is exposed at the bottom surface of the first gate terminal portion contact hole 19 and the lower layer source wiring 15 and the source terminal 15T that are made of an Al alloy are respectively exposed at the bottom surfaces of the first source wiring contact hole 10 and the first source terminal portion contact hole 20, the Al alloy is not subjected to etching by a dry etching using a gas in which oxygen (O₂) is added to sulfur hexafluoride (SF₆), so that the patterns remain as they are.

Note that, as a material of the resin series insulating film used for the interlayer insulating film 16, besides an acrylic organic resin material, an olefin series material, a novolac series material, a polyimide series material, and a siloxane series material can be also used. Such coating type organic insulating materials have low dielectric constant and is easy to be formed into a thick film having a thickness of not less than 2.0 μm, making it possible to suppress wiring capacity to a low capacity. Thus, using such materials makes it possible to drive the TFT substrate at a low voltage, making it possible to contribute to reducing power consumption. This makes it possible to make the transmissive pixel electrode 24 be arranged on the gate wiring or the source wiring to overlap, also making it possible to make aperture ratio high.

Furthermore, for the interlayer insulating film 16, instead of the resin series insulating film material, an inorganic series insulating material such as silicon nitride (SiN) and silicon oxide (SiO) can be also used. When such an inorganic series insulating material is used, the first source wiring contact hole 10, the second source electrode contact hole 17, the second drain electrode contact hole 18, the first gate terminal portion contact hole 19, and the first source terminal portion contact hole 20 are formed using a photoresist pattern as a mask. Alternatively, an inorganic series insulating film material and a resin series insulating film material may be appropriately combined to be used.

Next, the third conductive film and the fourth conductive film are laminated in this order on the entire surface of the interlayer insulating film 16. In the embodiment, a transparent conductive film (translucent conductive film) is used as the third conductive film. As the transparent conductive film, ITO (in which mix ratio of indium oxide (In₂O₃) and tin oxide (SnO₂) is, for example, 90:10 (mass percent)) is used. Herein, by a spattering method, an ITO film having a thickness of 100 nm is formed in amorphous gas, moisture (H₂O), or the like is mixed with argon (Ar). Furthermore, an Al alloy film having light shielding properties is used as the fourth conductive film. Herein, an Al alloy film having a thickness of 100 nm is formed by a spattering method using Ar gas.

Fourth Photolithography Step

Next, a photoresist material is applied on the entire surface of the fourth conductive film (Al alloy film), a photoresist pattern is formed by a fourth photolithography step, and the Al ally film and the amorphous ITO film are sequentially subjected to etching using the photoresist pattern as a mask.

Herein, by performing a half exposure using a half exposure mask, a photoresist pattern having different thicknesses is formed. That is, portions for leaving the fourth conductive film to form the patterns of the upper layer light shielding films 22b and 23b are made thick in their film thicknesses. Note that the fourth conductive film is subjected to etching by two steps, and the film thickness of the photoresist pattern at the portion removed by the second etching is made thin. For example, the film thickness is made thin on the region in which the transmissive pixel electrode 24 is formed so that the fourth conductive film on the region in which the transmissive pixel electrode 24 is formed is not removed in the first etching. Furthermore, the film thickness of the photoresist pattern is made thin also at the gate terminal portion and the source terminal portion.

Then, the fourth conductive film is subjected to patterning by etching using the photoresist pattern as a mask to remove the fourth conductive film at the portion that is not covered with the photoresist pattern. In the etching of the fourth conductive film, a wet etching using PAN chemical solution is used.

Subsequently, the third conductive film is subjected to patterning by etching using the same photoresist pattern as a mask to remove the third conductive film at the portion that is not covered with the photoresist pattern and the fourth conductive film. In the etching of the third conductive film (amorphous ITO film), a wet etching is used using oxalic acid series chemical solution of oxalic acid 5 wt %+water.

Then, the whole of the substrate 1 is heated to 150° C. This heating makes the amorphous ITO film be crystallized to become a polycrystalline ITO film. The substrate temperature is not limited to 150° C., and in the case of a typical amorphous ITO film having a mixture ratio in which indium oxide (In₂O₃) is not less than 85 wt % and not more than 95 wt %, and tin oxide (SnO₂) is not less than 5 wt % and not more than 15 wt % (total thereof is 100 wt %), not less than 140° C. enables crystallization. Furthermore, the temperature on the high-temperature side may be optionally determined depending on the heatproof temperature of the photoresist material or the like to be used. For example, in the embodiment, since an organic resin film of acrylic is used as the interlayer insulating film 16 (third insulating film), not more than 230° C. that is the heatproof temperature of the material is preferable, but, for example, in the case of using a typical photosensitivity resin of novolak series as the photoresist material, not more than 160° C. is preferable.

Next, by oxygen ashing, the film thickness of the photoresist pattern is totally reduced to completely remove the photoresist pattern whose film thickness is thin. In contrast, the photoresist pattern whose film thickness is thick is made thin to be left.

Next, the fourth conductive film is subjected to etching again by using a wet etching method using PAN chemical solution using the remaining photoresist pattern as a mask. In this context, since the ITO film that is the transparent conductive film that is the lower layer is poly crystallized, so that the ITO film is chemically very stable, making it possible to etch the Al alloy film that is not covered with a photoresist pattern, for example, the Al alloy film on the region in which the transmissive pixel electrode 24 is formed, and the Al alloy film of the gate terminal portion and the source terminal portion without suffering etching damage practically with respect to PAN chemical solution (disappearance of film or deterioration of electrical properties or optical properties).

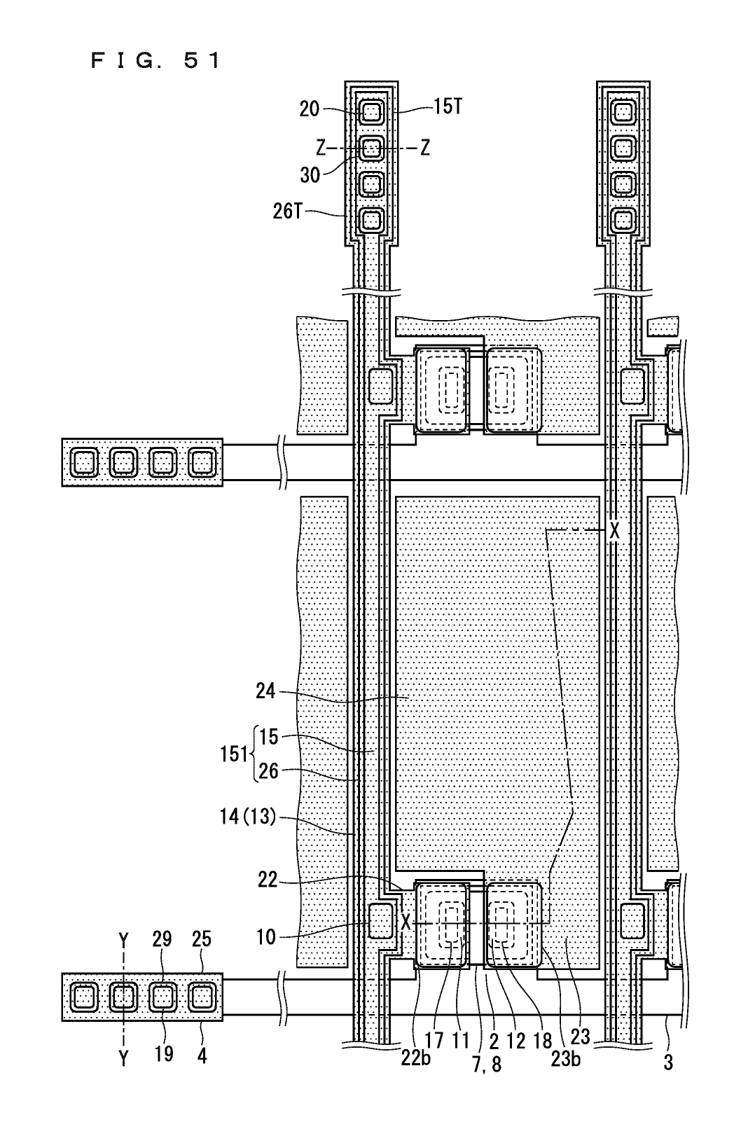

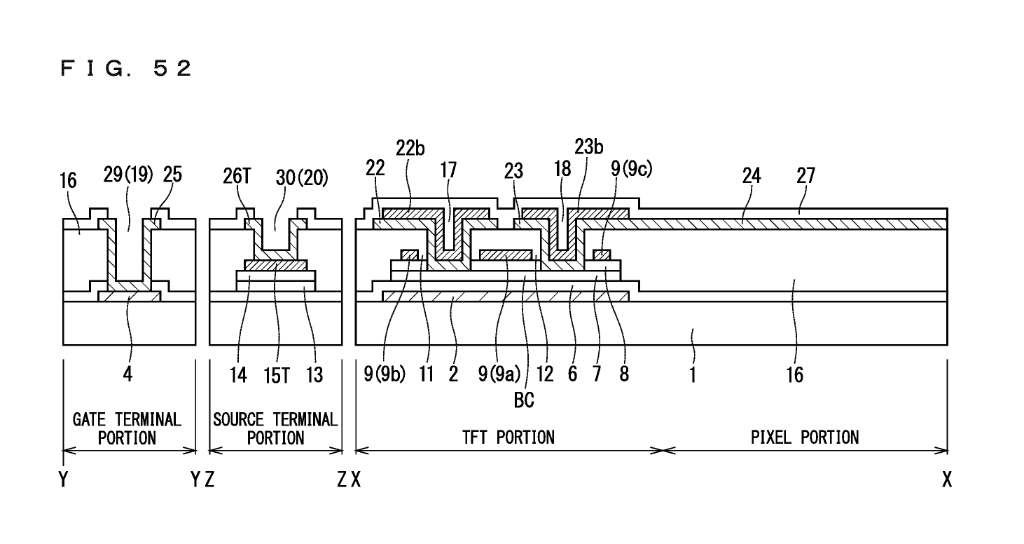

Then, by removing the photoresist pattern, as illustrated in FIG. 51 and FIG. 52, the gate terminal extraction electrode 25, the source electrode 22, the upper layer source wiring 26 extending from the source electrode 22, the source terminal extraction electrode 26T, the drain electrode 23, and the transmissive pixel electrode 24 extending from the drain electrode 23 configured by the transparent conductive film (polycrystalline ITO film) are formed. Furthermore, the upper layer light shielding films 22b and 23b are respectively formed on the upper portion of the source electrode 22 and the upper portion of the drain electrode 23 of the TFT portion. The upper layer light shielding films 22b and 23b are formed to cover substantially the whole of the planer pattern of the semiconductor channel layer 7 excluding the channel region BC in plan view.

Herein, the gate terminal extraction electrode 25 is directly connected to the gate terminal 4 via the first gate terminal portion contact hole 19. Furthermore, the source electrode 22 is directly connected to the semiconductor channel layer 7 via the second source electrode contact hole 17. Furthermore, the upper layer source wiring 26 is directly connected to the lower layer source wiring 15 via the first source wiring contact hole 10. Furthermore, the source wiring extraction electrode 26T is directly connected to the source terminal 15T via the first source terminal portion contact hole 20.

Next, the interlayer insulating film 27 (fourth insulating film) is formed on the entire upper main surface of the substrate 1. In the embodiment, a silicon nitride film (SiN) having a thickness of 400 nm is formed using a CVD method.

Fifth Photolithography Step

Next, a photoresist material is applied on the entire surface of the interlayer insulating film 27 (SiN film), a photoresist pattern is formed by a fifth photolithography step, and the interlayer insulating film 27 is subjected to etching using the photoresist pattern as a mask.

For the etching, a dry etching method using a gas including fluorine can be used. In the embodiment, dry etching is performed by using a gas in which oxygen (O₂) is added to sulfur hexafluoride (SF₆).

Then, by removing the photoresist pattern, as illustrated in FIG. 51 and FIG. 52, the interlayer insulating film 27 above the gate terminal extraction electrode 25 and the source wiring extraction electrode 26T is removed, and the second gate terminal portion contact hole 29 and the second source terminal portion contact hole 30 are respectively formed.

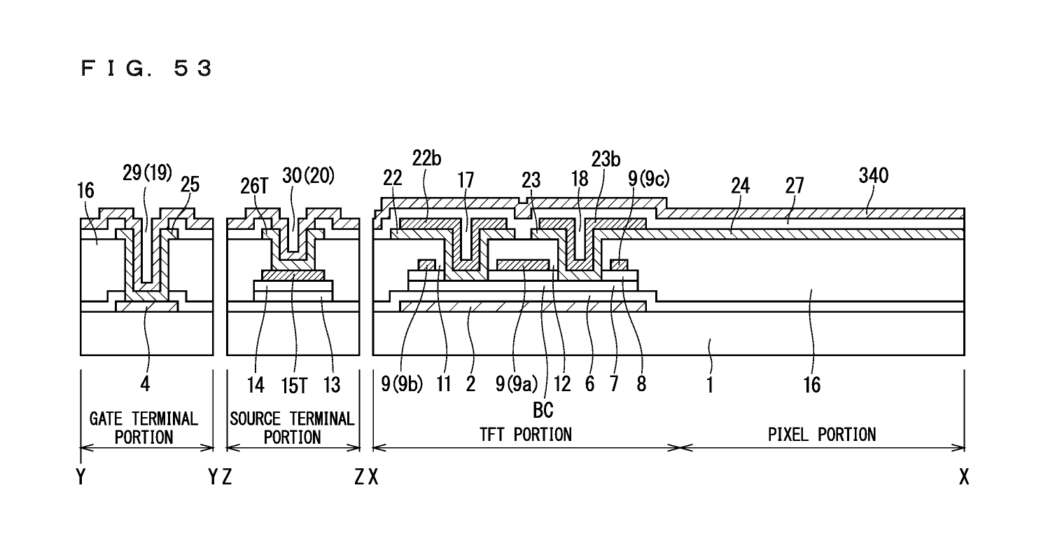

Then, the fifth conductive film 340 that is the material of the counter electrode 32 is formed on the entire upper surface of the interlayer insulating film 27 including the inside of the second gate terminal portion contact hole 29 and the inside of the second source terminal portion contact hole, as illustrated in FIG. 53. In the embodiment, as the fifth conductive film, an amorphous ITO film having a thickness of 100 nm the same as the transparent conductive film that is the third conductive film is formed by a spattering method.

Sixth. Photolithography Step

Next, a photoresist material is applied on the entire surface of the fifth conductive film 340 (amorphous ITO film), a photoresist pattern is formed by a sixth photolithography step, and the fifth conductive film 340 is subjected to etching using the photoresist pattern as a mask. In this etching, a wet etching method can be used using oxalic acid series chemical solution of oxalic acid 5 wt %+water.

Then, by removing the photoresist pattern, as illustrated in FIG. 43 and FIG. 44, the counter electrode 32 having slit opening portions, the gate terminal pad 34, and the source terminal pad 35 configured by an amorphous ITO film that is a transparent conductive film are formed. The gate terminal pad 34 is directly connected to the gate terminal extraction electrode 25 on the lower side via the second gate terminal portion contact hole 29. Furthermore, the source terminal pad 35 is directly connected to the source terminal extraction electrode 26T on the lower side via the second source terminal portion contact hole 30.

Then, the whole of the substrate 1 is heated at 200° C. to make the amorphous ITO film structuring the counter electrode 32, the gate terminal pad 34, and the source terminal pad 35 polycrystalline to complete the TFT substrate 400 illustrated in FIG. 43 and FIG. 44.

Note that upon assembling a liquid crystal display panel, an alignment film and a spacer are formed on a surface of the completed TFT substrate 400. The alignment film is a film for aligning liquid crystal, and is configured by polyimide or the like. Furthermore, a separately manufactured counter substrate equipped with a color filter, a counter electrode, an alignment film, and the like are bonded together with the TFT substrate 400. In this context, a gap is formed between the TFT substrate and the counter substrate by the spacer, and by enclosing liquid crystal in the gap, a liquid crystal display panel of FFS mode of light transmission type of lateral electric field method is formed. Finally, a liquid crystal display device is completed by arranging a light polarizing plate, a phase difference plate, a driving circuit, a backlight unit, and the like on an external side of the liquid crystal display panel.

As described above, the fourth embodiment makes it possible to manufacture the TFT substrate 400 used for a liquid crystal display device of FFS mode of etch stopper type using a high performance oxide semiconductor film as its channel layer with six photolithography steps. Specifically, the protective insulating film 8 that becomes an etch stopper is subsequently formed after forming the oxide semiconductor film, so that the semiconductor channel layer 7 is almost prevented from being deteriorated in its properties due to process damage of the subsequent TFT manufacturing step. This makes it possible to use the semiconductor channel layer 7 as the channel layer of the TFT in the state where high performance properties of the oxide semiconductor are kept.

Furthermore, the source wiring 151 has a two-layered structure of the lower layer source wiring 15 and the upper layer source wiring 26 that are independently formed via the interlayer insulating film, which is so called a redundant wiring. Furthermore, the upper layer source wiring 26 is directly connected to the lower layer source wiring 15 via a plurality of the first source wiring contact holes 10 provided in the interlayer insulating film 16, making it possible to complement the function by the other wiring even when one of the wirings is disconnected. This makes it possible to reduce generation of linear defect due to disconnection of the source wiring 151 to improve yield ratio during manufacturing and reliability of the product.

Furthermore, the lower layer source wiring 15 is consecutively formed with the oxide semiconductor film and the insulating film, making it possible to form the lower layer source wiring 15 (second conductive film) with good adhesiveness, making it possible to reduce generation of disconnection defect due to peeling off of film caused by lack of sticking force. This effect is specifically large at a step portion on the gate wiring pattern in the region in which the gate wiring 3 and the lower layer source wiring 15 intersect.

Furthermore, the semiconductor channel layer 7 is configured such that its entire region is shielded from light by the two-layered light shielding films also on the upper side of the semiconductor channel layer 7 in addition to light shielding by the gate electrode 2 on the lower side of the semiconductor channel layer 7, making it possible to prevent deterioration (optical deterioration) of the channel layer due to absorption of backlight light during operating the liquid crystal display device and external light.

Furthermore, forming the channel region lower layer light shielding film 9 with a conductive film and making the source electrode 22 and the drain electrode 23 be electrically separated (no short circuit occurs) to be an electrically floating state enables achievement of an electrostatic shielding effect with respect to the semiconductor channel layer 7 to suppress variation of TFT properties due to unspecified external noise or the like, making it possible to improve reliability.

Furthermore, using a resin series insulating film that has low permittivity, that is made thick in its film thickness to be not less than 2.0 μm, and that has a flattening action with respect to the main surface of the substrate 1 as the interlayer insulating film 16 (third insulating film) makes it possible to suppress wiring capacity to a low level. This makes it possible to drive the TFT substrate at a low voltage, making it possible to contribute to reducing power consumption. This makes it possible to make the transmissive pixel electrode 24 be arranged on the gate wiring or the source wiring to overlap, also making it possible to make aperture ratio high.

Note that upon overlapping the transmissive pixel electrode 24 and the counter electrode (common electrode) 32 on the source wiring for preferentially making aperture ratio high, it is preferable to omit the upper layer source wiring 26 in the same layer as the transmissive pixel electrode 24, specifically the portion redundantly arranged on the lower layer source wiring 15, that is, the upper layer source wiring 26 between the adjacent first source wiring contact holes 10. Although this fails to achieve the above described operation of reducing liner defect due to disconnection of the source wiring, this makes the transmissive pixel electrode 24 and the counter electrode 32 overlap on the lower layer source wiring 15 without interfering with the upper layer source wiring 26, making it possible to make aperture ratio of a liquid crystal display device of FFS mode high at a higher level.

Formation of Upper Most Layer Light Shielding Film

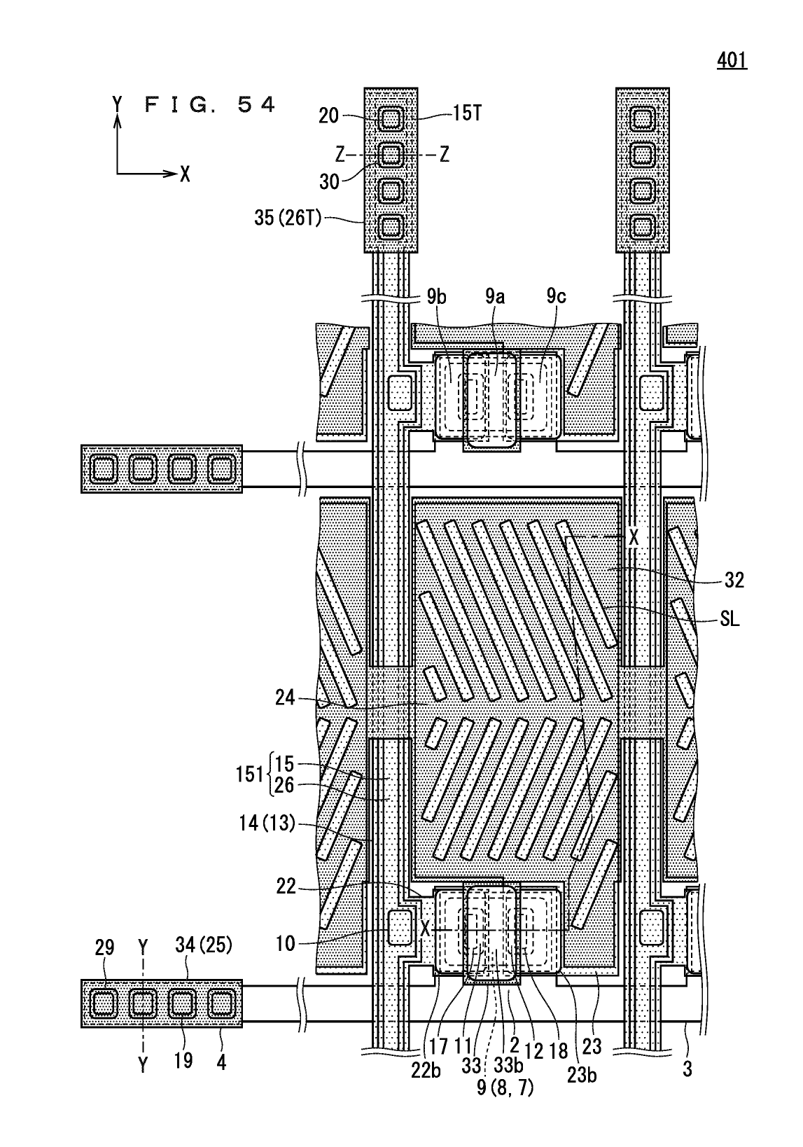

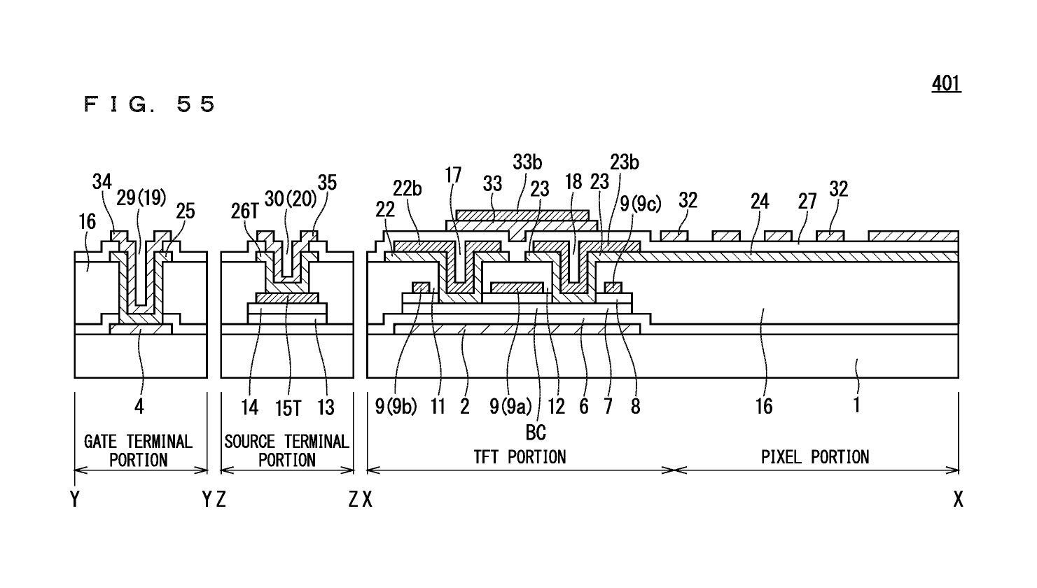

In the above described sixth photolithography step, although the counter electrode 32, the gate terminal pad 34, and the source terminal pad 35 are formed by patterning the fifth conductive film, a photoresist pattern having different thicknesses is formed by further forming a conductive film having light shielding properties (sixth conductive film) on the fifth conductive film and performing a half exposure using a half exposure mask on the laminated film of the fifth conductive film and the sixth conductive film. Then, by sequentially etching the laminated film of the fifth conductive film and the sixth conductive film using the photoresist pattern, as illustrated in FIG. 54 and FIG. 55, an upper most layer light shielding film 33 (lower layer film) and an upper most layer light shielding film 33b (upper layer film) covering the channel region in plan view may be formed above the channel region of the TFT portion.

To be more specific, after forming the fifth conductive film (amorphous ITO film) on the entire upper surface of the interlayer insulating film 27, an Al alloy film having light shielding properties is formed as the sixth conductive film, a photoresist pattern having different thicknesses is formed thereon by a half exposure, and the sixth conductive film (Al alloy film) and the fifth conductive film (amorphous ITO film) are sequentially subjected to etching using the photoresist pattern as a mask to form the counter electrode 32, the gate terminal pad 34, and the source terminal pad 35. Furthermore, above the channel region of the TFT portion, the laminated film of the upper most layer light shielding film 33 configured by an ITO film and the upper most layer light shielding film 33b configured by an Al alloy film are simultaneously formed. This makes it possible to reduce the number of manufacturing processes.

In this case, in the photoresist pattern having different thicknesses formed by a half exposure, portions for forming the patterns of the upper most layer light shielding films 33 and 33b by leaving the fifth and sixth conductive films are made thick in their film thickness. Note that the sixth conductive film is subjected to etching by two steps, and the portion removed by the second etching is made thin in the film thickness of the photoresist pattern. For example, the film thickness is made thin on the regions in which the counter electrode 32, the gate terminal pad 34, and the source terminal pad 35 are formed, and in the first etching, the sixth conductive film on the region in which these are formed is made to be not removed.

Then, the sixth conductive film is first subjected to patterning by etching using the photoresist pattern as a mask to remove the sixth conductive film at the portion that is not covered with the photoresist pattern. In the etching of the sixth conductive film, a wet etching using PAN chemical solution is used.

Subsequently, the fifth conductive film is subjected to patterning by etching using the same photoresist pattern as a mask to remove the fourth conductive film at the portion that is not covered with the photoresist pattern and the sixth conductive film. In the etching of the sixth conductive film (amorphous ITO), a wet etching is used using oxalic acid series chemical solution of oxalic acid 5 wt %+water.

Then, the whole of the substrate 1 is heated at 150° C. to make the amorphous ITO film structuring the counter electrode 32, the gate terminal pad 34, and the source terminal pad 35, and the upper most layer light shielding film 33 polycrystalline. Note that the substrate temperature is not limited to 150° C., and in the case of a typical amorphous ITO film having a mixture ratio in which indium oxide (In₂O₃) is not less than 85 wt % and not more than 95 wt %, and tin oxide (SnO₂) is not less than 5 wt % and not more than 15 wt % (total thereof is 100 wt %), not less than 140° C. enables crystallization. In contrast, on the high temperature side, temperature can be arbitrarily determined depending on the heatproof temperature of a material or the like used for the layer and the pattern formed on the TFT substrate. For example, in the embodiment, since an organic resin film of acrylic is used as the third insulating film, not more than 230° C. that is the heatproof temperature of the material is preferable, but, for example, in the case of using a typical photosensitivity resin of novolak series for the photoresist material, not more than 160° C. is preferable.

Next, by oxygen ashing, the film thickness of the photoresist pattern is totally reduced to completely remove the photoresist pattern whose film thickness is thin. In contrast, the photoresist pattern whose film thickness is thick is made thin to be left.

Next, the sixth conductive film is subjected to etching again by using a wet etching method using PAN chemical solution using the remaining photoresist pattern as a mask. In this context, since the ITO film that is a transparent conductive film that is the lower layer is poly crystallized, so that the ITO film is chemically very stable, making it possible to etch the Al alloy film that is not covered with a photoresist pattern, for example, the Al alloy film on the counter electrode 32 and the Al alloy film of the gate terminal portion and the source terminal portion without suffering etching damage practically with respect to PAN chemical solution (disappearance of film or deterioration of electrical properties or optical properties).

Then, by removing the photoresist pattern, as illustrated in FIG. 54 and FIG. 55, the TFT substrate 401 can be obtained in which the upper most layer light shielding films 33 and 33b covering the channel region in plan view are formed above the channel region of the TFT portion.

In the TFT substrate 401, the upper portion in plan view of the semiconductor channel layer 7 is configured such that light is perfectly shielded by the light shielding films of the three layers including the upper most layer light shielding films 33 and 33b in addition to the lower layer light shielding films 9a, 9b, 9c and the upper layer light shielding films 22b, 23b, making it possible to further suppress deterioration (optical deterioration) of the channel layer due to absorption of backlight light during operation of the liquid crystal display device and external light.

Modification

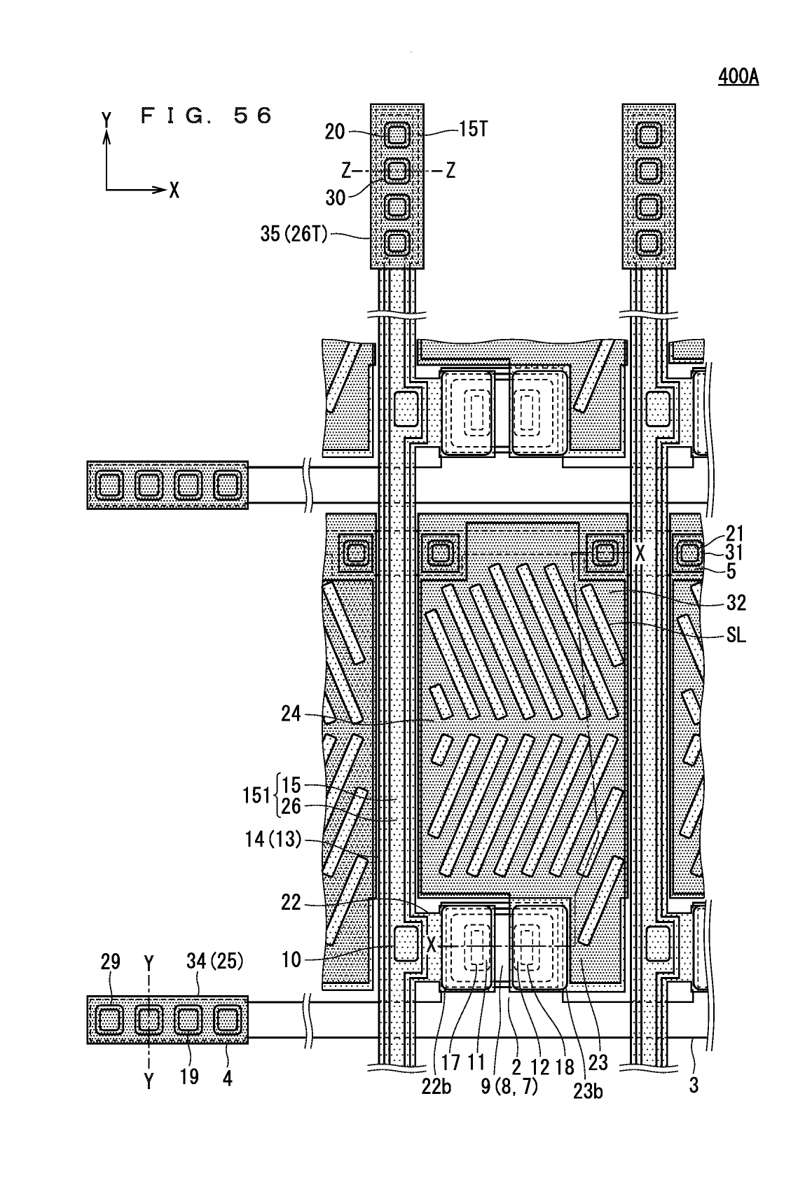

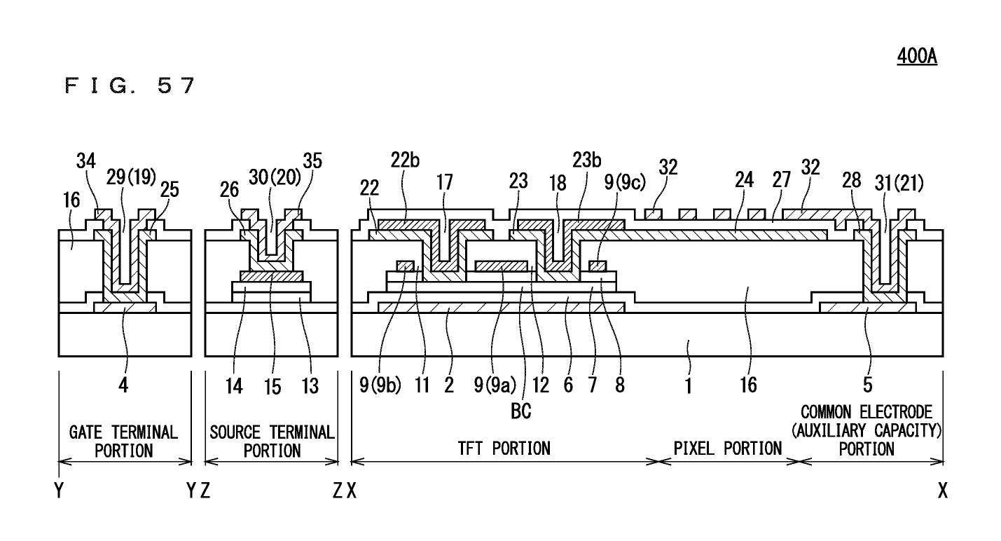

Next, with reference to FIG. 56 and FIG. 57, a configuration of a TFT substrate 400A according to a modification of the fourth embodiment will be described. The TFT substrate 400A has a configuration further including a common electrode that becomes an auxiliary capacity of a pixel electrode in the pixel portion of the TFT substrate 400.

Note that, the same reference numerals are given to the same components as those in the TFT substrate 400 described by using FIG. 43 and FIG. 44, and the overlapping description will be omitted.

Configuration of Pixel of TFT Substrate FIG. 56 is a plan view illustrating a planar configuration of a pixel according to the modification of the fourth embodiment, and FIG. 57 is a cross sectional view illustrating a cross sectional configuration taken along the line X-X (cross sectional configuration of TFT portion, cross sectional configuration of pixel portion, and cross sectional configuration of common electrode portion), a cross sectional configuration taken along the line Y-Y (cross sectional configuration of gate terminal portion), and a cross sectional configuration taken along the line Z-Z (cross sectional configuration of source terminal portion) in FIG. 56. Note that, in the following description, the TFT substrate 400A shall be used for a liquid crystal display device of FFS mode of light transmission type.

As illustrated in FIG. 56, in the TFT substrate 400A, in addition to the configuration of the TFT substrate 400, a common electrode 5 is included, arranged to extend in parallel to a gate wiring 3, and formed by a first conductive film the same as the gate wiring 3. The common electrode 5 forms an auxiliary capacity of a transmissive pixel electrode 24 in the pixel portion and supplies a constant common electrical potential to a counter electrode 32 of the pixel portion. Therefore, the counter electrode 32 is independent for each pixel, and is electrically connected to the common electrode 5 via a common electrode extraction electrode 28 provided in a first common electrode portion contact hole 21.

Next, a cross sectional configuration of the TFT substrate 400A will be described using FIG. 57. As illustrated in FIG. 57, the TFT substrate 400A includes a substrate 1 that is a transparent insulating substrate such as a glass as its base material, and a gate electrode 2 (including gate wiring 3), a gate terminal 4, and the common electrode 5 are arranged on the substrate 1.

Then, an insulating film 6 (first insulating film) is arranged to cover the gate electrode 2, the gate terminal 4, and the common electrode 5. The insulating film 6 functions as a gate insulating film at the TFT portion, so that the insulating film 6 is referred to as a gate insulating film 6 in some cases.

In the TFT portion, an oxide semiconductor film 7 is arranged on the insulating film 6 at the position overlapping with the gate electrode 2. A protective insulating film 8 (second insulating film) is arranged on a semiconductor channel layer 7, and a channel region lower layer light shielding film 9 (second conductive film) formed of a metal film having light shielding properties or the like is arranged on the protective insulating film 8.

Then, an interlayer insulating film 16 (third insulating film) is arranged above the entire surface of the substrate 1 to cover the insulating film 6, the semiconductor channel layer 7, the protective insulating film 8, and the channel region lower layer light shielding film 9. Then, in the TFT portion, a second source electrode contact hole 17 and a second drain electrode contact hole 18 penetrating the interlayer insulating film 16 and the protective insulating film 8 to reach the semiconductor channel layer 7 are provided. The second source electrode contact hole 17 is arranged to be located inside the outer circumference of a first source electrode contact hole 11 in plan view, and is formed such that a surface of the semiconductor channel layer 7 is exposed at its bottom surface. Furthermore, the second drain electrode contact hole 18 is arranged to be located inside the outer circumference of a first drain electrode contact hole 12 in plan view, and is formed such that a surface of the semiconductor channel layer 7 is exposed at its bottom surface. Furthermore, in the common electrode portion, the first common electrode portion contact hole 21 penetrating the interlayer insulating film 16 and the insulating film 6 to reach the common electrode 5 is provided in the region overlapping the pattern of the common electrode 5 on the lower side in plan view.

Then, a source electrode 22 and a drain electrode 23 formed as a third conductive film are arranged so as to be separated from each other and directly connected to the semiconductor channel layer 7 via the second source electrode contact hole 17 and the second drain electrode contact hole 18, respectively. The region between the source electrode 22 and the drain electrode 23 in the semiconductor channel layer 7 forms a channel region BC. Note that, in the embodiment, a transparent conductive film (translucent conductive film) is used as the third conductive film.

Furthermore, the transmissive pixel electrode 24 extending from the drain electrode 23 is provided such that a portion thereof overlaps the common electrode 5 on the lower side in a common electrode formation region in plan view, and an auxiliary capacity for the pixel electric potential is formed via the insulating film 6 and the interlayer insulating film 16.

Furthermore, in the first common electrode portion contact hole 21, the common electrode extraction electrode 28 formed as the third conductive film is provided to be directly connected to the common electrode 5 on the lower side. Note that the common electrode extraction electrode 28 is formed as a pattern separated from the source electrode 22 and the drain electrode 23 (including transmissive pixel electrode 24) so as not to be electrically connected (not to cause short circuit) therewith.

Upper layer light shielding films 22b and 23b (forth conductive film) are respectively provided on the source electrode 22 and the drain electrode 23, and as illustrated in FIG. 56, the upper region of the semiconductor channel layer 7 of the TFT portion is configured such that light from an upper surface is shielded in its entire region in plan view by the upper layer light shielding films 22b and 23b and lower layer light shielding films 9a, 9b, 9c. Furthermore, the lower region of the semiconductor channel layer 7 of the TFT portion is configured such that light from a lower surface (surface on the side of the substrate 1) is shielded in its entire region in plan view by the gate electrode 2.

Then, an interlayer insulating film 27 (fourth insulating film) is formed above the whole of the substrate 1 to cover the source electrode 22, the drain electrode 23, the transmissive pixel electrode 24, and the upper layer light shielding films 22b, 23b, and the common electrode extraction electrode 28. Note that in the common electrode portion, a second common electrode portion contact hole 31 is provided in the interlayer insulating film 27. The second common electrode portion contact hole 31 is arranged in the region overlapping the pattern of the common electrode 5 and the common electrode extraction electrode 28 on thy: lower side in plan view, and is formed such that the surface of the common electrode extraction electrode 28 that is the lower layer is exposed.

The counter electrode 32 (fifth conductive film) is provided on the interlayer insulating film 27. As illustrated in FIG. 57, the counter electrode 32 is provided so as to be directly connected to the common electrode extraction electrode 28 that is the lower layer via the second common electrode portion contact hole 31, and is electrically connected to the common electrode 5 on the lower side via the common electrode extraction electrode 28, so that a constant common electric potential is supplied to the counter electrode 32.

Manufacturing Method

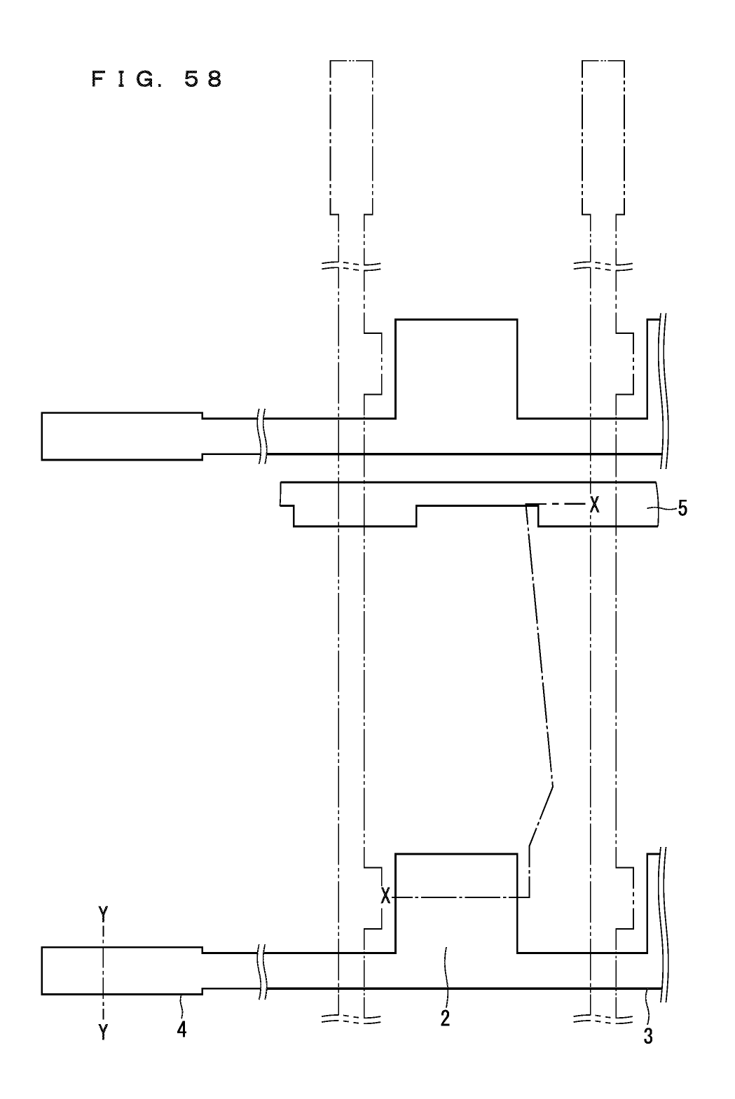

Hereinafter, a manufacturing method of the TFT substrate 400A according to the modification of the fourth embodiment will be described using FIG. 58 to FIG. 68. Note that a plan view and a cross sectional view illustrating the final step respectively correspond to FIG. 56 and FIG. 57.

The first conductive film that is the material of the gate electrode 2, the gate wiring 3, the common electrode 5, and the like is formed on one of the entire main surfaces of the substrate 1 that has been washed. The material capable of being used as the first conductive film is described in the fourth embodiment, so that overlapping description will be omitted. In the modification, an aluminum (Al) alloy film shall be used as the first conductive film, and the Al alloy film is formed to have a thickness of 200 nm by a sputtering method using argon (Ar) gas.

First Photolithography Step

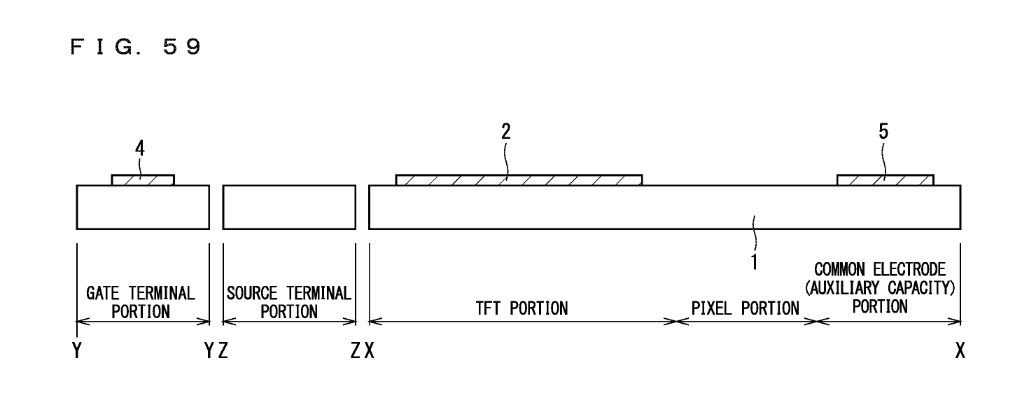

Then, a photoresist material is applied on the first conductive film, a photoresist pattern is formed in a first photolithography step, and the first conductive film is subjected to patterning by etching using the photoresist pattern as a mask. Herein, a wet etching using PAN chemical solution is used. Then, by removing the photoresist pattern, as illustrated in FIG. 58 and FIG. 59, the gate electrode 2, the gate wiring 3 (not shown in FIG. 59), the gate terminal 4, and the common electrode 5 are formed on the upper main surface of the substrate 1.

Second Photolithography Step

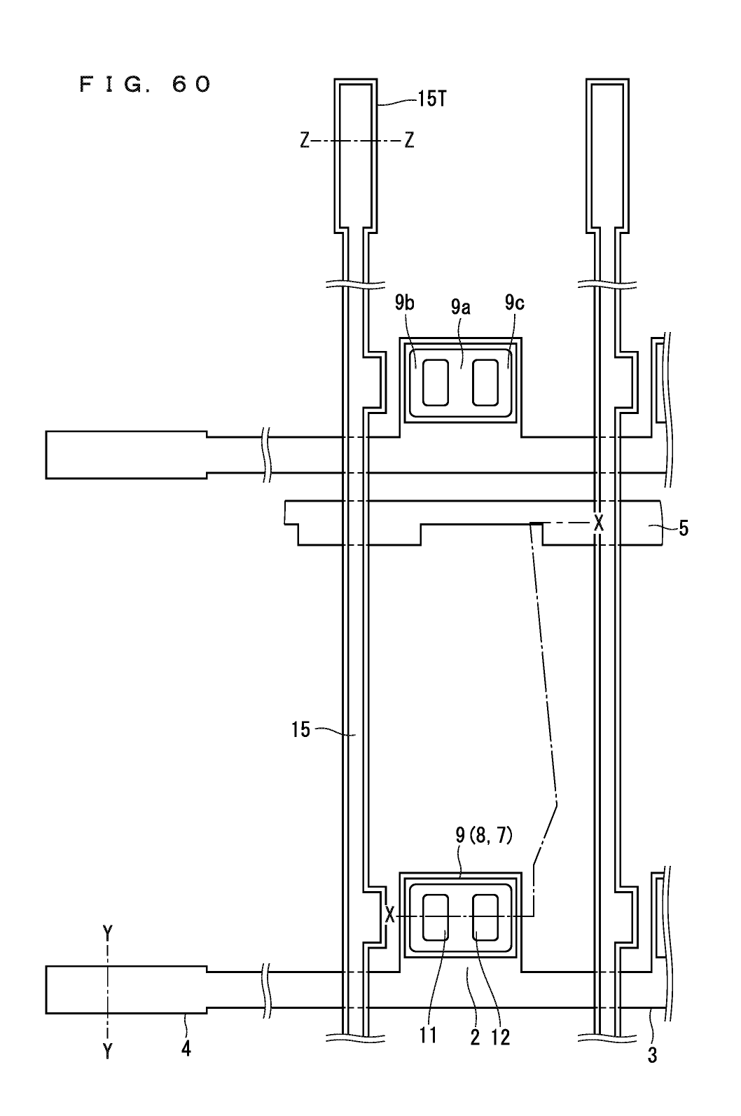

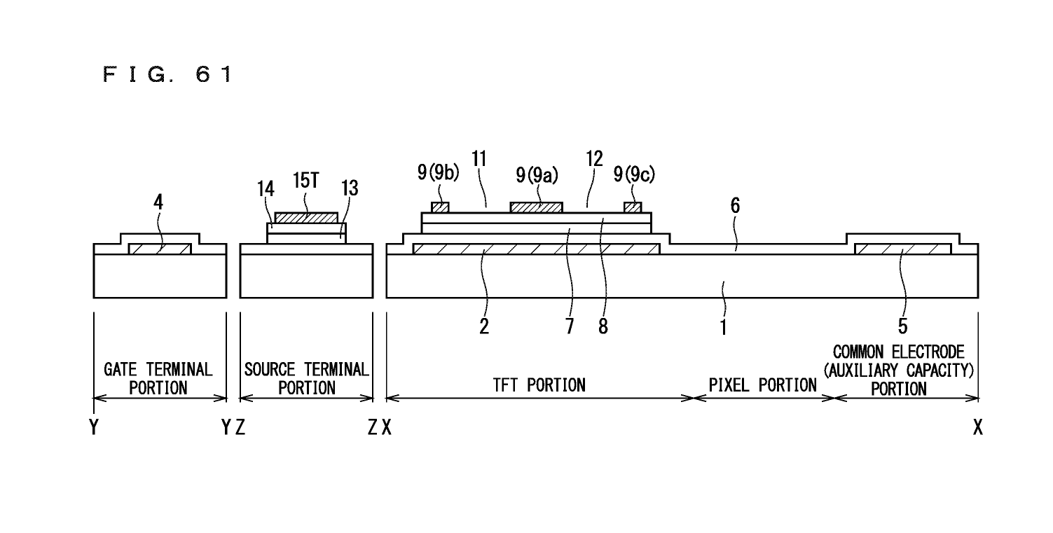

Then, after the insulating film 6 (first insulating film) is formed on the entire upper main surface of the substrate 1 to cover the gate electrode 2, the gate wiring 3, the gate terminal 4, and the common electrode 5, the oxide semiconductor film, the second insulating film, and the second conductive film are laminated in this order on the insulating film 6. Then, in a second photolithography step, a photoresist pattern having different thicknesses is formed by an exposure (half exposure) using a half exposure mask, and the oxide semiconductor film, the second insulating film, and the second conductive film are subjected to patterning by etching using the photoresist pattern. Herewith, as illustrated in FIG. 60 and FIG. 61, the laminate of the semiconductor channel layer 7, the protective insulating film 8, and the channel region lower layer light shielding film 9 is obtained above the gate electrode 2 in the TFT portion, and the first source electrode contact hole 11 and the first drain electrode contact hole 12 are formed in the channel region lower layer light shielding film 9. Herein, the outline of the semiconductor channel layer 7 in plan view is arranged to exist inside the outline of the gate electrode 2.

Furthermore, for descriptive purposes, the channel region lower layer light shielding film 9 that remains between the first source electrode contact hole 11 and the first drain electrode contact hole 12 is referred to as the lower layer light shielding film 9a, the channel region lower layer light shielding film 9 that remains on the side opposite to the lower layer light shielding film 9a of the first source electrode contact hole 11 is referred to as the lower layer light shielding film 9b, and the channel region lower layer light shielding film 9 that remains on the side opposite to the lower layer light shielding film 9a of the first drain electrode contact hole 12 is referred to as the lower layer light shielding film 9c.

Furthermore, in a source wiring formation region, a laminate of an oxide semiconductor film 13, an insulating film 14, and a lower layer source wiring 15 is formed, and in a source terminal formation region, a laminate of the oxide semiconductor film 13, the insulating film 14, and a source terminal 15T is formed by the same process as the above process.

Note that, as for the material and forming method of the insulating film 6, the oxide semiconductor film, the second insulating film, and the second conductive film, and the etching using a photoresist pattern formed by a half exposure, description is made using FIG. 19 to FIG. 22 in the second embodiment, so that the description will be omitted.

Next, the interlayer insulating film 16 (third insulating film) is formed above the entire upper main surface of the substrate 1. In the modification, a resin series insulating film is formed by an organic resin material. Specifically, for example, an organic resin material of an acrylic having photosensitivity is applied on the substrate 1 to have a thickness of 2.0 to 3.0 μm by a spin coat method as the interlayer insulating film 16.

Third Photolithography Step

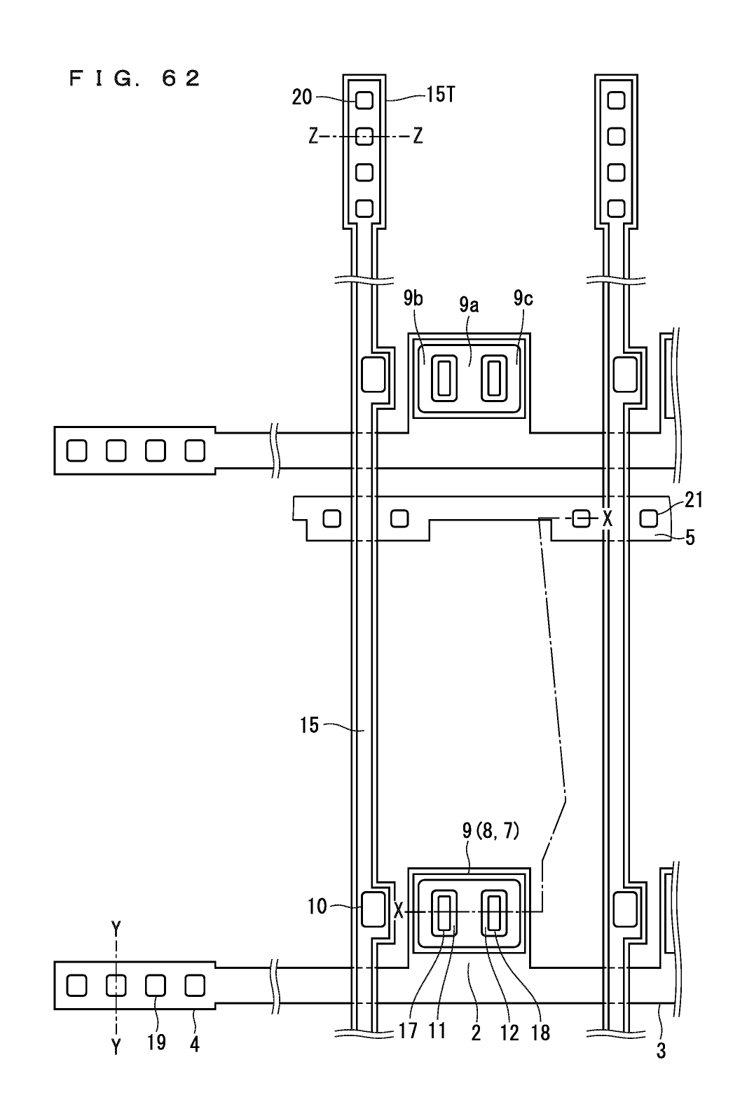

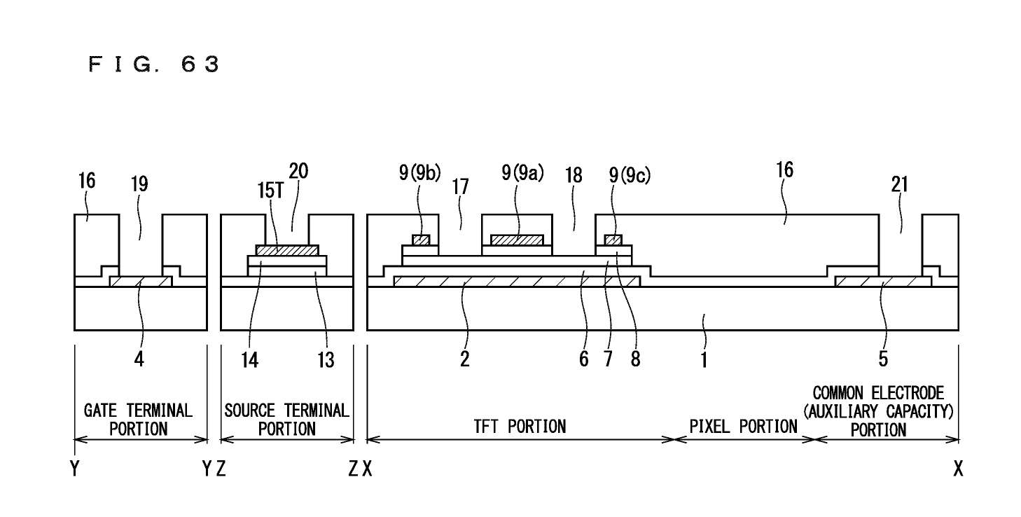

Next, the interlayer insulating film 16 is exposed and developed in a third photolithography step, and as illustrated in FIG. 62 and FIG. 63, a first source wiring contact hole 10 (not shown in FIG. 63), the second source electrode contact hole 17, the second drain electrode contact hole 18, a first gate terminal portion contact hole 19, a first source terminal portion contact hole 20, and the first common electrode portion contact hole 21 penetrating the interlayer insulating film 16 are formed.

Then, the protective insulating film 8 exposed at the bottom portions of the second source electrode contact hole 17 and the second drain electrode contact hole 18 are subjected to etching. In the etching, dry etching is performed using a gas in which oxide (O₂) is added to sulfur hexafluoride (SF₆). By the etching, as illustrated in FIG. 62 and FIG. 63, the semiconductor channel layer 7 is exposed at the bottom surfaces of the second source electrode contact hole 17 and the second drain electrode contact hole 18.

Furthermore, although the first gate terminal portion contact hole 19 and the first common electrode portion contact hole 21 also penetrate the insulating film 6, and the gate terminal 4 and the common electrode 5 of Al alloy are respectively exposed at their bottom surfaces, and the lower layer source wiring 15 and the source terminal 15T of Al alloy are respectively exposed at the bottom surfaces of the first source wiring contact hole 10 and the first source terminal portion contact hole 20, the Al alloy is not etched by dry etching using a gas in which oxygen (O₂) is added to sulfur hexafluoride (SF₆), so that the patterns remain as they are.

Note that, as a material of the resin series insulating film used for the interlayer insulating film 16, besides an acrylic organic resin material, an olefin series material, a novolac series material, a polyimide series material, and a siloxane series material can be also used. Such coating type organic insulating materials have low dielectric constant and is easy to be formed into a thick film having a thickness of not less than 2.0 μm, making it possible to suppress wiring capacity to a low capacity. Thus, using such materials makes it possible to drive the TFT substrate at a low voltage, making it possible to contribute to reducing power consumption. This makes it possible to make the transmissive pixel electrode 24 be arranged on the gate wiring or the source wiring to overlap, also making it possible to make aperture ratio high.

Furthermore, for the interlayer insulating film 16, instead of the resin series insulating film material, an inorganic series insulating material such as silicon nitride (SiN) and silicon oxide (SiO) can be also used. When such an inorganic series insulating material is used, the first source wiring contact hole 10, the second source electrode contact hole 17, the second drain electrode contact hole 18, the first gate terminal portion contact hole 19, and the first source terminal portion contact hole 20 are formed using a photoresist pattern as a mask. Alternatively, an inorganic series insulating film material and a resin series insulating film material may be appropriately combined to be used.

Next, the third conductive film and the fourth conductive film are laminated in this order on the entire surface of the interlayer insulating film 16. In the modification, a transparent conductive film (translucent conductive film) is used as the third conductive film, and an Al alloy film having light shielding properties is used as the fourth conductive film. Note that the material, the film thickness, and the manufacturing method of the transparent conductive film, and the material, the film thickness, and the manufacturing method of the Al alloy film are the same as those in the fourth embodiment, so that the description will be omitted.

Fourth Photolithography Step

Next, a photoresist material is applied on the entire surface of the fourth conductive film (Al alloy film), and a photoresist pattern is formed in a fourth photolithography step. Herein, by performing a half exposure using the half exposure mask described in the second photolithography step, a photoresist pattern having different thicknesses is formed.

Then, the fourth conductive film is subjected to patterning by a wet etching using PAN chemical solution using the photoresist pattern as a mask to remove the fourth conductive film at the portion that is not covered with the photoresist pattern.

Subsequently, the third conductive film is subjected to patterning by a wet etching using an oxalic acid series chemical solution of oxalic acid 5 wt %+water using the same photoresist pattern as a mask to remove the third conductive film at the portion that is not covered with the photoresist pattern and the fourth conductive film.

Then, the whole of the substrate 1 is heated to 150° C. to make the amorphous ITO film be crystallized to be a polycrystalline ITO film.

Next, by oxygen ashing, the film thickness of the photoresist pattern is totally reduced to completely remove the photoresist pattern whose film thickness is thin. In contrast, the photoresist pattern whose film thickness is thick is made thin to be left.

Next, the fourth conductive film is subjected to etching again by using a wet etching method using PAN chemical solution using the remaining photoresist pattern as a mask. In this context, the ITO film that is the transparent conductive film that is the lower layer is poly crystallized, making it possible to etch the Al alloy film that is not covered with a photoresist pattern, for example, the Al alloy film on the region in which the transmissive pixel electrode 24 and the common electrode extraction electrode 28 are formed and the Al alloy film of the gate terminal portion and the source terminal portion without suffering etching damage practically with respect to PAN chemical solution (disappearance of film or deterioration of electrical properties or optical properties).

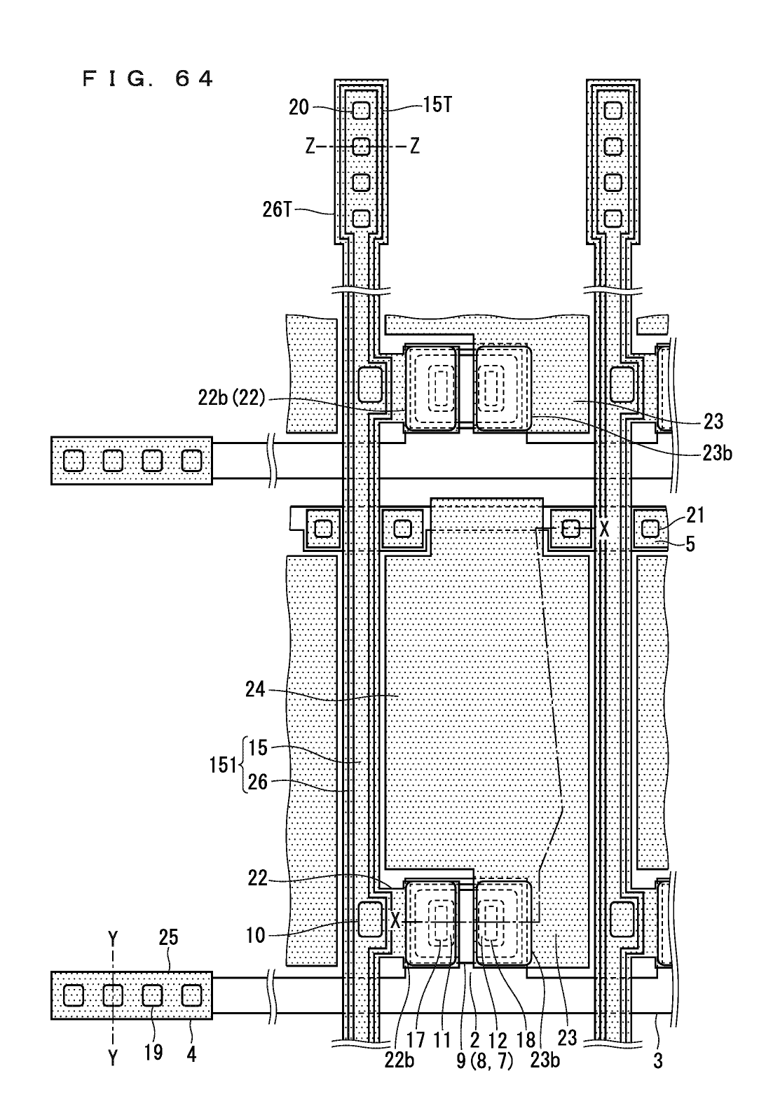

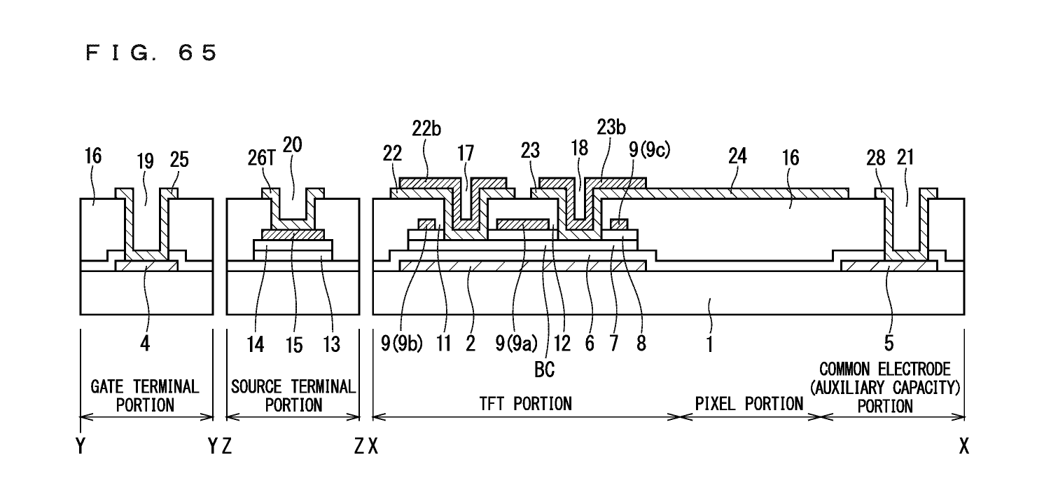

Then, by removing the photoresist pattern, as illustrated in FIG. 64 and FIG. 65, a gate terminal extraction electrode 25, the source electrode 22, an upper layer source wiring 26 extending from the source electrode 22, a source terminal extraction electrode 26T, the drain electrode 23, and the transmissive pixel electrode 24 extending from the drain electrode 23, and the common electrode extraction electrode 28 configured by the transparent conductive film (polycrystalline ITO film) are formed. Note that the common electrode extraction electrode 28 is formed by an independent pattern electrically separated from the transmissive pixel electrode 24. Furthermore, the upper layer light shielding films 22b and 23b are respectively formed on the upper portion of the source electrode 22 and the upper portion of the drain electrode 23 of the TFT portion. The upper layer light shielding films 22b and 23b are formed to cover substantially the whole of the planer pattern of the semiconductor channel layer 7 excluding the channel region BC in plan view.

Herein, the gate terminal extraction electrode 25 is directly connected to the gate terminal 4 via the first gate terminal portion contact hole 19. Furthermore, the source electrode 22 is directly connected to the semiconductor channel layer 7 via the second source electrode contact hole 17. Furthermore, the upper layer source wiring 26 is directly connected to the lower layer source wiring 15 via the first source wiring contact hole 10. Furthermore, the source wiring extraction electrode 26T is directly connected to the source terminal 15T via the first source terminal portion contact hole 20. Then, the common electrode extraction electrode 28 is directly connected to the common electrode 5 via the first common electrode portion contact hole 21.

Next, the interlayer insulating film 27 (fourth insulating film) is formed above the entire upper main surface of the substrate 1. In the embodiment, a silicon nitride film (SiN) having a thickness of 400 nm is formed using a CVD method.

Fifth Photolithography Step

Next, a photoresist material is applied on the entire surface of the interlayer insulating film 27 (SiN film), a photoresist pattern is formed by a fifth photolithography step, and the interlayer insulating film 27 is subjected to etching using the photoresist pattern as a mask.

For the etching, a dry etching method using a gas including fluorine can be used. In the modification, dry etching is performed by using a gas in which oxygen (O₂) is added to sulfur hexafluoride (SF₆).

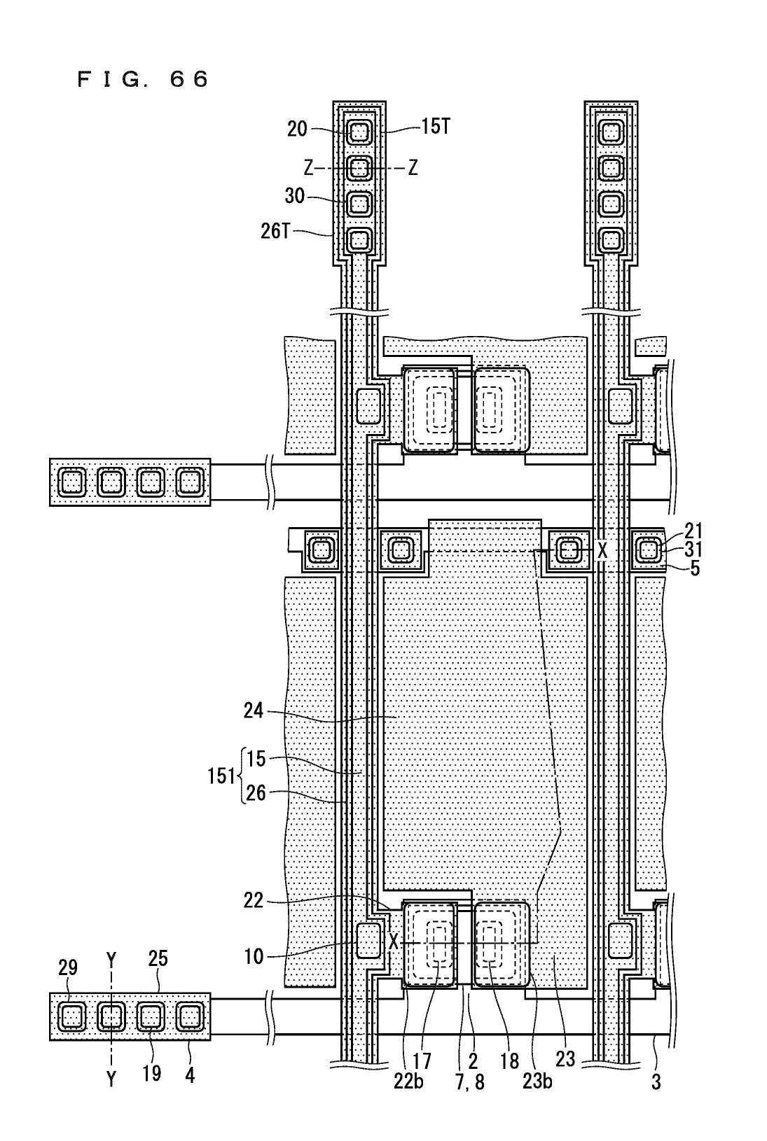

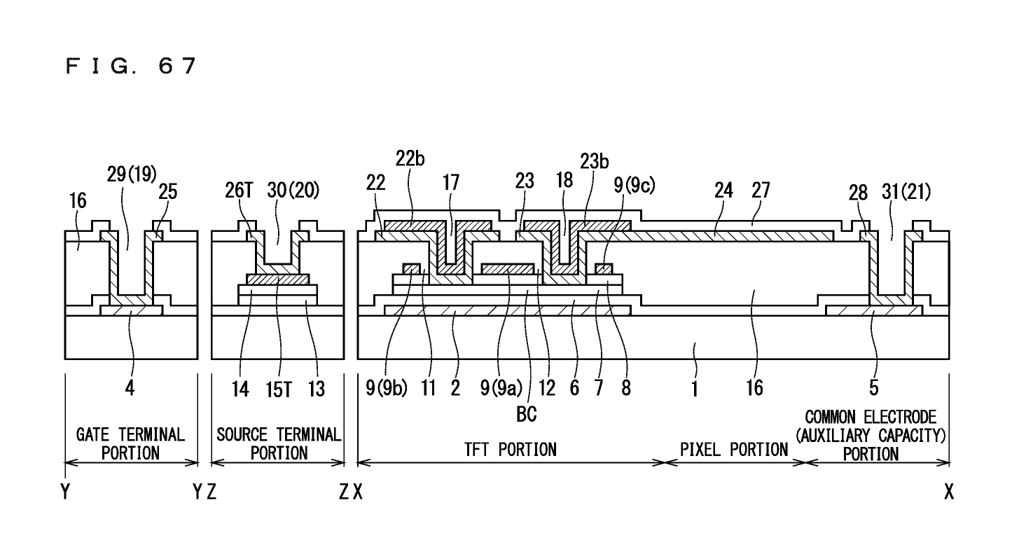

Then, by removing the photoresist pattern, as illustrated in FIG. 66 and FIG. 67, the interlayer insulating film 27 above the gate terminal extraction electrode 25, the source wiring extraction electrode 26T, and the common electrode extraction electrode 28 is removed, and a second gate terminal portion contact hole 29, a second source terminal portion contact hole 30, and the second common electrode portion contact hole 31 are respectively formed.

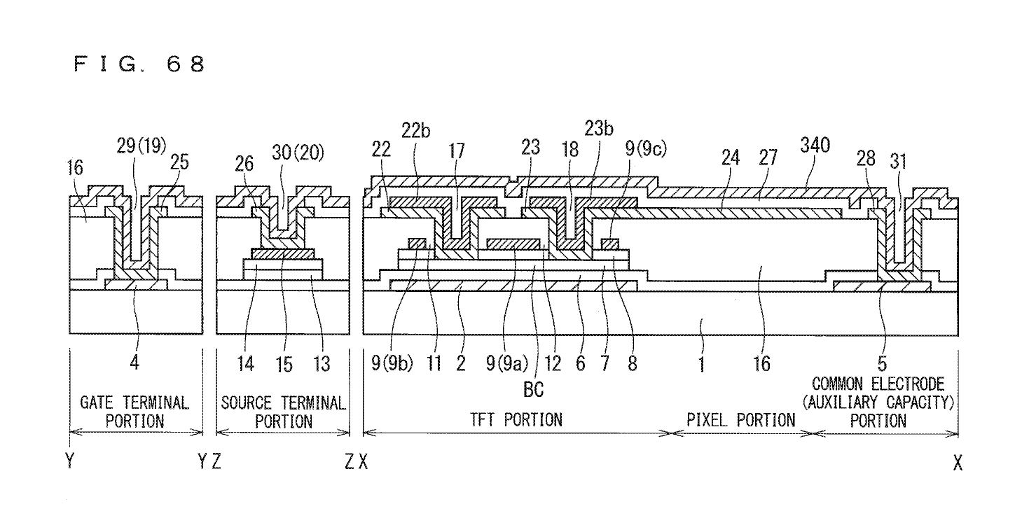

Then, the fifth conductive film 340 that is the material of the counter electrode 32 is formed on the entire upper surface of the interlayer insulating film 27 including the inside of the second gate terminal portion contact hole 29, the inside of the second source terminal portion contact hole, and the inside of the second common electrode portion contact hole 31 as illustrated in FIG. 68. In the modification, as the fifth conductive film, an amorphous ITO film having a thickness of 100 nm the same as the transparent conductive film that is the third conductive film is formed by a spattering method.

Sixth Photolithography Step

Next, a photoresist material is applied on the entire surface of the fifth conductive film 340 (amorphous ITO film), a photoresist pattern is formed by a sixth photolithography step, and the fifth conductive film 340 is subjected to etching using the photoresist pattern as a mask. In this etching, a wet etching method can be used using oxalic acid series chemical solution of oxalic acid 5 wt %+water.

Then, by removing the photoresist pattern, as illustrated in FIG. 56 and FIG. 57, the counter electrode 32 having slit opening portions, a gate terminal pad 34, and a source terminal pad 35 configured by an amorphous ITO film that is a transparent conductive film are formed. The gate terminal pad 34 is directly connected to the gate terminal extraction electrode 25 on the lower side via the second gate terminal portion contact hole 29. Furthermore, the source terminal pad 35 is directly connected to the source terminal extraction electrode 26T on the lower side via the second source terminal portion contact hole 30. Furthermore, the counter electrode 32 is directly connected to the common electrode extraction electrode 28 that is the lower layer via the second common electrode portion contact hole 31.

Then, the whole of the substrate 1 is heated at 200° C. to make the amorphous ITO film that is the counter electrode 32 having slit opening portions, the gate terminal pad 34, and the source terminal pad 35 polycrystalline. By the above processes, the TFT substrate 400A of the modification illustrated in FIG. 56 and FIG. 57 is completed.

Then, the liquid crystal display panel is assembled and a light polarizing plate, a phase difference plate, a driving circuit, a backlight unit, and the like are arranged outside the liquid crystal display panel to complete the liquid crystal display device, but the detail thereof is described in the first embodiment, so that the description thereof is omitted.

As described above, in the modification, an auxiliary capacity can be added to the transmissive pixel electrode 24 by providing the common electrode 5, making it possible to increase a leak margin of a display signal electric potential applied to the transmissive pixel electrode 24 in addition to the effects the same as those in the fourth embodiment. This makes it possible to reduce display defect caused by retention failure of signal electric potential to achieve a higher quality liquid crystal display device.

Furthermore, the counter electrode 32 is electrically directly connected to the common electrode 5 on the lower side via the first common electrode portion contact hole 21 and the second common electrode portion contact hole 31 provided for each pixel, so that a constant common electric potential signal is surely supplied to each pixel, making it possible to reduce generation of display trouble such as point defect.

Furthermore, instead of making the pattern of the counter electrode 32 be an independent pattern for each pixel, as illustrated in FIG. 43 of the fourth embodiment, the counter electrode 32 may be formed in a consecutive shape to stride between at least adjacent pixels in the lateral direction to supply a constant common electric potential from an end (not shown) of the display region. In this case, a constant common electric potential is to be supplied to the counter electrode 32 from both the common electrode 5 and the end of the display region, so that even when a disconnection trouble occurs in one of them, the common electric potential is supplied from the other one, further increasing the effect of preventing generation of display trouble such as point defect and line defect.

Formation of Upper Most Layer Light Shielding Film

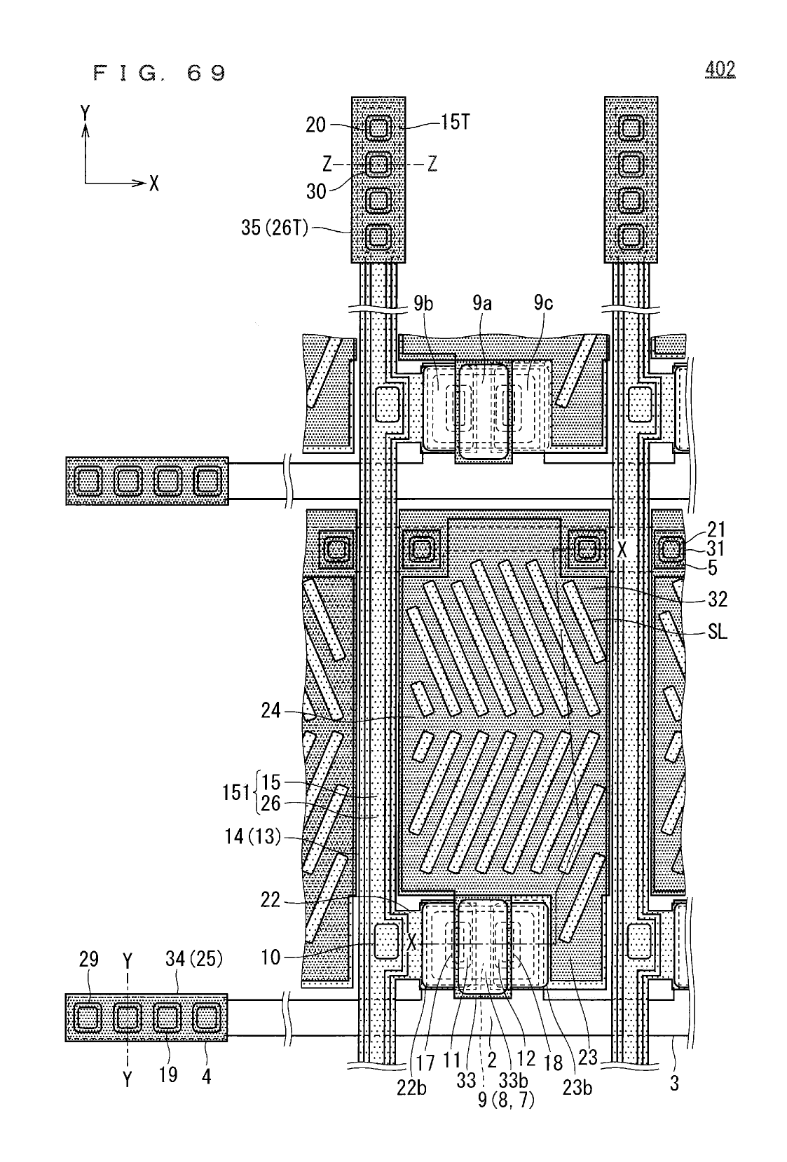

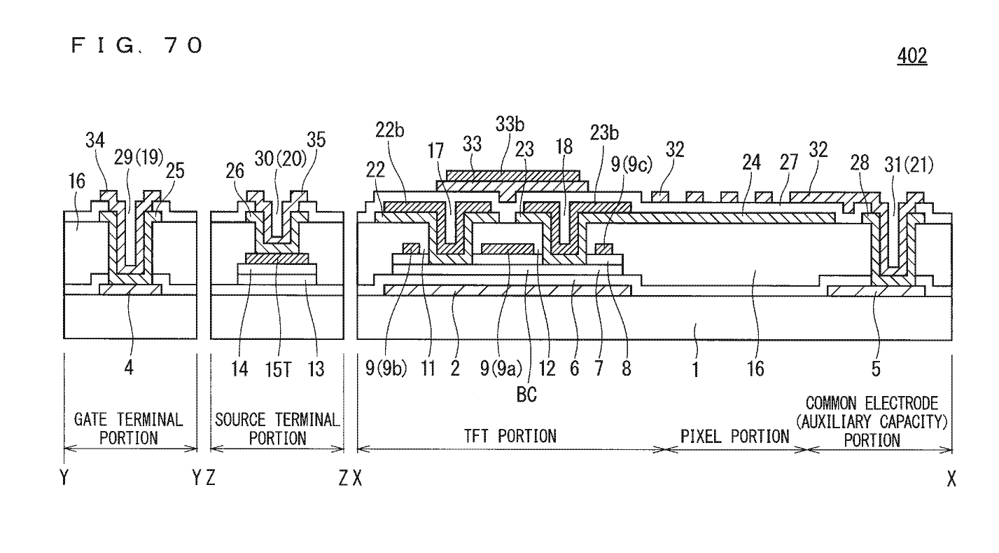

In the above described sixth photolithography step, although the counter electrode 32, the gate terminal pad 34, and the source terminal pad 35 are formed by patterning the fifth conductive film, it is also preferable that an upper most layer light shielding film 33 (lower layer film) and an upper most layer light shielding film 33b (upper layer film) covering the channel region in plan view may be formed above the channel region of the TFT portion as illustrated in FIG. 69 and FIG. 70 by forming photoresist pattern having different thicknesses by forming a conductive film having light shielding properties (sixth conductive film) on the fifth conductive film and performing a half exposure using a half exposure mask on the laminated film of the fifth conductive film and the sixth conductive film, and by sequentially subjecting the laminated film of the fifth conductive film and the sixth conductive film to etching using the photoresist pattern.

To be more specific, after forming the fifth conductive film (amorphous ITO film) on the entire upper surface of the interlayer insulating film 27, an Al alloy film having light shielding properties is formed as the sixth conductive film to be a laminated film, a photoresist pattern having different thicknesses is formed thereon by a half exposure, and the sixth conductive film (Al alloy film) and the fifth conductive film (amorphous ITO film) are sequentially subjected to etching using the photoresist pattern as a mask to form the counter electrode 32, the gate terminal pad 34, and the source terminal pad 35, and to form the laminated film of the upper most layer light shielding film 33 configured by an ITO film and the upper most layer light shielding film 33b configured by an Al alloy film above the channel region of the TFT portion.

In this case, in the photoresist pattern having different thicknesses formed by a half exposure, portions for forming the patterns of the upper most layer light shielding films 33 and 33b by leaving the fifth and sixth conductive films are made thick in their film thickness. Note that the sixth conductive film is subjected to etching by two steps, and the portion removed by the second etching is made thin in the film thickness of the photoresist pattern. For example, the film thickness is made thin on the regions in which the counter electrode 32, the gate terminal pad 34, and the source terminal pad 35 are formed, and in the first etching, the sixth conductive film on the region in which these are formed is made to be not removed.

Then, the sixth conductive film is first subjected to patterning by etching using the photoresist pattern as a mask to remove the sixth conductive film at the portion that is not covered with the photoresist pattern. In the etching of the fourth conductive film, a wet etching using PAN chemical solution is used.

Subsequently, the fifth conductive film is subjected to patterning by etching using the same photoresist pattern as a mask to remove the fourth conductive film at the portion that is not covered with the photoresist pattern and the sixth conductive film. In the etching of the fourth conductive film (amorphous ITO), a wet etching is used using oxalic acid series chemical solution of oxalic acid 5 wt %+water.

Then, the whole of the substrate 1 is heated at 150° C. to make the amorphous ITO film structuring the counter electrode 32, the gate terminal pad 34, and the source terminal pad 35, and the upper most layer light shielding film 33 polycrystalline. Note that the substrate temperature is not limited to 150° C., and in the case of a typical amorphous ITO film having a mixture ratio in which indium oxide (In₂O₃) is not less than 85 wt % and not more than 95 wt %, and tin oxide (SnO₂) is not less than 5 wt % and not more than 15 wt % (total thereof is 100 wt %), not less than 140° C. enables crystallization. In contrast, on the high temperature side, temperature can be arbitrarily determined depending on the heatproof temperature of a material or the like used for the layer and the pattern formed on the TFT substrate. For example, in the embodiment, since an organic resin film of acrylic is used as the third insulating film, not more than 230° C. that is the heatproof temperature of the material is preferable, but, for example, in the case of using a typical photosensitivity resin of novolak series for the photoresist material, not more than 160° C. is preferable.

Next, by oxygen ashing, the film thickness of the photoresist pattern is totally reduced to completely remove the photoresist pattern whose film thickness is thin. In contrast, the photoresist pattern whose film thickness is thick is made thin to be left.

Next, the sixth conductive film is subjected to etching again by using a wet etching method using PAN chemical solution using the remaining photoresist pattern as a mask. In this context, since the ITO film that is a transparent conductive film that is the lower layer is poly crystallized, so that the ITO film is chemically very stable, making it possible to etch the Al alloy film that is not covered with a photoresist pattern, for example, the Al alloy film on the counter electrode 32 and the Al alloy film of the gate terminal portion and the source terminal portion without suffering etching damage practically with respect to PAN chemical solution (disappearance of film or deterioration of electrical properties or optical properties).

Then, by removing the photoresist pattern, as illustrated in FIG. 69 and FIG. 70, a TFT substrate 402 can be obtained in which the upper most layer light shielding films 33 and 33b covering the channel region in plan view are formed above the channel region of the TFT portion.

In the TFT substrate 402, the upper portion in plan view of the semiconductor channel layer 7 is configured such that light is perfectly shielded by the light shielding films of the three layers including the upper most layer light shielding films 33 and 33b in addition to the lower layer light shielding films 9a, 9b, 9c and the upper layer light shielding films 22b, 23b, making it possible to further suppress deterioration (optical deterioration) of the channel layer due to absorption of backlight light during operation of the liquid crystal display device and external light.

### Fifth Embodiment

Also in the case of a liquid crystal display device of FFS mode, like the liquid crystal display device of TN mode in the third embodiment, it is also possible that the channel region lower layer light shielding film is directly connected to the drain electrode and the pixel electrode to make electric potential of the pixel electrode be applied to the lower layer light shielding film.

Configuration of Pixel of TFT Substrate

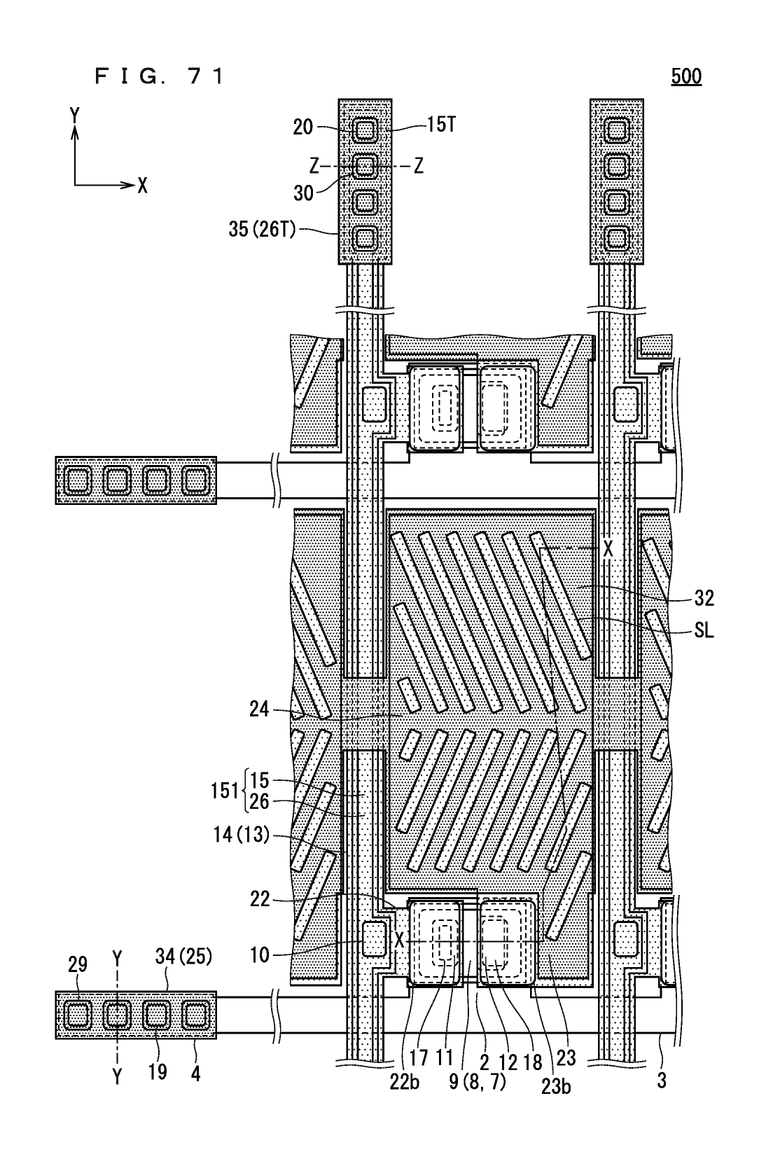

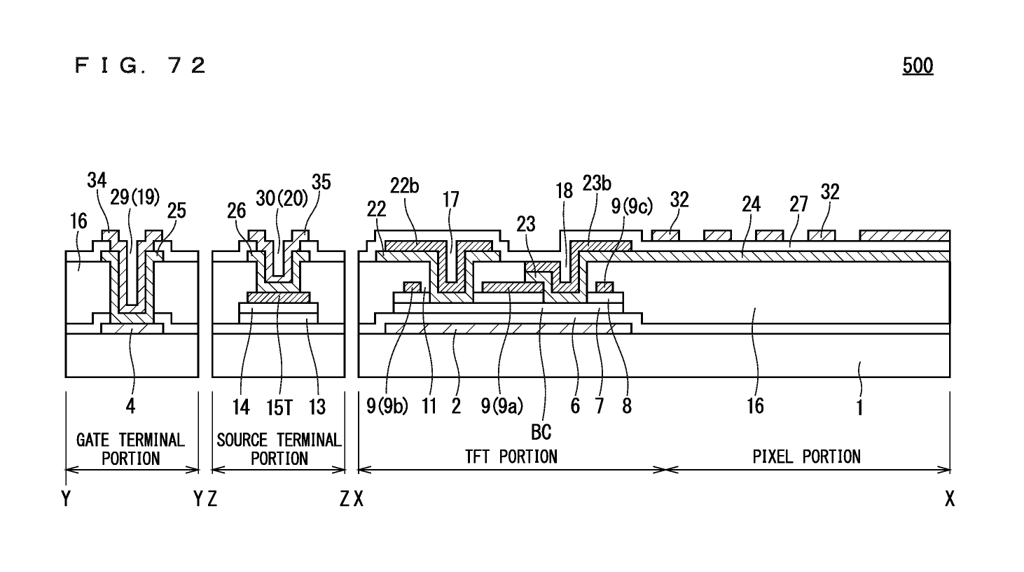

First, with reference to FIG. 71 and FIG. 72, a configuration of a TFT substrate 500 according to a fifth embodiment will be described. Note that, the same reference numerals are given to the same components as those in the TFT substrate 400 described by using FIG. 43 and FIG. 44, and the overlapping description will be omitted.

FIG. 71 is a plan view illustrating a planar configuration of a pixel according to the fifth embodiment, and FIG. 72 is a cross sectional view illustrating a cross sectional configuration taken along the line X-X (cross sectional configuration of TFT portion and cross sectional configuration of pixel portion), a cross sectional configuration taken along the line Y-Y (cross sectional configuration of gate terminal portion), and a cross sectional configuration taken along the line Z-Z (cross sectional configuration of source terminal portion) in FIG. 71. Note that, in the following description, the TFT substrate 500 shall be used for a liquid crystal display device of FFS mode of light transmission type.

As illustrated in FIG. 71, in the TFT substrate 500, a gate electrode 2 of the TFT is configured by a portion of a gate wiring 3. That is, a portion brunched from the gate wiring 3 to extend to a formation region of the TFT (TFT portion) forms the gate electrode 2. In the embodiment, the depth and the width of the portion to be the gate electrode 2 is made wider than the width of the gate wiring 3 so as to be a size that enables a source electrode 22 and a drain electrode 23 to be arranged above the gate electrode 2.

One end of the gate wiring 3 is electrically connected to a gate terminal 4, and a gate terminal extraction electrode 25 is connected to the gate terminal 4 via a first gate terminal portion contact hole 19. Then, to the gate terminal extraction electrode 25, a gate terminal pad 34 on the upper side is connected via a second gate terminal portion contact hole 29. Note that as the gate wiring 3 and the gate terminal 4, as described below, a first conductive film made of a metal or an alloy having light shielding properties, for example, a metal such as molybdenum (Mo), and aluminum (Al), or an alloy obtained by adding another element to the metal is used.

As illustrated in FIG. 71, the gate wiring 3 is arranged to extend in the lateral direction (X direction), and a source wiring 151 is arranged to extend in the vertical direction (Y direction). Note that the source wiring 151 is configured by a lower layer source wiring 15 and an upper layer source wiring 26.

Furthermore, one end of the lower layer source wiring 15 is connected to a source terminal 15T, and a source terminal extraction electrode 26T is connected to the source terminal 15T via a first source terminal portion contact hole 20. Then, to the source extraction electrode 26T, a source terminal pad 35 on the upper side is connected via a second source terminal portion contact hole 30.

Making the upper layer source wiring 26 extending from the source electrode 22 be connected to the lower layer source wiring 15 via a first source wiring contact hole 10 makes the source electrode 22 be electrically connected to the lower layer source wiring 15. Furthermore, the drain electrode 23 extends to a pixel region to form a transmissive pixel electrode 24. Furthermore, upper layer light shielding films 22b and 23b are respectively provided on the regions of the source electrode 22 and the drain electrode 23.

Note that the region surrounded by the adjacent gate wirings 3 and the adjacent lower layer source wirings 15 becomes a pixel region, so that in the TFT substrate 500, pixel regions are arranged in a matrix manner.

Next, a cross sectional configuration of the TFT substrate 500 will be described using FIG. 72. As illustrated in FIG. 72, the TFT substrate 500 includes a substrate 1 that is a transparent insulating substrate such as a glass as its base material, and the gate electrode 2 (including gate wiring 3), and the gate terminal 4 are arranged on the substrate 1.

Then, an insulating film 6 (first insulating film) is arranged to cover the gate electrode 2 and the gate terminal 4. The insulating film 6 functions as a gate insulating film at the TFT portion, so that the insulating film 6 is referred to as a gate insulating film 6 in some cases.

In the TFT portion, an oxide semiconductor film 7 is arranged on the insulating film 6 at the position overlapping with the gate electrode 2. The oxide semiconductor film 7 functions as a channel layer of the TFT, so that the oxide semiconductor film 7 is referred to as a semiconductor channel layer 7 in some cases. Note that, in the embodiment, the planer pattern of the semiconductor channel layer 7 is made smaller than the planer pattern of the gate electrode 2 in plan view, so that the outline of the semiconductor channel layer 7 exists inside the outline of the gate electrode 2. Note that the material of the semiconductor channel layer 7 is the same as that described in the first embodiment, making it possible to increase mobility as compared with a conventional configuration in which amorphous silicon is used for the semiconductor channel layer.

A protective insulating film 8 (second insulating film) is arranged on the semiconductor channel layer 7, and a channel region lower layer light shielding film 9 (second conductive film) formed of a metal film having light shielding properties or the like is arranged on the protective insulating film 8.

In the embodiment, as the channel region lower layer light shielding film 9, for example, a metal such as molybdenum (Mo) and aluminum (Al), or an alloy obtained by adding another element to the metal is used. Then, a first source electrode contact hole 11 and a first drain electrode contact hole 12 are provided in the channel region lower layer light shielding film 9 above the semiconductor channel layer 7. Note that the channel region lower layer light shielding film 9 is referred to as a lower layer light shielding film 9a, 9b, or 9c in some cases depending on its arranged position for descriptive purposes.

Furthermore, in the source terminal portion, an oxide semiconductor film 13 in the same layer as the semiconductor channel layer 7 of the TFT portion is provided, and an insulating film 14 in the layer the same as the protective insulating film 8 is provided on the oxide semiconductor film 13. Then, the source terminal 15T (including lower layer source wiring 15) in the same layer as the channel region lower layer light shielding film 9 (second conductive film) is provided on the insulating film 14, so that the source terminal 15T is the upper most layer film of the laminate of the three layers. Furthermore, in the gate terminal portion, the insulating film 6 is formed to cover the gate terminal 4 (including gate wiring 3).

Then, an interlayer insulating film 16 (third insulating film) is arranged above the entire surface of the substrate 1 to cover the insulating film 6, the semiconductor channel layer 7, the protective insulating film 8, and the channel region lower layer light shielding film 9. Then, in the TFT portion, a second source electrode contact hole 17 and a second drain electrode contact hole 18 penetrating the interlayer insulating film 16 and the protective insulating film 8 to reach the semiconductor channel layer 7 are provided. The second source electrode contact hole 17 is arranged to be located inside the outer circumference of the first source electrode contact hole 11 in plan view, and is formed such that a surface of the semiconductor channel layer 7 is exposed at its bottom surface. Furthermore, the second drain electrode contact hole 18 is arranged such that at least a portion thereof is located outside the outer circumference of the first drain electrode contact hole 12 in plan view, and is formed such that both of the surface of the semiconductor channel layer 7 and the surface of at least a portion of the region of the channel region lower layer light shielding film 9 (region of the lower layer light shielding film 9a in the embodiment) are exposed.

Then, the source electrode 22 and the drain electrode 23 formed as a third conductive film are arranged so as to be separated from each other and directly connected to the semiconductor channel layer 7 via the second source electrode contact hole 17 and the second drain electrode contact hole 18, respectively. The region between the source electrode 22 and the drain electrode 23 in the semiconductor channel layer 7 forms a channel region BC. Note that the drain electrode 23 is connected to the semiconductor channel layer 7 and also directly connected to the lower layer light shielding film 9a.

The upper layer light shielding films 22b and 23b (fourth conductive film) are respectively provided on the source electrode 22 and the drain electrode 23. When the upper layer light shielding films 22b and 23b are formed by, for example, a metal film having light shielding properties, the upper layer light shielding films 22b and 23b are formed so as to be separated from each other to prevent electrical short circuit between the source electrode 22 and the drain electrode 23. In the embodiment, as the upper layer light shielding films 22b, 23b, a metal such as molybdenum (Mo) and aluminum (Al), or an alloy obtained by adding another element to the metal can be used.

As illustrated in FIG. 71, the upper region of the semiconductor channel layer 7 of the TFT portion is configured such that light from an upper surface is shielded in its entire region in plan view by the upper layer light shielding films 22b, 23b, and the lower layer light shielding films 9a, 9b, 9c. Furthermore, the lower region of the semiconductor channel layer 7 of the TFT portion is configured such that light from a lower surface (surface on the side of the substrate 1) is shielded in its entire region in plan view by the gate electrode 2. Forming the TFT portion in this manner makes it possible to almost perfectly prevent backlight light, external light, and scattering light thereof from being incident on the semiconductor channel layer 7 (light shielding), making it possible to prevent property degradation of the semiconductor channel layer 7 due to light absorption.

Then, an interlayer insulating film 27 (fourth insulating film) is formed on the whole of the substrate 1 to cover the source electrode 22, the drain electrode 23, the transmissive pixel electrode 24, and the upper layer light shielding films 22b, 23b, and a counter electrode 32 (fifth conductive film) is provided on the interlayer insulating film 27. The counter electrode 32 is, as illustrated in FIG. 71, arranged to overlap with the transmissive pixel electrode 24 on the lower side in plan view. In the embodiment, the counter electrodes 32 are formed in a consecutive shape to stride between pixels adjacent in the lateral direction (X direction), and are configured such that a constant common electric potential is supplied to the counter electrode 32 at a peripheral portion (not shown) of the display region.

Furthermore, slit opening portions SL are provided in the counter electrode 32, and applying a voltage between the transmissive pixel electrode 24 and the counter electrode 32 makes it possible to generate between with the transmissive pixel electrode 24 an electric filed in substantially lateral direction with respect to the main surface of the substrate 1 above the counter electrode 32. Note that although the configuration in which slit shaped opening portions are formed in the counter electrode 32 is illustrated in the embodiment, it is also preferable that an opening portion may be formed having a comb-tooth shape in which one ends of a plurality of slits are jointed.

Furthermore, in the source terminal portion, the source extraction electrode 26T is provided to be directly connected to the source terminal 15T via the first source terminal portion contact hole 20 penetrating the interlayer insulating film 16 to reach the source terminal 15T. Then, then, to the source extraction electrode 26T, the source terminal pad 35 on the upper side is connected to overlap in plan view via the second source terminal portion contact hole 30 penetrating the interlayer insulating film 27.

Furthermore, in the gate terminal portion, the gate terminal extraction electrode 25 is provided to be directly connected to the gate terminal 4 via the first gate terminal portion contact hole 19 penetrating the interlayer insulating film 16 and the insulating film 6 to reach the gate terminal. Then, to the gate terminal extraction electrode 25, the gate terminal pad 34 on the upper side is connected to overlap in plan view via the second gate terminal portion contact hole 29 penetrating the interlayer insulating film 27.

Note that, the source extraction electrode 26T and the gate terminal extraction electrode 25 are formed by the third conductive film in the same layer as the source electrode 22 and the drain electrode 23 of the TFT portion. Furthermore, the source terminal pad 35 and the gate terminal pad 34 are formed by the fifth conductive film in the same layer as the counter electrode 32 of the TFT portion.

Manufacturing Method

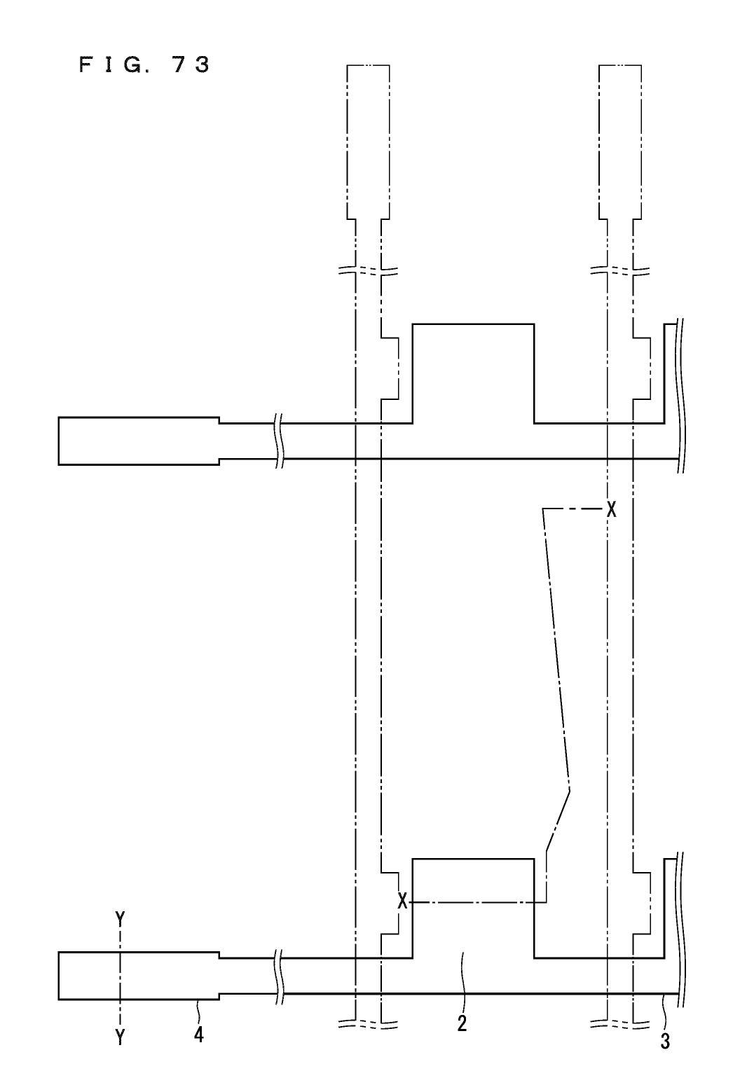

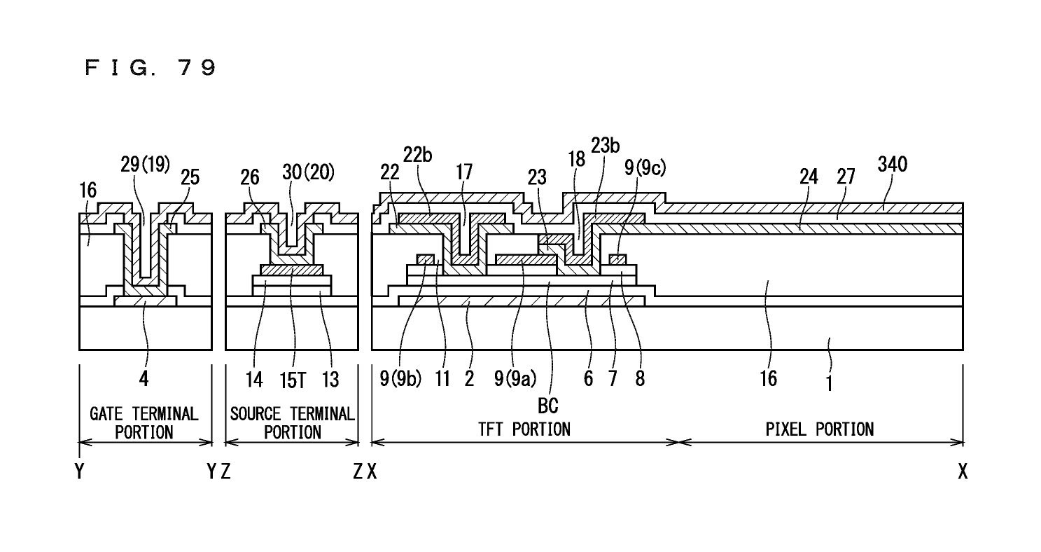

Hereinafter, a manufacturing method of the TFT substrate 500 according to the fifth embodiment will be described using FIG. 73 to FIG. 79. Note that, a planer view and a cross sectional view respectively illustrating the final step correspond to FIG. 71 and FIG. 72.

First, the substrate 1 that is a transparent insulating substrate such as a glass is washed using cleaning liquid or pure water. In the embodiment, a glass substrate having a thickness of 0.6 mm is used as the substrate 1. Then, the first conductive film that is the material of the gate electrode 2, the gate wiring 3, and the like is formed on one of the entire main surfaces of the substrate 1 that has been washed. The material capable of being used as the first conductive film is described in the first embodiment, so that overlapping description will be omitted. In the embodiment, an aluminum (Al) alloy film shall be used as the first conductive film, and the Al alloy film is formed to have a thickness of 200 nm by a sputtering method using argon (Ar) gas.

First Photolithography Step

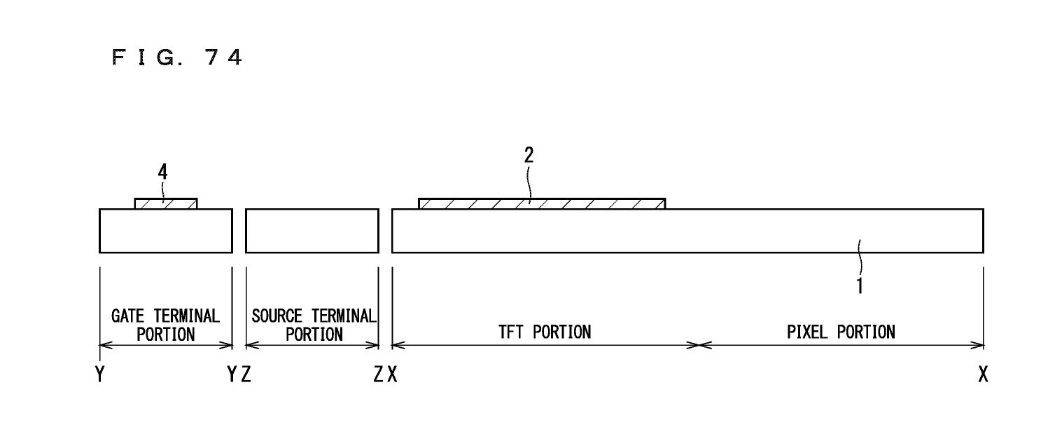

Then, a photoresist material is applied on the first conductive film, a photoresist pattern is formed in a first photolithography step, and the first conductive film is subjected to patterning by etching using the photoresist pattern as a mask. Herein, a wet etching using PAN chemical solution is used. Then, by removing the photoresist pattern, as illustrated in FIG. 73 and FIG. 74, the gate electrode 2, the gate wiring 3 (not shown in FIG. 74), and the gate terminal 4 are formed on the upper main surface of the substrate 1.

Second Photolithography Step

Next, after forming the insulating film 6 (first insulating film) on the entire upper main surface of the substrate 1 to cover the gate electrode 2, the gate wiring 3, and the gate terminal 4, the oxide semiconductor film, the second insulating film, and the second conductive film are laminated in this order on the insulating film 6 to form a photoresist pattern having different thicknesses by an exposure (half exposure) using a half exposure mask in a second photolithography step, and using the photoresist pattern, by patterning the oxide semiconductor film, the second insulating film, and the second conductive film by etching, as illustrated in FIG. 37 and FIG. 38 of the third embodiment, in the TFT portion, the laminate of the semiconductor channel layer 7, the protective insulating film 8, and the channel region lower layer light shielding film 9 are obtained above the gate electrode 2, and the first source electrode contact hole 11 and the first drain electrode contact hole 12 are formed in the channel region lower layer light shielding film 9. Herein, the outline of the semiconductor channel layer 7 in plan view is arranged to exist inside the outline of the gate electrode 2.

Furthermore, for descriptive purposes, the channel region lower layer light shielding film 9 that remains between the first source electrode contact hole 11 and the first drain electrode contact hole 12 is referred to as the lower layer light shielding film 9a, the channel region lower layer light shielding film 9 that remains on the side opposite to the lower layer light shielding film 9a of the first source electrode contact hole 11 is referred to as the lower layer light shielding film 9b, and the channel region lower layer light shielding film 9 that remains on the side opposite to the lower layer light shielding film 9a of the first drain electrode contact hole 12 is referred to as the lower layer light shielding film 9c.

Furthermore, in a source wiring formation region, a laminate of the oxide semiconductor film 13, the insulating film 14, and the lower layer source wiring 15 is formed, and in a source terminal formation region, a laminate of the oxide semiconductor film 13, the insulating film 14 and the source terminal 15T is formed by the same process as the above process.

Note that, as for the material and forming method of the insulating film 6, the oxide semiconductor film, the second insulating film, and the second conductive film, and the etching using a photoresist pattern formed by a half exposure, description is made using FIG. 19 to FIG. 22 in the second embodiment, so that the description will be omitted.

Next, the interlayer insulating film 16 (third insulating film) is formed above the entire upper main surface of the substrate 1. In the embodiment, a resin series insulating film is formed by an organic resin material. Specifically, for example, an organic resin material of an acrylic having photosensitivity is applied on the substrate 1 to have a thickness of 2.0 to 3.0 μm by a spin coat method as the interlayer insulating film 16.

Third Photolithography Step

Next, the interlayer insulating film 16 is exposed and developed in a third photolithography step, and as illustrated in FIG. 39 and FIG. 40 of the third embodiment, the first source wiring contact hole 10 (not shown in FIG. 40), the second source electrode contact hole 17, the second drain electrode contact hole 18, the first gate terminal portion contact hole 19, and the first source terminal portion contact hole 20 penetrating the interlayer insulating film 16 are formed.

Then, the protective insulating film 8 exposed at the bottom portions of the second source electrode contact hole 17 and the second drain electrode contact hole 18 are subjected to etching. For the etching, a dry etching method using a gas including fluorine can be used.

In the embodiment, dry etching is performed by using a gas in which oxygen (O₂) is added to sulfur hexafluoride (SF₆). Adding O₂ gas makes it possible to suppress that the oxide semiconductor film 7 below the protective insulating film 8 is damaged by reduction reaction during etching. By the etching, as illustrated in FIG. 39 and FIG. 40, the semiconductor channel layer 7 is exposed at the bottom surface of the second source electrode contact hole 17. Furthermore, the semiconductor channel layer 7 and a portion of the channel region lower layer light shielding film 9 (lower layer light shielding film 9a in the embodiment) are exposed at the bottom surface of the second drain electrode contact hole 18.

Furthermore, although the gate terminal 4 of an Al alloy is exposed at the bottom surface of the first gate terminal portion contact hole 19 and the lower layer source wiring 15 and the source terminal 15T that are made of an Al alloy are respectively exposed at the bottom surfaces of the first source wiring contact hole 10 and the first source terminal portion contact hole 20, the Al alloy is not subjected to etching by a dry etching using a gas in which oxygen (O₂) is added to sulfur hexafluoride (SF₆), so that the patterns remain as they are.

Note that, as a material of the resin series insulating film used for the interlayer insulating film 16, besides an acrylic organic resin material, an olefin series material, a novolac series material, a polyimide series material, and a siloxane series material can be also used. Such coating type organic insulating materials have low dielectric constant and is easy to be formed into a thick film having a thickness of not less than 2.0 μm, making it possible to suppress wiring capacity to a low capacity. Thus, using such materials makes it possible to drive the TFT substrate at a low voltage, making it possible to contribute to reducing power consumption. This makes it possible to make the transmissive pixel electrode 24 be arranged on the gate wiring or the source wiring to overlap, also making it possible to make aperture ratio high.

Furthermore, for the interlayer insulating film 16, instead of the resin series insulating film material, an inorganic series insulating material such as silicon nitride (SiN) and silicon oxide (SiO) can be also used. When such an inorganic series insulating material is used, the first source wiring contact hole 10, the second source electrode contact hole 17, the second drain electrode contact hole 18, the first gate terminal portion contact hole 19, and the first source terminal portion contact hole 20 are formed using a photoresist pattern as a mask. Alternatively, an inorganic series insulating film material and a resin series insulating film material may be appropriately combined to be used.

Next, the third conductive film and the fourth conductive film are laminated in this order on the entire surface of the interlayer insulating film 16. In the embodiment, a transparent conductive film (translucent conductive film) is used as the third conductive film. As the transparent conductive film, ITO (in which mix ratio of indium oxide (In₂O₃) and tin oxide (SnO₂) is, for example, 90:10 (mass percent)) is used. Herein, by a spattering method, an ITO film having a thickness of 100 nm is formed in amorphous state by using a gas in which a gas including hydrogen (H), for example, hydrogen (H₂) gas, moisture (H₂O), or the like is mixed with argon (Ar). Furthermore, an Al alloy film having light shielding properties is used as the fourth conductive film. Herein, an Al alloy film having a thickness of 100 nm is formed by a spattering method using Ar gas.

Fourth Photolithography Step

Next, a photoresist material is applied on the entire surface of the fourth conductive film (Al alloy film), a photoresist pattern is formed by a fourth photolithography step, and the Al alloy film and the amorphous ITO film are sequentially subjected to etching using the photoresist pattern as a mask.

Herein, by performing a half exposure using a half exposure mask, a photoresist pattern having different thicknesses is formed. That is, portions for leaving the fourth conductive film to form the patterns of the upper layer light shielding films 22b and 23b are made thick in their film thicknesses. Note that the fourth conductive film is subjected to etching by two steps, and the film thickness of the photoresist pattern at the portion removed by the second etching is made thin. For example, the film thickness is made thin on the region in which the transmissive pixel electrode 24 is formed so that the fourth conductive film on the region in which the transmissive pixel electrode 24 is formed is not removed in the first etching. Furthermore, the film thickness of the photoresist pattern is made thin also at the gate terminal portion and the source terminal portion.

Then, the fourth conductive film is subjected to patterning by etching using the photoresist pattern as a mask to remove the fourth conductive film at the portion that is not covered with the photoresist pattern. In the etching of the fourth conductive film, a wet etching using PAN chemical solution is used.

Subsequently, the third conductive film is subjected to patterning by etching using the same photoresist pattern as a mask to remove the third conductive film at the portion that is not covered with the photoresist pattern and the fourth conductive film. In the etching of the third conductive film (amorphous ITO film), a wet etching is used using oxalic acid series chemical solution of oxalic acid 5 wt %+water.

Then, the whole of the substrate 1 is heated to 150° C. This heating makes the amorphous ITO film be crystallized to become a polycrystalline ITO film. The substrate temperature is not limited to 150° C., and in the case of a typical amorphous ITO film having a mixture ratio in which indium oxide (In₂O₃) is not less than 85 wt % and not more than 95 wt %, and tin oxide (SnO₂) is not less than 5 wt % and not more than 15 wt % (total thereof is 100 wt %), not less than 140° C. enables crystallization. Furthermore, the temperature on the high-temperature side may be optionally determined depending on the heatproof temperature of the photoresist material or the like to be used. For example, in the embodiment, since an organic resin film of acrylic is used as the interlayer insulating film 16 (third insulating film), not more than 230° C. that is the heatproof temperature of the material is preferable, but, for example, in the case of using a typical photosensitivity resin of novolak series as the photoresist material, not more than 160° C. is preferable.

Next, by oxygen ashing, the film thickness of the photoresist pattern is totally reduced to completely remove the photoresist pattern whose film thickness is thin. In contrast, the photoresist pattern whose film thickness is thick is made thin to be left.

Next, the fourth conductive film is subjected to etching again by using a wet etching method using PAN chemical solution using the remaining photoresist pattern as a mask. In this context, since the ITO film that is the transparent conductive film that is the lower layer is poly crystallized, so that the ITO film is chemically very stable, making it possible to etch the Al alloy film that is not covered with a photoresist pattern, for example, the Al alloy film on the region in which the transmissive pixel electrode 24 is formed, and the Al alloy film of the gate terminal portion and the source terminal portion without suffering etching damage practically with respect to PAN chemical solution (disappearance of film or deterioration of electrical properties or optical properties).

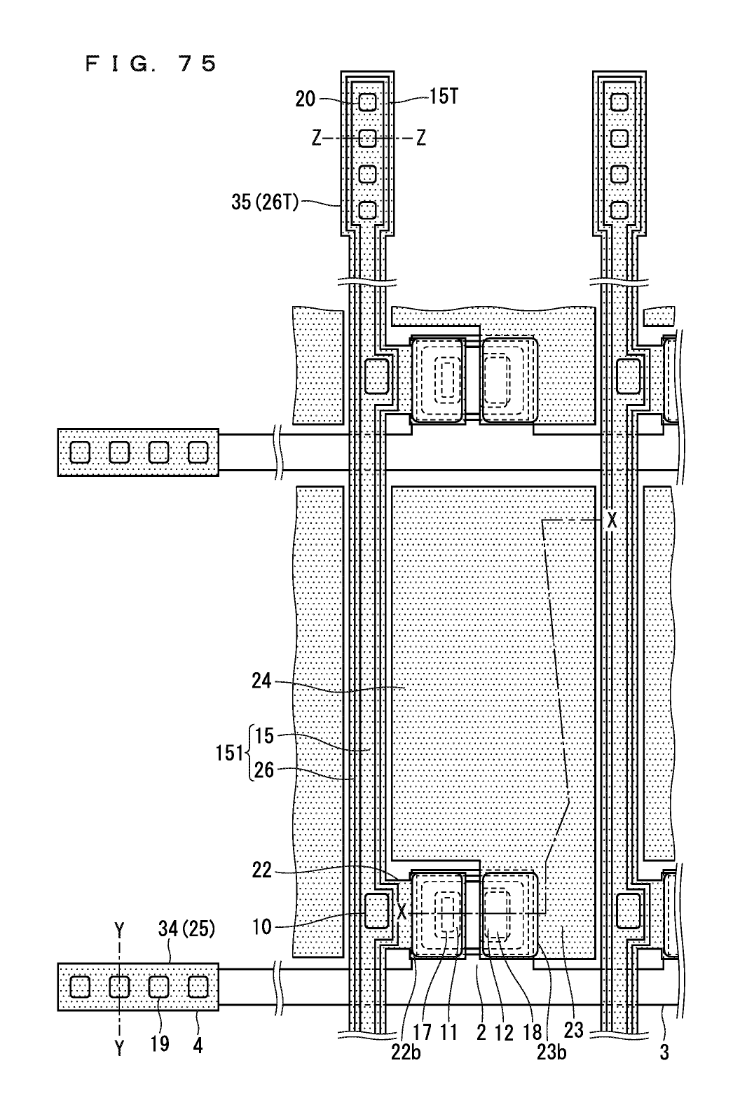

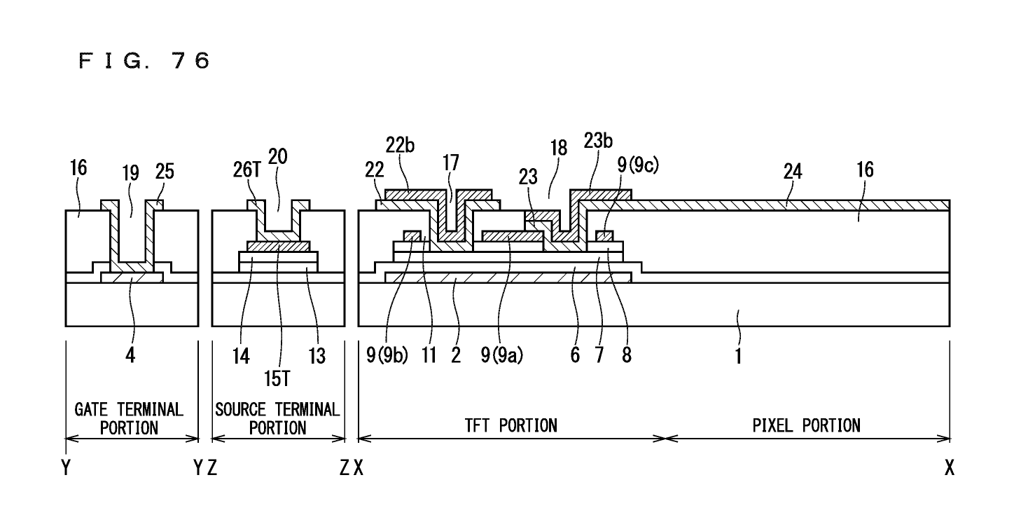

Then, by removing the photoresist pattern, as illustrated in FIG. 75 and FIG. 76, the gate terminal extraction electrode 25, the source electrode 22, the upper layer source wiring 26 extending from the source electrode 22, the source terminal extraction electrode 26T, the drain electrode 23, and the transmissive pixel electrode 24 extending from the drain electrode 23 configured by the transparent conductive film (polycrystalline ITO film) are formed. Furthermore, the upper layer light shielding films 22b and 23h are respectively formed on the upper portion of the source electrode 22 and the upper portion of the drain electrode 23 of the TFT portion. The upper layer light shielding films 22b and 23b are formed to cover substantially the whole of the planer pattern of the semiconductor channel layer 7 excluding the channel region BC in plan view.

Herein, the gate terminal extraction electrode 25 is directly connected to the gate terminal 4 via the first gate terminal portion contact hole 19. Furthermore, the source electrode 22 is directly connected to the semiconductor channel layer 7 via the second source electrode contact hole 17. Furthermore, the upper layer source wiring 26 is directly connected to the lower layer source wiring 15 via the first source wiring contact hole 10. Furthermore, the source wiring extraction electrode 26T is directly connected to the source terminal 15T via the first source terminal portion contact hole 20.

Next, the interlayer insulating film 27 (fourth insulating film) is formed above the entire upper main surface of the substrate 1. In the embodiment, a silicon nitride film (SiN) having a thickness of 400 nm is formed using a CVD method.

Fifth Photolithography Step

Next, a photoresist material is applied on the entire surface of the interlayer insulating film 27 (SiN film), a photoresist pattern is formed by a fifth photolithography step, and the interlayer insulating film 27 is subjected to etching using the photoresist pattern as a mask.

For the etching, a dry etching method using a gas including fluorine can be used. In the embodiment, dry etching is performed by using a gas in which oxygen (O₂) is added to sulfur hexafluoride (SF₆).

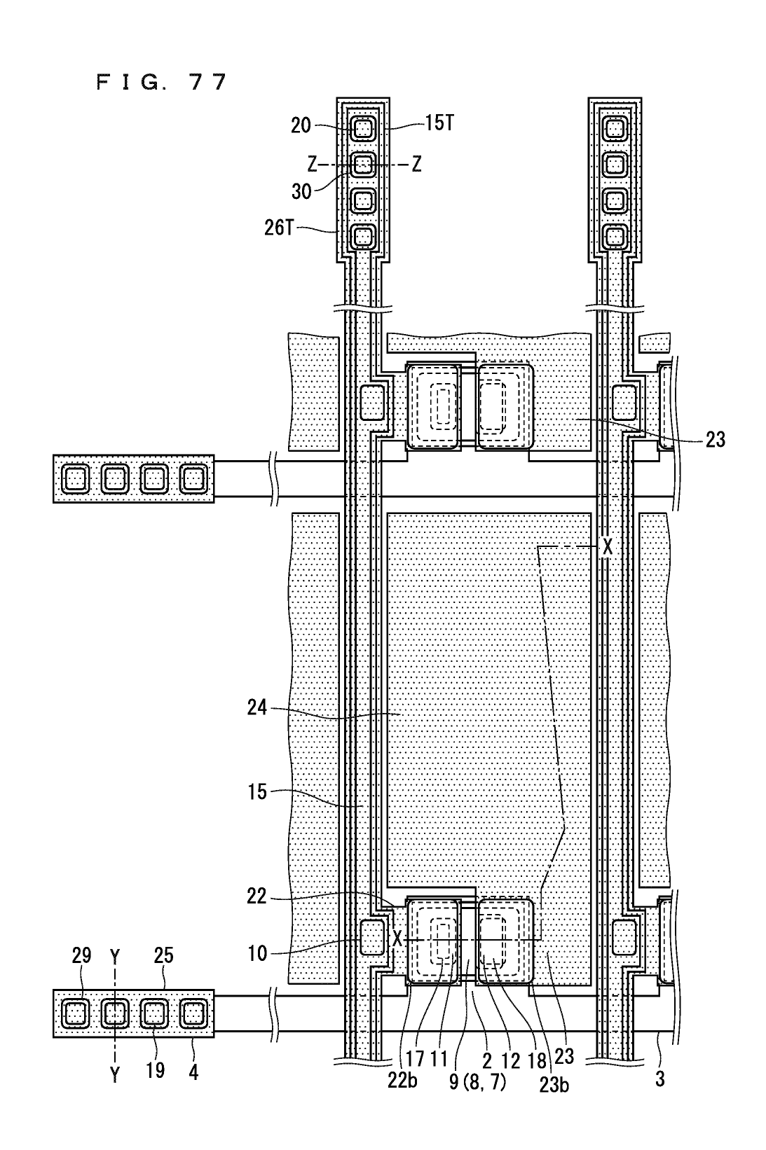

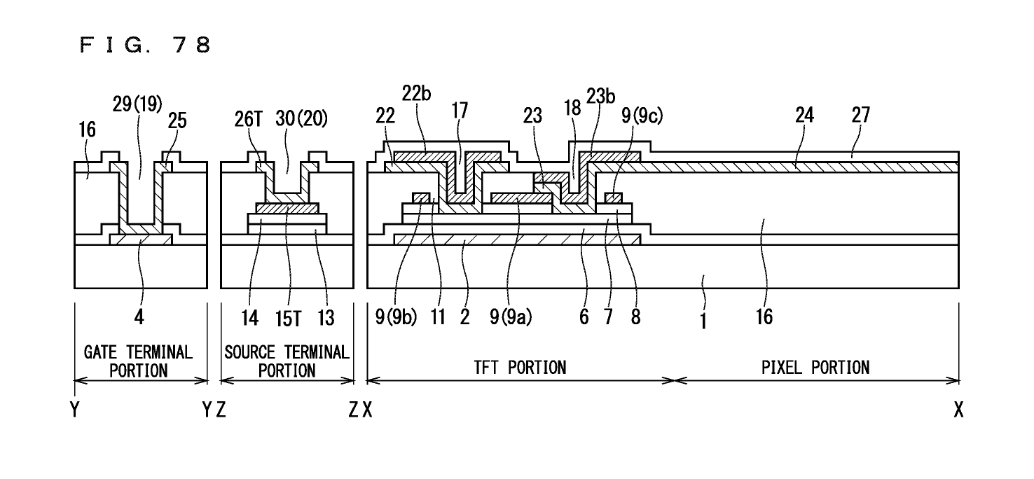

Then, by removing the photoresist pattern, as illustrated in FIG. 77 and FIG. 78, the interlayer insulating film 27 above the gate terminal extraction electrode 25 and the source wiring extraction electrode 26T is removed, and the second gate terminal portion contact hole 29 and the second source terminal portion contact hole 30 are respectively formed.

Then, the fifth conductive film 340 that is the material of the counter electrode 32 is formed on the entire upper surface of the interlayer insulating film 27 including the inside of the second gate terminal portion contact hole 29 and the inside of the second source terminal portion contact hole 30. In the embodiment, as the fifth conductive film, an amorphous ITO film having a thickness of 100 nm the same as the transparent conductive film that is the third conductive film is formed by a spattering method.

Sixth Photolithography Step

Next, a photoresist material is applied on the entire surface of the fifth conductive film 340 (amorphous ITO film), a photoresist pattern is formed by a sixth photolithography step, and the fifth conductive film 340 is subjected to etching using the photoresist pattern as a mask. In this etching, a wet etching method can be used using oxalic acid series chemical solution of oxalic acid 5 wt %+water.

Then, by removing the photoresist pattern, as illustrated in FIG. 71 and FIG. 72, the counter electrode 32 having slit opening portions, the gate terminal pad 34, and the source terminal pad 35 configured by an amorphous ITO film that is a transparent conductive film are formed. The gate terminal pad 34 is directly connected to the gate terminal extraction electrode 25 on the lower side via the second gate terminal portion contact hole 29. Furthermore, the source terminal pad 35 is directly connected to the source terminal extraction electrode 26T on the lower side via the second source terminal portion contact hole 30.

Then, the whole of the substrate 1 is heated at 200° C. to make the amorphous ITO film structuring the counter electrode 32, the gate terminal pad 34, and the source terminal pad 35 polycrystalline to complete the TFT substrate 500 illustrated in FIG. 71 and FIG. 72.

Note that upon assembling a liquid crystal display panel, an alignment film and a spacer are formed on a surface of the completed TFT substrate 500. The alignment film is a film for aligning liquid crystal, and is configured by polyimide or the like. Furthermore, a separately manufactured counter substrate equipped with a color filter, a counter electrode, an alignment film, and the like are bonded together with the TFT substrate 500. In this context, a gap is formed between the TFT substrate and the counter substrate by the spacer, and by enclosing liquid crystal in the gap, a liquid crystal display panel of FFS mode of light transmission type of lateral electric field method is formed. Finally, a liquid crystal display device is completed by arranging a light polarizing plate, a phase difference plate, a driving circuit, a backlight unit, and the like on an external side of the liquid crystal display panel.

As described above, the fifth embodiment makes it possible to manufacture the TFT substrate 500 used for a liquid crystal display device of FFS mode of etch stopper type using a high performance oxide semiconductor film as its channel layer with six photolithography steps. Specifically, the protective insulating film 8 that becomes an etch stopper is subsequently formed after forming the oxide semiconductor film, so that the semiconductor channel layer 7 is almost prevented from being deteriorated in its properties due to process damage of the subsequent TFT manufacturing step. This makes it possible to use the semiconductor channel layer 7 as the channel layer of the TFT in the state where high performance properties of the oxide semiconductor are kept.

Furthermore, the source wiring 151 has a two-layered structure of the lower layer source wiring 15 and the upper layer source wiring 26 that are independently formed via the interlayer insulating film, which is so called a redundant wiring. Furthermore, the upper layer source wiring 26 is directly connected to the lower layer source wiring 15 via a plurality of the first source wiring contact holes 10 provided in the interlayer insulating film 16, making it possible to complement the function by the other wiring even when one of the wirings is disconnected. This makes it possible to reduce generation of linear defect due to disconnection of the source wiring 151 to improve yield ratio during manufacturing and reliability of the product.

Furthermore, the lower layer source wiring 15 is consecutively formed with the oxide semiconductor film and the insulating film, making it possible to form the lower layer source wiring 15 (second conductive film) with good adhesiveness, making it possible to reduce generation of disconnection defect due to peeling off of film caused by lack of sticking force. This effect is specifically large at a step portion on the gate wiring pattern in the region in which the gate wiring 3 and the lower layer source wiring 15 intersect.

Furthermore, the semiconductor channel layer 7 is configured such that light is shielded in its entire region by the light shielding films of two layers also on the upper side of the semiconductor channel layer 7 in addition to light shielding by the gate electrode 2 on the lower side of the semiconductor channel layer 7, making it possible to prevent deterioration (optical deterioration) of the channel layer due to absorption of backlight light during operating the liquid crystal display device and external light.

Furthermore, using a resin series insulating film that has low permittivity, that is made thick in its film thickness to be not less than 2.0 μm, and that has a flattening action with respect to the main surface of the substrate 1 as the interlayer insulating film 16 (third insulating film) makes it possible to suppress wiring capacity to a low level. This makes it possible to drive the TFT substrate at a low voltage, making it possible to contribute to reducing power consumption. This makes it possible to make the transmissive pixel electrode 24 be arranged on the gate wiring or the source wiring to overlap, also making it possible to make aperture ratio high.

Furthermore, because the channel region lower layer light shielding film 9 is formed by a conductive film and the drain electrode 23 and the transmissive pixel electrode 24 are made to be directly connected, the electric potential of the transmissive pixel electrode 24 is applied on the channel region BC as bias electric potential. This makes it possible to reduce variation of a threshold voltage (Vth) of the plurality of TFTs structuring display pixels and suppress variation of TFT properties due to unspecified external noise or the like, making it possible to further improve display properties and reliability. Note that the channel region lower layer light shielding film 9 may be directly connected to the source electrode 22 instead of the drain electrode 23.

Formation of Upper Most Layer Light Shielding Film

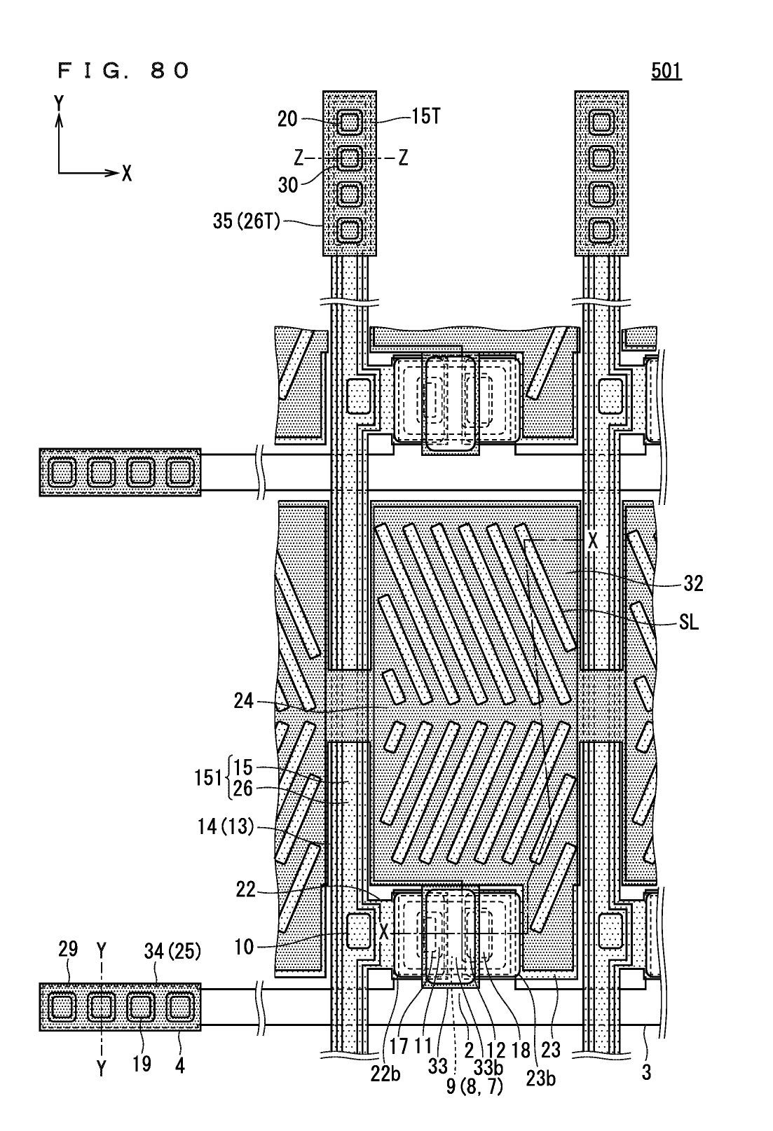

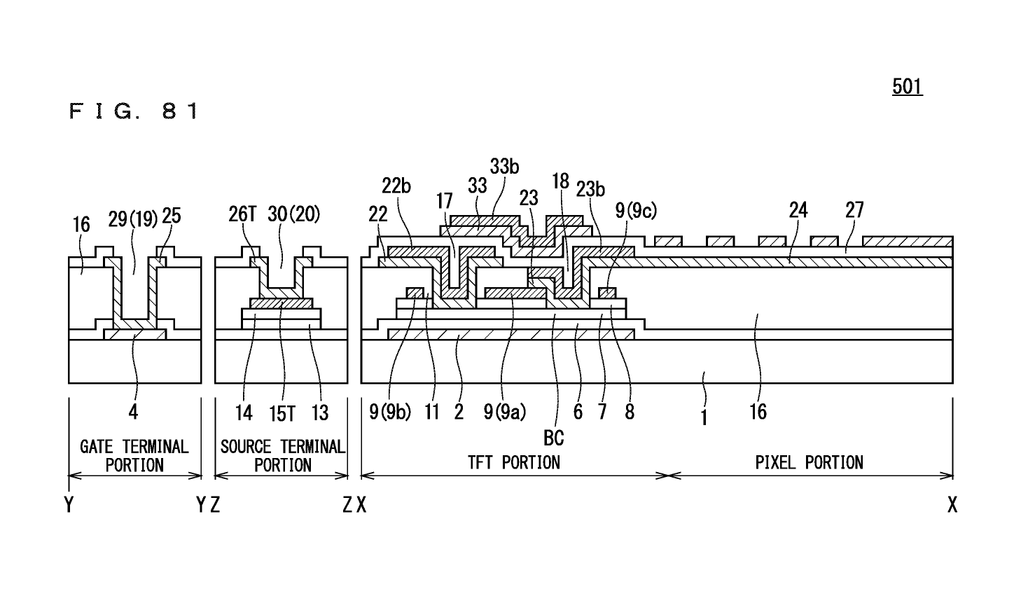

In the above described sixth photolithography step, although the counter electrode 32, the gate terminal pad 34, and the source terminal pad 35 are formed by patterning the fifth conductive film, it is also preferable that an upper most layer light shielding film 33 (lower layer film) and an upper most layer light shielding film 33b (upper layer film) covering the channel region in plan view may be formed above the channel region of the TFT portion as illustrated in FIG. 80 and FIG. 81 by forming a photoresist pattern having different thicknesses by forming a conductive film having light shielding properties (sixth conductive film) on the fifth conductive film and performing a half exposure using a half exposure mask on the laminated film of the fifth conductive film and the sixth conductive film, and by sequentially subjecting the laminated film of the fifth conductive film and the sixth conductive film to etching using the photoresist pattern.

To be more specific, after forming the fifth conductive film (amorphous ITO film) on the entire upper surface of the interlayer insulating film 27, an Al alloy film having light shielding properties is formed as the sixth conductive film to be a laminated film, a photoresist pattern having different thicknesses is formed thereon by a half exposure, and the sixth conductive film (Al alloy film) and the fifth conductive film (amorphous ITO film) are sequentially subjected to etching using the photoresist pattern as a mask to form the counter electrode 32, the gate terminal pad 34, and the source terminal pad 35, and to form the laminated film of the upper most layer light shielding film 33 configured by an ITO film and the upper most layer light shielding film 33b configured by an. Al alloy film above the channel region of the TFT portion.

In this case, in the photoresist pattern having different thicknesses formed by a half exposure, portions for forming the patterns of the upper most layer light shielding films 33 and 33b by leaving the fifth and sixth conductive films are made thick in their film thickness. Note that the sixth conductive film is subjected to etching by two steps, and the portion removed by the second etching is made thin in the film thickness of the photoresist pattern. For example, the film thickness is made thin on the regions in which the counter electrode 32, the gate terminal pad 34, and the source terminal pad 35 are formed, and in the first etching, the sixth conductive film on the region in which these are formed is made to be not removed.

Then, the sixth conductive film is first subjected to patterning by etching using the photoresist pattern as a mask to remove the sixth conductive film at the portion that is not covered with the photoresist pattern. In the etching of the fourth conductive film, a wet etching using PAN chemical solution is used.

Subsequently, the fifth conductive film is subjected to patterning by etching using the same photoresist pattern as a mask to remove the fourth conductive film at the portion that is not covered with the photoresist pattern and the sixth conductive film. In the etching of the fourth conductive film (amorphous ITO), a wet etching is used using oxalic acid series chemical solution of oxalic acid 5 wt %+water.

Then, the whole of the substrate 1 is heated at 150° C. to make the amorphous ITO film structuring the counter electrode 32, the gate terminal pad 34, and the source terminal pad 35, and the upper most layer light shielding film 33 polycrystalline. Note that the substrate temperature is not limited to 150° C., and in the case of a typical amorphous ITO film having a mixture ratio in which indium oxide (In₂O₃) is not less than 85 wt % and not more than 95 wt %, and tin oxide (SnO₂) is not less than 5 wt % and not more than 15 wt % (total thereof is 100 wt %), not less than 140° C. enables crystallization. In contrast, on the high temperature side, temperature can be arbitrarily determined depending on the heatproof temperature of a material or the like used for the layer and the pattern formed on the TFT substrate. For example, in the embodiment, since an organic resin film of acrylic is used as the third insulating film, not more than 230° C. that is the heatproof temperature of the material is preferable, but, for example, in the case of using a typical photosensitivity resin of novolak series for the photoresist material, not more than 160° C. is preferable.

Next, by oxygen ashing, the film thickness of the photoresist pattern is totally reduced to completely remove the photoresist pattern whose film thickness is thin. In contrast, the photoresist pattern whose film thickness is thick is made thin to be left.

Next, the sixth conductive film is subjected to etching again by using a wet etching method using PAN chemical solution using the remaining photoresist pattern as a mask. In this context, since the ITO film that is a transparent conductive film that is the lower layer is poly crystallized, so that the ITO film is chemically very stable, making it possible to etch the Al alloy film that is not covered with a photoresist pattern, for example, the Al alloy film on the counter electrode 32 and the Al alloy film of the gate terminal portion and the source terminal portion without suffering etching damage practically with respect to PAN chemical solution (disappearance of film or deterioration of electrical properties or optical properties).

Then, by removing the photoresist pattern, as illustrated in FIG. 80 and FIG. 81, a TFT substrate 501 can be obtained in which the upper most layer light shielding films 33 and 33b covering the channel region in plan view are formed above the channel region of the TFT portion.

In the TFT substrate 501, the upper portion in plan view of the semiconductor channel layer 7 is configured such that light is perfectly shielded by the light shielding films of the three layers including the upper most layer light shielding films 33 and 33b in addition to the lower layer light shielding films 9a, 9b, 9c and the upper layer light shielding films 22b, 23b, making it possible to further suppress deterioration (optical deterioration) of the channel layer due to absorption of backlight light during operation of the liquid crystal display device and external light.

Modification

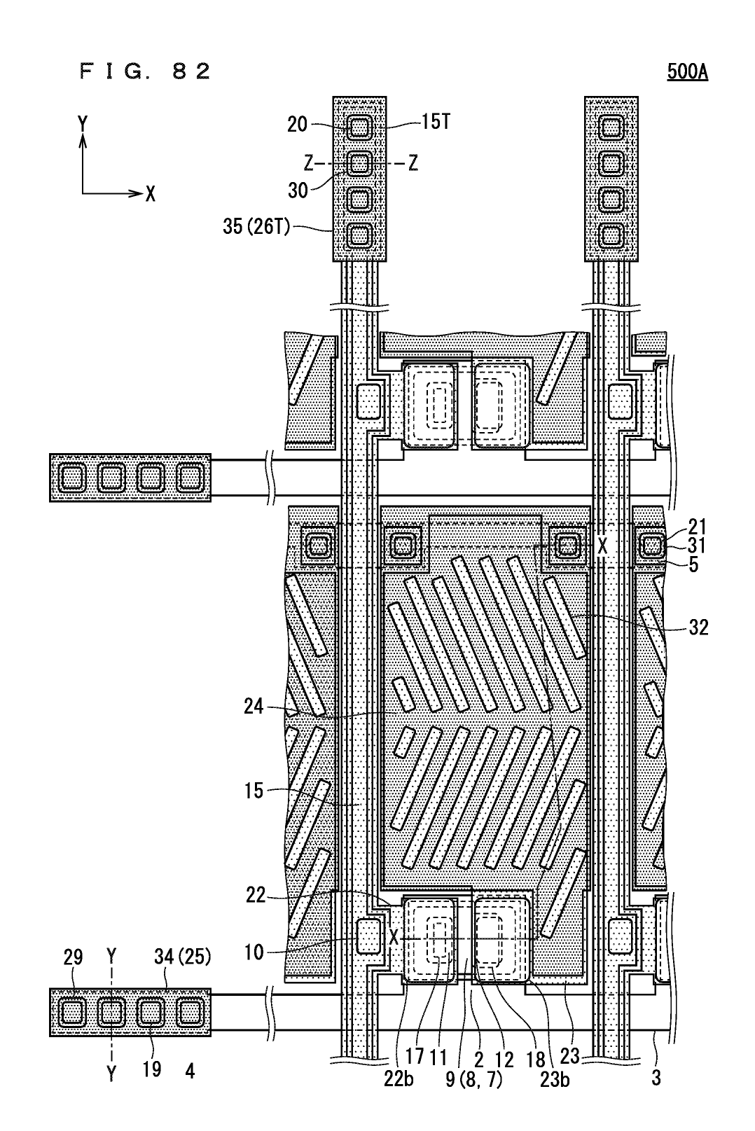

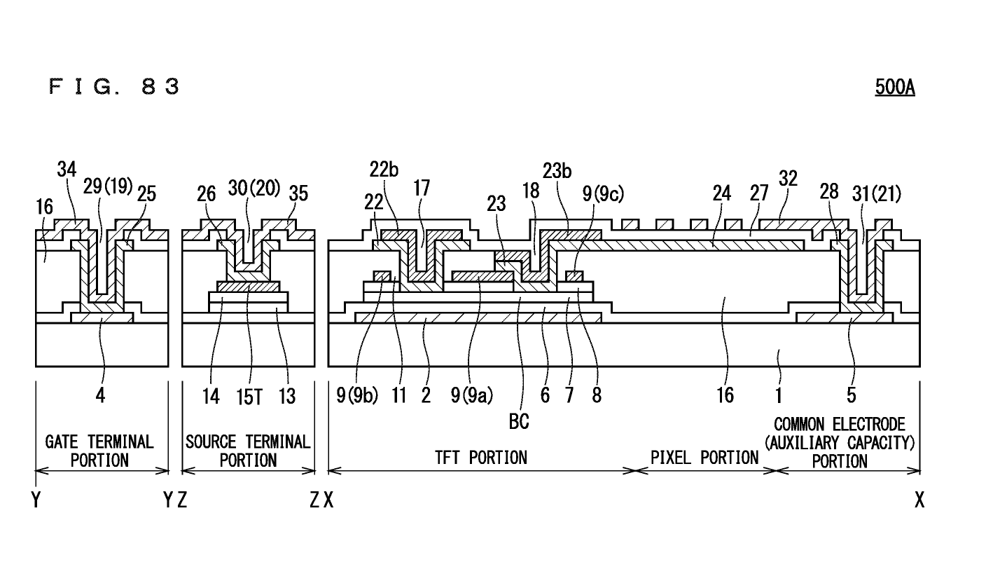

Next, with reference to FIG. 82 and FIG. 83, a configuration a TFT substrate 500A according to a modification of the fifth embodiment will be described with reference to FIG. 82 and FIG. 83. The TFT substrate 500A has a configuration further including a common electrode that becomes an auxiliary capacity of a pixel electrode in the pixel portion of the TFT substrate 500. Note that, the same reference numerals are given to the same components as those in the TFT substrate 500 described by using FIG. 71 and FIG. 72, and the overlapping description will be omitted.

Configuration of Pixel of TFT Substrate

FIG. 82 is a plan view illustrating a planar configuration of a pixel according to the modification of the fifth embodiment, and FIG. 83 is a cross sectional view illustrating a cross sectional configuration taken along the line X-X (cross sectional configuration of TFT portion, cross sectional configuration of pixel portion, and cross sectional configuration of common electrode portion), a cross sectional configuration taken along the line Y-Y (cross sectional configuration of gate terminal portion), and a cross sectional configuration taken along the line Z-Z (cross sectional configuration of source terminal portion) in FIG. 82. Note that, the TFT substrate 500A shall be used for a liquid crystal display device of FFS mode of light transmission type in the following description.

As illustrated in FIG. 82, in the TFT substrate 500A, in addition to the configuration of the TFT substrate 500, a common electrode 5 is included that is arranged to extend in parallel to a gate wiring 3 and formed by a first conductive film the same as the gate wiring 3. The common electrode 5 forms an auxiliary capacity of a transmissive pixel electrode 24 in the pixel portion and supplies a constant common electrical potential to a counter electrode 32 of the pixel portion. Therefore, the counter electrode 32 is independent for each pixel, and is electrically connected to the common electrode 5 via a common electrode extraction electrode 28 provided in a first common electrode portion contact hole 21.

Next, a cross sectional configuration of the TFT substrate 500A will be described using FIG. 83. As illustrated in FIG. 83, the TFT substrate 500A includes a substrate 1 that is a transparent insulating substrate such as a glass as its base material, and a gate electrode 2 (including gate wiring 3), a gate terminal 4, and the common electrode 5 are arranged on the substrate 1.

Then, an insulating film 6 (first insulating film) is arranged to cover the gate electrode 2, the gate terminal 4, and the common electrode 5. The insulating film 6 functions as a gate insulating film at the TFT portion, so that the insulating film 6 is referred to as a gate insulating film 6 in some cases.

In the TFT portion, an oxide semiconductor film 7 is arranged on the insulating film 6 at the position overlapping with the gate electrode 2. A protective insulating film 8 (second insulating film) is arranged on the semiconductor channel layer 7, and a channel region lower layer light shielding film 9 (second conductive film) formed of a metal film having light shielding properties or the like is arranged on the protective insulating film 8.

In the modification, as the channel region lower layer light shielding film 9, for example, a metal such as Mo and Al, or an alloy obtained by adding another element to the metal is used. Then, a first source electrode contact hole 11 and a first drain electrode contact hole 12 are provided in the channel region lower layer light shielding film 9 above the semiconductor channel layer 7. Note that the channel region lower layer light shielding film 9 is referred to as a lower layer light shielding film 9a, 9b, or 9c in some cases depending on its arranged position for descriptive purposes.

Furthermore, in the source terminal portion, an oxide semiconductor film 13 in the same layer as the semiconductor channel layer 7 of the TFT portion is provided, and an insulating film 14 in the layer the same as the protective insulating film 8 is provided on the oxide semiconductor film 13. Then, a source terminal 15T (including lower layer source wiring 15) in the same layer as the channel region lower layer light shielding film 9 (second conductive film) is provided on the insulating film 14, so that the source terminal 15T is the upper most layer film of the laminate of the three layers. Furthermore, in the gate terminal portion, the insulating film 6 is formed to cover the gate terminal 4 (including gate wiring 3).

Then, an interlayer insulating film 16 (third insulating film) is arranged above the entire surface of the substrate 1 to cover the insulating film 6, the semiconductor channel layer 7, the protective insulating film 8, and the channel region lower layer light shielding film 9. Then, in the TFT portion, a second source electrode contact hole 17 and a second drain electrode contact hole 18 penetrating the interlayer insulating film 16 and the protective insulating film 8 to reach the semiconductor channel layer 7 are provided. The second source electrode contact hole 17 is arranged to be located inside the outer circumference of the first source electrode contact hole 11 in plan view, and is formed such that a surface of the semiconductor channel layer 7 is exposed at its bottom surface. Furthermore, the second drain electrode contact hole 18 is arranged such that at least a portion thereof is located outside the outer circumference of the first drain electrode contact hole 12 in plan view, and is formed such that both of the surface of the semiconductor channel layer 7 and the surface of at least a portion of the region of the channel region lower layer light shielding film 9 (region of the lower layer light shielding film 9a in the embodiment) are exposed.

Furthermore, in the common electrode portion, the first common electrode portion contact hole 21 penetrating the interlayer insulating film 16 and the insulating film 6 to reach the common electrode 5 is provided in the region overlapping the pattern of the common electrode 5 on the lower side in plan view.

Then, a source electrode 22 and a drain electrode 23 formed as a third conductive film are arranged so as to be separated from each other and directly connected to the semiconductor channel layer 7 via the second source electrode contact hole 17 and the second drain electrode contact hole 18, respectively. The region between the source electrode 22 and the drain electrode 23 in the semiconductor channel layer 7 forms a channel region BC. Note that, in the modification, a transparent conductive film (translucent conductive film) is used for the third conductive film.

Furthermore, the transmissive pixel electrode 24 extending from the drain electrode 23 is provided such that a portion thereof overlaps the common electrode 5 on the lower side in a common electrode formation region in plan view, and an auxiliary capacity for the pixel electric potential is formed via the insulating film 6 and the interlayer insulating film 16.

Furthermore, in the first common electrode portion contact hole 21, the common electrode extraction electrode 28 formed as the third conductive film is provided to be directly connected to the common electrode 5 on the lower side. Note that the common electrode extraction electrode 28 is formed as a pattern separated from the source electrode 22 and the drain electrode 23 (including transmissive pixel electrode 24) so as not to be electrically connected (not to cause short circuit) therewith.

Upper layer light shielding films 22b and 23b (fourth conductive film) are respectively provided on the source electrode 22 and the drain electrode 23. When the upper layer light shielding films 22b and 23b are formed by, for example, a metal film having light shielding properties, the upper layer light shielding films 22b and 23b are formed so as to be separated from each other to prevent electrical short circuit between the source electrode 22 and the drain electrode 23. In the embodiment, as the upper layer light shielding films 22b, 23b, a metal such as molybdenum (Mo) and aluminum (Al), or an alloy obtained by adding another element to the metal can be used.

As illustrated in FIG. 82, the upper region of the semiconductor channel layer 7 of the TFT portion is configured such that its entire region is shielded from the light from an upper surface in plan view by the upper layer light shielding films 22b, 23b and the lower layer light shielding films 9a, 9b, 9c. Furthermore, the lower region of the semiconductor channel layer 7 of the TFT portion is configured such that light from a lower surface (surface on the side of the substrate 1) is shielded in its entire region in plan view by the gate electrode 2. Forming the TFT portion in this manner makes it possible to almost perfectly prevent backlight light, external light, and scattering light thereof from being incident on the semiconductor channel layer 7 (light shielding), making it possible to prevent property degradation of the semiconductor channel layer 7 due to light absorption.

Then, an interlayer insulating film 27 (fourth insulating film) is formed above the whole of the substrate 1 to cover the source electrode 22, the drain electrode 23, the transmissive pixel electrode 24, and the upper layer light shielding films 22b, 23b, and the common electrode extraction electrode 28. Note that in the common electrode portion, a second common electrode portion contact hole 31 is provided in the interlayer insulating film 27. The second common electrode portion contact hole 31 is arranged in the region overlapping the pattern of the common electrode 5 and the common electrode extraction electrode 28 on the lower side in plan view, and is formed such that the surface of the common electrode extraction electrode 28 that is the lower layer is exposed.

The counter electrode 32 (fifth conductive film) is provided on the interlayer insulating film 27. As illustrated in FIG. 83, the counter electrode 32 is provided so as to be directly connected to the common electrode extraction electrode 28 that is the lower layer via the second common electrode portion contact hole 31, and is electrically connected to the common electrode 5 on the lower side via the common electrode extraction electrode 28, so that a constant common electric potential is supplied to the counter electrode 32.

Furthermore, slit opening portions SL are provided in the counter electrode 32, and applying a voltage between the transmissive pixel electrode 24 and the counter electrode 32 makes it possible to generate between with the transmissive pixel electrode 24 an electric filed in substantially lateral direction with respect to the main surface of the substrate 1 above the counter electrode 32. Note that although the configuration in which slit shaped opening portions are formed in the counter electrode 32 is illustrated in the embodiment, it is also preferable that an opening portion may be formed having a comb-tooth shape in which one ends of a plurality of slits are jointed.

Furthermore, in the source terminal portion, a source extraction electrode 26T is provided to be directly connected to the source terminal 15T via a first source terminal portion contact hole 20 penetrating the interlayer insulating film 16 to reach the source terminal 15T. Then, then, to the source extraction electrode 26T, a source terminal pad 35 on the upper side is connected to overlap in plan view via a second source terminal portion contact hole 30 penetrating the interlayer insulating film 27.

Furthermore, in the gate terminal portion, a gate terminal extraction electrode 25 is provided to be directly connected to the gate terminal 4 via a first gate terminal portion contact hole 19 penetrating the interlayer insulating film 16 and the insulating film 6 to reach the gate terminal. Then, to the gate terminal extraction electrode 25, a gate terminal pad 34 on the upper side is connected to overlap in plan view via a second gate terminal portion contact hole 29 penetrating the interlayer insulating film 27.

Note that, the source extraction electrode 26T and the gate terminal extraction electrode 25 are formed by the third conductive film in the same layer as the source electrode 22 and the drain electrode 23 of the TFT portion. Furthermore, the source terminal pad 35 and the gate terminal pad 34 are formed by the fifth conductive film in the same layer as the counter electrode 32 of the TFT portion.

Manufacturing Method

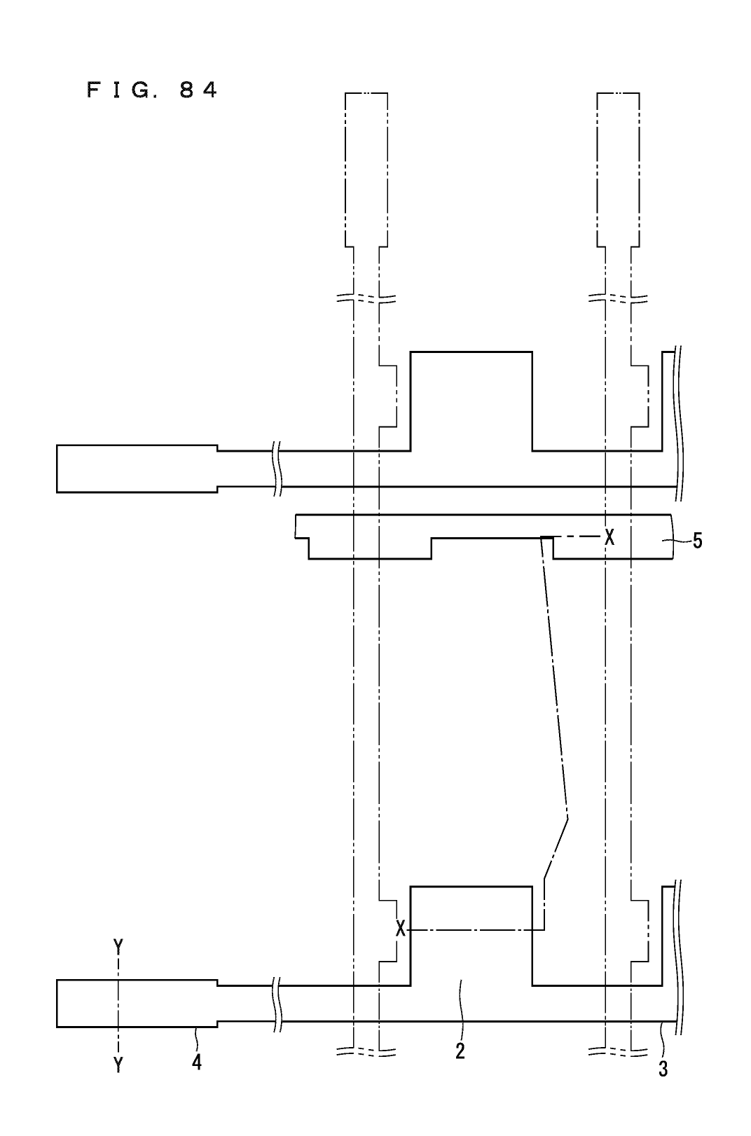

Hereinafter, a manufacturing method of the TFT substrate 500A according to the modification of the fifth embodiment will be described using FIG. 84 to FIG. 92. Note that a plan view and a cross sectional view illustrating the final step respectively correspond to FIG. 82 and FIG. 83,

The first conductive film that is the material of the gate electrode 2, the gate wiring 3, the common electrode 5, and the like is formed on one of the entire main surfaces of the substrate 1 that has been washed. The material capable of being used as the first conductive film is described in the fifth embodiment, so that overlapping description will be omitted. In the modification, an aluminum (Al) alloy film shall be used as the first conductive film, and the Al alloy film is formed to have a thickness of 200 nm by a sputtering method using argon (Ar) gas.

First Photolithography Step

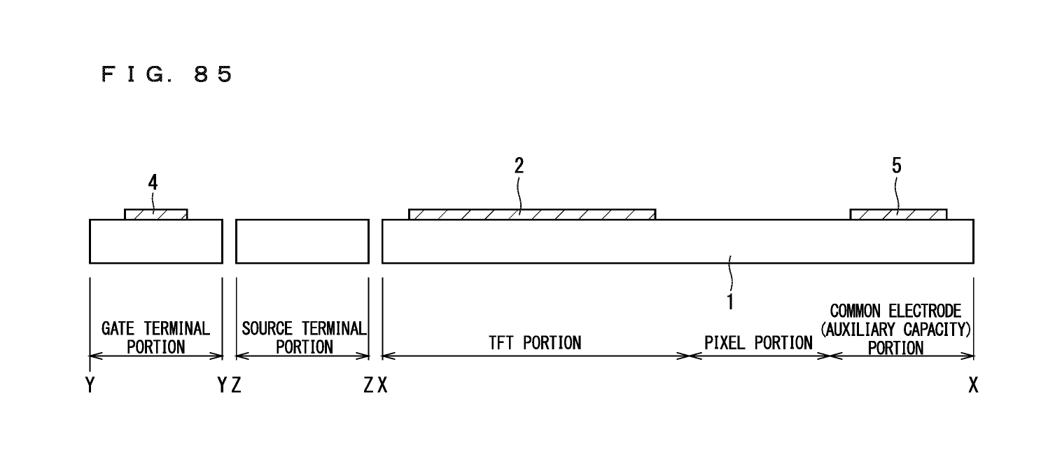

Then, a photoresist material is applied on the first conductive film, a photoresist pattern is formed in a first photolithography step, and the first conductive film is subjected to patterning by etching using the photoresist pattern as a mask. Herein, a wet etching using PAN chemical solution is used. Then, by removing the photoresist pattern, as illustrated in FIG. 84 and FIG. 85, the gate electrode 2, the gate wiring 3 (not shown in FIG. 85), the gate terminal 4, and the common electrode 5 are formed on the upper main surface of the substrate 1.

Second Photolithography Step

Then, after the insulating film 6 (first insulating film) is formed on the entire upper main surface of the substrate 1 to cover the gate electrode 2, the gate wiring 3, the gate terminal 4, and the common electrode 5, the oxide semiconductor film, the second insulating film, and the second conductive film are laminated in this order on the insulating film 6. Then, in a second photolithography step, a photoresist pattern having different thicknesses is formed by an exposure (half exposure) using a half exposure mask, and the oxide semiconductor film, the second insulating film, and the second conductive film are subjected to patterning by etching using the photoresist pattern. Herewith, as illustrated in FIG. 60 and FIG. 61 of the fourth embodiment, in the TFT portion, the laminate of the semiconductor channel layer 7, the protective insulating film 8, and the channel region lower layer light shielding film 9 is obtained above the gate electrode 2, and the first source electrode contact hole 11 and the first drain electrode contact hole 12 are formed in the channel region lower layer light shielding film 9. Herein, the outline of the semiconductor channel layer 7 in plan view is arranged to exist inside the outline of the gate electrode 2.

Furthermore, for descriptive purposes, the channel region lower layer light shielding film 9 that remains between the first source electrode contact hole 11 and the first drain electrode contact hole 12 is referred to as the lower layer light shielding film 9a, the channel region lower layer light shielding film 9 that remains on the side opposite to the lower layer light shielding film 9a of the first source electrode contact hole 11 is referred to as the lower layer light shielding film 9b, and the channel region lower layer light shielding film 9 that remains on the side opposite to the lower layer light shielding film 9a of the first drain electrode contact hole 12 is referred to as the lower layer light shielding film 9c.

Furthermore, in a source wiring formation region, a laminate of the oxide semiconductor film 13, the insulating film 14, and the lower layer source wiring 15 is formed, and in a source terminal formation region, a laminate of the oxide semiconductor film 13, the insulating film 14, and the source terminal 15T is formed by the same process as the above process.

Note that, as for the material and forming method of the insulating film 6, the oxide semiconductor film, the second insulating film, and the second conductive film, and the etching using a photoresist pattern formed by a half exposure, description is made using FIG. 19 to FIG. 22 in the second embodiment, so that the description will be omitted.

Next, the interlayer insulating film 16 (third insulating film) is formed above the entire upper main surface of the substrate 1. In the modification, a resin series insulating film is formed by an organic resin material. Specifically, for example, an organic resin material of an acrylic having photosensitivity is applied on the substrate 1 to have a thickness of 2.0 to 3.0 μm by a spin coat method as the interlayer insulating film 16.

Third Photolithography Step

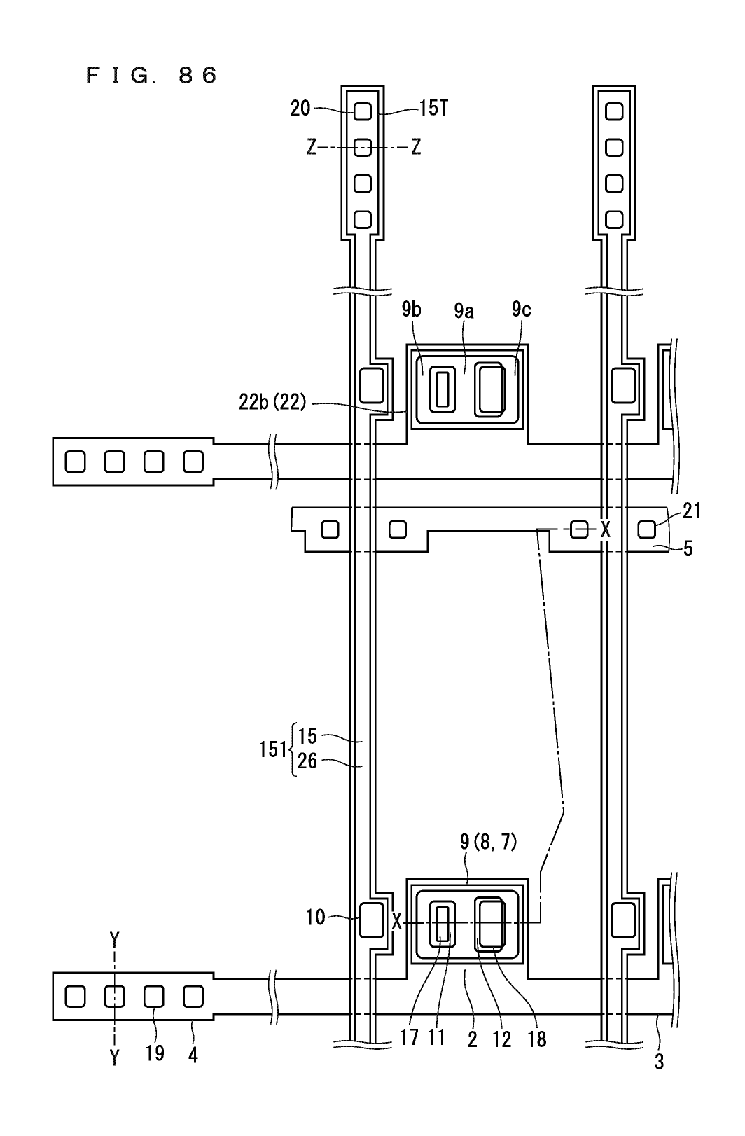

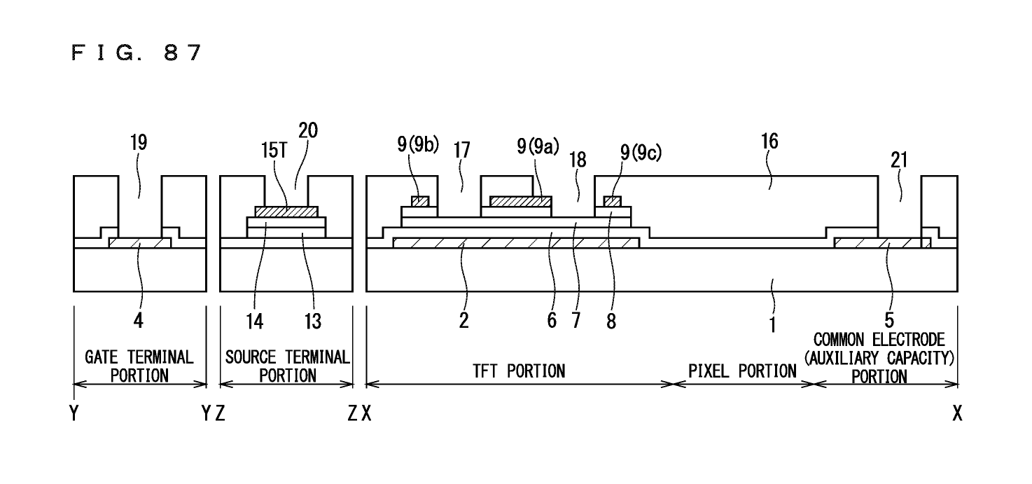

Next, the interlayer insulating film 16 is exposed and developed in a third photolithography step, and as illustrated in FIG. 86 and FIG. 87, a first source wiring contact hole 10 (not shown in FIG. 63), the second source electrode contact hole 17, the second drain electrode contact hole 18, the first gate terminal portion contact hole 19, and the first source terminal portion contact hole 20, and the first common electrode portion contact hole 21 penetrating the interlayer insulating film 16 are formed.

Then, the protective insulating film 8 exposed at the bottom portions of the second source electrode contact hole 17 and the second drain electrode contact hole 18 are subjected to etching. In the etching, dry etching is performed using a gas in which oxide (O₂) is added to sulfur hexafluoride (SF₆). By the etching, as illustrated in FIG. 86 and FIG. 87, the semiconductor channel layer 7 is exposed at the bottom surfaces of the second source electrode contact hole 17 and the second drain electrode contact hole 18. Furthermore, the semiconductor channel layer 7 and a portion of the channel region lower layer light shielding film 9 (lower layer light shielding film 9a in the embodiment) are exposed at the bottom surface of the second drain electrode contact hole 18.

Furthermore, although the first gate terminal portion contact hole 19 and the first common electrode portion contact hole 21 also penetrate the insulating film 6, and the gate terminal 4 and the common electrode 5 of Al alloy are respectively exposed at their bottom surfaces, and the lower layer source wiring 15 and the source terminal 15T of Al alloy are respectively exposed at the bottom surfaces of the first source wiring contact hole 10 and the first source terminal portion contact hole 20, the Al alloy is not etched by dry etching using a gas in which oxygen (O₂) is added to sulfur hexafluoride (SF₆), so that the patterns remain as they are.

Note that, as a material of the resin series insulating film used for the interlayer insulating film 16, besides an acrylic organic resin material, an olefin series material, a novolac series material, a polyimide series material, and a siloxane series material can be also used. Such coating type organic insulating materials have low dielectric constant and is easy to be formed into a thick film having a thickness of not less than 2.0 μm, making it possible to suppress wiring capacity to a low capacity. Thus, using such materials makes it possible to drive the TFT substrate at a low voltage, making it possible to contribute to reducing power consumption. This makes it possible to make the transmissive pixel electrode 24 be arranged on the gate wiring or the source wiring to overlap, also making it possible to make aperture ratio high.

Furthermore, for the interlayer insulating film 16, instead of the resin series insulating film material, an inorganic series insulating material such as silicon nitride (SiN) and silicon oxide (SiO) can be also used. When such an inorganic series insulating material is used, the first source wiring contact hole 10, the second source electrode contact hole 17, the second drain electrode contact hole 18, the first gate terminal portion contact hole 19, and the first source terminal portion contact hole 20 are formed using a photoresist pattern as a mask. Alternatively, an inorganic series insulating film material and a resin series insulating film material may be appropriately combined to be used.

Next, the third conductive film and the fourth conductive film are laminated in this order on the entire surface of the interlayer insulating film 16. In the modification, a transparent conductive film (translucent conductive film) is used as the third conductive film, and an Al alloy film having light shielding properties is used as the fourth conductive film. Note that the material, the film thickness, and the manufacturing method of the transparent conductive film, and the material, the film thickness, and the manufacturing method of the Al alloy film are the same as those in the fifth embodiment, so that the description will be omitted.

Fourth Photolithography Step

Next, a photoresist material is applied on the entire surface of the fourth conductive film (Al alloy film), and a photoresist pattern is formed in a fourth photolithography step. Herein, by performing a half exposure using the half exposure mask described in the second photolithography step, a photoresist pattern having different thicknesses is formed.

Then, the fourth conductive film is subjected to patterning by a wet etching using PAN chemical solution using the photoresist pattern as a mask to remove the fourth conductive film at the portion that is not covered with the photoresist pattern.

Subsequently, the third conductive film is subjected to patterning by a wet etching using an oxalic acid series chemical solution of oxalic acid 5 wt %+water using the same photoresist pattern as a mask to remove the third conductive film at the portion that is not covered with the photoresist pattern and the fourth conductive film.

Then, the whole of the substrate 1 is heated to 150° C. to make the amorphous ITO film be crystallized to be a polycrystalline ITO film.

Next, by oxygen ashing, the film thickness of the photoresist pattern is totally reduced to completely remove the photoresist pattern whose film thickness is thin. In contrast, the photoresist pattern whose film thickness is thick is made thin to be left.

Next, the fourth conductive film is subjected to etching again by using a wet etching method using PAN chemical solution using the remaining photoresist pattern as a mask. In this context, the ITO film that is the transparent conductive film that is the lower layer is poly crystallized, making it possible to etch the Al alloy film that is not covered with a photoresist pattern, for example, the Al alloy film on the region in which the transmissive pixel electrode 24 and the common electrode extraction electrode 28 are formed and the Al alloy film of the gate terminal portion and the source terminal portion without suffering etching damage practically with respect to PAN chemical solution (disappearance of film or deterioration of electrical properties or optical properties).

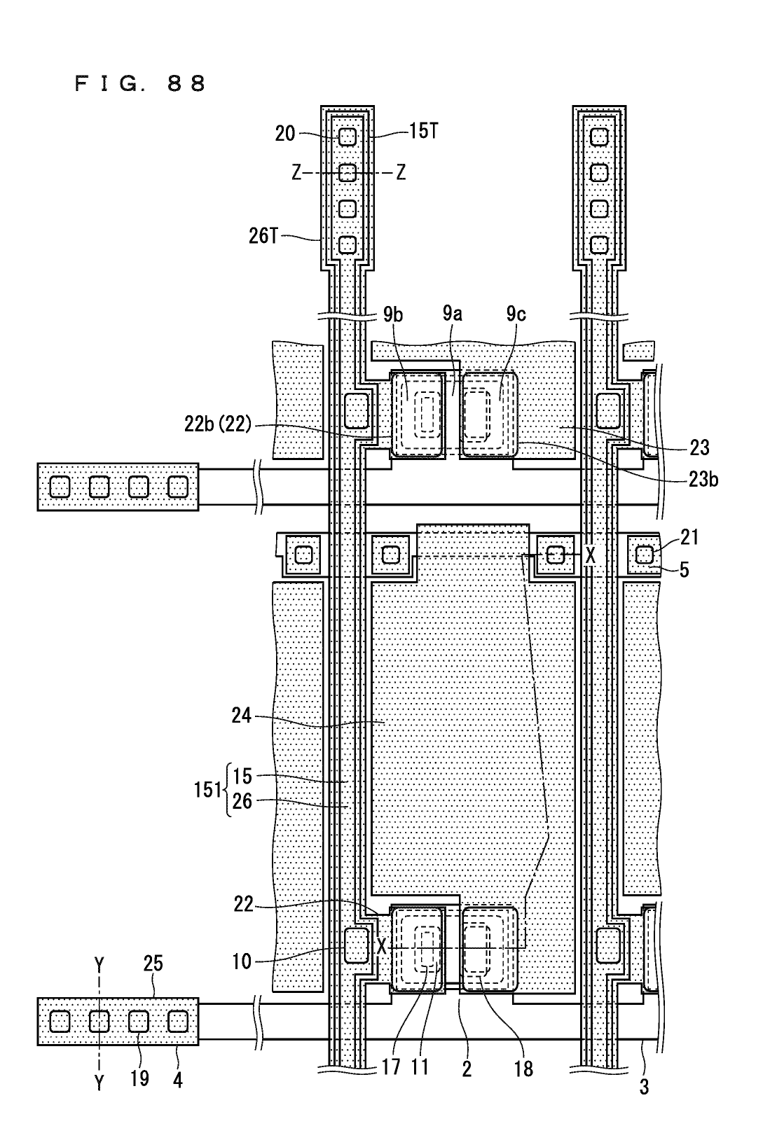

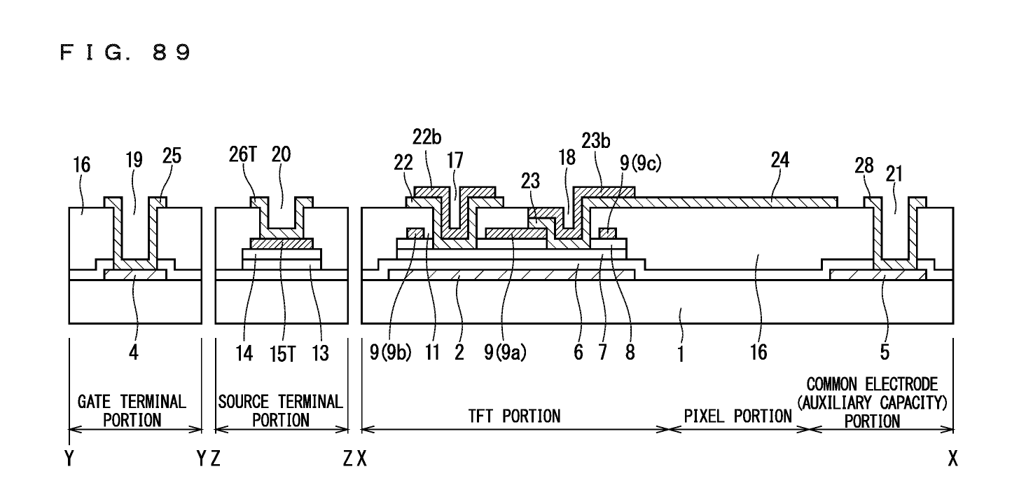

Then, by removing the photoresist pattern, as illustrated in FIG. 88 and FIG. 89, the gate terminal extraction electrode 25, the source electrode 22, an upper layer source wiring 26 extending from the source electrode 22, the source terminal extraction electrode 261, the drain electrode 23, the transmissive pixel electrode 24 extending from the drain electrode 23, and the common electrode extraction electrode 28 configured by the transparent conductive film (polycrystalline ITO film) are formed. Note that the common electrode extraction electrode 28 is formed by an independent pattern electrically separated from the transmissive pixel electrode 24. Furthermore, the upper layer light shielding films 22b and 23b are respectively formed on the upper portion of the source electrode 22 and the upper portion of the drain electrode 23 of the TFT portion. The upper layer light shielding films 22b and 23b are formed to cover substantially the whole of the planer pattern of the semiconductor channel layer 7 excluding the channel region BC in plan view.

Herein, the gate terminal extraction electrode 25 is directly connected to the gate terminal 4 via the first gate terminal portion contact hole 19. Furthermore, the source electrode 22 is directly connected to the semiconductor channel layer 7 via the second source electrode contact hole 17. Furthermore, the upper layer source wiring 26 is directly connected to the lower layer source wiring 15 via the first source wiring contact hole 10. Furthermore, the source wiring extraction electrode 261 is directly connected to the source terminal 15T via the first source terminal portion contact hole 20. Then, the common electrode extraction electrode 28 is directly connected to the common electrode 5 via the first common electrode portion contact hole 21.

Next, the interlayer insulating film 27 (fourth insulating film) is formed above the entire upper main surface of the substrate 1. In the embodiment, a silicon nitride film (SiN) having a thickness of 400 nm is formed using a CVD method.

Fifth Photolithography Step

Next, a photoresist material is applied on the entire surface of the interlayer insulating film 27 (SiN film), a photoresist pattern is formed by a fifth photolithography step, and the interlayer insulating film 27 is subjected to etching using the photoresist pattern as a mask.

For the etching, a dry etching method using a gas including fluorine can be used. In the modification, dry etching is performed by using a gas in which oxygen (O₂) is added to sulfur hexafluoride (SF₆).

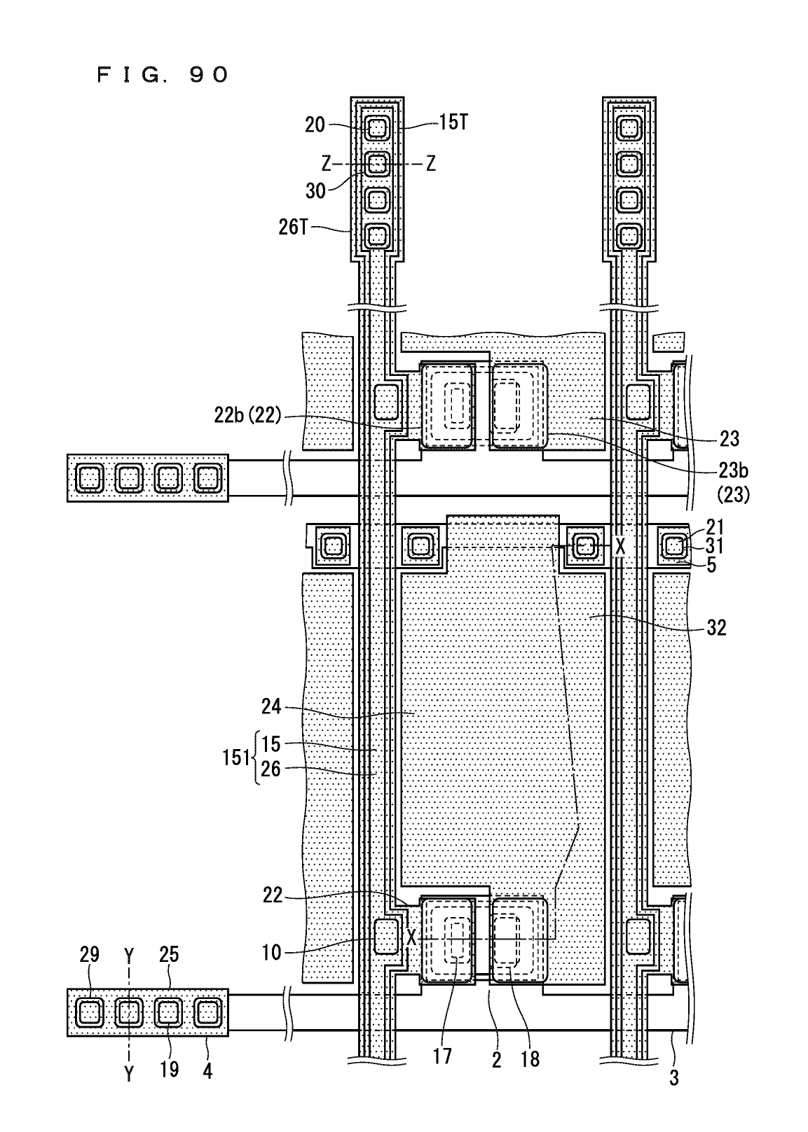

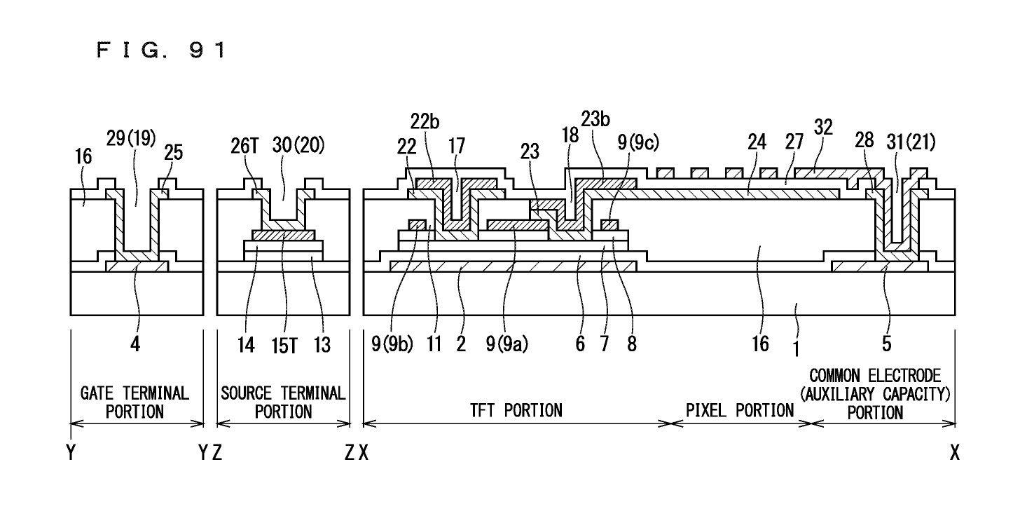

Then, by removing the photoresist pattern, as illustrated in FIG. 90 and FIG. 91, the interlayer insulating film 27 above the gate terminal extraction electrode 25, the source wiring extraction electrode 26T, and the common electrode extraction electrode 28 is removed, and the second gate terminal portion contact hole 29, the second source terminal portion contact hole 30, and the second common electrode portion contact hole 31 are respectively formed.

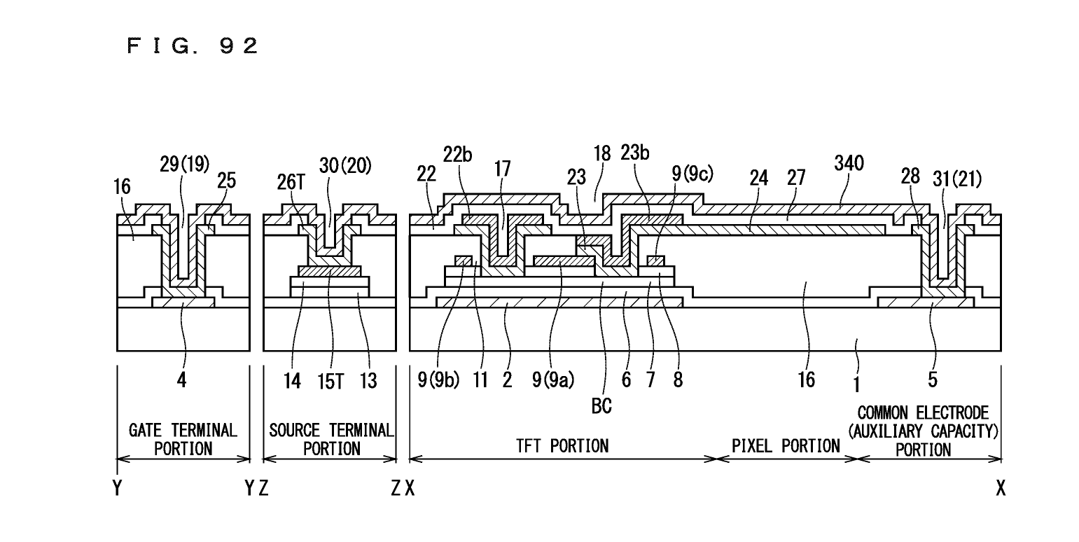

Then, the fifth conductive film 340 that is the material of the counter electrode 32 is formed on the entire upper surface of the interlayer insulating film 27 including the inside of the second gate terminal portion contact hole 29, the inside of the second source terminal portion contact hole, and the inside of the second common electrode portion contact hole 31 as illustrated in FIG. 92. In the modification, as the fifth conductive film, an amorphous ITO film having a thickness of 100 nm the same as the transparent conductive film that is the third conductive film is formed by a spattering method.

Sixth Photolithography Step

Next, a photoresist material is applied on the entire surface of the fifth conductive film 340 (amorphous ITO film), a photoresist pattern is formed by a sixth photolithography step, and the fifth conductive film 340 is subjected to etching using the photoresist pattern as a mask. In this etching, a wet etching method can be used using oxalic acid series chemical solution of oxalic acid 5 wt %+water.

Then, by removing the photoresist pattern, as illustrated in FIG. 82 and FIG. 83, the counter electrode 32 having slit opening portions, the gate terminal pad 34, and the source terminal pad 35 configured by an amorphous ITO film that is a transparent conductive film are formed. The gate terminal pad 34 is directly connected to the gate terminal extraction electrode 25 on the lower side via the second gate terminal portion contact hole 29. Furthermore, the source terminal pad 35 is directly connected to the source terminal extraction electrode 26T on the lower side via the second source terminal portion contact hole 30. Furthermore, the counter electrode 32 is directly connected to the common electrode extraction electrode 28 that is the lower layer via the second common electrode portion contact hole 31.

Then, the whole of the substrate 1 is heated at 200° C. to make the amorphous ITO film that is the counter electrode 32 having slit opening portions, the gate terminal pad 34, and the source terminal pad 35 polycrystalline. By the above processes, the TFT substrate 500A of the modification illustrated in FIG. 82 and FIG. 83 is completed.

Then, the liquid crystal display panel is assembled and a light polarizing plate, a phase difference plate, a driving circuit, a backlight unit, and the like are arranged outside the liquid crystal display panel to complete the liquid crystal display device, but the detail thereof is described in the first embodiment, so that the description thereof is omitted.

As described above, in the modification, an auxiliary capacity can be added to the transmissive pixel electrode 24 by providing the common electrode 5, making it possible to increase a leak margin of a display signal electric potential applied to the transmissive pixel electrode 24 in addition to the effects the same as those in the fifth embodiment. This makes it possible to reduce display defect caused by retention failure of signal electric potential to achieve a higher quality liquid crystal display device.

Furthermore, the counter electrode 32 is electrically directly connected to the common electrode 5 on the lower side via the first common electrode portion contact hole 21 and the second common electrode portion contact hole 31 provided for each pixel, so that a constant common electric potential signal is surely supplied to each pixel, making it possible to reduce generation of display trouble such as point defect.

Furthermore, instead of making the pattern of the counter electrode 32 be an independent pattern for each pixel, as illustrated in FIG. 71 of the fifth embodiment, the counter electrode 32 may be formed in a consecutive shape to stride between at least adjacent pixels in the lateral direction to supply a constant common electric potential from a peripheral portion (not shown) of the display region. In this case, a constant common electric potential is to be supplied to the counter electrode 32 from both the common electrode 5 and the end of the display region, so that even when a disconnection trouble occurs in one of them, the common electric potential is supplied from the other one, further increasing the effect of preventing generation of display trouble such as point defect and line defect.

Formation of Upper Most Layer Light Shielding Film

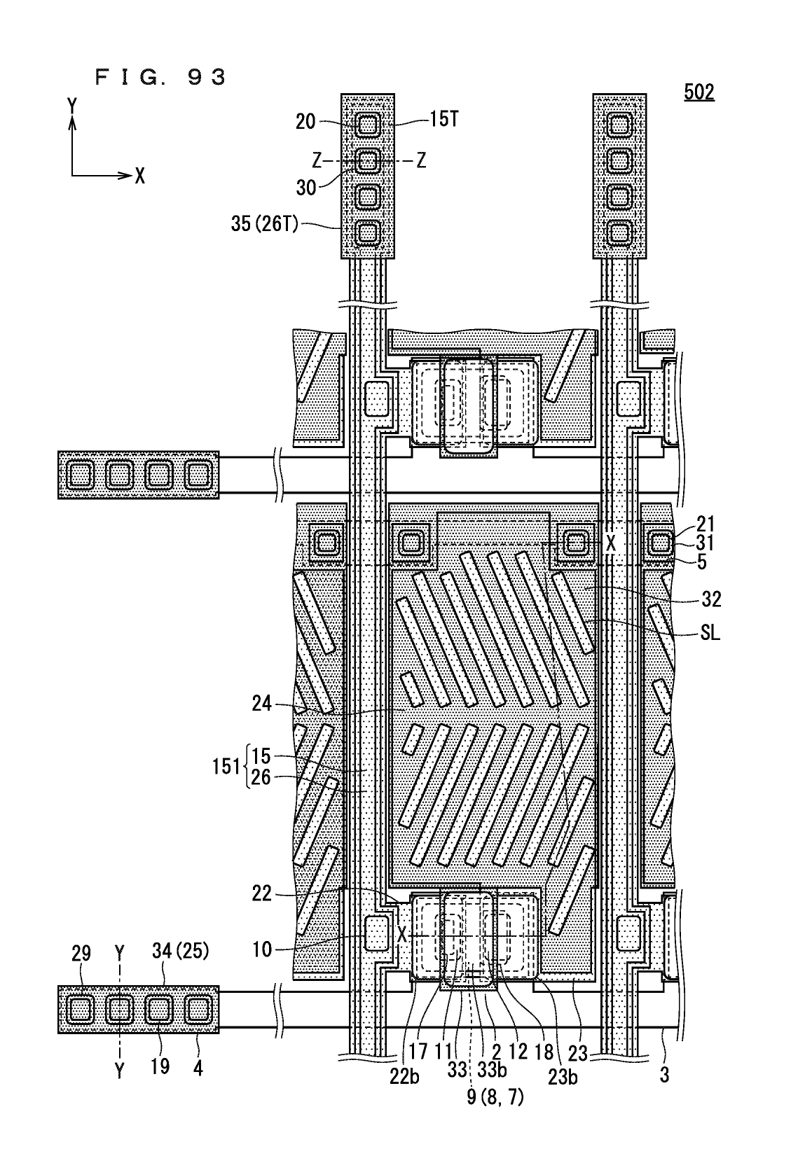

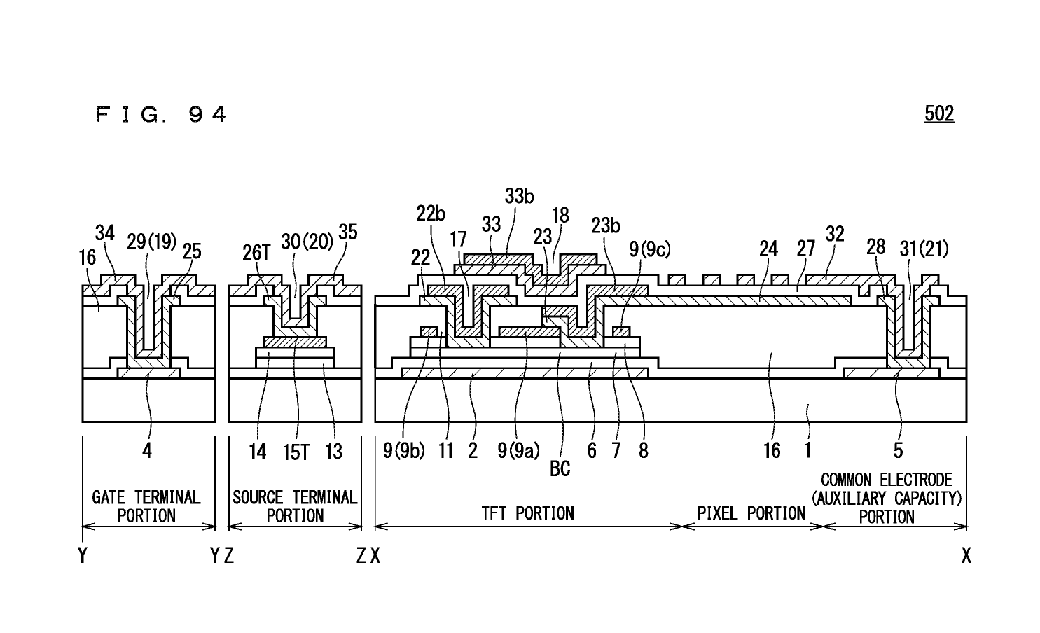

In the above described sixth photolithography step, although the counter electrode 32, the gate terminal pad 34, and the source terminal pad 35 are formed by patterning the fifth conductive film, it is also preferable that an upper most layer light shielding film 33 (lower layer film) and an upper most layer light shielding film 33b (upper layer film) covering the channel region in plan view may be formed above the channel region of the TFT portion as illustrated in FIG. 93 and FIG. 94 by forming a photoresist pattern having different thicknesses by forming a conductive film having light shielding properties (sixth conductive film) on the fifth conductive film and performing a half exposure using a half exposure mask on the laminated film of the fifth conductive film and the sixth conductive film, and by sequentially subjecting the laminated film of the fifth conductive film and the sixth conductive film to etching using the photoresist pattern.

To be more specific, after forming the fifth conductive film (amorphous ITO film) on the entire upper surface of the interlayer insulating film 27, an Al alloy film having light shielding properties is formed as the sixth conductive film, a photoresist pattern having different thicknesses is formed thereon by a half exposure, and the sixth conductive film (Al alloy film) and the fifth conductive film (amorphous ITO film) are sequentially subjected to etching using the photoresist pattern as a mask to form the counter electrode 32, the gate terminal pad 34, and the source terminal pad 35. Furthermore, above the channel region of the TFT portion, the laminated film of the upper most layer light shielding film 33 configured by an ITO film and the upper most layer light shielding film 33b configured by an Al alloy film are simultaneously formed. This makes it possible to reduce the number of manufacturing processes.

In this case, in the photoresist pattern having different thicknesses formed by a half exposure, portions for forming the patterns of the upper most layer light shielding films 33 and 33b by leaving the fifth and sixth conductive films are made thick in their film thickness. Note that the sixth conductive film is subjected to etching by two steps, and the portion removed by the second etching is made thin in the film thickness of the photoresist pattern. For example, the film thickness is made thin on the regions in which the counter electrode 32, the gate terminal pad 34, and the source terminal pad 35 are formed, and in the first etching, the sixth conductive film on the region in which these are formed is made to be not removed.

Then, the sixth conductive film is first subjected to patterning by etching using the photoresist pattern as a mask to remove the sixth conductive film at the portion that is not covered with the photoresist pattern. In the etching of the fourth conductive film, a wet etching using PAN chemical solution is used.

Subsequently, the fifth conductive film is subjected to patterning by etching using the same photoresist pattern as a mask to remove the fourth conductive film at the portion that is not covered with the photoresist pattern and the sixth conductive film. In the etching of the fourth conductive film (amorphous ITO), a wet etching is used using oxalic acid series chemical solution of oxalic acid 5 wt %+water.

Then, the whole of the substrate 1 is heated at 150° C. to make the amorphous ITO film structuring the counter electrode 32, the gate terminal pad 34, and the source terminal pad 35, and the upper most layer light shielding film 33 polycrystalline. Note that the substrate temperature is not limited to 150° C., and in the case of a typical amorphous ITO film having a mixture ratio in which indium oxide (In₂O₃) is not less than 85 wt % and not more than 95 wt %, and tin oxide (SnO₂) is not less than 5 wt % and not more than 15 wt % (total thereof is 100 wt %), not less than 140° C. enables crystallization. In contrast, on the high temperature side, temperature can be arbitrarily determined depending on the heatproof temperature of a material or the like used for the layer and the pattern formed on the TFT substrate. For example, in the embodiment, since an organic resin film of acrylic is used as the third insulating film, not more than 230° C. that is the heatproof temperature of the material is preferable, but, for example, in the case of using a typical photosensitivity resin of novolak series for the photoresist material, not more than 160° C. is preferable.

Next, by oxygen ashing, the film thickness of the photoresist pattern is totally reduced to completely remove the photoresist pattern whose film thickness is thin. In contrast, the photoresist pattern whose film thickness is thick is made thin to be left.

Next, the sixth conductive film is subjected to etching again by using a wet etching method using PAN chemical solution using the remaining photoresist pattern as a mask. In this context, since the ITO film that is a transparent conductive film that is the lower layer is poly crystallized, so that the ITO film is chemically very stable, making it possible to etch the Al alloy film that is not covered with a photoresist pattern, for example, the Al alloy film on the counter electrode 32 and the Al alloy film of the gate terminal portion and the source terminal portion without suffering etching damage practically with respect to PAN chemical solution (disappearance of film or deterioration of electrical properties or optical properties).

Then, by removing the photoresist pattern, as illustrated in FIG. 93 and FIG. 94, a TFT substrate 502 can be obtained in which the upper most layer light shielding films 33 and 33b covering the channel region in plan view are formed above the channel region of the TFT portion.

In the TFT substrate 502, the upper portion in plan view of the semiconductor channel layer 7 is configured such that light is perfectly shielded by the light shielding films of the three layers including the upper most layer light shielding films 33 and 33b in addition to the lower layer light shielding films 9a, 9b, 9c and the upper layer light shielding films 22b, 23b, making it possible to further suppress deterioration (optical deterioration) of the channel layer due to absorption of backlight light during operation of the liquid crystal display device and external light.

Although the present invention is described in detail, the above descriptions are only examples in all aspects, so that the present invention is not limited thereto. It is understood that numerous modifications that are not exemplified can be assumed without departing the scope of the present invention.

Note that, in the present invention, any combination of the embodiments, and appropriate modification or omission of each embodiment are possible within the scope of the invention.

1. A thin film transistor substrate in which a plurality of pixels is provided in a matrix manner, wherein
each of said pixels includes:
a gate electrode selectively provided on a substrate,
a gate insulating film covering said gate electrode,
a semiconductor channel layer selectively provided on said gate insulating film, said semiconductor channel layer being formed by an oxide semiconductor film,
a protective insulating film provided on said semiconductor channel layer,
a first interlayer insulating film provided on said substrate to cover a laminated film of said protective insulating film and said semiconductor channel layer,
a source electrode and a drain electrode formed by a transparent conductive film, said source electrode and said drain electrode being separated from each other and directly in contact with said semiconductor channel layer via respective contact holes penetrating said first interlayer insulating film and said protective insulating film, and
a pixel electrode extending from said drain electrode, and wherein
a region between said source electrode and said drain electrode in said semiconductor channel layer forms a channel region,
a first light shielding film is provided on said protective insulating film to overlap with at least said channel region in plan view, and
a second light shielding film is provided on said source electrode and said drain electrode to overlap with said semiconductor channel layer and said first light shielding film in plan view.

2. The thin film transistor substrate according to claim 1, wherein
said first light shielding film is formed by a conductive film having light shielding properties and electrically separated from said source electrode and said drain electrode to be provided in an electrically floating state.

3. The thin film transistor substrate according to claim 1, wherein
said first light shielding film is formed by a conductive film having light shielding properties and electrically connected directly to one of said source electrode and said drain electrode.

4. The thin film transistor substrate according to claim 1, wherein
said second light shielding film is provided to cover regions from formation regions of said contact holes to a formation region of said first light shielding film in plan view.

5. The thin film transistor substrate according to claim 2, wherein
each of said pixels includes
a gate wiring in the same layer as said gate electrode provided on said substrate, and
a source wiring provided on said gate insulating film, and wherein
said source wiring is formed by a lower layer source wiring in the same layer as said first light shielding film formed on a laminated film of a semiconductor film in the same layer as said semiconductor channel layer and an insulating film in the same layer as said protective insulating film, and an upper layer source wiring in the same layer as said source electrode, the upper layer source wiring being extended from said source electrode.

6. The thin film transistor substrate according to claim 5, wherein
each of said pixels further includes
a common electrode provided on said substrate, said common electrode being in the same layer as said gate electrode and said gate wiring, and wherein
said common electrode is electrically separated from said gate wiring and provided in parallel with said gate wiring, and
said pixel electrode is provided to oppose said common electrode to overlap with at least a portion of said common electrode in plan view, and forms an auxiliary capacity for pixel electric potential between said pixel electrode and said common electrode via at least said first interlayer insulating film.

7. The thin film transistor substrate according to claim 5, wherein
each of said pixels includes
a second interlayer insulating film provided on said first interlayer insulating film to cover said source electrode, said drain electrode, and said pixel electrode,
a counter electrode provided to oppose said pixel electrode in plan view, said counter electrode being formed by a transparent conductive film on said second interlayer insulating film, and
a third light shielding film provided on said second interlayer insulating film to overlap with at least said semiconductor channel layer and said first and said second light shielding films in plan view.

8. The thin film transistor substrate according to claim 7, wherein
each of said pixels further includes
a common electrode provided on said substrate, said common electrode being in the same layer as said gate electrode and said gate wiring, and wherein
said common electrode is electrically separated from said gate wiring and provided in parallel with said gate wiring, and
said pixel electrode is provided to oppose said common electrode to overlap with at least a portion of said common electrode in plan view, and forms an auxiliary capacity for pixel electric potential between said pixel electrode and said common electrode via at least said first interlayer insulating film.

9. The thin film transistor substrate according to claim 8, wherein
said counter electrode is electrically connected to said common electrode via a contact hole penetrating said gate insulating film and said first and said second interlayer insulating films.

10. The thin film transistor substrate according to claim 7, wherein
said third light shielding film includes a laminated film of a lower layer film in the same layer as said counter electrode provided on said second interlayer insulating film, and an upper layer film formed by a conductive film having light shielding properties provided on said lower layer film.

11. A method for manufacturing a thin film transistor substrate comprising the steps of:
(a) forming a first conductive film on a substrate and forming a gate electrode by performing patterning;
(b) forming a first insulating film on said substrate to cover said gate electrode to form said gate insulating film;
(c) laminating an oxide semiconductor film, a second insulating film, and a second conductive film having light shielding properties in this order on said gate insulating film, and forming a semiconductor channel layer and a protective insulating film by forming a laminate by performing patterning;
(d) forming a first light shielding film by patterning said second conductive film to form a plurality of first contact holes reaching said second insulating film;
(e) forming a third insulating film on said substrate including said laminate to form a first interlayer insulating film;
(f) forming a plurality of second contact holes penetrating said first interlayer insulating film at respective portions corresponding to upper portions of said plurality of first contact holes, and said protective insulating film below said plurality of first contact holes to reach said semiconductor channel layer;
(g) forming a third conductive film on said first interlayer insulating film including insides of said plurality of second contact holes, and forming a source electrode, a drain electrode, and a pixel electrode by performing patterning; and
(h) forming a fourth conductive film having light shielding properties on said source electrode and said drain electrode, and forming a second light shielding film by performing patterning, wherein
in at least one of a combination of said step (c) and said step (d) and a combination of said step (g) and said step (h), photolithography steps are commonalized by forming a photoresist pattern equipped with a plurality of different film thicknesses and performing patterning using said photoresist pattern.

12. The method for manufacturing a thin film transistor substrate according to claim 11 comprising the steps of:
after said step (h),
(i) forming a second interlayer insulating film by forming a fourth insulating film above said first interlayer insulating film including a portion on said second light shielding film;
(j) forming a fifth conductive film on said second interlayer insulating film, and forming a counter electrode opposing said pixel electrode in plan view by performing patterning; and
(k) forming a sixth conductive film having light shielding properties above said second interlayer insulating film, and forming a third light shielding film overlapping with at least said semiconductor channel layer and said first and said second light shielding films in plan view by performing patterning, wherein
said step (j) and said step (k) commonalize a photolithography step of forming said counter electrode and said third light shielding film formed by a laminated film of said fifth conductive film and said sixth conductive film by laminating said fifth conducting film and said sixth conducting film on said second interlayer insulating film in this order, forming a photoresist pattern having a plurality of different film thicknesses, and performing patterning using the photoresist pattern.

13. The thin film transistor substrate according to claim 3, wherein
each of said pixels includes
a gate wiring in the same layer as said gate electrode provided on said substrate, and
a source wiring provided on said gate insulating film, and wherein
said source wiring is formed by a lower layer source wiring in the same layer as said first light shielding film formed on a laminated film of a semiconductor film in the same layer as said semiconductor channel layer and an insulating film in the same layer as said protective insulating film, and an upper layer source wiring in the same layer as said source electrode, the upper layer source wiring being extended from said source electrode.

14. The thin film transistor substrate according to claim 13, wherein
each of said pixels further includes
a common electrode provided on said substrate, said common electrode being in the same layer as said gate electrode and said gate wiring, and wherein
said common electrode is electrically separated from said gate wiring and provided in parallel with said gate wiring, and
said pixel electrode is provided to oppose said common electrode to overlap with at least a portion of said common electrode in plan view, and forms an auxiliary capacity for pixel electric potential between said pixel electrode and said common electrode via at least said first interlayer insulating film.

15. The thin film transistor substrate according to claim 13, wherein
each of said pixels includes
a second interlayer insulating film provided on said first interlayer insulating film to cover said source electrode, said drain electrode, and said pixel electrode,
a counter electrode provided to oppose said pixel electrode in plan view, said counter electrode being formed by a transparent conductive film on said second interlayer insulating film, and
a third light shielding film provided on said second interlayer insulating film to overlap with at least said semiconductor channel layer and said first and said second light shielding films in plan view.

16. The thin film transistor substrate according to claim 15, wherein
each of said pixels further includes
a common electrode provided on said substrate, said common electrode being in the same layer as said gate electrode and said gate wiring, and wherein
said common electrode is electrically separated from said gate wiring and provided in parallel with said gate wiring, and
said pixel electrode is provided to oppose said common electrode to overlap with at least a portion of said common electrode in plan view, and forms an auxiliary capacity for pixel electric potential between said pixel electrode and said common electrode via at least said first interlayer insulating film.

17. The thin film transistor substrate according to claim 16, wherein
said counter electrode is electrically connected to said common electrode via a contact hole penetrating said gate insulating film and said first and said second interlayer insulating films.

18. The thin film transistor substrate according to claim 15, wherein
said third light shielding film includes a laminated film of a lower layer film in the same layer as said counter electrode provided on said second interlayer insulating film, and an upper layer film formed by a conductive film having light shielding properties provided on said lower layer film.
